(19) United States
(12) Patent Application Publication
(10) Pub. No.: US 2025/0133865 A1
(43) Pub. Date: Apr. 24, 2025

(54) SOLDER BRIDGE METALLIZATION USING SOLDER BALL JETTING

(71) Applicant: POET Technologies, Inc., Allentown, PA (US)

(72) Inventors: SURESH VENKATESAN, Los Gatos, CA (US); SIMON BOOTHROYD, Allentown, PA (US); JING YANG, Singapore (SG); LUCAS SOLDANO, Allentown, PA (US); YONG MENG LEE, Allentown, PA (US)

(21) Appl. No.: 18/918,143

(22) Filed: Oct. 17, 2024

Related U.S. Application Data
(60) Provisional application No. 63/544,812, filed on Oct. 19, 2023.

(51) Int. Cl. H01L 31/02; H01L 31/024; H01L 31/18

(52) U.S. Cl. CPC H10F 77/933; H10F 71/128; H10F 77/60

(57) ABSTRACT

Wafer level solder ball bridge formation is used to provide electrical and thermal coupling between bond pads formed on substrates and bond pads formed on devices mounted on substrates. Solder balls anchored to solder-wettable bond pads enable sequential linking of laterally coupled solder balls over non-solder-wettable surface in the formation of solder ball bridge assemblies. Solder ball bridges formed between a device disposed on a substrate and a substrate enables thermal energy transfer and electrical interconnection between the device and the substrate.

This application claims priority to Provisional Application U.S. 63/544,812 filed on Oct. 19, 2023, hereby incorporated by reference in its entirety.

This application is related to application Ser. No. 17/499,323 now U.S. Pat. No. 11,686,906 issued on Jun. 27, 2023, hereby incorporated by reference in its entirety.

### FIELD OF THE INVENTION

The present invention relates to photonic integrated circuits and other integrated circuits and in particular, to photonic integrated circuits comprising integrated devices on an interposer substrate.

### BACKGROUND

Developments in methods of manufacturing of photonic integrated circuits (PICs) have enabled the fabrication and integration of electrical, optoelectrical, and optical devices on the same substrate. In some applications, pre-formed optoelectrical die are integrated within PICs to provide functionality that may not be easily obtainable with similar devices formed directly on or within the substrate. Semiconductor lasers that emit optical signals at specific wavelengths suited for optical communications, for example, are readily fabricated from indium phosphide materials. The fabrication of devices that emit at these telecommunications wavelengths is not practical or achievable using silicon or insulating substrates, and thus the integration of pre-formed lasers into PIC mounting structures, for example, provides a viable method of overcoming the limitations of photonic integrated circuits formed on these substrates. The integration of lasers and other optoelectrical die, and the integration of electrical die, in general, into PICs and ICs, however, requires the formation of electrical interconnections between electrical contacts on the mounted die and electrical connections on the substrate to which the die are mounted. Electrical contacts to mounted devices may be formed using flip chip technology to form electrical interconnections between the facing surfaces of the mounted chip and the substrate to which the mounted chip is mounted, and using wire bonding to form contacts between electrical contacts on the top sides of mounted chips and electrical contacts on the substrate to which the mounted chip is mounted.

Caution must be exercised with the use of wire bonding for the formation of electrical interconnections between electrical contacts on the exposed surfaces of mounted devices due to the potential for introducing excessive stress on the mounted die during the formation of the wire bond that may lead to fracturing of the mounted die, loss of integrity of electrical contacts formed on the underside of the mounted chip, among other detrimental effects. The use of wire bonding techniques is also largely limited to thin wire diameters that can lead to connections having high inductance and high resistance. Wire bonding is largely used for the wiring of packaged die and is generally not suitable for wafer level processing.

As methods of integration of optoelectrical and electrical devices onto substrates used in the formation of photonic and non-photonic integrated circuits have improved in recent years, further improvements would be enabled with the availability of techniques suitable for wafer level processing particularly in the formation of electrical interconnections between mounted devices and the substrate to which the mounted devices are mounted. Further improvements would be enabled with the availability of structures and techniques that enable the formation of low inductance electrical interconnections having low electrical resistance in comparison to current techniques. Low inductance electrical connections that utilize large cross-sectional areas can provide an additional benefit of increased thermal coupling between mounted devices and the substrates to which the devices are mounted.

The availability of such techniques will further contribute to the practicality and widespread adoption of photonic and non-photonic device integration, and to the formation of circuits using mounted devices.

Thus, a need in the art exists for the formation of interconnections between mounted devices and the substrates to which the mounted devices are mounted that provide improved electrical and thermal conductivity from the mounted devices and the substrate.

### BRIEF DESCRIPTION OF THE FIGURES

FIG. 1A shows a schematic cross-sectional drawing of an embodiment of an assembly comprising a substrate, a device disposed on the substrate, and a solder ball bridge wherein the solder ball bridge is formed between a horizontally-oriented bond pad formed on the substrate and a horizontally-oriented bond pad formed on the mounted device.

FIG. 1B shows a schematic top schematic drawing of the embodiment of the assembly shown in FIG. 1A.

FIG. 1C shows a schematic cross-sectional drawing of a portion of the embodiment of the assembly as in FIG. 1A comprising a substrate and a device disposed on the substrate without the solder ball bridge.

FIG. 1D shows a schematic cross-sectional drawing of another embodiment of an assembly comprising a substrate, a device disposed on the substrate, and a solder ball bridge wherein the solder ball bridge is formed between a horizontally-oriented bond pad on the substrate and a vertically-oriented bond pad on the device disposed on the substrate.

FIG. 1E shows a top view schematic drawing of the embodiment of the assembly shown in FIG. 1D.

FIG. 1F shows a schematic cross-sectional drawing of yet another embodiment of an assembly comprising a substrate, a first and second device disposed on the substrate, and a solder ball bridge wherein the solder ball bridge is formed between a vertically-oriented bond pad on the first device and a vertically-oriented bond pad on the second device.

FIG. 1G shows a top view schematic drawing of the embodiment of the assembly shown in FIG. 1F.

FIG. 1H shows a schematic cross-sectional drawing of yet another embodiment of an assembly comprising a substrate, a device disposed on the substrate, and a solder ball bridge wherein the solder ball bridge is formed between an angled bond pad on the device and a horizontally-oriented bond pad on the substrate.

FIG. 1I shows a schematic cross-sectional drawing of yet another embodiment of an assembly comprising a substrate, a first and second device disposed on the substrate, and a solder ball bridge wherein the solder ball bridge is formed between angled bond pads on the first and second devices.

FIG. 1J shows a schematic cross-sectional drawing of yet another embodiment of an assembly comprising a substrate, a device disposed on the substrate, and a solder ball bridge wherein the solder ball bridge is formed between an angled bond pad on the device and a horizontally-oriented bond pad on the substrate wherein the angled bond pad on the device is at an angle such that the surface of the bond pad is substantially downward facing. INSET shows a top-down view of an example configuration of solder balls in the embodiment of the assembly.

FIG. 2A shows a schematic drawing of a portion of a typical solder ball jetting apparatus.

FIG. 2B shows a perspective drawing of a portion of a solder ball jetting apparatus and a substrate having a plurality of die for which the solder ball jetting apparatus forms solder ball bridges.

FIG. 2C shows a solder ball bridge formed on a solder-wettable surface on which solder balls are disposed.

FIG. 2D shows a schematic top view drawing of a photonic integrated circuit assembly having a plurality of instances of an embodiment of an assembly.

FIG. 2E shows a schematic top view drawing of a photonic integrated circuit assembly having a plurality of solder ball bridge assemblies each comprising the substrate, a mounted device, and a solder ball bridge wherein the substrate further comprises heatsinks coupled to a terminal end of the solder ball bridges.

FIG. 3A shows a schematic top view drawing of a portion of a photonic integrated circuit assembly having contact pads receptive to solder balls used in the formation of solder ball bridges.

FIG. 3B shows a schematic top view drawing of the portion of the photonic integrated circuit assembly shown in FIG. 3A after formation of embodiments of solder ball bridges coupled to the bond pads.

FIG. 3C shows a schematic top view drawing of the portion of the photonic integrated circuit assembly shown in FIG. 3A having solder ball bridges coupled to a plurality of the contact pads and having wire bonds coupled to a plurality of other contact pads to form a photonic integrated circuit assembly having both solder ball bridges and wirebonds.

FIG. 4A shows a schematic top view drawing of a photonic integrated circuit assembly having a plurality instances of another embodiment of an assembly comprising a substrate, a mounted device, and a solder ball bridge wherein a terminal end of each solder ball bridge is coupled to a vertically-oriented bond pad formed on the mounted device.

FIG. 4B shows a schematic perspective drawing of a substrate having a plurality of die and further shows a portion of a pick-and-place apparatus for placement of devices onto the substrate.

FIG. 4C shows a schematic perspective drawing of a portion of a solder ball jetting apparatus and a substrate having a plurality of die for which the solder ball jetting apparatus forms solder ball bridges each having a terminal end that forms a contact with a vertically-oriented surface of the mounted die on the substate.

FIGS. 5A-5F show schematic drawings of embodiments of solder ball bridge assemblies comprising a substrate, a mounted device, and a solder ball bridge wherein the solder ball bridge is formed from a single solder ball

FIG. 5A shows a top view schematic drawing of an embodiment of an assembly comprising a substrate, a mounted device, and a solder ball bridge wherein the solder ball bridge is formed from a single solder ball disposed on horizontally-oriented bond pads formed on the substrate and the mounted device.

FIG. 5B shows a cross-sectional schematic drawing of the embodiment of the assembly shown in FIG. 5A

FIG. 5C shows a top view schematic drawing of an embodiment of an assembly comprising a substrate, a mounted device, and a solder ball bridge wherein the solder ball bridge is formed from a single solder ball disposed on a horizontally-oriented bond pad formed on the substrate and a vertically-oriented bond pad formed on the mounted device.

FIG. 5D shows a cross-sectional schematic drawing of the embodiment of the assembly shown in FIG. 5C.

FIG. 5E shows a top view schematic drawing of an embodiment of an assembly comprising a substrate, a mounted device, and a solder ball bridge wherein the solder ball bridge is formed from a single solder ball disposed between vertically-oriented bond pads formed on the substrate and the mounted device.

FIG. 5F shows a cross-sectional schematic drawing of the embodiment of the assembly shown in FIG. 5E.

FIGS. 6A-6F show schematic drawings of embodiments of solder ball bridge assemblies comprising a substrate, a mounted device, and a solder ball bridge wherein the solder ball bridge is formed from two solder balls.

FIG. 6A shows a top view schematic drawing of an embodiment of an assembly comprising a substrate, a mounted device, and a solder ball bridge wherein the solder ball bridge is formed from two solder balls disposed on horizontally-oriented bond pads formed on the substrate and the mounted device.

FIG. 6B shows a cross-sectional schematic drawing of the embodiment of the assembly shown in FIG. 6A.

FIG. 6C shows a top view schematic drawing of an embodiment of an assembly comprising a substrate, a mounted device, and a solder ball bridge formed from two solder balls disposed on a horizontally-oriented bond pad formed on the substrate and a vertically-oriented bond pad formed on the mounted device.

FIG. 6D shows a cross-sectional schematic drawing of the embodiment of the assembly shown in FIG. 6C.

FIG. 6E shows a top view schematic drawing of an embodiment of an assembly comprising a substrate, a mounted device, and a solder ball bridge formed from two solder balls disposed on vertically-oriented bond pads formed on the substrate and the mounted device.

FIG. 6F shows a cross-sectional schematic drawing of the embodiment of the assembly shown in FIG. 6E.

FIG. 7A shows a cross-sectional schematic drawing of a solder ball disposed on a bond pad wherein the solder ball is disposed with an accompanying “low” laser energy such that the spheroidal shape of the solder ball is maintained at least in part.

FIG. 7B shows a cross-sectional schematic drawing of the bond pad of FIG. 7A after deposition of a second solder ball.

FIG. 7C shows a cross-sectional schematic drawing of a solder ball disposed on a bond pad wherein the solder ball is disposed with an accompanying “high” laser energy such that the spheroidal shape of the solder ball is no longer distinguishable as the solder from the solder ball is distributed across the solder-wettable surface of the bond pad.

FIG. 7D shows a cross-sectional schematic drawing of the bond pad of FIG. 7C after deposition of a second solder ball.

FIG. 7E shows a cross-sectional schematic drawing of an embodiment of an assembly comprising a substrate, a mounted device, and a solder ball bridge wherein the solder ball bridge is formed between two horizontally-oriented bond pads and wherein the solder balls are deposited using a “low” laser energy to maintain the spheroidal shape of the solder balls.

FIG. 7F shows a cross-sectional schematic drawing of the embodiment of the solder ball bridge of FIG. 7E, for example, after post-deposition heating.

FIG. 7G shows a cross-sectional schematic drawing of an embodiment of an assembly comprising a substrate, a mounted device, and a solder ball bridge wherein the solder ball bridge is formed between two horizontally-oriented bond pads using a plurality of nominal solder ball sizes and wherein the solder balls are deposited using a “low” laser energy to maintain the spheroidal shape of the solder balls.

FIG. 7H shows a cross-sectional schematic drawing of the embodiment of the solder ball bridge of FIG. 7G, for example, after post-deposition heating.

FIGS. 8A-8D show steps in the formation of embodiments of solder ball bridge assemblies comprising a substrate, a mounted device, and a solder ball bridge 101 wherein the solder balls used in the formation of the solder ball bridges are deposited with accompanying “high” energy levels such that the original spheroidal shapes of the solder balls are not distinguishable after deposition.

FIG. 8A shows a cross-sectional schematic drawing of a portion of an embodiment of an assembly comprising a substrate and a mounted device wherein a bond pad on the mounted device is shown having two solder balls deposited with accompanying “high” laser energy and a bond pad on the substrate is shown having one solder ball deposited with “high” accompanying laser energy.

FIG. 8B shows a cross-sectional schematic drawing of the two bond pads of FIG. 8A after deposition of a second solder ball onto the bond pad of the substrate wherein the second solder ball is also deposited with accompanying “high” laser energy.

FIG. 8C shows a cross-sectional schematic drawing of the two bond pads of FIG. 8B and a fifth solder ball just prior to the formation of the solder ball bridge.

FIG. 8D shows a cross-sectional schematic drawing of an embodiment of an assembly comprising a substrate, a mounted device, and a solder ball bridge formed from the five solder balls disposed on the two horizontally-oriented bond pads as in FIGS. 8A-8C, wherein the bond pads are formed on the substrate and the mounted device and wherein the solder balls are deposited with accompanying “high” laser energy.

FIGS. 9A-9D show steps in the formation of an embodiment of an assembly comprising a substrate, a mounted device, and a solder ball bridge having four solder balls.

FIG. 9A shows a top view schematic drawing of a portion of an embodiment of an assembly comprising a substrate, a mounted device, and a partially formed solder ball bridge wherein the substrate and mounted device are configured having horizontally-oriented bond pads.

FIG. 9A shows a top view schematic drawing of a portion of an embodiment of an assembly comprising a substrate, a mounted device, and a partially formed solder ball bridge wherein the order of placement of the first three solder balls into the assembly, for the embodiment, corresponds to the subscript of the solder ball label.

FIG. 9B shows a cross-sectional schematic drawing of the portion of the embodiment of the assembly of FIG. 9A

FIG. 9C shows a top view schematic drawing of an embodiment of the assembly comprising the substrate, mounted device, and solder ball bridge of FIGS. 9A and 9B after deposition of a fourth solder ball to complete the formation of the solder ball bridge.

FIG. 9D shows a cross-sectional schematic drawing of the embodiment of the assembly of FIG. 9C.

FIG. 10A shows a cross-sectional schematic drawing of a portion of an embodiment of an assembly comprising a substrate, a mounted device, and a partially formed solder ball bridge wherein the substrate and mounted device are configured having horizontally-oriented bond pads and wherein the bond pads are configured having surface area larger than the coverage area of a solder ball.

FIG. 10B shows a cross-sectional schematic drawing of an embodiment of an assembly comprising the substrate, mounted device, and portion of the solder ball bridge of FIG. 10A after deposition of a fifth solder ball to complete the formation of the solder ball bridge.

FIG. 11A shows a top view schematic drawing of an embodiment of an assembly comprising a substrate, a mounted device, and a solder ball bridge wherein the solder ball bridge is formed from a plurality of solder balls and wherein the plurality of solder balls comprises two or more nominal diameters.

FIG. 11B shows a cross-sectional schematic drawing of the embodiment of the assembly of FIG. 11A.

FIG. 12A shows a cross-sectional schematic drawing of an embodiment of an assembly comprising a substrate, a mounted device, and a solder ball bridge wherein the mounted device is configured having a vertically-oriented bond pad and the substrate is configured having a horizontally-oriented bond pad, and wherein the solder ball bridge comprises four laterally couple solder balls.

FIG. 12B shows a cross-sectional schematic drawing of an embodiment of an assembly comprising a substrate, a mounted device, and a solder ball bridge wherein the mounted device is configured having a vertically-oriented bond pad and the substrate is configured having a horizontally-oriented bond pad, and wherein the solder ball bridge comprises five laterally coupled solder balls.

FIG. 13 shows a cross-sectional schematic drawing of an embodiment of an assembly comprising a substrate, a first mounted device, a second mounted device, and a solder ball bridge wherein the first and second mounted devices are configured having vertically-oriented bond pads.

FIG. 14A shows the cross-sectional schematic drawing of an embodiment of an assembly comprising a substrate, a mounted device, and a solder ball bridge wherein the solder ball bridge forms an arch over the spacing between the bond pads.

FIG. 14B shows the top view schematic drawing of the embodiment of the assembly of FIG. 14A.

FIG. 15A shows a cross-sectional schematic drawing of an embodiment of an assembly comprising a substrate, a mounted device, and a solder ball bridge wherein the top surfaces of the bond pads formed on the substrate and the mounted device are at differing elevations.

FIG. 15B shows a top view schematic drawing of the embodiment of FIG. 15A.

FIG. 15C shows a cross-sectional schematic drawing of another embodiment of an assembly comprising a substrate, a mounted device, and a solder ball bridge wherein the top surfaces of the bond pads formed on the substrate and the mounted device are at differing elevations.

FIG. 15D shows a top view schematic drawing of the embodiment of FIG. 15C.

FIGS. 16A-16E show cross-sectional schematic drawings of embodiments of solder ball bridge assemblies comprising a substrate, a mounted device, and a solder ball bridge wherein the assemblies further comprise a layer having a high thermal conductivity coupled to a bond pad formed at a terminal end of the solder ball bridge.

FIG. 16A shows a cross-sectional schematic drawing of an embodiment of an assembly comprising a substrate, a mounted device, and a solder ball bridge wherein the assembly further comprises a layer having a high thermal conductivity formed in the substrate.

FIG. 16B shows a cross-sectional schematic drawing of an embodiment of another assembly comprising a substrate, a mounted device, and a solder ball bridge wherein the assembly further comprises a layer having a high thermal conductivity formed on the substrate.

FIG. 16C shows a cross-sectional schematic drawing of an embodiment of an assembly comprising a substrate, a mounted device, and a solder ball bridge wherein the assembly further comprises a layer having a high thermal conductivity formed within the substrate and connected to a bond pad formed at a terminal end of the solder ball bridge.

FIG. 16D shows a cross-sectional schematic drawing of an embodiment of an assembly comprising a substrate, a mounted device, and a solder ball bridge wherein the assembly further comprises a layer having a high thermal conductivity formed in a via within the substrate.

FIG. 16E shows a cross-sectional schematic drawing of an embodiment of an assembly comprising a substrate, a mounted device, and a solder ball bridge wherein the assembly further comprises a layer having a high thermal conductivity formed in the substrate and coupled to a bond pad at a terminal end of the solder ball bridge through an electrical interconnect layer.

FIGS. 17A-17D show cross-sectional schematic drawings of embodiments of solder ball bridge assemblies comprising a substrate, a mounted device, and a solder ball bridge wherein the assemblies further comprise a heat sink formed in a trench in the substrate and wherein the solder ball bridges are extended into the trenches.

FIG. 17A shows a cross-sectional schematic drawing of an embodiment of an assembly comprising a substrate, a mounted device, and a solder ball bridge wherein the assembly further comprises a trench and wherein a terminal end of the solder ball bridge is extended to the trench bottom.

FIG. 17B shows a cross-sectional schematic drawing of an embodiment of an assembly comprising a substrate, a mounted device, and a solder ball bridge wherein the assembly further comprises a trench and wherein a terminal end of the solder ball bridge is extended to the trench bottom for an embodiment in which the solder balls in the substrate are heated to conform the solder balls disposed in the trench to the walls of the trench.

FIG. 17C shows a cross-sectional schematic drawing of an embodiment of an assembly comprising a substrate, a mounted device, and a solder ball bridge wherein the assembly further comprises a trench coupled to one or more high thermal conductivity layers and wherein a terminal end of the solder ball bridge is extended to the one or more high thermal conductivity layers that intersect the trench.

FIG. 17D shows a cross-sectional schematic drawing of an embodiment of an assembly comprising a substrate, a mounted device, and a solder ball bridge wherein the assembly further comprises a trench coupled to a high thermal conductivity layer that intersects the bottom of the trench, and a high thermal conductivity layer that intersects the sidewall of the trench, wherein deposited solder balls in the substrate are heated to conform the solder balls disposed in the trench to the walls of the trench, and wherein a terminal end of the solder ball bridge is coupled to the conforming solder balls coupled to the thermally conductive layers at the bottom of the trench and at the sidewall of the trench.

FIG. 17E shows a cross-sectional schematic drawing of an embodiment of an assembly comprising a substrate, a mounted device, and a solder ball bridge wherein the assembly further comprises a trench coupled to an electrical interconnect layer and an optional thermally conductive layer and wherein a terminal end of the solder ball bridge is extended to the electrical interconnect layer at the trench bottom.

FIGS. 18A-18H show cross-sectional schematic drawings of embodiments of solder ball bridge assemblies comprising a substrate, a device, and a solder ball bridge wherein a bond pad at a terminal end of the solder ball bridge is further coupled to an electrical interconnect layer formed in the substrate.

FIG. 18A shows a cross-sectional schematic drawing of an embodiment of an assembly comprising a substrate, a device, and a solder ball bridge wherein the device is formed on the substrate and the solder ball bridge is formed between a horizontally-oriented bond pad on the device and a horizontally-oriented bond pad on the substrate, and wherein the bond pad on the substrate is further coupled to an electrical interconnect layer formed in the substrate.

FIG. 18B shows a cross-sectional schematic drawing of an embodiment of an assembly comprising a substrate, a device, and a solder ball bridge wherein the device is formed on the substrate and the solder ball bridge is formed between a vertically-oriented bond pad on the device and a horizontally-oriented bond pad on the substrate, and wherein the bond pad on the substrate is further coupled to an electrical interconnect layer formed in the substrate.

FIG. 18C shows a cross-sectional schematic drawing of an embodiment of an assembly comprising a substrate, a mounted device, and a solder ball bridge wherein the mounted device is a surface-mounted device and the solder ball bridge is formed between a horizontally-oriented bond pad on the surface mounted device and a horizontally-oriented bond pad on the substrate, and wherein the bond pad on the substrate is further coupled to an electrical interconnect layer formed in the substrate.

FIG. 18D shows a cross-sectional schematic drawing of an embodiment of an assembly comprising a substrate, a mounted device, and a solder ball bridge wherein the mounted device is a surface-mounted device and the solder ball bridge is formed between a vertically-oriented bond pad on the surface mounted device and a horizontally-oriented bond pad on the substrate, and wherein the bond pad on the substrate is further coupled to an electrical interconnect layer formed in the substrate.

FIG. 18E shows a cross-sectional schematic drawing of an embodiment of an assembly comprising a substrate, a mounted device, and a solder ball bridge wherein the mounted device is mounted in a cavity formed in the substrate, and the solder ball bridge is formed between a horizontally-oriented bond pad on the cavity mounted device and a horizontally-oriented bond pad on the substrate, and wherein the bond pad on the substrate is further coupled to an electrical interconnect layer formed in the substrate.

FIG. 18F shows a cross-sectional schematic drawing of an embodiment of an assembly comprising a substrate, a mounted device, and a solder ball bridge wherein the mounted device is mounted in a cavity formed in the substrate, and the solder ball bridge is formed between a vertically-oriented bond pad on the cavity mounted device and a horizontally-oriented bond pad on the substrate, and wherein the bond pad on the substrate is further coupled to an electrical interconnect layer formed in the substrate.

FIG. 18G shows a cross-sectional schematic drawing of the embodiment of the assembly as in FIG. 18E having a plurality of high thermal conductivity layers formed in the substrate.

FIG. 18H shows a cross-sectional schematic drawing of an embodiment of an assembly comprising a substrate, a mounted device, and a solder ball bridge wherein the mounted device is mounted in a cavity formed in the substrate, and wherein the solder ball bridge is formed between a vertically-oriented bond pad on the cavity mounted device and a horizontally-oriented bond pad on the substrate, and wherein the bond pad on the substrate is further coupled to electrical interconnect layers formed in and on the substrate.

FIGS. 19A-19E show cross-sectional schematic drawings of embodiments of solder ball bridge assemblies comprising a substrate, a mounted device, and a solder ball bridge wherein a terminal end of the solder ball bridge is coupled to a radiative solder ball array.

FIG. 19A shows a cross-sectional schematic drawing of an embodiment of an assembly comprising a substrate, a mounted device, and a solder ball bridge wherein a terminal end of the solder ball bridge is coupled to one or more of a high thermal conductivity layer and an electrical interconnect layer, and wherein the one or more of the high thermal conductivity layer and the electrical interconnect layer are further coupled to a radiative solder ball array formed on bond pads further formed on the one or more of the high thermal conductivity layer and electrical interconnect layer.

FIG. 19B shows a cross-sectional schematic drawing of an embodiment of an assembly comprising a substrate, a mounted device, and a solder ball bridge wherein a terminal end of the solder ball bridge is coupled to one or more of a high thermal conductivity layer and an electrical interconnect layer, and wherein the one or more of a high thermal conductivity layer and electrical interconnect layer are further coupled to a radiative solder ball array formed on bond pads further formed on the one or more of a high thermal conductivity layer and electrical interconnect layer, and wherein the radiative solder ball array is configured having one or more stacked solder balls.

FIG. 19C shows a cross-sectional schematic drawing of an embodiment of an assembly comprising a substrate, a mounted device, and a solder ball bridge wherein a terminal end of the solder ball bridge is coupled to one or more of a high thermal conductivity layer and an electrical interconnect layer, and wherein the one or more of a high thermal conductivity layer and electrical interconnect layer are further coupled to a radiative solder ball array formed on bond pads further formed on the one or more of a high thermal conductivity layer and electrical interconnect layer, and wherein the one or more of the solder balls in the radiative solder ball array are laterally coupled.

FIG. 19D shows a cross-sectional schematic drawing of the embodiment of the assembly shown in FIG. 19C with the inclusion of one or more stacks of solder balls wherein one or more of the solder balls in the stack of solder balls are laterally coupled.

FIG. 19E shows a cross-sectional schematic drawing of an embodiment of an assembly comprising a substrate, a mounted device, and a solder ball bridge wherein a terminal end of the solder ball bridge is coupled to one or more of a high thermal conductivity layer and an electrical interconnect layer, and wherein the one or more of the high thermal conductivity layer and electrical interconnect layer are further coupled to a radiative solder ball array formed on a solder-wettable surface of the one or more of the high thermal conductivity layer and electrical interconnect layer, and wherein the one or more of the solder balls in the radiative solder ball array are laterally coupled.

FIGS. 20A-20C show top view schematic drawings of embodiments of solder ball bridge assemblies comprising a substrate, a mounted device, and a solder ball bridge wherein a terminal end of the solder ball bridge is coupled to a radiative solder ball array.

FIG. 20A shows a top view schematic drawing of an embodiment of an assembly comprising a substrate, a mounted device, and a solder ball bridge wherein a terminal end of the solder ball bridge is coupled to a radiative solder ball array comprising a row of solder balls and wherein the radiative solder ball array is formed on one or more of a high thermal conductivity layer and an electrical interconnect layer.

FIG. 20B shows a top view schematic drawing of an embodiment of an assembly comprising a substrate, a mounted device, and a solder ball bridge wherein a terminal end of the solder ball bridge is coupled to a radiative solder ball array comprising a plurality of solder balls configured in a multidimensional array, and wherein the radiative solder ball array is formed on one or more of a high thermal conductivity layer and an electrical interconnect layer.

FIG. 20C shows a top view schematic drawing of an embodiment of an assembly comprising a substrate, a mounted device, and a solder ball bridge wherein a terminal end of the solder ball bridge is coupled to a radiative solder ball array comprising a plurality of solder balls configured in another embodiment of a multidimensional array, and wherein the radiative solder ball array is formed on one or more of a high thermal conductivity layer and an electrical interconnect layer.

FIGS. 21A-21C show top view schematic drawings of embodiments of solder ball bridge assemblies comprising a substrate, a mounted device, and a solder ball bridge wherein a terminal end of the solder ball bridge is coupled to a radiative solder ball array, and wherein one or more of the solder balls in the radiative solder ball array are laterally coupled.

FIG. 21A shows a top view schematic drawing of an embodiment of an assembly comprising a substrate, a mounted device, and a solder ball bridge wherein a terminal end of the solder ball bridge is coupled to a radiative solder ball array comprising a plurality of solder balls configured in a multidimensional array, wherein the radiative solder ball array is formed on one or more of a high thermal conductivity layer and an electrical interconnect layer, and wherein two or more of the solder balls in the radiative solder ball array are laterally coupled.

FIG. 21B shows a top view schematic drawing of an embodiment of an assembly comprising a substrate, a mounted device, and a solder ball bridge wherein a terminal end of the solder ball bridge is coupled to a radiative solder ball array comprising a plurality of solder balls configured in another embodiment of a multidimensional radiative solder ball array, wherein the multidimensional radiative solder ball array is formed on one or more of a high thermal conductivity layer and an electrical interconnect layer, and wherein two or more of the solder balls in the multidimensional radiative solder ball array are laterally coupled.

FIG. 21C shows a top view schematic drawing of an embodiment of an assembly comprising a substrate, a mounted device, and a solder ball bridge wherein a terminal end of the solder ball bridge is coupled to a radiative solder ball array comprising a plurality of solder balls configured in yet another embodiment of a multidimensional radiative solder ball array, wherein the multidimensional radiative solder ball array is formed on one or more of a high thermal conductivity layer and an electrical interconnect layer, and wherein two or more of the solder balls in the multidimensional radiative solder ball array are laterally coupled.

FIGS. 22A-22C show cross-sectional schematic drawings of embodiments of solder ball bridge assemblies comprising a substrate, a mounted device, and a solder ball bridge wherein the substrate further comprises a planar waveguide layer formed on an electrical interconnect layer and wherein the mounted device is mounted in a cavity that intersects the optical axis of the planar waveguide layer.

FIG. 22A shows a cross-sectional schematic drawing of an embodiment of an assembly comprising an interposer substrate, a mounted device, and a solder ball bridge wherein the interposer substrate further comprises a planar waveguide layer formed on an electrical interconnect layer, wherein the mounted device is mounted in a cavity that intersects the core layer of a patterned planar waveguide, and wherein the solder ball bridge is formed between a horizontally-oriented bond pad formed on the mounted device and a horizontally-oriented bond pad formed on the interposer substrate.

FIG. 22B shows a cross-sectional schematic drawing of an embodiment of an assembly comprising an interposer substrate, a mounted device having a horizontally-oriented bond pad, and a solder ball bridge wherein a terminal end of the solder ball bridge extends into a trench formed in the interposer substrate, and wherein the extension of the solder ball bridge into the trench forms all or a portion of a heat sink.

FIG. 22C shows a cross-sectional schematic drawing of an embodiment of an assembly comprising a substrate, a mounted device having a vertically-oriented bond pad, and a solder ball bridge wherein a terminal end of the solder ball bridge extends into a trench formed in the interposer substrate, and wherein the extension of the solder ball bridge into the trench forms all or a portion of a heat sink.

FIG. 23A shows a cross-sectional schematic drawing of an embodiment of a photonic integrated circuit assembly formed on an interposer substrate that includes two assemblies each comprising the interposer substrate, a mounted device having either a vertically-oriented bond pad or a horizontally-oriented bond pad, and a solder ball bridge wherein the interposer substrate comprises a planar waveguide layer on an electrical interconnect layer and wherein the solder ball bridges are formed between a bond pad on a mounted device and a bond pad on the interposer substrate.

FIG. 23B shows a cross-sectional schematic drawing of an embodiment of a photonic integrated circuit assembly formed on an interposer substrate that includes two assemblies each comprising the interposer substrate, a mounted device having a vertically-oriented bond pad and mounted in a cavity, and a solder ball bridge.

FIGS. 24A-24F show cross-sectional schematic drawings of embodiments of solder ball bridge assemblies comprising a substrate, a plurality of mounted devices, and a plurality of solder ball bridges wherein the substrate further comprises a planar waveguide layer formed on an electrical interconnect layer and wherein one or more of the mounted devices may be mounted in a cavity that intersects the optical axis of the planar waveguide layer and wherein the solder ball bridges are formed between the mounted devices of the plurality of mounted devices.

FIG. 24A shows a cross-sectional schematic drawing of a photonic integrated circuit assembly having two assemblies wherein the mounted devices are cavity-mounted devices.

FIG. 24B shows a cross-sectional schematic drawing of an embodiment of a photonic integrated circuit assembly having an assembly comprising an interposer substrate, a mounted device, and a solder ball bridge wherein the mounted device is mounted in a cavity formed from the planar waveguide layer of the interposer substrate, and wherein the integrated circuit assembly is further configured having surface-mounted devices comprising a first mounted device and a second mounted device wherein a first terminal end of the solder ball bridge is coupled to bond pad of the first mounted device and a second terminal end of the solder ball bridge is coupled to a bond pad of the second mounted device.

FIG. 24C shows a cross-sectional schematic drawing of an embodiment of a photonic integrated circuit assembly comprising the solder ball bridge assembly of FIG. 24B wherein the solder ball bridge assembly comprises an interposer substrate, a mounted device mounted in a cavity formed in the planar waveguide layer of the interposer substrate, and a solder ball bridge, and wherein the integrated circuit assembly is further configured having surface-mounted devices comprising a first mounted device and a second mounted device, wherein a wirebond is used to form an electrical interconnect between a bond pad of the first mounted device and a bond pad of the second mounted device.

FIG. 24D shows a cross-sectional schematic drawing of an embodiment of a photonic integrated circuit assembly configured having a surface-mounted device on a surface-mounted submount wherein the surface-mounted submount is further mounted on an interposer substrate, and wherein solder ball bridges are used to form interconnections between the surface mounted device on the submount and the surface-mounted submount, and wherein solder ball bridges are further used to form interconnections between the surface-mounted submount and a cavity-mounted device mounted on the interposer substrate.

FIG. 24E shows a cross-sectional schematic drawing of the embodiment of the photonic integrated circuit assembly as in FIG. 24D wherein wirebonds are used to form interconnections between mounted devices and the submount and solder ball bridges are used to form interconnections between the submount and the interposer substrate.

FIG. 24F shows a cross-sectional schematic drawing of an embodiment of a photonic integrated circuit assembly configured having a cavity-mounted device on a cavity-mounted submount wherein solder ball bridges are used to form interconnections between the cavity-mounted device on the submount and the cavity-mounted submount and are further used to form interconnections between the cavity-mounted submount and the interposer substrate.

FIG. 25A shows a cross-sectional schematic drawing of an embodiment of an assembly comprising an interposer substrate, a mounted device, and a solder ball bridge wherein the interposer substrate comprises a planar waveguide layer formed on an electrical interconnect layer, and wherein the mounted device is mounted in a cavity having alignment aids formed from planar waveguide layer.

FIG. 25B shows an enlarged portion of the cross-sectional schematic drawing of the embodiment shown in FIG. 25A.

FIG. 26A shows a top view schematic drawing of a photonic integrated circuit assembly formed on an interposer structure wherein the photonic integrated circuit assembly includes multiple instances of embodiments of solder ball bridge assemblies comprising the substrate, a mounted device, and a solder ball bridge and wherein the mounted devices are formed in cavities having self-aligned alignment features that enable lateral alignment of the mounted devices. (Note: the self-aligned features formed from the planar waveguide layer of the interposer structure are shown highlighted with black fill).

FIG. 26B shows Section A-A′ from FIG. 26A. (Note: the self-aligned features formed from the planar waveguide layer of the interposer structure are shown highlighted with black fill).

FIG. 26C shows Section B-B′ from FIG. 26A. (Note: the self-aligned features formed from the planar waveguide layer of the interposer structure are shown highlighted with black fill).

FIG. 27A shows a top view schematic drawing of the interposer structure from the photonic integrated circuit assembly of FIG. 26A without the mounted devices, without the solder ball bridges, and without the mounted optical fiber (Note: the self-aligned features formed from the planar waveguide layer of the interposer structure are shown highlighted with black fill).

FIG. 27B shows Section A-A′ from FIG. 27A. (Note: the self-aligned features formed from the planar waveguide layer of the interposer structure are shown highlighted with black fill).

FIG. 27C shows Section B-B′ from FIG. 27A. (Note: the self-aligned features formed from the planar waveguide layer of the interposer structure are shown highlighted with black fill).

FIG. 28A shows a top view schematic drawing of a photonic integrated circuit assembly formed on an interposer structure wherein the photonic integrated circuit assembly includes multiple instances of embodiments of solder ball bridge assemblies comprising the substrate, a mounted device, and a solder ball bridge and wherein the mounted devices are formed in cavities having self-aligned alignment pillars enabling both lateral and vertical alignment of the mounted device. (Note: the self-aligned features formed from the planar waveguide layer of the interposer structure are shown highlighted with black fill; hidden self-aligned features are filled with checkerboard pattern).

FIG. 28B shows Section A-A′ from FIG. 28A. (Note: the self-aligned features formed from the planar waveguide layer of the interposer structure are shown highlighted with black fill).

FIG. 28C shows Section B-B′ from FIG. 28A. (Note: the self-aligned features formed from the planar waveguide layer of the interposer structure are shown highlighted with black fill).

FIG. 29A shows a top view schematic drawing of the interposer structure from the photonic integrated circuit assembly of FIG. 28A without the mounted devices, without the solder ball bridges, and without the mounted optical fiber (Note: the self-aligned features formed from the planar waveguide layer of the interposer structure are shown highlighted with black fill).

FIG. 29B shows Section A-A′ from FIG. 29A. (Note: the self-aligned features formed from the planar waveguide layer of the interposer structure are shown highlighted with black fill).

FIG. 29C shows Section B-B′ from FIG. 29A. (Note: the self-aligned features formed from the planar waveguide layer of the interposer structure are shown highlighted with black fill).

FIG. 30 shows a flowchart for a method of forming an interposer structure having self-aligned alignment features formed from the planar waveguide layer.

FIGS. 31A-31E show cross-sectional schematic drawings of some steps in the formation of an interposer structure having self-aligned alignment features wherein the cross sections are taken through the location of Section A-A′ of FIG. 29A.

FIG. 31A shows an interposer structure comprising a planar waveguide core layer, a cladding layer, and an electrical interconnect layer on a substrate (after Step 191-1 of method 191).

FIG. 31B shows the interposer structure of FIG. 31A after formation of a patterned hard mask and subsequent patterning of the planar waveguide core layer (after Steps 191-2 and 191-3 of method 191).

FIG. 31C shows the interposer structure of FIG. 31B after formation of a second patterned mask layer and removal of first patterned mask layer from patterned planar waveguides (after Step 191-4 of method 191).

FIG. 31D shows the interposer structure of FIG. 31C after removal of the second patterned mask layer, formation of a top cladding layer, and formation of a third patterned mask layer, wherein the third patterned mask layer includes patterned portions to facilitate the formation of one or more cavities in the planar waveguide layer (after Step 191-5 of method 191).

FIG. 31E shows the interposer structure of FIG. 31D after formation of cavities in the planar waveguide layer and subsequent removal of the third patterned mask layer (after Step 191-6 of method 191).

FIGS. 32A-32E show cross-sectional schematic drawings of some steps in the formation of an interposer structure having self-aligned alignment features. Cross sections are taken through the location of Section B-B′ of FIG. 29A.

FIG. 32A shows an interposer structure comprising a planar waveguide core layer, a cladding layer, and an electrical interconnect layer on a substrate (after Step 191-1 of method 191).

FIG. 32B shows the interposer structure of FIG. 32A after formation of a patterned hard mask and subsequent patterning of the planar waveguide core layer (after Steps 191-2 and 191-3 of method 191).

FIG. 32C shows the interposer structure of FIG. 32B after formation of a second patterned mask layer and removal of first patterned mask layer from patterned planar waveguides; note: patterned planar waveguides not present in this section. (after Step 191-4 of method 191).

FIG. 32D shows the interposer structure of FIG. 32C after removal of the second patterned mask layer, formation of a top cladding layer, and formation of a third patterned mask layer, wherein the third patterned mask layer includes patterned portions to facilitate the formation of one or more cavities in the planar waveguide layer (after Step 191-5 of method 191).

FIG. 32E shows the interposer structure of FIG. 32D after formation of cavities in the planar waveguide layer and subsequent removal of the third patterned mask layer (after Step 191-6 of method 191).

FIG. 33A shows schematic perspective drawings that illustrate aspects of the alignment of the optical axes of two optical devices.

FIG. 33B shows schematic perspective drawings that illustrate aspects of the alignment of the optical axes of a mounted device in a cavity and a patterned planar waveguide core that intersects the wall of the cavity.

FIGS. 34A-34F show cross-sectional schematic drawings of embodiments of solder ball bridge assemblies comprising a substrate, a mounted device, and a solder ball bridge that illustrate the potential benefits of post-deposition heating on a number of configurations of solder ball bridges.

FIG. 34A shows a cross-sectional schematic drawing of an embodiment of an assembly comprising a substrate having a horizontally-oriented bond pad, a mounted device having a horizontally-oriented bond pad, and a solder ball bridge formed between the bond pad on the substrate and the bond pad on the mounted device wherein the solder balls in the solder ball bridge are as-deposited without additional post deposition heating exposure.

FIG. 34B shows a cross-sectional schematic drawing of an embodiment of an assembly comprising a substrate having a horizontally-oriented bond pad, a mounted device having a vertically-oriented bond pad, and a solder ball bridge formed between the bond pad on the substrate and the bond pad on the mounted device wherein the solder balls in the solder ball bridge are as-deposited without additional post deposition heating exposure.

FIG. 34C shows a cross-sectional schematic drawing of the embodiment of the solder ball assembly of FIG. 34A after having been exposed to post deposition heating that reshapes the solder ball bridge.

FIG. 34D shows a cross-sectional schematic drawing of the embodiment of the solder ball assembly of FIG. 34B after having been exposed to post deposition heating that reshapes the solder ball bridge.

FIGS. 35A-35B and 35D-35F show cross-sectional schematic drawings, and FIG. 35C shows a top view drawing, of embodiments of solder ball bridge assemblies comprising a substrate, a mounted device, and a solder ball bridge wherein the solder ball bridges are formed from a large quantity of small diameter solder balls

FIG. 35A shows a cross-sectional schematic drawing of an embodiment of an assembly comprising a substrate, a mounted device, and a solder ball bridge formed between a bond pad on the mounted device and a bond pad formed on the substrate wherein the solder ball bridge is configured with a multitude of small diameter solder balls deposited in a single layer.

FIG. 35B shows a cross-sectional schematic drawing of another embodiment of an assembly comprising a substrate, a mounted device, and a solder ball bridge formed between a bond pad on the mounted device and a bond pad formed on the substrate wherein the solder ball bridge is configured with a multitude of small diameter solder balls vertically stacked in a plurality of layers.

FIG. 35C shows a schematic top view drawing of the embodiment of the assembly shown in FIG. 35B.

FIG. 35D shows a cross-sectional drawing of another embodiment of an assembly comprising a substrate, a mounted device, and a solder ball bridge formed from small diameter solder balls in relation to the length of the solder ball bridge and for which the solder balls are stacked to enable higher density stacking of the solder balls.

FIG. 35E shows a cross-sectional schematic drawing of the embodiment of the assembly shown in FIG. 35D wherein the assembly is subjected to heating at temperatures in proximity to the melting temperature of the solder used in the solder ball bridge in the embodiment.

FIGS. 36A-36F show top-down schematic drawings of embodiments of solder ball bridge assemblies having one or more U-shaped bond pads at the one or more terminal ends of a solder ball bridge.

FIG. 37 shows a flowchart for a method of forming some embodiments of solder ball bridge assemblies wherein the assemblies comprise a substrate, a device mounted or otherwise formed on the substrate, and a solder ball bridge formed between the mounted device and the substrate.

FIG. 38 shows a flowchart for a method of forming some embodiments of solder ball bridge assemblies wherein the assemblies comprise a substrate having a metallized layer, a mounted device mounted or otherwise formed on the substrate wherein the mounted device has a metallized layer, and a solder ball bridge formed between the metallized layers of the mounted device and the substrate.

FIG. 39 shows a flowchart for a method of forming some embodiments of solder ball bridge assemblies wherein the assemblies comprise a substrate having electrical contacts, a mounted device mounted or otherwise formed on the substrate wherein the mounted device has a metallized layer, and a solder ball bridge formed between the metallized layers of the mounted device and the electrical contacts of the substrate.

FIG. 40 shows a flowchart for a method of forming some embodiments of solder ball bridge assemblies wherein the assemblies comprise a substrate having alignment aids formed in a cavity, a device receptive to the alignment aids mounted in the substrate cavity, and a solder ball bridge formed between the substrate having the alignment aids and the cavity-mounted device.

### DESCRIPTION OF EMBODIMENTS

Described herein are embodiments of assemblies, structures, and methods of forming these structures and assemblies, that utilize solder balls to form electrically and thermally conductive interconnects between positionally displaced bond pads or other solder-wettable surfaces of one or more mounted device and the substrate to which the one or more mounted device is mounted or otherwise disposed.

“Solder ball bridge” as described herein, refers to a solder bridge formed from one or more solder balls wherein a solder bridge is one or more of an electrical and thermal interconnection formed using solder, a metal alloy, or a metal. “Solder balls”, as further described herein, are spherical balls of one or more of solder, alloys of solder, metal, and alloys of metal, suitable for deposition using a solder ball jetting apparatus. The term “solder ball bridge” as described herein, refers to a solder bridge formed using solder balls as a method of providing one or more of solder, solder alloy, metal, and metal alloy, as further described herein, in the formation of electrical and thermal interconnections. Although the use of solder balls in the formation of solder bridge structures may be apparent in some embodiments, the use of solder balls in resulting solder bridges may not be apparent in other embodiments. The spheroidal shaped solder balls and resulting bridge structures formed from these solder balls, may be significantly deformed from the original spheroidal shapes that are characteristic of solder balls prior to any changes that may occur as a result of being processed through a solder ball jetting apparatus and that may result from the fusing with bond pads and other solder-wettable surfaces, and that may result from fusing with other solder balls in a solder ball bridge structure. “Solder ball bridge” is used herein throughout this disclosure to describe embodiments of electrical and thermal interconnections formed using solder balls and may be used interchangeably with “solder bridge”. A “solder bridge”, as used herein, is a solder ball bridge in which deposited solder balls are connected and fused together.

In some embodiments, solder ball bridge structures between laterally displaced solder-wettable surfaces, for example, are formed using techniques in which initially placed solder balls are placed in contact with solder-wettable surfaces on one or more of the mounted device and the substrate and subsequently placed solder balls are anchored to the initially placed and secured solder balls to form a solder-based interconnect over non-solder-wettable surfaces on one or more of the mounted device and the substrate.

In other embodiments, solder ball bridge structures are formed between laterally and vertically displaced solder-wettable surfaces in which the initially placed solder balls are placed in contact with solder-wettable surfaces on one of more of the mounted device and the substrate and subsequently placed solder balls are anchored to the initially placed and secured solder balls to form a solder-based interconnect between the laterally and vertically displaced solder-wettable surfaces on the mounted device and the substrate. In some embodiments, solder balls are deposited with accompanying “low” energy, as described herein, to substantially maintain the spheroidal shape of the solder ball and, for example, and to limit the movement of the solder in the deposited solder ball upon placement onto a solder-wettable surface and limit the movement of the solder in previously deposited solder balls that are contacted by the deposited solder ball having accompanying “low” energy. In some embodiments, solder balls are deposited with accompanying “high” energy, as described herein, to provide improved wettability to solder-wettable areas on one or more of a mounted device and a substrate and to limit the movement of solder in previously deposited solder balls, for example, that are contacted by the deposited solder balls having accompanying “high” energy.

In some embodiments, solder balls in a solder ball bridge structure may contact a non-solder-wettable surface between bond pads on one or more of a mounted device and a substrate. In other embodiments, solder balls in a solder ball bridge may be used to form an arching structure that does not contact a solder-wettable surface between bond pads on one or more of a mounted device and a substrate.

In some embodiments of solder ball bridge assemblies, assemblies are formed comprising a mounted device, a substrate, and a solder ball bridge that spans a positionally displaced solder-wettable surface on the mounted device and a solder-wettable surface on a substrate. In some embodiments, the mounted device is a device used in the formation of a photonic integrated circuit. In some embodiments, the mounted device is an emitting device such as a laser. In some embodiments, the mounted device is a receiving device such as a photodiode. In some embodiments, the mounted device may be mounted in a cavity formed in the substrate. In some embodiments, the optical axis of a mounted device mounted in a cavity is aligned with the optical axis of a patterned planar waveguide formed on the substrate that intersects the wall of the cavity.

In some embodiments, the substrate is a mechanical support for the formation of a photonic integrated circuit. In some embodiments, the substrate includes one or more of a planar waveguide layer, an electrical interconnect layer underlying the planar waveguide layer, and a mechanical support substrate upon which the planar waveguide layer and the electrical interconnect layer are formed. In some embodiments, the substrate may be an interposer substrate.

In some embodiments of a solder ball bridge assembly comprising a mounted device, a substrate, and a solder ball bridge, alignment aids are formed on the substrate to facilitate alignment of the mounted device with patterned planar waveguides also formed on the substrate as further described herein. Also described herein are embodiments of solder ball bridge assemblies that are further coupled, or inclusive of, one or more of a high thermal conductivity layer, a metal-filled trench, a radiative solder ball array, and other form of heat sink. And yet also described herein are embodiments of solder ball bridge assemblies that are further coupled, or inclusive of, one or more of an electrical interconnect to one or more of an electrical interconnect layer underlying the planar waveguide layer of an interposer structure and an electrical interconnect layer on the planar waveguide layer of the interposer.

Also described herein are embodiments of solder ball bridge assemblies that form all or a portion of embodiments of photonic integrated circuit assemblies. In some embodiments of photonic integrated circuit assemblies, a substrate is utilized having patterned planar waveguides that form all or a portion of patterned optical waveguide cores encapsulated in one or more cladding layers that facilitate the guided propagation of optical signals within the photonic integrated circuit assembly. In some embodiments of photonic integrated circuit assemblies, a substrate is utilized having an electrical interconnect layer positioned below the planar waveguide layer to facilitate the electrical interconnection of electrical and optoelectrical devices in the photonic integrated circuit assembly. And in some embodiments of photonic integrated circuit assemblies, a substrate is utilized having an electrical interconnect layer positioned above the planar waveguide layer to facilitate the electrical interconnection of electrical and optoelectrical devices in the photonic integrated circuit assembly. In some embodiments of photonic integrated circuit assemblies, a solder ball bridge is used to form an electrical interconnection between a bond pad on a mounted device and a bond pad on the substrate wherein the bond pad on the substrate is connected to one or more of an electrical interconnect layer formed below the planar waveguide layer and an electrical interconnect layer formed above the planar waveguide layer.

In some embodiments of photonic integrated circuit assemblies having a plurality of electrical interconnections, solder ball bridges are used in combination with wirebonding wherein one or more electrical interconnection of the photonic integrated circuit assembly is formed using a solder ball bridge and one or more electrical interconnection of the photonic integrated circuit assembly is formed using wirebonding.

Some embodiments of photonic integrated circuit assemblies described herein, may be used in the formation of photonic integrated circuit assemblies for telecommunications applications. Some embodiments of photonic integrated circuit assemblies described herein, may be used in the formation of receiver circuits used in optical telecommunication applications. And some embodiments of photonic integrated circuit assemblies, described herein, may be used in the formation of transmitter circuits used in optical telecommunications.

Disclosed herein are these and other embodiments of solder ball bridge structures and assemblies, and photonic integrated circuit assemblies that utilize these solder ball bridge structures and assemblies. Methods of formation of these solder ball bridge structures and assemblies, and methods of formation of embodiments of photonic integrated circuit assemblies are also disclosed.

Thermally conductive solder ball bridges and electrically conductive solder ball bridges are formed using a range of solder materials and metal alloys, as described herein, that are formed from individual solder balls that are firstly anchored to a solder-wettable surface on the mounted device and on the substrate after which adjoining solder balls are then laterally placed and anchored to fill the spacing over non-solder-wettable surfaces between the initially placed anchored solder balls to complete the formation of the solder ball bridges.

Solder ball jetting is an innovative technique enabling the formation and precise placement of solder balls onto electronic components using controlled ejection of molten solder droplets through a nozzle onto desired locations on wafer-sized substrates. The process of droplet formation and placement typically utilizes a piezoelectric actuator that generates a pressure pulse to propel individual solder droplets. Precise control of droplet size, velocity, and placement is achieved through advanced control algorithms and feedback mechanisms. Typical solder ball apparatuses can place solder balls in the range of 0.020 to 2 mm in diameter at a rate of approximately 10 solder balls per second. Solder balls materials include SnAgCu, SnAg, AuSn, PbSn, and indium-based solder balls, among others. Solder ball jetting apparatus is widely used in semiconductor processing to deposit solder balls typically in the form of a grid ball array in which a substrate is populated with solder balls to align with a mating substrate having contact pads receptive to the solder balls. The solder balls in the grid ball array provide electrically conductive pathways between the mating boards to form an assembly.

Mounting of discrete semiconductor chips onto a submount, interposer, or other substrate for the formation of multichip modules requires interconnects to be made between laterally and vertically displaced locations on the submount, interposer, or other substrate and locations on chips mounted to the submount, interposer, or other substrate. Interconnects between the substrates and the mounted devices must take into consideration such characteristics as thermal conduction and electrical conduction to satisfy the thermal requirements and the electrical interconnectivity to other devices required for the intended circuit performance. Conversely, the formation of poorly controlled interconnections can lead to excessive heating and inadequate electrical interconnectivity. Mounted devices such as lasers, for example, can generate a significant amount of heat during operation, and this heat must be effectively dissipated to the substrate on which the laser is mounted or other heat sink to maintain stable optical output from the laser. For mounted lasers in which the heat is dissipated to an underlying host substrate, effective thermally conductive pathways must be provided between the mounted lasers and the substrate to ensure stable operation. Described herein, in embodiments, are solder ball bridge assemblies comprising a mounted device, such as a laser, for example; a substrate; and a solder ball bridge formed from one or more solder balls that provide one or more of electrical and thermal connectivity between laterally displaced solder-wettable locations on the mounted device and on the substrate. In some embodiments of solder ball bridge assemblies described herein, the solder ball bridge assemblies further comprise one or more heat sinks that may include a thermally conductive layer, a metal-filled trench, and a radiative solder ball array, among other heat sinks.

In addition to providing thermally conductive pathways between mounted devices and the substrates to which the mounted devices are mounted, embodiments of solder ball bridge structures in solder ball bridge assemblies disclosed herein enable high electrical conductance between laterally and vertically displaced solder-wettable surfaces on mounted devices and the substrate to which the devices are mounted. Electrical and optoelectrical devices such as lasers and photodiodes, among other devices, benefit from electrical connections having low inductance and low electrical resistivity. Electrical contact on the mating sides of the devices and substrates are commonly achieved using flip-chip technology, for example, using patterned solder-containing metallization structures on one or both of the mounted device and substrate that are firstly aligned and then heated to form an electrically conductive connection between the mating contacts. Conversely, the formation of electrical contacts between non-mating surfaces of a mounted device and the substrate, when necessary, is often achieved using wire bonding. A wire bond formed between an electrical contact on an exposed bond pad of a mounted chip and an electrical contact on the submount, interposer, or other substrate, however, can induce significant mechanical stress on the mounted device resulting in fracturing of the mounted device, compromising of already-formed electrical connections on the mating sides of the devices, among other potential performance limiting and deleterious effects. Wire bonds may also introduce significant undesirable inductance into the electrical connections due to the narrow wire gauges and lengthy wire connections typically used. High frequency applications are particularly prone to the deleterious effects induced by high inductance interconnections. Additionally, wire bonding is typically not suitable for applications requiring bonding at the wafer level (prior to singulation of chips from a host wafer).

Embodiments of structures, assemblies, and methods of forming these structures and assemblies are disclosed herein that utilize solder ball jetting to form one or more of electrically conductive and thermally conductive solder ball bridge structures between a mounted device and the substrate to which the mounted device is mounted or otherwise disposed. And also described herein, are embodiments of structures, assemblies, and methods of forming these structures and assemblies that utilize solder ball jetting to form one or more of electrically conductive and thermally conductive solder ball bridge structures between two mounted devices on a substrate to which the mounted devices are mounted or otherwise disposed.

In some embodiments, thermal connections are formed between a mounted device and a substrate to which the mounted device is mounted or otherwise disposed using a solder ball jetting apparatus to form a solder ball bridge between the mounted device and the substrate. In an embodiment, a solder ball bridge is formed using one or more solder balls deposited or otherwise formed on the assembly comprising the disposed device and the substrate. The solder ball bridge, in an embodiment, forms a thermal connection between a top surface of the mounted device and a top surface of the substrate on which the mounted device is disposed. To facilitate the formation of the thermal connection between the device and the substrate, one or more solder balls form a contact with at least a portion of a solder-wettable surface of the disposed device and at least a portion of a solder-wettable surface of the substrate. In some embodiments, the solder-wettable surface on the mounted device and on the substrate may be a horizontally-oriented bond pad, a vertically-oriented bond pad, or an angled bond pad receptive to bonding with one or more deposited solder balls.

In some embodiments, solder balls are deposited onto solder-wettable surfaces that may include one or more of a bond pad and a metal layer receptive to adhesion with the deposited material in the solder balls used in the formation of a solder ball bridge.

In some embodiments, solder ball bridge structures may be used to form thermal connections, that is an interconnection without an explicit electrical requirement, simply to secure a mounted device in a fixed position onto a substrate. In some embodiments, solder ball bridge structures may be used to form thermal connections simply to secure a mounted device in a fixed position with another mounted device. In some embodiments, one or more mounted device may be mounted in a cavity and secured in a position within the cavity using a solder ball bridge structure having a first terminal end of the solder ball bridge coupled to a solder-wettable surface on the mounted device and a second terminal end of the solder ball bridge coupled to one or more of a solder-wettable surface on the substrate 110 and a solder-wettable surface on another mounted device.

The use of metal layers may be beneficial for the formation of wetted solder connections to mounted devices and to substrates to improve one or more of the thermal and electrical conductivity between the mounted device and the solder and between the substrate and the solder. The use of metal layers that form wetted solder connections may be beneficial for embodiments for which the surfaces of the mounted device and the surfaces of the substrate do not form adequate thermally and electrically conductive connections with the solder used in the solder balls of the solder ball bridge. Solder flux may be used to improve and enhance the wetting properties between the solder and the metallization layer to which the solder of the solder balls is in contact.

In yet other embodiments, electrical connections are further formed in addition to the thermal contacts between metal contacts formed on the mounted devices and metal contacts formed on the substrate. In embodiments, a mounted device may be an electrical device, for example, or an optoelectrical device, for example, among other forms of devices that require one or more electrical connections.

In some embodiments, one or more solder ball bridges may be formed using solder ball jetting. In some embodiments, one or more thermally conductive contacts may be formed to one or more solder ball bridges formed by solder ball jetting. In some embodiments, one or more electrical connections may be formed to one or more solder ball bridges. In some embodiments, one or more thermally conductive contacts not having electrical connection may be formed with one or more electrical connections to one or more solder ball bridges.

Various embodiments are described herein with reference to the accompanying drawings that are intended to convey the scope of the invention to those skilled in the art. Accordingly, features and components described in the examples of embodiments described herein may be combined with features and components of other embodiments. Embodiments are not limited to the relative sizes and spacings illustrated in the accompanying figures. A “layer” as referenced herein may include a single material layer or a plurality of layers. For example, an “insulating layer” may include a single layer of a specific dielectric material such as silicon dioxide, or may include a plurality of layers such as one or more layers of silicon dioxide and one or more other layers such as silicon nitride, aluminum nitride, among others. The term “insulating layer” in this example, refers to the functional characteristic layer provided for the purpose of providing the insulation property, and is not limited as such to a single layer of a specific material. Similarly, an electrical interconnect layer, as used herein, refers to a composite layer that includes both the electrically conductive materials for transmitting electrical signals and the intermetal and other layers required to insulate the electrically conductive materials. An electrical interconnect layer, as described herein may therefore include a patterned layer of electrically conducting material such as copper or aluminum as well as the intermetal dielectric material such as silicon dioxide, and spacer layers above and below the electrically conductive materials, for example, among other layers. Additionally, references herein to a layer formed “on” a substrate or other layer may refer to the layer formed directly on the substrate or other layer or on an intervening layer or layers formed on the substrate or other layer. References to the term “optical” devices, as used herein, may refer to a purely optical device such as a waveguide that does not have an electrical feature and to an optoelectrical device that has both an optical feature and an electrical feature, unless specified otherwise. An optical device, as used herein, is a device such as a waveguide, an arrayed waveguide, a spot size converter, a lens, a grating, among others, and an optoelectrical device is a device such as a laser or a photodetector that includes an optical feature and an electrical feature. In embodiments described herein, the use of the term “optical device” may include both optical devices and optoelectrical devices particularly in the context of the alignment of optical features of optical die that pertains to devices with or without an electrical feature. References to the term “optical signal” as used herein, refers to electromagnetic radiation in the visible and infrared ranges from 200 nm to 2000 nm, and includes electromagnetic radiation having wavelengths commonly used in optical communications.

“Optical signals” specific to optical communications include, but are not limited to such wavelength ranges as the O-band (1260-1360 nm), the E-band (1360-1460 nm), S-band (1460-1530 nm), C-band (1530-1565 nm), L-band (1565-1625 nm), and U-band (1625-1675 nm). An “optical signal” may be one or more of a single photon and a multitude of photons. References to the term “optical axis” as used herein, refers to a primary propagation axis of an optical device or feature. An optical axis for a waveguide, for example, is the axis around which an optical signal in the waveguide would propagate along an axis or direction of propagation. The “optical axis” of an end facet, for example, may be, for example, the geometric center around which an optical signal would emerge from the end facet of a waveguide. As used herein, the term “optical axis” is used to describe a preferred reference for alignment of two or more optical features that when aligned, would produce a minimum in loss of signal transfer between the two or more features. Use of the term “optical axis” herein, as in “two or more devices being in alignment along an optical axis” of an assembly thus indicates that the two or more devices in alignment along the optical axis are aligned such that losses attributable to alignment are minimized. The term “optical axes” as used herein, refers to two or more of an “optical axis.” Optical features as used in the context of the terms. “optical axis” and “optical axes” may be all or a portion of an optical device, all or a portion of an optoelectrical device, among others that guide or otherwise provide directionality to a propagating optical signal. The terms “cavity” as used herein, refers to a receptacle formed in the substrate, described herein in embodiments, for mounting one or more devices.

The term “self-alignment” as used herein, refers to the alignment that results from the formation of multiple patterned features from a same lithographic pattern. Use of a same patterned mask layer, for example, to form a lithographic pattern that includes the patterned planar waveguides, fiducials, lateral alignment aids, and alignment pillars ensures that the relative positions of these lithographic features are formed within the tolerance of the lithographic technology used to form the patterning in the self-aligned layer. Self-alignment using conventional lithographic techniques can provide lithographic resolution of much less than a micrometer in current technologies commonly used in photonic device processing.

Like numbers in drawings refer to like elements throughout, and the various layers and regions illustrated in the figures are illustrated schematically. Figures provided herein are not drawn to scale but rather are intended to include and convey the various features comprising the embodiments described. Features described herein, in embodiments, can vary over a wide range. The physical dimensions of a substrate having a photonic integrated circuit assembly as described herein, for example, may be on the order of 1-10 millimeters in length and width and formed on a substrate that may be on the order of 0.5 to 1 mm in thickness. In comparison, the dimensions of a typical single mode optical fiber cable are approximately 900 microns for the jacket. 250 microns for the cladding coating. 125 microns for the cladding, and 10 microns for the core. In further comparison, the film thicknesses of a planar waveguide layer on a substrate may be, but are not limited to 1 to 20 microns. An electrical interconnect layer positioned between a silicon substrate and a planar waveguide layer may be on the order of several microns in thickness. Thicker electrical interconnect layers and thinner electrical interconnect layers may also be used. Although the actual dimensions may differ significantly from these approximations, they indicate the broad differences in dimensions of key features described in embodiments. As such, efforts have been made to include and describe the features of the embodiments without undue concern for maintaining dimensional scale for these features in relation to other features.

### Solder Ball Bridge Assembly

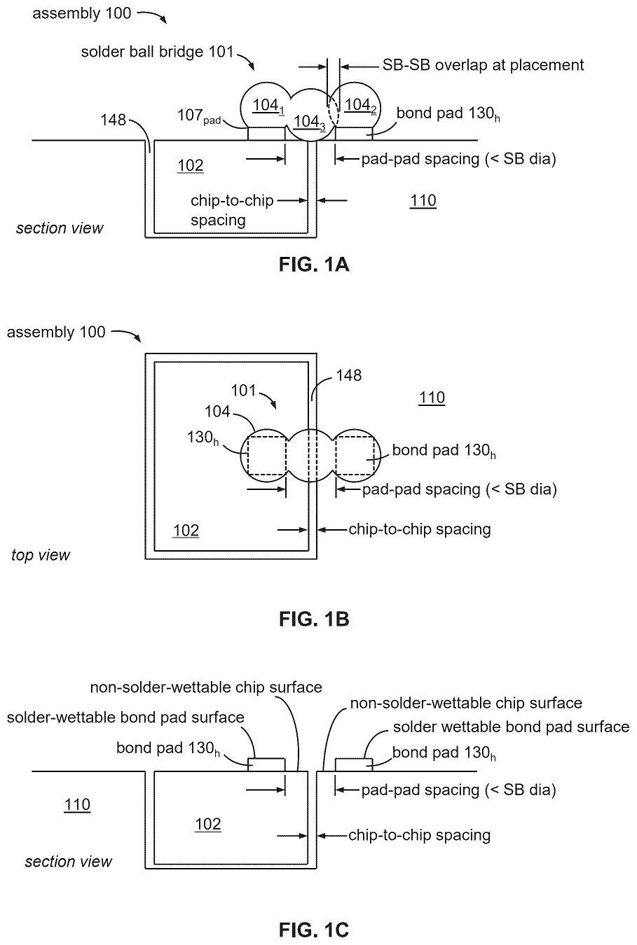

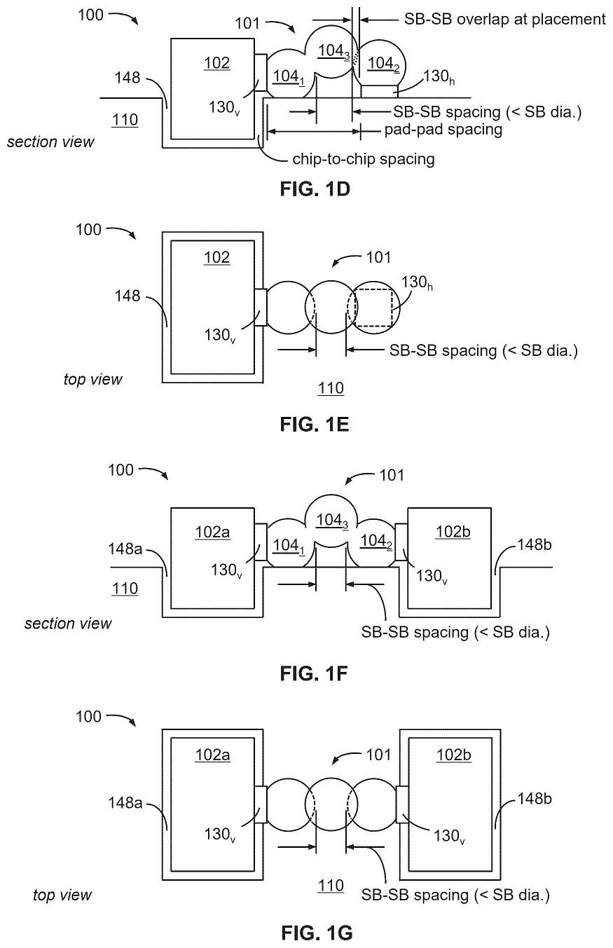

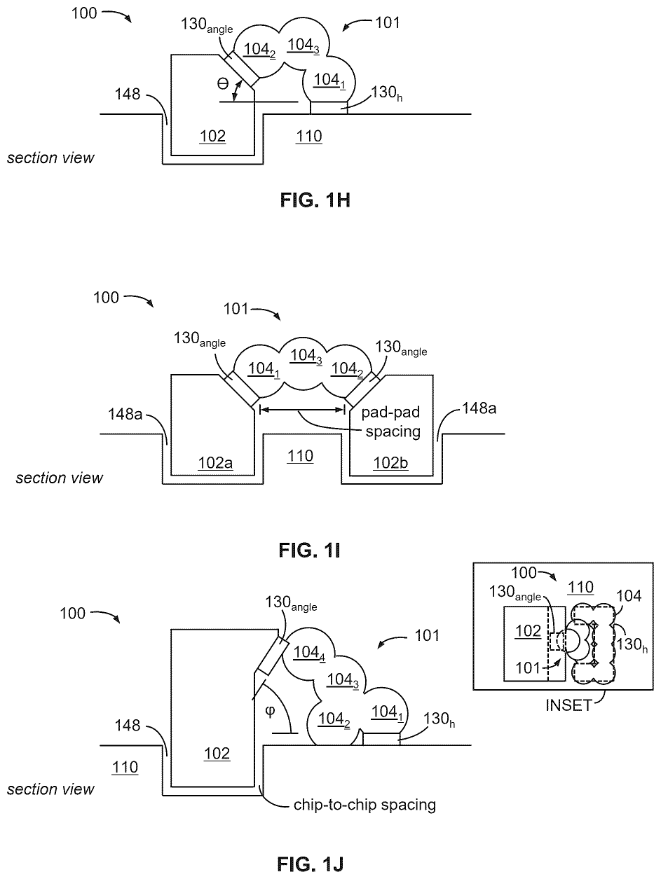

FIGS. 1A and 1B show schematic cross-sectional and top view drawings, respectively, of an embodiment of a solder ball bridge assembly 100 comprising a substrate 110, a mounted device 102 disposed on the substrate 110, and a solder ball bridge 101 wherein the solder ball bridge 101 is formed between a horizontally-oriented bond pad 130ₕ formed on the substrate 110 and a horizontally-oriented bond pad 130ₕ formed on the mounted device 102. The bond pads 130ₕ on the substrate 110 and on the mounted device 102 are separated by a distance labeled “pad-pad spacing”. In the embodiment shown, the “pad-pad spacing” is configured having a lateral distance that is less than the diameter of the solder ball 104 shown FIG. 1C further shows a schematic cross-sectional drawing of the portion of the solder ball bridge assembly 100 as in FIG. 1A comprising substrate 110 and mounted device 102 disposed on the substrate 110 prior to the formation of solder ball bridge 101.

As used herein, a horizontally-oriented bond pad 130ₕ is a bond pad 130 provided on a horizontal or substantially horizontal surface of a mounted device 102 or a substrate 110. Conversely, a vertically-oriented bond pad 130ᵥ is a bond pad provided on a vertical or substantially vertical surface of a mounted device 102 or a substrate 110. A horizontal surface of a mounted device is a surface that is parallel to the primary plane of the substrate wherein the primary plane of the substrate is, for example, a plane that is parallel to a horizontal tabletop or a horizontal plane wherein a horizontal plane is any plane that is perpendicular to an imaginary line that intersects the earth's surface and extends through the center of the earth. A “substantially horizontal” surface refers herein to a surface that may not be horizontal but may be within +/−20 degrees of horizontal. A vertically-oriented bond pad 130ᵥ is a bond pad having a surface that is parallel to an imaginary line that intersects the earth's surface and extends through the center of the earth. A “substantially vertical” bond pad is a bond pad having a surface that is perpendicular to the surface of a “substantially horizontal” bond pad. It should be noted that the surface of a bond pad may not be a flat surface and some bond pads may be formed having curved surfaces.

A bond pad 130ᵥ as used herein, without a subscript, refers to a bond pad without a specific reference to orientation although a particular orientation may be indicated in a figure that accompanies discussion of an embodiment. Bond pads, as used herein, are conductive areas formed on mounted devices 102 and substrates 110, among other semiconductor-related structures, that may serve, for example, as interface locations between a terminal ends of solder ball bridges 101, wirebonds, and other forms of electrical and thermal interconnections. Bond pads 130 are typically made of conductive materials such as gold, copper, and aluminum. Other metals and metal layers may be used in the formation of the bond pads described herein. The formation of bond pads is well understood in the art of semiconductor device fabrication. A primary property of a bond pad is its wettability in relation to the solder material with which it is used. Bond pad materials are presumably selected and used with compatible materials in the solder balls in embodiments described herein.

Solder ball bridge 101, in the embodiment shown in FIGS. 1A and 1B, is formed from individual solder balls 104 positioned between the bond pads 130ₕ to form one or more of a thermally and electrically conductive connection between the bond pads 130ₕ. Individual solder ball 104 may be extracted, for example, from a solder ball jetting apparatus and precisely positioned and placed onto bond pad 130ₕ and other locations on the substrate 110 and on mounted devices 102. A surface-to-surface connection 107 pad is shown in FIG. 1A formed between the bond pad 130ₕ and solder ball 104 deposited onto the bond pad 130ₕ.

Mounted device 102 may be, for example, a mountable optical device mounted or otherwise formed on the substrate 110. In some embodiments, mounted device 102 is an optoelectrical device, such as a laser for example, that produces heat during operation and solder ball bridge 101 enables transfer of heat from the mounted device 102 to the substrate 110. In other embodiments, mounted device 102 is an optoelectrical device, and solder ball bridge 101 provides an electrical connection between the optoelectrical device and the substrate 110. And in yet other embodiments, mounted device is an optoelectrical device, and solder ball bridge 101 provides a thermally conductive and an electrically conductive connection to one or more of a heat sink and an electrical interconnect formed on the substrate 110.

In some embodiments, substrate 110, may be, for example, all or a portion of an interposer structure. In other embodiments, substrate 110 may be, for example, all or a portion of a submount. In these and other embodiments, substrate 110 may facilitate mounting and interconnectivity for devices such as laser, photodiodes, lenses, drivers, waveguides, arrayed waveguides, filters, among other optoelectrical and optical devices used in the formation of photonic integrated circuit assemblies.

In some embodiments, mounted device 102 may be a mountable device such as surface mountable device. Surface mountable devices may include photodiodes, for example, among other devices. In other embodiments, mounted device 102 may be a cavity-mounted device such as a laser, among other devices.

The embodiment in FIGS. 1A-1C shows a cavity-mounted device positioned in a cavity 148 wherein the cavity 148 is formed in substrate 110. Placement of the mounted device 102 into cavity 148 typically requires clearance to avoid a collision between the mountable mounted device 102 and the walls of the cavity 148 within which the mounted device 102 is to be placed. Automated pick-and-place apparatus may be used, for example, to place the mounted devices 102 into a cavity 148. Positioning of cavity-mounted devices using current advanced automated pick-and-place apparatus, for example, requires a spacing allowance of approximately 0.5 microns between the mounted device 102 and the walls of the cavity 148.

In embodiments having a mounted device 102 mounted in a cavity 148, such as is shown in FIGS. 1A-1C, solder ball bridge 101 spans the “pad-to-pad spacing” between bond pads 130ₕ which includes the “chip-to-chip spacing” as noted in the embodiment shown. Typical solder ball diameters in the range of 20 microns to 2000 microns may be used, for example, in embodiments, to form a solder ball bridge 101. Typical bond pad sizes, used in embodiments, may be in the range, for example, of 20 microns by 20 microns to hundreds of microns by hundreds of microns, although other pad sizes and shapes may be used in embodiments. In an embodiment, the “pad-to-pad spacing” as noted in FIGS. 1A-1C may be, for example, in the range of 20-100 microns. In other embodiments, other “pad-to-pad spacings” may be used. In an embodiment configured having a “pad-to-pad spacing” of 50 microns and having a square pad 50 microns by 50 microns, three solder balls having a diameter of 50-70 microns may be used, for example, to form a solder ball bridge 101 to form one or more of an electrically conductive interconnection and a thermally conductive interconnection between the two bond pads 130ₕ. The “chip-to-chip spacing” can vary over a wide range within the “pad-to-pad spacing” range. In the example “pad-to-pad spacing” of 20-100 microns using a solder ball diameter of 50-70 microns, for example, the “chip-to-chip spacing” may vary between 0 microns, wherein the facing surfaces on the mounted device and the cavity wall are in contact, and 20-100 microns, the “pad-to-pad spacing” beyond which the pads would no longer be supported for the embodiment shown in FIGS. 1A and 1B.

In some embodiments, solder ball bridges 101 may provide lateral interconnect formation between bond pads 130 wherein one or more surfaces between the bond pads have non-solder-wettable surfaces. A solder-wettable surface, as used herein, refers to a surface that allows molten solder to spread and adhere, and to form a reliable connection between the solder in the solder ball and the surface to which the solder in the solder ball is adhered. In some instances, a solder-wettable surface facilitates the formation of a strong metallurgical bond between the solder in a solder ball 104 and the surface of the bond pad or other solder-wettable surface. In some instances, molten solder may wet the surface of the bond pad or other solder-wettable surface and form an interfacial reaction at the interface between the solder and the bond pad or other solder-wettable surface. In wetting of the surface, solder in the solder ball may redistribute across the solder-wettable surface of the bond pad or other solder-wettable surface. The extent of the redistribution of the solder in a solder ball with a bond pad or other solder-wettable surface may be dependent on the temperature of the solder ball upon impact with the bond pad or solder-wettable surface and the temperature of the bond pad or solder-wettable surface upon which the solder ball is deposited. A solder ball deposited at a low temperature, relative to its melting point, for example, may have little or no redistribution on the bond pad or other solder-wettable surface whereas a solder ball deposited having a temperature at or greater than the melting point of the solder in the solder ball may be significantly redistributed upon impact with the bond pad. The size of the bond pad, among other factors, may also impact the extent of the redistribution of solder in a solder ball upon impacting a bond pad or other solder-wettable surface on a mounted device or substrate. Solder-wettable materials may include such materials, for example, as silver, copper, and nickel, among others.

In contrast to solder-wettable surfaces, non-solder-wettable surfaces are surfaces that exhibit poor or no adhesive properties with the solder material used in solder balls 104, particularly for solder in the molten state. Non-solder-wettable surfaces may be, for example, oxide layer, nitride layer, polymer layers, and other layers having poor or no adhesive properties with the solder material used in a solder ball. It should be noted that a material may be solder-wettable for some solder materials and non-solder-wettable for other solder materials.

In FIG. 1C, bond pads 130ₕ have solder-wettable bond pad surfaces at least on the surface to which the solder balls are to be adhered. Bond pad surfaces are shown labeled “solder-wettable bond pad surface” in FIG. 1C. Vertical edges of bond pads 130ₕ having solder-wettable properties may be used in some embodiments. In other embodiments, the vertical edges of bond pads may be non-solder-wettable surfaces. And in yet other embodiments, bond pads 130 may not have exposed vertical edges. The surfaces of the mounted device 102 and the substrate 110, within the “pad-to-pad spacing” distance identified in FIG. 1C and elsewhere herein, are typically formed from materials having non-solder-wettable properties. These surfaces are labeled in FIG. 1C as “non-solder-wettable surface”. Silicon oxide layers, for example, are commonly used as top protective passivation layers through or on which the bond pads are formed in typical semiconductor fabrication processes. These oxide layers typically form non-solder-wettable surfaces that provide little or no adhesion to molten solder.

Solder ball bridges 101 enable the formation of lateral interconnections between laterally displaced bond pads or other solder-wettable surfaces. These lateral interconnections may be formed, in embodiments, over the non-solder-wettable surfaces present between bond pads illustrated, for example, in FIG. 1C and elsewhere herein.

In the embodiment shown in FIGS. 1A and 1B, the solder ball bridge 101 comprises three solder balls to span the bond pads and the “pad-to-pad spacing” distance shown. In an example placement sequence used in the formation of the lateral bridge formed on and between the bond pads 130ₕ, a first solder ball 104₁ may be firstly positioned such that the solder in solder ball 104₁ is anchored to the horizontally-oriented bond pad 130ₕ on the mounted device 102. A second solder ball 104₂, in the example placement sequence, may then be positioned on horizontally-oriented bond pad 130ₕ on the substrate 110. Having first solder ball 104₁ anchored to the horizontally-oriented bond pad 130ₕ on the mounted device 102 and second solder ball 104₂ anchored to the horizontally-oriented bond pad 130ₕ on the substrate 110 leaves a remaining spacing between solder balls 104₁ and 104₂ that is less than the diameter of the solder balls used to form the solder ball bridge 101 in the embodiment shown. The formation of the lateral solder ball bridge 101 is completed, in the embodiment, with the addition of third solder ball 104₃ deposited onto the overlap between the diameter of the third solder ball 104; and the shoulders of the first and second solder balls 104₁. 104₂, respectively. The overlapping portion of the third solder ball 104₃ and the second solder ball 104₂ is labeled in the embodiment as “SB-SB overlap at placement”. The third solder ball 104₃ is shown anchored in position to a portion of the first solder ball 104₁ and the second solder ball 104₂ such that the third solder ball 104; resides, in the embodiment, on the non-solder-wettable surface of the substrate 110. In some embodiments, the third solder ball 104₃, bridging the gap between the first solder ball 104₁ and second solder ball 104₂, may be held in position over the non-solder-wettable surface of the substrate as described further herein. In some embodiments, as shown in the embodiment in FIGS. 1A and 1B, the third solder ball 104₃ may have sufficient thermal energy to enable movement between the first solder ball 104₁ and the second solder ball 104₂ such that this third solder ball 104₃ reaches the substrate 110. The extent of the moveability of the third solder ball 104₃ may depend on such factors as the temperature of the third solder ball 104₃ in relation to the melting temperature of the solder used in the third solder ball 104₃, the temperature of the substrate 110 and the previously deposited first solder ball 104₁ and second solder ball 104₂, the size of the bond pads 130ₕ, the extent of the overlap between the third solder ball 104₃ and the first solder ball 104₁ and second solder ball 104₂, and the extent of the coupling of the bond pads 130ₕ to underlying conductive layers that may contribute to the cooling rate of the solder in the third solder ball 104₃.

The solder ball bridge 101 shown in the embodiment of the solder ball bridge assembly 100 shown in FIGS. 1A and 1B is shown without excessive deformation and may be idealized. In some embodiments, some deformation in the solder ball bridge 101 may be anticipated as numerous competing forces may contribute to the ultimate shape of the solder ball bridge including the factors listed in the previous paragraph that affect the moveability of the third solder ball. These same factors, and other factors such as the molten state of the deposited solder and the surface tension within molten portions of the solder, among other factors may contribute to the ultimate shape of the solder ball bridge 101 in the embodiment of the solder ball bridge 101 in embodiments described in conjunction with FIGS. 1A and 1B and in other embodiments described herein.

FIGS. 1D and 1E show schematic cross-sectional and top view drawings, respectively, of another embodiment of a solder ball bridge assembly 100 comprising a substrate 110, a mounted device 102 disposed on the substrate 110, and a solder ball bridge 101 wherein the solder ball bridge 101 is formed between a horizontally-oriented bond pad 130ₕ formed on the substrate 110 and a vertically-oriented bond pad 130ᵥ formed on the mounted device 102. A vertically-oriented bond pad 130ᵥ may be formed, for example, on a mounted device 102 such as a photodiode. A vertically-oriented bond pad may be formed, for example, on an optical device such as a lens array to enable the fixing in position of the lens array in a cavity 148 formed in substrate 110. Other mounted devices 102 may also be formed having one or more vertically-oriented bond pads 130ᵥ that may be used in embodiments of solder ball bridge assemblies 100 to which a terminal end of a solder ball bridge 101 may be coupled. A wide range of devices may be fabricated having horizontally-oriented bond pads 130ₕ formed during the device fabrication process that are preferably mounted into photonic integrated circuit assemblies such that these horizontally-oriented bond bads 130ₕ are configured as vertically-oriented bond pads 130ᵥ in some solder ball bridge assemblies 100. Formation of a solder ball bridge 101 having a terminal end that forms a contact on a mounted device 102 having a vertically-oriented bond pad 130; enables the use of a broadened range of mounted devices 102. Photodiodes, for example, are commonly formed having an optical axis of the receiving aperture that is perpendicular to the broad receiving area of the aperture. Horizontally-oriented bond pads are typically formed in a geometric plane that is parallel to the surface of these broad receiving apertures. These photodiodes, when integrated into photonic integrated circuit assemblies, however, may preferably be positioned such that the broad receiving area and the horizontally oriented bond pads are oriented vertically to enable coupling of the broad receiving area of the photodiode with the end facet of a planar waveguide formed on the substrate 110.

In the configuration shown in FIGS. 1D and 1E, the solder ball bridge 101 comprises three solder balls to span the “pad-to-pad spacing” distance shown. In an example placement sequence used in the formation of the lateral solder ball bridge 101 formed between the bond pads 130 . . . 130ₕ, a first solder ball 104₁ may be firstly positioned such that the solder in solder ball 104₁ is anchored to vertically-oriented bond pad 130ᵥ on the mounted device 102. In the embodiment shown, the solder in solder ball 104₁ is anchored to the solder-wettable surface of the vertically-oriented bond pad 130ᵥ but supported at least in part, by non-adhesive contact with the non-solder-wettable surface of the substrate 110. A second solder ball 104₂, in the example placement sequence, may then be positioned and anchored to the solder-wettable surface on horizontally-oriented bond pad 130ₕ on substrate 110. Having first solder ball 104₁ anchored to the vertically-oriented bond pad 130ᵥ on the mounted device 102, and the second solder ball 104₂ anchored to the horizontally-oriented bond pad 130ₕ on the substrate 110 leaves a remaining spacing between solder balls 104₁ and 104₂, labeled in FIGS. 1D and 1E as “SB-SB spacing” that is less than the diameter of the solder balls 104 used to form the solder ball bridge 101 in the embodiment shown. The lateral solder ball bridge 101 is completed, in the embodiment, with the addition of third solder ball 104₃ deposited onto the overlap between the diameter of the third solder ball 104₃ and the shoulders of the first and second solder balls 104₁, 104₂, respectively. The third solder ball 104₃ is anchored in position over the non-solder-wettable surface of the substrate 110 by the melding with the first and second solder balls 104₁, 104₂, respectively, in the embodiment. In the embodiment shown, insufficient energy is provided to enable movement of third solder ball 104₃ through the “SB-SB spacing” to reach the substrate as shown, for example, in the embodiment in FIGS. 1A and 1B. In some embodiments, sufficient energy may be provided to enable the third solder ball 104₃ to fall within the “SB-SB spacing” to reach the substrate as shown, for example in the embodiment in FIGS. 1A and 1B.

The “chip-to-chip spacing” in FIGS. 1D and 1E shows a portion of the cavity 148 unfilled by the mounted device 102. This “chip-to-chip spacing” may contribute to the distance required to be bridged by the solder ball bridge 101 in some embodiments.

FIGS. 1F and 1G show schematic cross-sectional and top view drawings of yet another embodiment of a solder ball bridge assembly 100 wherein the solder ball bridge assembly 100 comprises substrate 110, first mounted device 102a and second device 102b disposed on the substrate 110, and solder ball bridge 101 wherein the solder ball bridge 101 is formed between a vertically-oriented bond pad 130ᵥ on the first mounted device 102a and a vertically-oriented bond pad 130ᵥ on the second mounted device 102b. First mounted device 102a and second mounted device 102b are shown in cavities 148a, 148b, respectively, formed in substrate 110. In this embodiment, the third solder ball 104₃ of the solder ball bridge 101 is used to complete the solder ball bridge assembly 100 after deposition and anchoring of the first solder ball 104₁ to the vertically-oriented bond pad 130ᵥ of the first mounted device 102a and deposition and anchoring of the second solder ball 104₂ to the vertically-oriented bond pad 130ᵥ of the second mounted device 102b. Anchoring of the first solder ball 104₁ to the vertically-oriented bond pad 130ᵥ of first mounted device 102a and anchoring of the second solder ball 104₂ to the vertically-oriented bond pad 130ᵥ of the second mounted device 102b may be performed, for example, as described for the anchoring of the first solder ball 104₁ of the embodiment shown in FIGS. 1D and 1E. The addition of third solder ball 104₃ onto the overlap between the diameter of the third solder ball 104₃ and the shoulders of the first and second solder balls 104₁, 104₂, respectively, completes the formation of the solder ball bridge assembly 100 comprising the substrate 110, the first mounted device 102a, the second mounted device 102b, and the solder ball bridge 101. In this embodiment, the solder ball bridge 101 is formed between solder-wettable surfaces on the mounted devices 102a, 102b and not directly to a solder-wettable surface on substrate 110. The third solder ball 104₃ is anchored in position over the non-solder-wettable surface of the substrate 110 by the melding with the first and second solder balls 104₁, 104₂, respectively, in the embodiment.

FIGS. 1H-1J show drawings of embodiments of solder ball bridge assemblies 100 comprising substrate 110, one or more mounted devices 102, and solder ball bridge 101 wherein one or more of the mounted devices 102 is provided having a bond pad 130_{angle} formed at an angle in relation to the surface of a horizontally-oriented bond pad 130ₕ formed on substrate 110.

FIG. 1H shows a schematic cross-sectional drawing of an embodiment of a solder ball bridge assembly 100 comprising substrate 110, mounted device 102 disposed in cavity 148 on the substrate 110, and solder ball bridge 101 wherein the solder ball bridge 101 is formed between an angled bond pad 130_{angle} on the mounted device 102 and a horizontally-oriented bond pad 130ₕ on the substrate 110. FIG. 1H shows angle “θ” wherein the angle “θ” as used herein refers to the angular displacement between the solder-wettable surface of bond pad 130_{angle} and the solder-wettable surface of a horizontally-oriented bond pad formed on the substrate 110. In the embodiment shown in FIG. 1H, the angle “θ” is an angle between 0 and 90 degrees.

In the embodiment shown in FIG. 1H, the solder ball bridge 101 comprises three solder balls to span the spacing between the bond pads in the solder ball bridge assembly 100. In an example placement sequence used in the formation of the lateral bridge formed between the bond pads, a first solder ball 104₁ may be firstly positioned such that the solder in solder ball 104₁ is anchored to horizontally-oriented bond pad 130ₕ on the substrate 110. A second solder ball 104₂, in the example placement sequence, may then be positioned on the angled bond pad 130_{angle} on the mounted device 102. Having first solder ball 104₁ anchored to the horizontally-oriented bond pad 130ₕ on the substrate 110, and the second solder ball 104₂ anchored to the angled bond pad 130_{angle} on the mounted device 102 leaves a remaining spacing between solder balls 104₁ and 104₂ that is less than the diameter of the solder balls 104 used to form the solder ball bridge 101 in the embodiment shown. The deposition of the third solder ball 104₃ onto the shoulders of the first and second solder balls 104₁, 104₂, respectively completes the formation of the solder ball bridge 101 in the embodiment of the solder ball bridge assembly 101. The third solder ball 104₃ is anchored in position over the non-solder-wettable surface of the substrate 110 by the melding with the first and second solder balls 104₁, 104₂, respectively, in the embodiment. In the embodiment shown in FIG. 1H, an arching structure is shown for which the solder balls 104₁-104₃ do not contact the portion of the substrate 110 between the bond pads 130_{angle}, 130ₕ. In other embodiments, a solder ball 104 of the solder ball bridge may contact the portion of the substrate 110 between the bond pads 130_{angle}, 130ₕ. And in some embodiments, one or more additional solder balls 104 may be used to form the solder ball bridge 101. And in yet other embodiments, one or more solder balls 104 having one or more larger relative diameters may be used. And in yet other embodiments, one or more solder balls 104 having one or more smaller relative diameters may be used.

FIG. 1I shows a schematic cross-sectional drawing of yet another embodiment of a solder ball bridge assembly 100 comprising substrate 110, first mounted device 102a and second mounted device 102b disposed on the substrate 110, and solder ball bridge 101 wherein the solder ball bridge 101 is formed between angled bond pads 130_{angle} on the first mounted device 102a and the second mounted device 102b. Angled bond pads 130_{angle} in FIG. 11 are as described for the embodiment of FIG. 1H. In the embodiment shown, the substrate 110 provides a structure for the mounting of the first mounted device 102a and the second mounted device 102b and does not include a bond pad to which a terminal end of a solder ball bridge 101 is formed. In this embodiment, the solder ball bridge 101 is formed between solder-wettable surfaces on the mounted devices 102a, 102b and unlike the embodiment shown in FIGS. 1F and 1G, no contact is made with the substrate 110. In other embodiments, solder ball bridge 101 may form a contact with one or more of an optional solder-wettable surface on substrate 110 or a non-solder-wettable surface on substrate 110.

In the embodiment shown in FIG. 1I, the solder ball bridge 101 comprises three solder balls 104₁-104₃ to span the bond pads and the “pad-to-pad spacing” distance in the solder ball bridge assembly 100 shown. In an example placement sequence used in the formation of the solder ball bridge 100 formed between the bond pads 130_{angle}, a first solder ball 104₁ may be firstly positioned such that the solder in solder ball 104₁ is anchored to angled bond pad 130_{angle} on the first mounted device 102a. A second solder ball 104₂, in the example placement sequence, may then be positioned on the angled bond pad 130_{angle} on the second mounted device 102b. Having first solder ball 104₁ anchored to the angled bond pad 130_{angle} on the first mounted device 102a and second solder ball 104₂ anchored to the angled bond pad 130_{angle} on second mounted device 102b leaves a remaining spacing between first and second solder balls 104₁, 104₂, respectively, that is less than the diameter of the solder balls 104 used to form the solder ball bridge 101 in the embodiment shown. The lateral solder ball bridge 101 is completed, in the embodiment, with the addition of third solder ball 104₃ deposited onto the shoulders of the first and second solder balls 104₁, 104₂, respectively. The third solder ball 104₃ is anchored in position over the non-solder-wettable surface of the substrate 110 by the melding with the first and second solder balls 104₁, 104₂, respectively, in the embodiment. In other embodiments configured as shown in FIG. 1I, third solder ball 104₃ may contact the non-solder-wettable surface of the substrate 110 while maintaining contact with the first and second solder balls 104₁, 104₂, respectively.

FIG. 1J shows a schematic cross-sectional drawing of yet another embodiment of solder ball bridge assembly 100 comprising substrate 110, mounted device 102 disposed in a cavity 148 on substrate 110, and solder ball bridge 101 wherein the solder ball bridge 101 is formed between an angled bond pad 130_{angle} on the device 102 and a horizontally-oriented bond pad 130ₕ on the substrate 110 wherein the angled bond pad 130_{angle} on the mounted device 102 is at an angle such that the surface of the bond pad 130_{angle} is substantially facing the substrate 110. The INSET of FIG. 1J shows a top-down drawing of an example configuration of solder balls 104 that may be used in the formation of the embodiment of the solder ball bridge assembly 100 configured having a mounted device 102 wherein the mounted device 102 includes a bond pad 130_{angle} as in FIG. 1J that substantially faces the substrate 110. The INSET of FIG. 1J shows a different configuration of solder balls than the configuration shown in the cross-sectional drawing of FIG. 1J but related in that the INSET also shows an angled bond pad 130_{angle} that substantially faces the substrate 110.

FIG. 1J shows an angle “o” to illustrate the angle of the surface of bond pad 130_{angle} of mounted device 102 with respect to the surface of horizontally-oriented bond pad 130ₕ on the substrate 110. The angle “o” as shown refers to the angular displacement between the solder-wettable surface of bond pad 130_{angle} and the surface of the horizontally-oriented bond pad 130ₕ on the substrate 110. In the embodiment shown in FIG. 1J, the angle “ϕ” is an angle between 0 and 90 degrees. In other embodiments other reference angles may be used to describe the relative angle between an angled bond pad 130_{angle} on a mounted device 102 and a reference surface of the substrate 110. The surface of a bond pad that “substantially” faces the substrate 110 is a surface having an angle “ϕ” that is greater than 0 degrees and less than approximately 70 degrees. Angles of “ϕ” that are greater than 70 degrees, as described herein, may be considered vertically-oriented bond pads.

In the embodiment shown in the cross-sectional drawing of FIG. 1J, solder ball bridge 101 comprises four solder balls to span the spacing between bond pads 130_{angle}, 130ₕ in the solder ball bridge assembly 100. In an example placement sequence used in the formation of the solder ball bridge formed between bond pads 130_{angle}, 130ₕ, a first solder ball 104₁ may be firstly positioned such that the solder in solder ball 104₁ is anchored to horizontally-oriented bond pad 130ₕ on the substrate 110. A second solder ball 104₂, in the example placement sequence, may then be positioned on a shoulder of the first solder ball to anchor the second solder ball 104₂ to the first solder ball 104₁. In the embodiment shown in the cross-sectional drawing of FIG. 1J, the second solder ball 104₂ is shown in contact with a non-solder-wettable portion of the substrate and melded with first solder ball 104₁. In other embodiments, the second solder ball 104₂ may not contact the non-solder-wettable surface of the substrate 110. In the embodiment shown, third solder ball 104₃ may then be deposited on the first and second solder balls 104₁, 104₂, respectively, leaving a gap between the third solder ball 104₃ and the angled bond pad 130_{angle} on the mounted device 102 which is subsequently filled with fourth solder ball 104₄ in the embodiment. Deposition of the fourth solder ball 104₄ onto the third solder ball 104₃ and in contact with the angled bond pad 130_{angle} completes the formation of the solder ball bridge 101 in the embodiment of the solder ball bridge assembly 100. The third solder ball 104₃ is anchored in position by melding with the first and second solder balls 104₁, 104₂, respectively, in the embodiment. In the embodiment shown in FIG. 1J, an arching structure is formed by the solder balls 104₃, 104₄ between the second solder ball 104₂ and the angled bond pad 130_{angle} of the mounted device 102. In other embodiments, a solder ball bridge 101 may be formed that does not contact the portion of the substrate 110 between the bond pads 130ₕ, 130_{angle}.

And in some embodiments, one or more additional solder balls 104 may be used to form solder ball bridge 101 between bond pad 130_{angle} on the mounted device 102 and horizontally-oriented bond pad 130ₕ on the substrate 110. The INSET of FIG. 1J shows, for example, a top-down view of a configuration of solder balls 104 in a solder ball bridge 101 having eleven solder balls 104. In the embodiment in the INSET of FIG. 1J, the solder balls 104 are arranged in a manner to facilitate stacking in bridging the distance between a U-shaped bond pad 130 on the substrate 110 and the substrate-facing angled bond pad 130_{angle} on the mounted device 102.

In yet other embodiments, one or more solder balls 104 having one or more larger relative diameters may be used. And in yet other embodiments, one or more solder balls 104 having one or more smaller relative diameters may be used.

In other embodiments, a larger horizontally-oriented bond pad may be used to provide a larger base upon which the stacked solder balls 104 may be deposited in building up a mound of solder to reach the angled bond pad 130_{angle} on the mounted device 102. And in yet other embodiments, the solder balls may be stacked out of the plane of the two-dimensional drawing, as shown for example, in the INSET of FIG. 1J to enable three-dimensional stacking of the solder balls 104 and to enable a larger base upon which to secure the solder balls to the substrate 110.

The embodiment shown in the INSET of FIG. 1J shows a U-shaped bond pad to facilitate adhesion and stacking of solder balls 104 to reach the elevated bond pad 130_{angle} on the mounted device. U-shaped bond pads may be used in the embodiment shown in FIGS. 1J and 1n other embodiments described herein to facilitate three-dimensional stacking of solder balls 104.

In the embodiments of the solder ball bridge assemblies 100 having one or more angled bond pads 130_{angle} shown in FIGS. 1H-1J, reference angles “0” and “ϕ” between an angled bond pad 130_{angle} formed on a mounted device 102 and a horizontally-oriented surface on the substrate 110 is used to illustrate configurations that may be used in embodiments for which the surface of the angled bond pads 130_{angle} differs from typical horizontally-oriented and vertically-oriented bond pads 130ₕ, 130ᵥ respectively, that may be used in the formation of solder ball bridge assemblies. Other reference angles may be used in embodiments to describe the non-vertically-oriented bond pads and non-horizontally-oriented bond pads that may be used on mounted devices 102 in these embodiments.

Mounted devices 102 that are mounted in cavities 148 may be configured having one or more of horizontally-oriented bond pads 130ₕ and vertically-oriented bond pads 130ᵥ to facilitate one or more of electrical and thermal connections to other bonding locations in the photonic integrated circuit assembly within which the cavity-mounted devices are utilized. As in embodiments described in FIGS. 1A and 1B having horizontally-oriented bond pads 130ₕ, solder ball bridge 101 may be used in embodiments, to form a lateral interconnect between one or more vertically-oriented bond pads 130ᵥ as in FIGS. 1D-1G. In yet other embodiments, solder ball bridges 101 may be formed between one or more angled bond pads as shown, for example, in FIGS. 1H-1J.

### Wafer Level Solder Ball Jetting

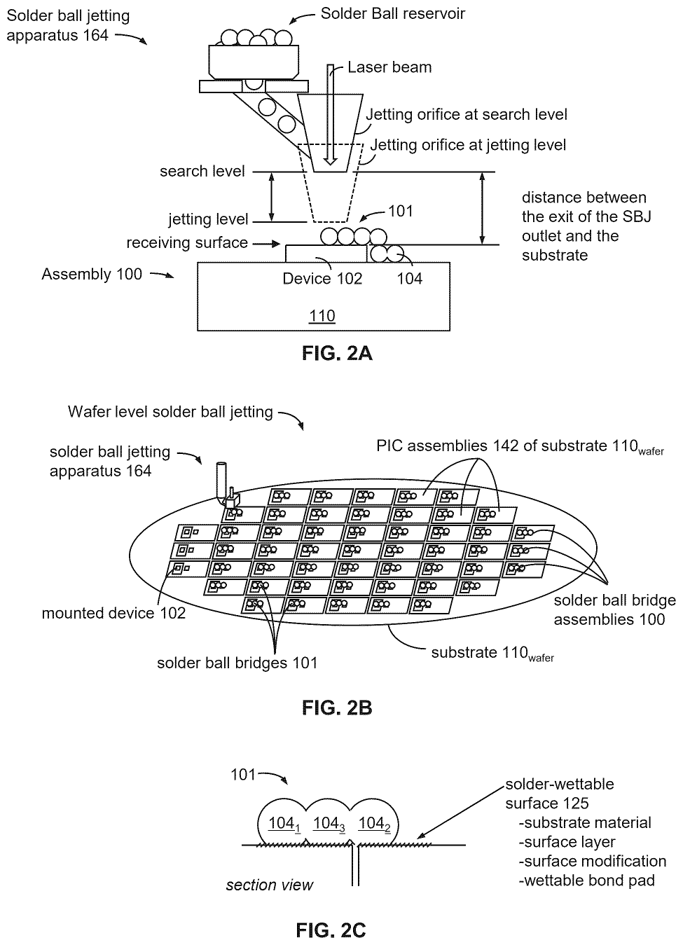

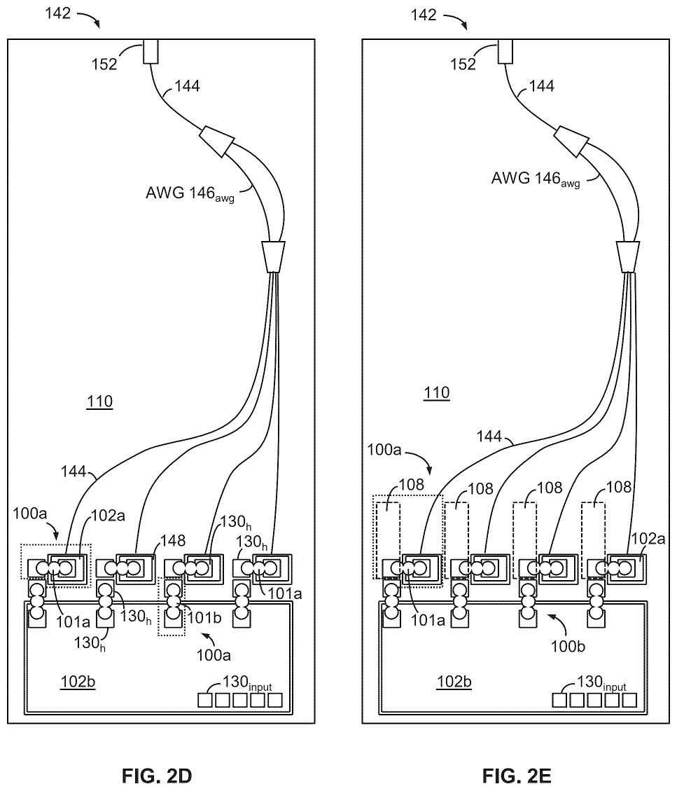

FIG. 2A shows a schematic drawing of a portion of a typical solder ball jetting apparatus 164 that may be used in the formation of embodiments of solder ball bridge 101. An example solder ball jetting apparatus is the “SB2-Jet” platform manufactured by Pacific Technologies GmbH. Solder ball jetting apparatus 164 is shown with integrated laser that facilitates heating of solder balls prior to, during, and after deposition onto a substrate such as substrate 110 having mounted device 102 disposed thereon. A multitude of solder balls 104 are provided in a solder ball reservoir on the solder ball apparatus 164 that are ejected from an orifice in proximity to a receiving surface on, for example, the mounted device 102 as shown. Solder ball jetting apparatus 164 is shown having a “search level” and a “jetting level”. A location within a die having all or a portion of a photonic integrated circuit assembly may be identified, for example, at the search level using a pattern recognition system integrated into the solder ball jetting apparatus. Solder balls 104 are typically ejected from the orifice at the “jetting level”. FIG. 2A shows a mounted device 102 disposed on substrate 110 wherein the mounted device 102 and substrate 110 are positioned below the jetting orifice to receive the ejected solder balls 104 from the jetting orifice of the solder ball jetting apparatus 164. Solder ball jetting apparatus such as solder ball jetting apparatus 164 shown schematically in FIG. 2A and other solder ball jetting apparatuses are typically used in the delivery of one or more solder balls to a bond pad to form a solder ball bump to which a device having a mating bond pad is aligned to form an assembly. A plurality of such solder ball bumps are formed in what is typically called a grid ball array on a first surface having an array of bond pads that are then aligned and combined with a similar array on a mating device to form an assembly. In such assemblies, the solder ball bumps are used to form vertical interconnects between the mating devices.

In embodiments of solder ball bridge assemblies 100 described herein, structures and methods of forming positionally displaced bond pads are described in configurations that are not limited to vertically aligned bond pads as in assemblies that utilize grid ball arrays but rather that enable the anchoring of adjacent solder balls to span the distance between bond pads 130 that typically include a lateral component to the positional displacement between bond pads 130. The use of solder ball jetting to form a solder ball bridge having a lateral displacement between bond pads or other solder-wettable surfaces enables these structures to span lateral distances over non-solder-wettable surfaces.

Solder ball bridge 101 of solder ball bridge assembly 100 is formed between a portion of the substrate 110 and a portion of the mounted device 102 disposed on substrate 110. In the embodiment shown in FIG. 2A, material for forming a solder ball bridge 101 is emitted from solder ball apparatus 164 in the form of solder balls 104 and deposited onto one or more of the substrate 110, mounted device 102, and previously deposited solder balls 104 in the solder ball bridge 101. Solder ball bridge 101 is comprised of solder balls 104 that are deposited, for example, using solder ball jetting apparatus 164. During operation, solder ball apparatus 164 deposits solder balls 104 formed from a solder or indium-based material to form solder ball bridge 101. Solder balls 104 in solder ball bridge 101 may be formed from alloys of tin, silver, copper, gold, and lead such as SnAgCu, SnAg, AuSn, and PbSn, for example. Solder balls in solder ball bridge 101 may also be formed from indium-based alloys such as indium-based alloys formed with gallium, lead, tin, gold, and bismuth, for example. Solder balls 104 formed from other alloys and other indium-based alloys may also be used. Any metal or alloy that can be formed into a solder ball and emitted from a solder ball apparatus may be used in the formation of solder ball bridges provided that sufficient adhesion at the terminal ends of the solder ball bridge are provided to a solder-wettable surface on the substrate 110 and the mounted device 102 as described herein. Solder flux may be used in embodiments to facilitate one or more or of adhesion, bonding, and alloying between one or more solder balls 104 and a solder-wettable portion of a disposed mounted device 102 and one or more solder balls 104 and a solder-wettable portion of substrate 110. In some embodiments, for example, bond pads 130 may be formed on one or more of a mounted device 102 disposed on a substrate 110, and the substrate 110 to facilitate alloying between one or more elements of a solder ball 104 and one or more elements of the substrate 110 or bond pad 130 formed on the substrate 110. Bond pads 130 may be formed, for example, using solder-wettable surface layers to facilitate adhesion between the deposited solder balls 104 and the surface of a bond pad 130.

FIG. 2B shows a perspective drawing of a substrate 110_{wafer} comprising a multitude of photonic integrated circuit assemblies 142 that may include all or a portion of a photonic integrated circuit that may further include one or more solder ball bridges 101. Wafer 110_{wafer} may be, for example, a single crystal silicon wafer having a diameter of 200 mm on which one or more die having all or a portion of one or more photonic integrated circuit assemblies are formed in an embodiment. Other substrate materials, sizes, and shapes may also be used in other embodiments. In some embodiments, substrate 110_{wafer} may comprise a multitude of integrated circuit assemblies having applications in photonic circuits such as driver circuits, ASICS, transimpedance amplifiers, among other integrated circuit assemblies and components that may be used in photonic integrated circuit assemblies 142. In some embodiments, substrate 110_{wafer} may comprise a multitude of other integrated circuit assemblies such as MEMs devices, non-photonic ASICs, memory devices, microprocessors, MEMs devices, signal processing devise, regulators, timers, controllers, power management devise, and rf devices, among other devices.

FIG. 2B shows a portion of a solder ball jetting apparatus 164 in proximity to substrate 110_{wafer} wherein the substrate 110_{wafer} comprises a plurality of die on which solder ball jetting apparatus 164 forms solder ball bridges 101. Solder ball jetting apparatus 164 deposits solder balls 104 onto the substrate 110_{wafer} to form the solder ball bridges 101 of solder ball bridge assemblies 100. Solder ball bridge assemblies 100, in the embodiment shown in FIG. 2B, comprise the common substrate 110_{wafer}, a mounted device 102 disposed on substrate 110_{wafer}, and solder ball bridge 101 formed between a horizontally-oriented bond pad 130ₕ formed on the mounted device 102 and a horizontally-oriented bond pad 130ₕ formed on the substrate 110_{wafer}. In the embodiments shown in FIG. 2B, one solder ball bridge 101 is shown for each of the completed solder ball bridge assemblies 100 to form a multitude of solder ball bridge assemblies 100 on the substrate 110_{wafer}. In a typical fabrication process, solder ball bridge assemblies 100 having one or more solder ball bridges 101, will be formed on each of the integrated circuit die on the substrate 110_{wafer}, although the formation of a solder ball bridge 101 on all integrated circuits on the substrate 110_{wafer} is not required. More than one solder ball bridge 101 may be formed on each photonic integrated circuit assembly formed on the substrate 110_{wafer} in some embodiments. Solder ball bridge assemblies 100 having laterally coupled solder balls 104 in solder ball bridge 101 may be formed at the wafer level using solder ball jetting apparatus 164. Wafer level processing, as used herein, refers to the processing of unsingulated substrates. Unsingulated substrates suitable for wafer level processing using methods described herein may comprise a multitude of photonic integrated circuit die. Other unsingulated substrates may comprise a multitude of non-photonic integrated circuit die. And in yet other example, unsingulated substrates may comprise one or more photonic integrated circuit and one or more non-photonic integrated circuit. Other methods of applying solder balls 104 in the formation of solder ball bridges 101 may also be used on non-singulated and singulated substrates using the methods of formation of solder ball assemblies described herein.

After formation of solder ball bridge assemblies 100 having solder ball bridges 101 on a non-singulated substrate 110_{wafer}, a passivation layer comprising one or more polymer layers such as photoresist, BCB, and other polymers layers may be used to secure the solder ball bridge structure and to provide a passivating layer over the solder ball bridge assemblies 100 prior to singularization of the die from the substrate 110_{wafer}. Dielectric layers formed using low temperature processes, below the melting temperature of the solder balls 104, for example, may also be used to form a passivation layer on wafer 110_{wafer} having the solder ball bridge assemblies 100. In some embodiments, a passivation layer may not be provided.

FIG. 2C shows a solder ball bridge 101 formed on a solder-wettable surface 125 on which solder balls 104 are disposed. The solder-wettable surface 125 may be formed from one or more of a solder-wettable surface material, a solder-wettable surface layer, a surface-wettable surface modification, and a surface-wettable bond pad. Solder-wettable surfaces are known in the art of semiconductor fabrication and a range of materials may be used to promote adhesion between the material used in a deposited solder ball 104 and the surface layer upon which the solder ball 104 is deposited.

FIG. 2D shows a schematic top view drawing of a photonic integrated circuit assembly 142 having a plurality of instances of an embodiment of solder ball bridge assembly 100a comprising substrate 110, mounted devices 102a, and solder ball bridge 101a wherein the solder ball bridges 101a of the plurality of instances on the photonic integrated circuit assembly 142 are each coupled to a horizontally-oriented bond pad 130ₕ formed on the mounted devices 102a and a horizontally-oriented bond pad 130ₕ formed on the substrate 110. A solder ball bridge assembly 100a of the plurality of solder ball bridge assemblies 100a in photonic integrated circuit assembly 142 is shown enclosed in a box having dotted line borders and label “100a” wherein the solder ball bridge assembly 100a comprises the common substrate 110, a mounted device 102a, and solder ball bridge 101a. The box having dotted line borders and label 100a encloses only a portion of the substrate 110.

Photonic integrated circuit assembly 142, formed on substrate 110, further includes a plurality of instances of an embodiment of solder ball bridge assembly 100b comprising substrate 110, mounted device 102b, and a solder ball bridge 101b wherein the solder ball bridges 101b of the plurality of instances on the photonic integrated circuit assembly 142 are each coupled to a horizontally-oriented bond pad 130ₕ formed on the mounted device 102b and horizontally-oriented bond pads 130ₕ formed on the substrate 110. A solder ball bridge assembly 100b of the plurality of solder ball bridge assemblies 100b in photonic integrated circuit assembly 142 is shown enclosed in a box having dotted line borders and label “100b” wherein the solder ball bridge assembly 100b comprises the common substrate 110, mounted device 102b, and solder ball bridge 101b. The box having dotted line borders and label “100b” encloses only a portion of the substrate 110 and only a portion of the mounted device 102b. As the embodiment of the photonic integrated circuit assembly in FIG. 2D shows, a plurality of solder ball bridges 101 may terminate on a mounted device 102.

The photonic integrated circuit assembly 142 in the configuration shown in FIG. 2D may be, for example, a multiplexing device wherein optical signals from the plurality of mounted devices 102a are coupled to patterned planar waveguides 144 of photonic integrated circuit assembly 142 to an arrayed waveguide 146_{awg}, for example, to provide a multiplexed optical signal to an outgoing optical fiber cable (not shown) mounted in fiber mounting site 152. Mounted devices 102a for a photonic integrated circuit assembly 142 configured as a multiplexing device may be, for example, laser devices. The lasers may be used in conjunction with mounted device 102b, which may be configured, for example, as a driver. Photonic integrated circuit assembly 142, configured as a multiplexing device, converts electrical signals provided by the driver circuit, for example, to optical signals generated by the mounted devices 102a which are subsequently multiplexed in arrayed waveguide 146_{awg} and provided to outgoing optical fiber cable 154 mounted in optical fiber mounting site 152. Electrical inputs to the driver circuit may be provided, for example, through bond pads 130ᵢₙₚᵤₜ.

FIG. 2E shows a schematic top view drawing of the photonic integrated circuit assembly 142 of FIG. 2D, wherein the substrate 110 further comprises heatsinks 108 coupled to a terminal end of the solder ball bridges 101a. The schematic top view drawing of the photonic integrated circuit assembly 142 of FIG. 2E shows a configuration having a plurality of instances of an embodiment of solder ball bridge assembly 100a comprising substrate 110, mounted devices 102a, and solder ball bridge 101a wherein the solder ball bridges 101a of the plurality of instances on the photonic integrated circuit assembly 142 are each coupled to a horizontally-oriented bond pad 130ₕ formed on the mounted devices 102a and a horizontally-oriented bond pad 130ₕ formed on the substrate 110. A heat sink 108 is shown coupled to a terminal end of each of the solder ball bridges 101a in the embodiment. A solder ball bridge assembly 100a of the plurality of solder ball bridge assemblies 100a in photonic integrated circuit assembly 142 is shown enclosed in a box having dotted line borders and label “100a” wherein the solder ball bridge assembly 100a comprises the common substrate 110, a mounted device 102a, and solder ball bridge 101a wherein each of the solder ball bridge assembly 100 is further coupled to a heat sink 108. The box having dotted line borders and label “100a” encloses only a portion of the substrate 110. Photonic integrated circuit assembly 142 further includes a plurality of instances of an embodiment of solder ball bridge assembly 100b which, in the embodiment, are as described in conjunction with the embodiment shown in FIG. 2D.

The photonic integrated circuit assembly 142 in the configuration shown in FIGS. 2D and 2E may be, for example, a multiplexing device wherein one or more electrical signals are coupled to a mounted device 102b that may be configured, for example, as one or more of a digital signal processor, an ASIC, and a driver, for example, that provides electrical signals to mounted devices 102a configured as lasers. Mounted devices 102a, configured as lasers, may be, for example, one or more of direct modulated lasers and electro-absorption-modulated lasers. Encoded optical output from the mounted devices 102a may be coupled to patterned planar waveguides 144 and multiplexed in arrayed waveguide 146_{awg}, and outgoing multiplexed optical signal is coupled to an optical fiber cable (not shown) mounted in optical fiber mounting site 152. Configured as lasers, devices 102a may have improved operational stability when coupled to heat sinks 108. Photonic integrated circuit assembly 142, configured as a multiplexing device having mounted devices configured as lasers, may be used to convert modulated optical signals output from the lasers to a multiplexed optical signal output to an optical fiber mounted in fiber mounting site 152 on substrate 110.

FIGS. 2D and 2E illustrate two example configurations of photonic integrated circuit assemblies 142 having a plurality of solder ball bridge assemblies 100 each comprising substrate 110, a mounted device 102, and a solder ball bridge 101. Other configurations of photonic integrated circuit assemblies 142 may also be formed having one or more solder ball bridge assemblies 100. And in some embodiments of photonic integrated circuit assemblies 142 having solder ball bridge assemblies 100, the use of solder ball bridges 101 may be combined with other methods of forming electrical and thermal interconnects on a same submount or interposer.

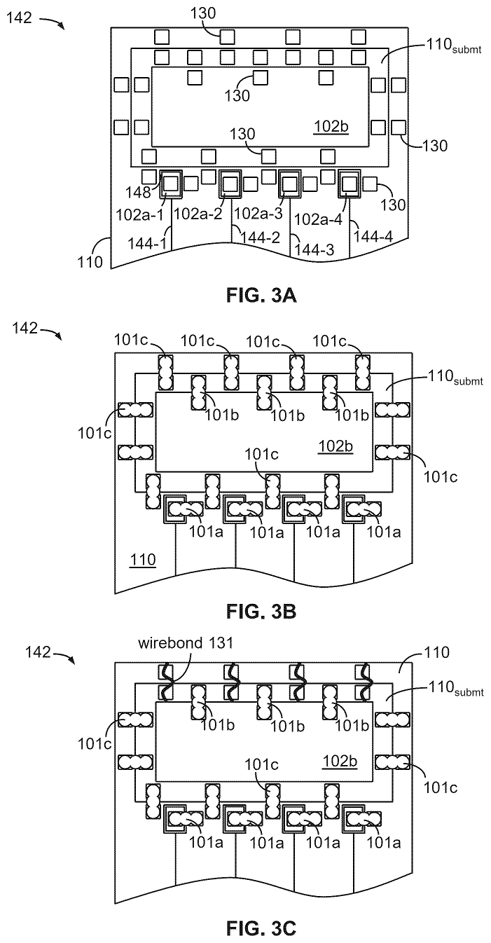

FIG. 3A shows a schematic top view drawing of a portion of a photonic integrated circuit assembly 142 having bond pads 130 receptive to solder balls 104 or other form of electrical and thermal interconnection and used, for example, in the formation of solder ball bridge assemblies 100. The photonic integrated circuit assembly 142 of FIG. 3A is shown configured with a plurality of mounted devices 102a-1 to 102a-4 and a mounted device 102b. Mounted device 102b is shown further mounted on submount 110_{subent}. Submount 110_{subent} may be, for example, a secondary substrate to which a mounted device 102b is mounted. Submount 110_{subent} having a mounted device 102b may be mounted onto substrate 110 as shown. Configurations such as the configuration shown in FIG. 3A having one or more mounted device 102a mounted on a substrate 110, and having a mounted device 102b mounted on a submount that is also mounted onto the substrate 110, may be used, for example, in the formation of multiplexing and demultiplexing devices used in optical telecommunications networks. Substrate 110 may itself be a submount that may get mounted onto another substrate. Substrate 110 may be an interposer structure in some embodiments. FIG. 3A shows a plurality of bond pads 130 formed on substrate 110, on the submount 110_{subent}, on mounted devices 102a-1 to 102a-4, and on mounted device 102b. Mounted devices 102a-1 to 102a-4 are shown in cavities 148. Patterned planar waveguides 144-1 to 144-4 are each terminated at the wall of a cavity 148 within which mounted devices 102a-1 to 102a-4 are mounted.

In the portion of the photonic integrated circuit assembly 142 shown in FIG. 3A, mounted devices 102a-1 to 102a-4 may be, for example, lasers used in a transceiver device or other transmitting device used in optical telecommunications networks and device 102b may be, for example, a driver used in the encoding of optical signals generated all or in part from the lasers. Other devices may also be used in other embodiments. The portion of the photonic integrated circuit assembly 142 shown in FIG. 3A provides an example configuration of a device structure having a plurality of bond pads 130 requiring lateral electrical interconnections to be formed and for which wafer level formation of these lateral interconnections would be highly beneficial.

The configuration of the photonic integrated circuit assembly 142 in FIG. 3A without electrical interconnections, is shown in FIG. 3B having solder ball bridges 101 formed between laterally aligned bond pads as shown to further illustrate an embodiment of a photonic integrated circuit assembly 142 having a plurality of solder ball bridge assemblies 100. In the embodiment of the photonic integrated circuit assembly 142 shown in FIG. 3B, each of the solder ball bridge assemblies 100 of the plurality of solder ball bridge assemblies 100 comprise substrate 110, one of the mounted devices 102a, 102b, and one of the solder ball bridges 101a, 101b, 101c. Solder ball bridges 101a are each formed between a bond pad 130 on one of the mounted devices 102a-1 to 102a-4 and a bond pad on the substrate 110. Solder ball bridges 101b are each formed between a bond pad 130 on mounted device 102b and submount 110_{subent}. And solder ball bridges 101c are each formed between a bond pad 130 on the substrate 110 and a bond pad on the submount 110_{subent}. All of the bond pad-to-bond pad interconnections shown in FIG. 3B are shown having solder ball bridges. The formation of solder ball bridges 101a, 101b, 101c shown in FIG. 3B may be formed using solder ball jetting at the wafer level (i.e., prior to singulation of the wafer).

The configuration of the photonic integrated circuit assembly 142 in FIG. 3A without electrical interconnections, is further shown in FIG. 3C with solder ball bridges 101 and with wirebonds 131 to illustrate an embodiment of a photonic integrated circuit assembly 142 having a plurality of solder ball bridge assemblies 100 formed in combination with a plurality of interconnections formed using a wirebond technique. As in FIG. 3C, the photonic integrated circuit assembly 142 of FIG. 3C shows solder ball bridge assemblies 100 comprising substrate 110, one of mounted devices 102a, 102b, and one of a solder ball bridge 101a, 101b, 101c wherein the solder ball bridges 101a are each formed between a bond pad 130 on a mounted device 102a and a bond pad on the substrate 110, wherein the solder ball bridges 101b are each formed between a bond pad 130 on the mounted device 102b and a bond pad 130 on the submount 110_{subent}, and wherein the solder ball bridges 101c are each formed between a bond pad 130 on the submount 110_{subent} and a bond pad 130 on the substrate 110. In addition to the electrical interconnections formed from solder ball bridges, however, the photonic integrated circuit assembly 142 in the embodiment shown in FIG. 3C further includes electrical interconnections formed from wirebonds 131. In the embodiment, wirebonds 131 are shown between some of the bond pads 130 on submount 110_{subent} and some of the bond pads 130 formed on the substrate 110. In some embodiments, one or more electrical interconnections may be formed using wirebonds 131 between bond pads 130 on one or more of the mounted devices 102a, 102b, substrate 110, and submount 110_{subent}, if present. The use of wirebonds 131 to form one or more electrical interconnections on substrate 110 may complement the use of the solder ball bridges 101 for configurations of photonic integrated circuit assemblies 142 in which the use of wirebonding techniques may provide an advantage over solder ball bridge 101. Wirebonding, for example, may enable a higher density of electrical interconnections than may be available with solder ball bridges. Other potential benefits of wirebonding may also warrant the use of configurations of photonic integrated circuit assemblies 142 having one or more electrical interconnection formed using solder ball bridges 101 and one or more electrical interconnections formed using wirebonds 131.

The use of wirebonding techniques is generally limited to the formation of interconnections after singulation of the wafer into individual die which is not a limitation of solder ball jetting. The formation of a large number of electrical interconnections prior to singulation can lead to significant reductions in the time required to form the interconnections, and the formation of these lateral interconnections using solder ball bridges can lead to significant time saving and productivity improvement in comparison to the use of wirebonding on singulated die. In embodiments, the formation of lateral interconnections prior to singulation can thusly enable significant improvements in productivity. Productivity improvements are further complemented with the cost savings associated with the use of solder in place of costly material commonly used to form wirebonds, such as gold.

Another disadvantage with wirebonding that may be overcome with the use of solder ball bridges 101, in place of wirebonds, is that the application of the wirebonding techniques may induce stresses in the structures to which the wirebonds are formed that may lead to undesirable damage to the photonic integrated circuit assemblies to which the wirebonds are formed particularly with the use of mounted devices. Mounted devices, such as mounted devices 102 described herein, may be damaged and underlying electrical connections to mounted devices may be disturbed, for example, with the bonding force and ultrasonic energy that are present in the formation of wirebonds from typical wirebonding apparatus that would not be present with the formation of solder ball bridges as described in embodiments herein.

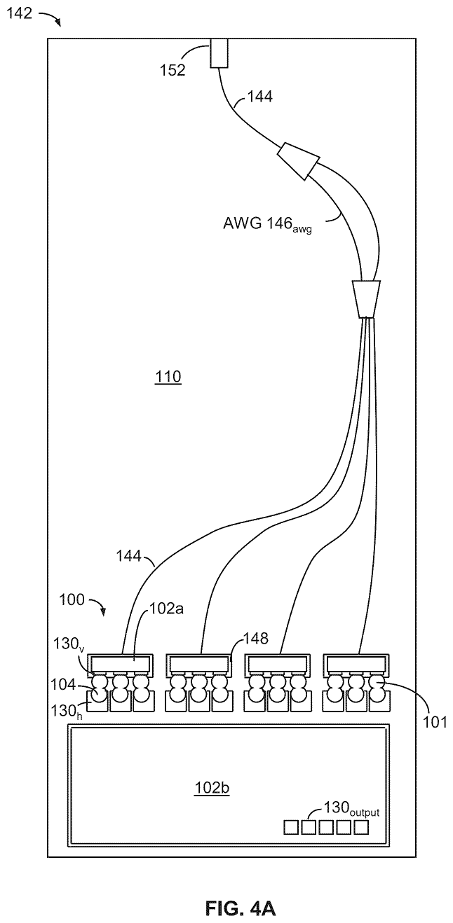

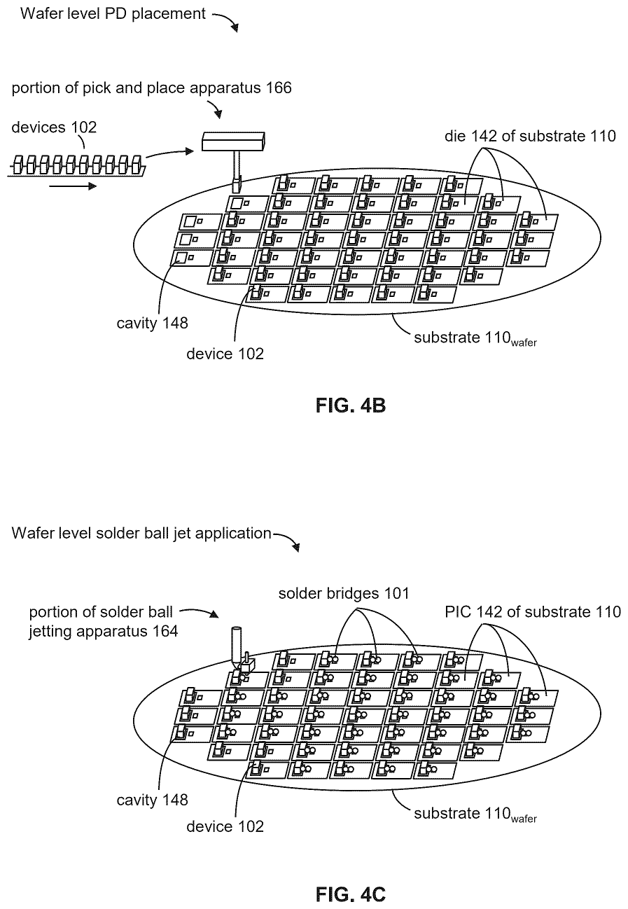

FIG. 4A shows a schematic top view drawing of a photonic integrated circuit assembly 142 configured having a plurality of instances of an embodiment of a solder ball bridge assembly 100 comprising substrate 110, a mounted device 102a, and solder ball bridge 101 wherein a terminal end of the solder ball bridge 101 in each instance is coupled to a vertically-oriented bond pad 130ᵥ formed on the mounted device 102a. In the embodiment, mounted device 102a may be, for example, a photodiode or other device having a vertically-oriented bond pad 130ᵥ after positioning in a cavity 148 formed on substrate 110. Mounting of a photodiode having a vertically-oriented bond pad 130ᵥ is described in additional detail herein.

The photonic integrated circuit assembly 142 in the configuration shown in FIG. 4A may be, for example, a demultiplexing device wherein an incoming multiplexed optical signal is coupled to the photonic integrated circuit assembly 142 through an optical fiber (not shown) mounted in optical fiber mounting site 152, and an arrayed waveguide 146 is used in the circuit to demultiplex the incoming optical signal into constituent signals that propagate through patterned planar waveguides 144 to mounted devices 102a configured as photodiodes. The photodiodes, may be used in conjunction with mounted device 102b, which may be configured, for example, as a transimpedance amplifier. Photonic integrated circuit assembly 142, configured as a demultiplexing device, converts the optical signals received by the mounted devices 102a to electrical signals at the output of the transimpedance amplifier which may be further coupled to an outgoing electrical connection through bond pads 130ₒᵤₜₚᵤₜ. In the embodiment shown in FIG. 4A, mounted device 102b is not configured having electrical or thermal interconnections using solder ball bridges 101 to the substrate 110 but rather may be electrically interconnected to an electrically or thermally conductive layer in an underlying electrical interconnect layer 103, for example.

FIG. 4B shows a schematic perspective drawing of a substrate 110_{wafer} having a plurality of die, wherein each die may comprise one or more photonic integrated circuit assembly 142, and further shows a portion of a pick-and-place apparatus 166 for placement of devices 102 onto the substrate 110_{wafer}. Automated pick-and-place apparatus enables automated placement of mounted devices 102 such as mounted device 102a, configured in the embodiment of the photonic integrated circuit assembly 142 as photodiodes, onto substrate 110. The mounted devices 102a are shown in FIG. 4B, having a vertically-oriented bond pad 130 . . . . These mounted devices 102a are positioned over, and then mounted within a cavity 148 formed in photonic integrated circuit assembly 142 on the common substrate 110_{wafer}. In other embodiments of photonic integrated circuit 142, mounted devices 102 having one or more horizontally-oriented bond pads 130ₕ may also be used as in, for example, the embodiment shown in FIG. 2B. And in yet other embodiments, mounted devices 102 having one or more vertically-oriented bond pads 130ᵥ may also be used. And in yet other embodiments, devices 102 having one or more of one or more horizontally-oriented and vertically-oriented bond pads may be used. In these and other embodiments of photonic integrated circuit assemblies 142, mounted devices 102 may be positioned in place on substrate 110 using pick-and-place apparatus such as pick-and-place apparatus 166 shown schematically in FIG. 4B to position mounted devices 102 onto substrate 110 prior to mounting. Mounting of the mounted devices 102 may require additional processing after placement using automated pick-and-place apparatus 166 such as, for example, with the use or activation of a bonding material between the mounted device 102 and the substrate 110.

FIG. 4C shows a schematic perspective drawing of a portion of a solder ball jetting apparatus 164 and a substrate 110_{wafer} having a plurality of die comprising one or more photonic integrated circuit assemblies 142 as in, for example, the embodiment shown in FIG. 4A. Solder ball jetting apparatus 164 forms solder ball bridges 101 each having a terminal end that forms a contact with a vertically-oriented bond pad 130ᵥ of a mounted device 102a on the unsingulated substrate 110_{wafer} as described, for example, in conjunction with the embodiment shown in FIG. 4B.

Wafer level processes enable significant improvements in productivity and are generally preferable in comparison to processes that are performed after singulation of a wafer into individual die. The benefits of wafer level processes are evident in the adoption and use of wafer level processes at the front end of the manufacturing process. A number of back-end processes leading up to the packaging of singulated die have not yet transitioned to the wafer level as the development of equipment and processing at the back end have lagged behind more stringent front-end processing in semiconductor fabrication technology. Embodiments described herein for the formation of positionally displaced electrical and thermal interconnections are processes that can be performed at the wafer level prior to singulation of the wafer into die having one or more photonic integrated circuit assemblies 142. The wafer level processes enabled with the use of lateral solder ball bridge formation, for example, to form one or more of an electrical and a thermal interconnect between bond pads 130 on a mounted device 102 and bond pads 130 on a substrate 110 may be used in combination with current wirebonding techniques to facilitate the transition to further the development of wafer level processing at the back end.

### Solder Ball Bridge Formation

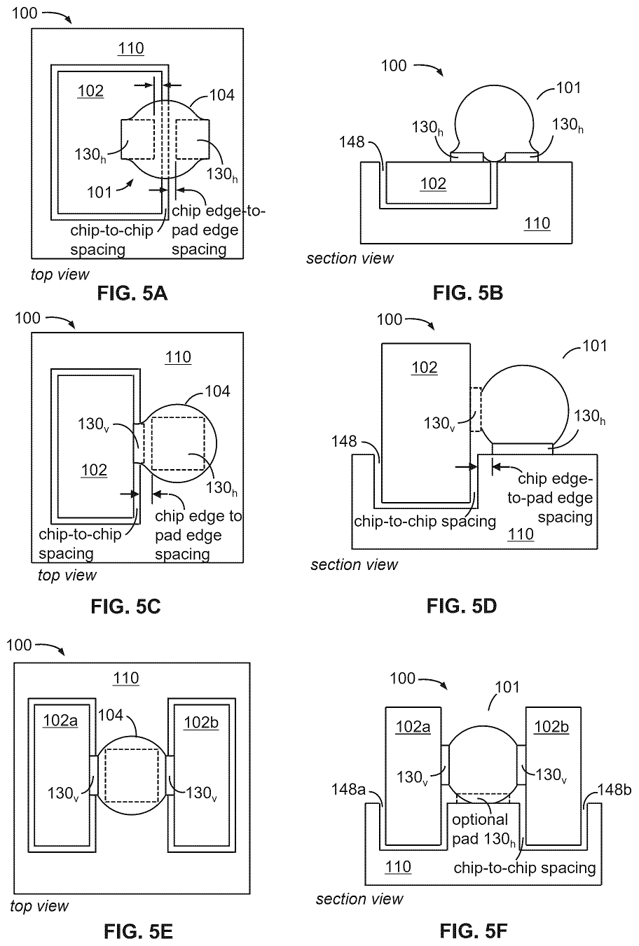

FIGS. 5A to 8D illustrate solder ball bridge structures, solder ball bridge assemblies 100, and steps in methods of formation of structures and assemblies that include a solder ball bridge 101. Particular detail is provided in these figures with respect to the quantity of solder balls 104 used in the formation of the solder ball bridge 101 and the orientation of bond pads 130 (or other solder-wettable surfaces) to which the terminal ends of solder ball bridges 101 are bonded in the embodiments described.

FIGS. 5A-5F show schematic drawings of embodiments of solder ball bridge assemblies 100 comprising a substrate 110, a mounted device 102, and a solder ball bridge 101 wherein the solder ball bridge 101 is formed from a single solder ball 104. Particular detail is provided with respect to the configuration of bond pads 130 used at the terminal ends of the solder ball bridges 101 formed from a single solder ball 104 in the described embodiments.

FIGS. SA and 5B show top view and cross-sectional schematic drawings, respectively, of an embodiment of solder ball bridge assembly 100 comprising substrate 110, mounted device 102, and solder ball bridge 101 wherein the solder ball bridge 101 is formed from a single solder ball 104 disposed on a horizontally-oriented bond pad 130ₕ formed on the substrate 110 and a horizontally-oriented bond pad 130ₕ formed on the mounted device 102. Solder ball bridge assembly 100 shows mounted device 102 mounted in cavity 148 as noted in the cross-sectional schematic drawing in FIG. 5B for the embodiment. Solder ball 104 spans the two horizontally-oriented bond pads 130ₕ to form solder ball bridge 101 that laterally spans the distance between the horizontally-oriented bond pads 130ₕ. In embodiments, the solder in the solder balls 104 binds to the solder-wettable surfaces on the bond pads 130ₕ and bridges the “chip-to-chip spacing” and the “chip edge-to-pad edge spacing” (within opposing sets of arrows for both the “chip edge-to-pad edge spacing” on the substrate 110 and the mounted device 102). Solder ball bridge 101 shown in FIGS. 5A and 5B spans the spacing between the two horizontally-oriented pads 130ₕ that includes the “chip-to-chip spacing” that is formed between the mounted device 102 and the cavity wall of the cavity 148 formed in the substrate 110. Typical solder balls, ranging in size from 20 microns to 2000 microns, may be used to form embodiments of the solder ball bridge assembly 100 having solder ball bridge 101 and thusly, to form a lateral interconnection between the two horizontally-oriented bond pads 130ₕ in the embodiment. In the embodiment shown in FIGS. 5A and 5B, the length of a side of the bond pads 130ₕ is shown to be approximately a third of the diameter of the solder ball 104 shown. In an embodiment configured as depicted in FIGS. 5A and 5B, a solder ball 104 that is 1000 microns in diameter may be used to form the solder ball bridge 101 that forms a lateral interconnect between bond pads 130ₕ having a square area of approximately 300 microns×300 microns (=90,000 microns squared).

In another embodiment configured as depicted in FIGS. 5A and 5B, a solder ball 104 that is 100 microns in diameter may be used to form the solder ball bridge 101 that forms a lateral interconnect between bond pads 130ₕ having a square area of approximately 30 microns×30 microns (=900 microns squared). Other combinations of solder ball diameters and bond pad areas may be used in other configurations of embodiments.

FIGS. 5C and 5D show top view and cross-sectional schematic drawings of an embodiment of a solder ball bridge assembly 100 comprising substrate 110, mounted device 102, and solder ball bridge 101 wherein the solder ball bridge 101 is formed from a single solder ball 104 disposed between a horizontally-oriented bond pad 130ₕ formed on the substrate 110 and a vertically-oriented bond pad 130ᵥ formed on the mounted device 102. Solder ball bridge assembly 100 in the embodiment, shows mounted device 102 mounted in cavity 148 as noted in the cross-sectional schematic drawing in FIG. 5D. Solder ball 104 spans the vertically-oriented bond pad 130ᵥ on the mounted device 102 and the horizontally-oriented bond pad 130ₕ on the substrate 110 to form the solder ball bridge 101. In embodiments, the solder in the solder balls 104 adheres to the solder-wettable surfaces on the bond pads 130ᵥ, 130ₕ.

The solder ball bridge 101 shown in the embodiment in FIGS. 5C and 5D spans the spacing between the vertically-oriented bond pad 130ᵥ on the mounted device 102 and all or a portion of the horizontally-oriented bond pad 130ₕ on the substrate 110 and that may further include all or a portion of a “chip-to-chip spacing” that is formed between the mounted device 102 and the cavity wall of the cavity 148 formed in the substrate 110. Although other solder ball sizes may be used, typical solder balls ranging in size from 20 microns to 2000 microns may be used to form embodiments of the solder ball bridge 101 and thusly, to form a lateral interconnection between the vertically-oriented bond pad 130ᵥ on the mounted device 102 and the horizontally-oriented bond pad 130ₕ on the substrate 110. In the embodiment shown in FIGS. 5C and 5D, the diameter of the solder ball is approximately 50% larger than the length of a side of the horizontally-oriented bond pads 130ₕ. In an embodiment configured as depicted in FIGS. 5C and 5D, a solder ball 104 that is 1000 microns in diameter may be used to form solder ball bridge 101 that forms a lateral interconnect between bond pad 130ₕ on the substrate and bond pad 130ᵥ on the mounted device 102 having a square area of approximately 667 microns×667 microns (˜445,000 microns squared).

In another configuration of the embodiment depicted in FIGS. 5C and 5D, a solder ball 104 having a diameter of 100 microns may be used to form solder ball bridge 101 that is used in the formation of the interconnect between bond pad 130ₕ on the substrate 110 and bond pad 130ᵥ on the mounted device 102 having a square area of approximately 67 microns×67 microns (˜4,500 microns squared). In these and other embodiments, the extent of the contact formed between the solder ball 104 and the vertically-oriented bond pad 130ᵥ on the mounted device 102 may vary. Other combinations of solder ball diameter and bond pad areas may be used in other configurations of the embodiment depicted in FIGS. 5C and 5D.

FIGS. 5E and 5F show top view and cross-sectional schematic drawings of an embodiment of a solder ball bridge assembly 100 comprising substrate 110, first mounted device 102a and second mounted device 102b, and solder ball bridge 101 wherein the solder ball bridge 101 is formed from a single solder ball 104 disposed between a vertically-oriented bond pad 130ᵥ on the first mounted device 102a and a vertically-oriented bond pad 130ᵥ on the second mounted device 102b. Solder ball bridge assembly 100 in the embodiment, shows first mounted device 102a mounted in cavity 148a and second mounted device 102b mounted in cavity 148b as noted in the cross-sectional schematic drawing in FIG. 5E. Solder ball 104 spans the distance between the vertically-oriented bond pad 130ᵥ on the first mounted device 102a and the vertically-oriented bond pad 130ᵥ on the second mounted device 102b to form the solder ball bridge 101 between these vertically-oriented bond pads 130 . . . . In embodiments, the solder in the solder balls 104 binds to the solder-wettable surfaces on the bond pads 130ᵥ.

The solder ball bridge 101 shown in the embodiment in FIGS. 5E and 5F spans the spacing between the vertically-oriented bond pads 130ᵥ on the first mounted device 102a and the second mounted device 102b and that may further include all or a portion of a “chip-to-chip spacing” that is formed between a first and second mounted device 102a, 102b and the cavity wall of a cavity 148a, 148b, respectively formed in the substrate 110. Although other solder ball sizes may be used, typical solder balls ranging in size from 20 microns to 2000 microns may be used to form embodiments of the solder ball bridge 101 and thusly, to form a lateral interconnection between the vertically-oriented bond pads 130ᵥ on the first and second mounted devices 102a, 102b, respectively. In the embodiment shown in FIGS. 5E and 5F, the diameter of the solder ball is approximately 50% larger than the length of a side of the optional horizontally-oriented bond pad 130ₕ shown. In some embodiments, adequate adhesion may be provided to the vertically-oriented bond pads 130ᵥ on the first and second mounted devices 102a, 102b, respectively, to form the interconnect between the two vertically-oriented bond pads 130 . . . . In other embodiments, an optional horizontally-oriented bond pad 130ₕ may be included to provide additional solder-wettable surface area within the solder ball bridge assembly to enable improved support for the solder in the solder ball bridge 101.

In an embodiment configured as depicted in FIGS. 5E and 5F, a solder ball 104 that is 1000 microns in diameter may be used to form solder ball bridge 101 that forms a lateral interconnect between the vertically-oriented bond pads 130ᵥ on the first and second mounted devices 102a, 102b. In another embodiment configured as depicted in FIGS. 5E and 5F, a solder ball 104 having a diameter of 100 microns may be used to form the solder ball bridge 101 that forms a lateral interconnect between vertically-oriented bond pads 130ᵥ on the first and second mounted devices 102a, 102b, respectively. In these and other embodiments, the extent of the contact formed between the solder ball 104 and the vertically-oriented bond pads 130ᵥ on the mounted devices 102a, 102b may vary depending on the diameter of the solder ball 104, among other factors.

Solder ball bridges 101, in embodiments, may be formed from one or more solder balls 104. As the number of solder balls 104 in the solder ball bridge 101 increases from a configuration having a single solder ball, increasing attention to the order of placement of the solder balls 104 may be necessary to facilitate adhesion to a bond pad 130 or other solder-wettable surface and to adjacent solder balls 104 in the solder ball bridge 101.

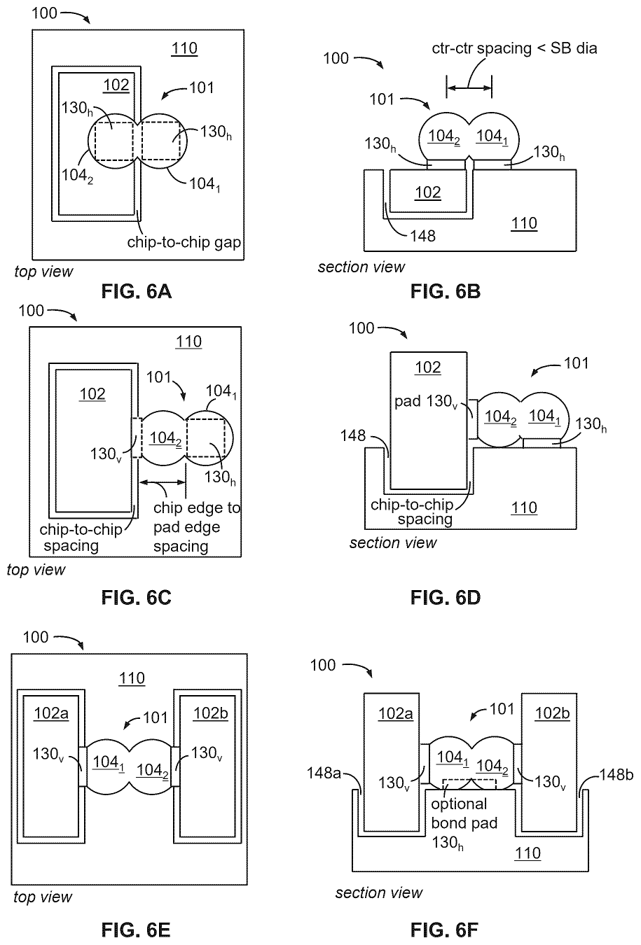

FIGS. 6A-6F show schematic drawings of embodiments of solder ball bridge assemblies 100 comprising substrate 110, mounted device 102, and solder ball bridge 101 wherein the solder ball bridge 101 is formed from two laterally coupled solder balls 104. Lateral coupling of solder balls 104 may further facilitate the formation of solder ball bridges 100 over non-solder-wettable surfaces present in solder ball bridge assemblies 100 between, for example, positionally displaced bond pads 130 as shown, for example, in FIGS. 6A-6F.

FIGS. 6A and 6B show top view and cross-sectional schematic drawings, respectively, of an embodiment of a solder ball bridge assembly 100 comprising substrate 110, mounted device 102, and solder ball bridge 101 wherein the solder ball bridge 101 is formed from two solder balls 104 disposed all or in part on a horizontally-oriented bond pads 130ₕ on the substrate 110 and a horizontally-oriented bond pad 130ₕ on the mounted device 102. Solder ball bridge assembly 100 in the embodiment, shows mounted device 102 mounted in cavity 148 as noted in the cross-sectional schematic drawing in FIG. 6B. The two solder balls 104₁, 104₂ shown in FIGS. 6A and 6B form solder ball bridge 101 that spans the two horizontally-oriented bond pads 130ₕ and the spacing between the two horizontally-oriented bond pads 130ₕ. In embodiments, the solder in the solder balls 104₁, 104₂ binds to the solder-wettable surfaces on the bond pads 130ₕ.

The solder ball bridge 101 shown in FIGS. 6A and 6B spans the spacing between the two horizontally-oriented bond pads 130ₕ that includes the “chip-to-chip spacing” that is formed between the mounted device 102 and the cavity wall of the cavity 148 formed in the substrate 110. Typical solder balls 104, ranging in size from 20 microns to 2000 microns, may be used to form embodiments of the solder ball bridge 101 and thusly, to form a lateral interconnection between the two horizontally-oriented bond pads 130ₕ. In the embodiment shown in FIGS. 6A and 6B, the diameter of the solder balls 104 in the solder ball bridge 101 is approximately 50% larger than the length of a side of the square bond pads 130ₕ although solder balls having other diameters may also be used in other embodiments. In an embodiment configured as depicted in FIGS. 6A and 6B, solder balls 104 having a diameter of 1000 microns would correspond to a side length of a square bond pad of approximately 670 microns. A solder ball bridge 101 formed from two solder balls 104 having a diameter of 1000 microns may enable, for, example, the formation of a lateral interconnect between bond pads 130ₕ having a square area of approximately 670 microns×670 microns (˜450,000 microns squared) configured, for example, as shown in FIGS. 6A and 6B having two horizontally-oriented bond pads 130ₕ.

In another embodiment configured as depicted in FIGS. 6A and 6B, a solder ball 104 having a diameter of 100 microns may be used to form the solder ball bridge 101 that forms a lateral interconnect between bond pads 130ₕ having a square area of approximately 67 microns×67 microns (˜4,500 microns squared).

Other combinations of solder ball diameter and bond pad area may be used in other embodiments.

Two solder balls 104₁, 104₂ are shown in FIGS. 6A and 6B in solder ball bridge 101 having sequential subscripts 1, 2, respectively that denote an example sequential placement for the solder balls 104₁, 104₂ into the solder ball bridge 101. In the embodiment shown, for example, a first solder ball 104₁ may be firstly positioned onto the horizontally-oriented bond pad 130ₕ on the substrate 110 after which a second solder ball 104₂ may be positioned onto the horizontally-oriented bond pad 130ₕ on the mounted device 102 to form solder ball bridge 101 in the embodiment. The narrow spacing between bond pads 130ₕ and the use of solder balls having a diameter that is larger than the side length of the bond pad 130ₕ, enables the solder balls to come into overlapping contact that further enables the solder in the two solder balls to be melded together at least in part to form an electrical interconnection. In other embodiments, other quantities of solder balls 104, other sequences of placement, and other solder ball sizes may be used as further described, for example, in descriptions provided herein.

FIGS. 6C and 6D show top view and cross-sectional schematic drawings, respectively, of an embodiment of a solder ball bridge assembly 100 comprising substrate 110, mounted device 102, and solder ball bridge 101 formed from two solder balls 104₁, 104₂ disposed between a horizontally-oriented bond pad 130ₕ formed on the substrate 110 and a vertically-oriented bond pad 130ᵥ formed on the mounted device 102. Solder ball bridge assembly 100 in the embodiment, shows mounted device 102 mounted in cavity 148 as noted in the cross-sectional schematic drawing in FIG. 6D. The two solder balls 104₁, 104₂ form solder ball bridge 101 that spans the distance between the vertically-oriented bond pad 130ᵥ on the mounted device 102 and the horizontally-oriented bond pad 130ₕ on the substrate 110. In embodiments, the solder in the solder balls 104 binds to the solder-wettable surfaces on the bond pads 130ᵥ, 130ₕ in the embodiment.

The solder ball bridge 101 formed from the two solder balls 104 shown in the embodiment in FIGS. 6C and 6D spans the spacing between the vertically-oriented bond pad 130ᵥ on the mounted device 102 and all or a portion of the horizontally-oriented bond pad 130ₕ on the substrate 110 and that may further include all or a portion of a “chip-to-chip spacing” that is formed between the mounted device 102 and the cavity wall of the cavity 148 formed in the substrate 110. Although other solder ball sizes may be used, typical solder balls ranging in size from 20 microns to 2000 microns may be used to form embodiments of the solder ball bridge 101 and thusly, to form a lateral interconnection between the vertically-oriented bond pad 130ᵥ on the mounted device 102 and the horizontally-oriented bond pad 130ₕ on the substrate 110. In the embodiment shown in FIGS. 6C and 6D, the diameter of the solder balls 104 in the solder ball bridge 101 is approximately 50% larger than the length of a side of the horizontally-oriented bond pads 130ₕ. In an embodiment configured as depicted in FIGS. 6C and 6D, solder balls 104 having a diameter of 1000 microns would correspond to a side length of a square bond pad on the substrate of approximately 670 microns. A solder ball bridge 101 formed from two solder balls 104 having a diameter of 1000 microns may be used, for example, to form a lateral interconnect between horizontally-oriented bond pad 130ₕ on the substrate and vertically-oriented bond pad 130ᵥ on the mounted device 102 having a square area of approximately 667 microns×667 microns (˜445,000 microns squared) configured as shown in FIGS. 6C and 6D.

In another embodiment configured as depicted in FIGS. 6C and 6D, solder balls 104 having a diameter of 100 microns may be used to form a solder ball bridge 101 and the resulting lateral interconnect between horizontally-oriented bond pad 130ₕ on the substrate 110 and vertically-oriented bond pad 130ᵥ on the mounted device 102 having a square area of approximately 67 microns×67 microns (˜4.500 microns squared). In these and other embodiments, the extent of the contact formed between the solder ball 104 and the vertically-oriented bond pad 130ᵥ on the mounted device 102 may vary. The configurations described herein are provided as examples only, and not intended to limit the scope of embodiments. Other combinations of solder ball diameter and bond pad area may be used in other embodiments.

The two solder balls 104₁, 104₂ shown in FIGS. 6C and 6D in solder ball bridge 101 having sequential subscripts 1, 2, respectively denote another example sequential placement for the solder balls 104₁, 104₂ into the solder ball bridge 101. In the embodiment shown, a first solder ball 104₁ may be firstly positioned onto, and wetted to, the horizontally-oriented bond pad 130ₕ on the substrate 110 after which a second solder ball 104₂ may be positioned between the vertically-oriented bond pad 130ₕ on the mounted device 102 and the first solder ball 104₁ to form solder ball bridge 101. The first solder ball 104₁, securely bound to the horizontally-oriented bond pad 130ₕ on the substrate 110, in the embodiment, and the solder-wettable vertically-oriented bond pad 130ᵥ on the mounted device 102, provide secure anchoring for second solder ball 104₂ despite the non-solder-wettable surfaces between the bond pads over which the lateral solder ball bridge 101 is formed. A narrow spacing between bond pads 130ᵥ, 130ₕ, relative to the diameter of the solder balls, and the use of solder balls 104₁, 104₂ having a diameter that is larger than the spacing between the vertically-oriented bond pad 130ᵥ on the mounted device 102 and the first solder ball 104₁, enables the solder ball 104₂ to come into overlapping contact with solder ball 104₁ that further enables the solder in the two solder balls 104₁, 104₂ to be melded together at least in part to form one or more of an electrical and thermal interconnection between the mounted device 102 and the substrate 110. The resulting solder ball bridge 101 is shown over non-solder-wettable surface area on the substrate 110 between the bond pads as described, for example, in conjunction with the description of FIG. 1C. In other embodiments, other quantities of solder balls 104, other sequences of placement, and other solder ball sizes may be used as further described, for example, in descriptions provided herein.

FIGS. 6E and 6F show top view and cross-sectional schematic drawings of an embodiment of a solder ball bridge assembly 100 comprising substrate 110, first mounted device 102a and second mounted device 102b both mounted to the substrate 110, and solder ball bridge 101 formed from two solder balls 104₁, 104₂ wetted to vertically-oriented bond pads 130ᵥ formed on the first and second mounted devices 102a, 102b, respectively. Solder ball bridge assembly 100 in the embodiment, shows first mounted device 102a mounted in cavity 148a and second mounted device 102b mounted in cavity 148b as noted in the cross-sectional schematic drawing in FIG. 6E. Two solder balls 104₁, 104₂ are used in the embodiment to form the solder ball bridge 101 that spans the lateral distance between the vertically-oriented bond pad 130ᵥ on the first mounted device 102a and the vertically-oriented bond pad 130ᵥ on the second mounted device 102b. In embodiments of the solder ball bridge assembly 101 as depicted in FIGS. 6E and 6F, the solder in the solder balls adheres to the solder-wettable surfaces on the vertically-oriented bond pads 130ᵥ, melds with the solder in the adjacent solder ball, and bridges the non-solder-wettable surface area of the substrate 110 underlying the spacing between the bond pads 130ᵥ.

The solder ball bridge 101 shown in the embodiment in FIGS. 6E and 6F spans the distance between the vertically-oriented bond pad 130ᵥ on the first mounted device 102a and the vertically-oriented bond pad 130ᵥ on the second mounted device 102b and that may further include all or a portion of a “chip-to-chip spacing” that is formed between a first and second mounted device 102a, 102b, respectively, and the cavity wall of cavity 148a, 148b, respectively formed in the substrate 110. Although other solder ball sizes may be used, typical solder balls ranging in size from 20 microns to 2000 microns may be used to form embodiments of the solder ball bridge 101 and thusly, to form an interconnection between the vertically-oriented bond pads 130ᵥ on the first and second mounted devices 102a, 102b, respectively. In the embodiment shown in FIGS. 6E and 6F, the diameter of the two solder balls 104₁, 104₂ is approximately 20% larger than half the distance between the two vertically-oriented bond pads in the solder ball bridge assembly 100. Solder balls having other relationships between the solder ball diameter and the spacing between vertically-oriented bond pads 104, may be used in other embodiments.

The two solder balls 104₁, 104₂ shown in FIGS. 6E and 6F in solder ball bridge 101 having sequential subscripts 1, 2, respectively denote another example sequential placement for the solder balls 104₁, 104₂ into the solder ball bridge 101. In the embodiment shown, a first solder ball 104₁ may be firstly positioned onto, and wetted to, the vertically-oriented bond pad 130ᵥ on the mounted device 102a, after which a second solder ball 104₂ may be positioned between the vertically-oriented bond pad 130ᵥ on the mounted device 102b and the first solder ball 104₁ to form solder ball bridge 101. The first solder ball 104₁, securely bound to the vertically-oriented bond pad 130ᵥ on the mounted device 102a, in the embodiment, along with the vertically-oriented bond pad 130ᵥ on the mounted device 102b, provides secure anchoring for second solder ball 104₂ despite the non-solder-wettable surfaces between the bond pads over which the lateral solder ball bridge 101 is formed. Semi-molten solder balls ejected from solder ball jetting apparatus 164 enables the second solder ball 104₂ to wet the solder-wettable bond pads and to meld with the first solder ball 104₁. The use of solder balls having a diameter that is larger than half the distance between vertically-oriented bond pads 130ᵥ enables the solder balls to come into overlapping contact that further enables the solder in the two solder balls 104₁, 104₂ to be melded together at least in part to form one or more of an electrical and thermal interconnection between the mounted devices 102a, 102b. In other embodiments, other quantities of solder balls 104, other sequences of placement, and other solder ball sizes may be used as further described, for example, in descriptions provided herein.

In some embodiments, adequate adhesion of the solder balls 104₁, 104₂ to the vertically-oriented bond pads 130ᵥ on the first and second mounted devices 102a, 102b, respectively, is provided upon placement to form the lateral interconnect between the two vertically-oriented bond pads 130. In some embodiments, one or more of optional horizontally-oriented bond pad 130ₕ and solder-wettable surface area may be included on the substrate 110 to facilitate containment of the solder within a solder-wettable surface area on the substrate 110 as described, for example, in conjunction with the embodiment shown in FIGS. 5A and 5B. Optional horizontally-oriented bond pad 130ₕ is also shown in the cross-sectional drawing in FIG. 6F. Other solder-wettable materials may be used on substrate 110 in all or a portion of the underlying spacing between vertically-oriented bond pads 130ᵥ on the first and second mounted devices 102a, 102b, respectively, in place of, or in addition to, the optional horizontally-oriented bond pad 130ₕ shown, for example, in FIG. 6F. Absent the optional horizontally-oriented bond pad 130ₕ shown in FIG. 6F, caution may be required in depositing at least the first solder ball 104₁ in the solder ball bridge as the impact with the non-solder-wettable surface area of the substrate 110 may lead to undesirable splattering of molten solder in the deposited solder ball.

In an embodiment configured as depicted in FIGS. 6E and 6F, solder balls 104₁, 104₂ having a diameter of 1000 microns may be used to form a solder ball bridge 101 to form a lateral interconnect between the vertically-oriented bond pads 130ᵥ on the first and second mounted devices 102a, 102b. Solder balls having a diameter of 1000 microns configured as shown in the embodiment in FIGS. 6E and 6F could span a distance of 2400 microns between the vertically-oriented bond pads 130ᵥ on the mounted devices 102a, 102b. In other embodiments, and in other configurations for the same embodiment, other solder balls having other diameters and combinations of diameters may also be used.

In another embodiment configured as depicted in FIGS. 6E and 6F, solder balls 104₁, 104₂ having a diameter of 100 microns may be used to form the solder ball bridge 101 and to form a lateral interconnect between the vertically-oriented bond pads 130ᵥ on the first mounted device 102a and the vertically-oriented bond pad 130ᵥ on the second mounted device 102b. In these and other embodiments, the extent of the contact formed between the solder balls 104₁, 104₂ and the vertically-oriented bond pads 130ᵥ on the mounted devices 102a, 102b may vary depending on the diameter of the solder balls used, among other factors. Solder balls having a diameter sufficient to span more than half the “pad-to-pad spacing” may be preferred for configurations of the solder ball bridge 101 having two solder balls 104.

FIGS. 5A-5F show schematic drawings of embodiments of solder ball bridge assemblies 100 that include solder ball bridge 101 comprising a single solder ball 104. FIGS. 6A-6F show schematic drawings of embodiments of solder ball bridge assemblies 100 that include solder ball bridge 101 comprising two solder balls 104₁, 104₂. And FIGS. 1A-1I show schematic drawings of embodiments of solder ball bridge assemblies 100 that include solder ball bridge 101 configured having three solder balls. Other quantities of solder balls 104 may be used to form other embodiments of solder ball bridge assemblies 100 having solder ball bridges 101 including solder ball bridges 101 comprising four solder balls, five solder balls, and more than five solder balls. As the number of solder balls 104 in the solder ball bridge 101 increases from a configuration having a single solder ball 104, increasing attention to the order of placement of the solder balls 104 may be necessary to facilitate adhesion to a bond pad 130 or other solder-wettable surface and to previously placed solder balls 104 in a solder ball bridge 101. Additional details pertaining to the formation of solder ball bridges 101 is provided in the following paragraphs including details regarding sequential placement of the solder balls 104 in the formation of solder ball bridges 101, regarding the anchoring and adhesion of solder balls 104 to solder-wettable surfaces and to previously placed solder balls 104 within a solder ball bridge 101, and the addition of various levels of laser energy accompanying the deposition of the solder balls in the formation of a solder ball bridge 101.

Additional details pertaining to the formation of solder ball bridges 100 is provided in the following paragraphs including the addition of various levels of laser energy that may accompany the deposition of the solder balls in the formation of a solder ball bridge 101, regarding the anchoring and adhesion of solder balls 104 to solder-wettable surfaces and to previously placed solder balls 104 of a solder ball bridge 101, and regarding the sequential placement of solder balls 104 in the formation of a solder ball bridge 101.

### Low and High Energy Solder Ball Deposition

In the following paragraphs, the addition of differing levels of laser energy accompanying the deposition of the solder balls in the formation of embodiments of solder ball bridge 101 is described.

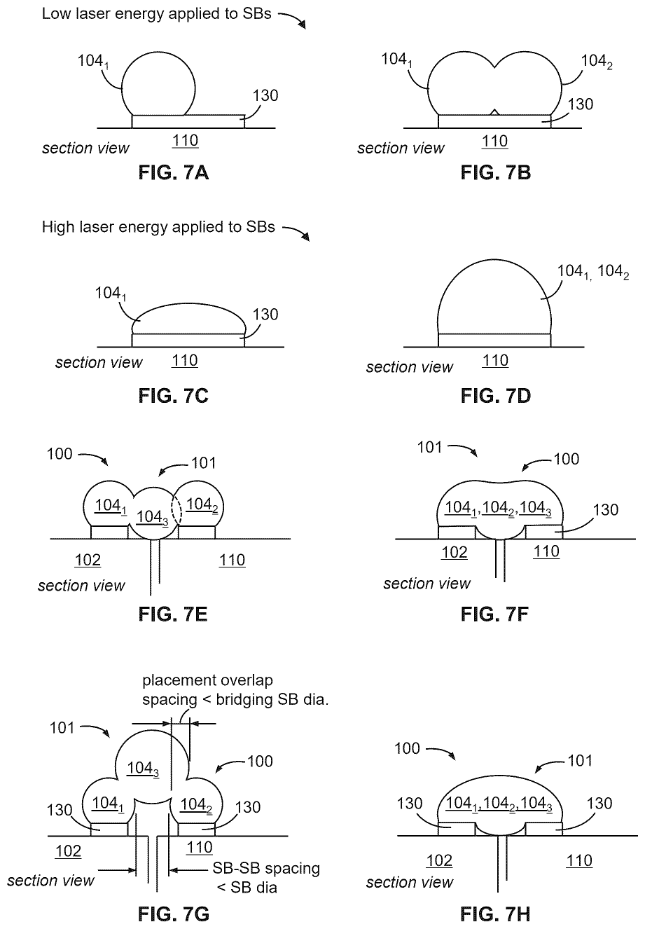

FIG. 7A shows a cross-sectional schematic drawing of a solder ball 104₁ disposed on a bond pad 130 from a solder ball jetting apparatus 164 wherein the solder ball is disposed with an accompanying “low” laser energy such that the spheroidal shape of the solder ball is maintained at least in part. The area of the bond pad 130ᵥ formed for example, on substrate 110 in an embodiment of a solder ball bridge assembly 100, is substantially greater than the contacting area of the solder in the solder ball 104 with the bond pad 130. “Substantially” greater area of the bond pad is relative to the diameter of the solder ball used in the solder ball bridge 101. With respect to the contact area of a particular sized solder ball 104, a “substantially” greater contact area of a bond pad 130 may be a bond pad having an area that is greater than 1.5 times the diameter of a solder ball deposited onto the bond pad.

In the example configuration shown in FIG. 7A, a “low” energy level is used to accompany the solder ball before, during, or after emission of the solder ball 104₁ from the solder ball jetting apparatus 164. A “low” energy, as used herein, describes a level of energy provided to a solder ball 104 from a solder ball jetting apparatus 164 such that the spheroidal shape of a solder ball 104 ejected from a solder ball jetting apparatus 164 is substantially maintained upon deposition onto a bond pad 130 or other solder-wettable surface. A solder ball having a “substantially” maintained spheroidal shape is a solder ball for which the origin as a solder ball may be recognizable as having been a solder ball after deposition into the all or a portion of the solder ball bridge assembly 100.

By contrast, a “high” energy, as used herein, describes a level of energy provided to a solder ball 104 before, during, or after emission from a solder ball jetting apparatus 164 such that the spheroidal shape of the solder ball 104 is no longer distinguishable on the bond pad 130 or other surface upon which the solder ball resides upon deposition from the solder ball jetting apparatus 164.

Solder balls 104 accompanied by a “low” amount of laser energy from a solder ball jetting apparatus 164, as used herein, substantially maintains the distinguishable spheroidal shape of the solder ball 104₁ on the bond pad 130 after anchoring of the solder ball 104₁ to the bond pad 130. An example of a solder ball 104 having a “low” accompanying energy level upon being deposited onto a bond pad 130 in a portion of an embodiment of a solder ball bridge assembly 100 is illustrated in FIG. 7A. The spheroidal shape of the solder ball 104₁ is shown to be significantly maintained after deposition onto the bond pad 130 shown in FIG. 7A.

FIG. 7B shows the bond pad and first solder ball 104₁ as in FIG. 7A with the addition of second solder ball 104₂ wherein the second solder ball 104₂ is deposited onto the bond pad 130 also accompanied with a “low” energy level. The second solder ball 104₂ is anchored to the solder-wettable bond pad 130 and to the first solder ball 104₁ illustrating the effect of anchoring of a second solder ball 104₂ to a previously deposited first solder ball 104₁ in addition to the effect of anchoring of the first solder ball 104₁ and the subsequently placed second solder ball 104₂ to the bond pad 130. These anchoring effects will be further illustrated with respect to other effects that facilitate the formation of lateral interconnections formed from one or more solder balls 104 used in the formation of embodiments of solder ball bridge assemblies 100 having a solder ball bridge 101.

Use of “low” energy to accompany the deposition of the solder balls 104 enables a plurality of solder balls 104 to be coupled to one or more of a bond pad 130 and previously deposited solder balls 104 in the formation of a solder ball bridge 101. In some embodiments, as-deposited solder ball bridges 101 may provide adequate gap filling, adhesion, and electrical conductivity to satisfy the electrical and thermal connectivity requirements in embodiments of solder ball bridge assembly 100. In other embodiments having “low” energy accompanying the deposition of one or more of the solder balls 104 in the solder ball bridge 101, one or more of a post deposition annealing step, post deposition heating step, post deposition laser heating, and other post deposition modification steps may be used to modify one or more of the as-deposited solder balls 104 in the solder ball bridge 101.

FIG. 7C shows a cross-sectional schematic drawing of a first solder ball 104₁ disposed on a bond pad 130 from a solder ball jetting apparatus 164 wherein the first solder ball 104₁ is disposed with an accompanying “high” laser energy such that the spheroidal shape of the solder ball 104₁ is not maintained upon deposition. The area of the bond pad 130 is substantially greater than the contact area between the solder ball 104₁ and bond pad 130 in the portion of the embodiment of the solder ball bridge assembly 100 shown in FIG. 7C. In the embodiment shown in FIG. 7C, a “high” energy level accompanies the deposition of the first solder ball 104₁ at one or more of before, during, and after emission of the solder ball 104₁ from the solder ball jetting apparatus 164. The original spheroidal shape of the first solder ball 104₁ is no longer distinguishable in the schematic cross-sectional drawing in FIG. 7C as the solder from the deposited solder ball 104₁, accompanied by the “high” energy level, is distributed across the solder-wettable surface of the bond pad 130 and bound by surface tension within the molten solder prior to cooling below the temperature at which the molten solder resolidifies. Solder balls 104 accompanied with a high energy may be highly molten, and prone to being distributed across the surface area of the solder-wettable bond pad 130.

FIG. 7D shows a cross-sectional schematic drawing of the bond pad and first solder ball 104₁ as in FIG. 7C with the addition of a second solder ball 104₂ wherein the second solder ball 104₂ is also deposited onto the bond pad 130 accompanied with a “high” energy level. The additional solder provided by the second solder ball 104₂ is melded into the solder from the first solder ball 104₁ to form a mound of solder that is bound by the forces imposed by the solder-wettable surface area of the bond pad 130 and the surface tension within the molten solder mound prior to cooling below the temperature at which the molten solder resolidifies. Prior to cooling, the shape of the solder mound may resemble, for example, the solder mound as shown in FIG. 7D. This shape may also be significantly maintained upon cooling below the solidification temperature. The shape of the solder mound may vary, in embodiments, as the ultimate shape of the solder mound is dependent on the amount of energy provided to the second solder ball 104₂ and the rate of dissipation of the energy accompanying the deposition of the both the first solder ball 104₁ and the second solder ball 104₂. Other factors such as the delay between the deposition of sequentially deposited solder balls 104 and the coupling of the bond pad 130 upon which the solder balls are deposited to structures in the substrate 110 and the mounted device that may affect the cooling rate of the deposited solder, among other factors, may also affect the final shape of the solder mound that is formed on a bond pad in embodiments of solder ball bridge assemblies 100.

The example cross-sections shown in FIGS. 7A-7D illustrate variations in the deposition of multiple solder balls onto a bond pad 130 and illustrate forces that may potentially act on the deposited solder as the amount of energy accompanying the deposition of the solder balls 104 is varied between a “low” energy level and a “high” energy level. For embodiments in which the solder balls 104 are accompanied with a “low” energy, the spheroidal shape of the deposited solder balls remains distinguishable after deposition and the deposited solder balls 104 become bound to the solder-wettable surfaces of bond pads 130 upon which the solder balls are deposited, without substantial distribution of the solder from the solder balls 104 across the solder-wettable surface of a bond pad 130. Conversely, for embodiments in which the solder balls 104 are accompanied with a “high” energy, the spheroidal shape of the deposited solder balls 104 becomes indistinguishable after deposition and the solder from the deposited solder balls 104 is free to distribute across the solder-wettable surface area of the bond pad 130 upon which the solder balls 104 are deposited. As molten solder in one or more deposited solder balls is free to redistribute as a consequence of a “high” accompanying energy level with the deposition of the solder balls 104, surface tension in the molten solder may contribute to the ultimate shape of the solder mound on the bond pad 130. The extent of the redistribution of the solder across the solder-wettable surface of the bond pad may become balanced by surface tension in the molten solder which can vary depending on the amount of energy provided to the deposited solder balls 104 and the rate of dissipation of the energy from the solder to the bond pad 130 and underlying substrate 110 below the bond pad 130. The solder from the solder balls 104 accompanied by the “high” energy, is anchored to the total area of the bond pad 130 upon which the solder balls 104 are deposited, and is not limited to the original contact surface area between the deposited solder ball 104 and the bond pad 130 as with solder balls 104 accompanied by a “low” energy.

As the quantity of solder balls 104 is increased, and sufficient energy is provided to maintain a molten state of the solder mound on a bond pad 130ᵥ a limit may be reached for which the surface tension in the molten solder can contain the solder thus resulting in a spillover of the solder onto the non-solder-wettable surfaces surrounding the bond pads. Spillover of the solder onto the surrounding non-solder-wettable surfaces can lead to loss of control of the forces that govern the formation of embodiments of solder ball bridges 101 described herein.

In embodiments, one or more deposited solder balls 104 may be accompanied with a “high” energy and one or more solder balls 104 may be accompanied with a “low” energy to form embodiments of solder ball bridge assemblies 100 having a solder ball bridge 101.

In FIGS. 7A-7D, the effects of providing various levels of accompanying energy before, during, or after the deposition of one or more solder balls onto a solder-wettable bond pad 130 is illustrated. These figures, and the description provided herein in conjunction with the figures, pertained primarily to energy accompanying the individual solder balls prior to completion of a solder ball bridge 101. Alternatively, or in addition to, energy may be added to one or more of the constituent solder balls of a solder ball bridge 101 after its formation.

In FIGS. 7E-7H, the potential effects of the addition of energy to embodiments of solder ball bridge assemblies 100 after formation of the solder ball bridge 101 in the solder ball bridge assemblies 100 are shown.

FIG. 7E shows a cross-sectional schematic drawing of an embodiment of a solder ball bridge assembly 100 comprising substrate 110, mounted device 102, and solder ball bridge 101 wherein the solder ball bridge 101 is formed from three laterally coupled solder balls between two horizontally-oriented bond pads and wherein the solder balls 104₁-104₃ are deposited using a “low” laser energy to maintain the spheroidal shape of the solder balls. In the embodiment, solder ball 104₁ may be a first deposited solder ball deposited onto a bond pad 130 on a mounted device 102, solder ball 104₂ may be a second deposited solder ball deposited onto a bond pad 130 on the substrate 110, and solder ball 104₃ may be a third deposited solder ball deposited into the gap formed between the first solder ball 104₁ and the second solder ball 104₂ in the formation of the resulting solder ball bridge 101 as shown. In the embodiment, the amount of energy accompanying the deposition of the solder balls 104₁-104₃ is such that the spheroidal shapes of the solder balls are substantially maintained after deposition (“low” energy condition as described herein). In the embodiment shown in FIG. 7E, third solder ball 104₃ is shown in contact with non-solder-wettable portions of the mounted device 102 and the substrate 110. It should be noted that in configurations having a solder ball that bridges a gap between two previously deposited solder balls, as in the case of the gap that is formed between the first solder ball 104₁ and second solder ball 104₂ prior to the deposition of the third solder ball 104₃ in the embodiment shown in FIG. 7E, that the final resting position of third solder ball 104₃ will be dependent on a number of factors that includes the amount of energy accompanying the deposition of the third solder ball 104₃, the temperature of the first solder ball 104₁ and the second solder ball 104₂ upon deposition of the third solder ball 104₃, among other factors. In some embodiments, third solder ball 104₃ may come to rest on the non-solder-wettable surface of substrate 110. In other embodiments, 104₃ may come to rest on the shoulders of the first solder ball 104₁ and the second solder ball 104₂.

FIG. 7F shows the embodiment of the solder ball bridge assembly 100 of FIG. 7E with the addition of sufficient energy or heating after deposition to enable all or a portion of the solder in the solder ball bridge 101 to reach a molten state. FIG. 7F shows the redistribution of the solder of the solder balls 104₁-104₃ of FIG. 7E wherein an amount of solder in the three solder balls 104₁, 104₂, 104₃ is sufficient to fully wet the solder-wettable top surface of the bond pads 130 and to form a more uniform cross section in the solder between the bond pads 130. In some embodiments, the redistribution of the solder may lead to improvements in the electrical properties, for example, of the solder ball bridge 101 and to the repeatability of these electrical properties. Redistribution of the solder, for example, may lead to improved coverage of the solder on and between the two bond pads 130ᵥ may lead to increased contact area between the deposited solder balls, may lead to a more uniform cross-section across the solder ball bridge 101, and may lead to improved alloying with the solder-wettable surfaces of the bond pads, among other potential benefits. The extent of the alloying between the solder in the deposited solder balls and the material on the bond pad may affect the contact resistance between the bond pad 130 and the solder ball bridge 101. The additional energy provided to the embodiment of the solder ball bridge assembly 100 shown in FIG. 7E, and other embodiments described herein, may be provided using one or more of a thermal annealing, laser exposure, rf energy, or other form of exposure to an energy source that would enable absorption of the added energy by the solder ball bridge 101 such that redistribution of the solder is enabled.

FIG. 7G shows a cross-sectional schematic drawing of an embodiment of an assembly comprising substrate 110, mounted device 102, and solder ball bridge 101 wherein the solder ball bridge 101 is formed between two horizontally-oriented bond pads 130 using a plurality of nominal solder ball sizes and wherein the solder balls 104 are deposited with an accompanying “low” laser energy from the solder ball jetting apparatus 164 such that the spheroidal shape of the solder balls is substantially maintained after deposition. The solder ball bridge 101 is configured in the embodiment shown in FIG. 7G having two equally sized solder balls 104₁, 104₂ formed on bond pads 130 and a larger solder ball 104₃ positioned to bridge the gap between the two equally sized solder balls 104₁, 104₂. In the embodiment, first solder ball 104₁ may be a first deposited solder ball, solder ball 104₂ may be a second deposited solder ball, and solder ball 104₃ may be a third deposited solder ball in the formation of the resulting solder ball bridge 101 as shown. In the embodiment, the amount of energy accompanying the deposition of the solder balls 104₁-104₃ is such that the spheroidal shapes of the solder balls are substantially maintained after deposition (“low” energy condition as described herein). The use of multiple diameters of solder balls 104, as in the configuration shown in FIG. 7G, may provide more flexibility in the formation of solder ball bridges 101 although multiple solder ball jetting apparatus or a change in the solder balls provided by the solder ball jetting apparatus may be required to facilitate the multiple size solder balls 104.

FIG. 7H shows the embodiment of the solder ball bridge assembly 100 of FIG. 7G with the addition of sufficient energy after deposition to enable all or a portion of the solder in the solder ball bridge 101 to reach a molten state. The additional energy provided to the embodiment of the solder ball bridge assembly 100 shown in FIG. 7H, and other embodiments described herein, may be provided using one or more of a thermal annealing, laser exposure, rf energy, or other form of exposure to an energy source that would enable absorption of the added energy by the solder ball bridge 101 such that redistribution of the solder is enabled. FIG. 7H shows an example redistribution of the solder of the solder balls 104₁-104₃ in the embodiment of the solder ball bridge 101. The additional solder in solder ball 104₃, in comparison to the smaller solder ball used in the embodiment shown in FIG. 7E, may lead to such effects as increased mounding of the solder, for example. In some embodiments, the redistribution of the solder as in the embodiment shown in FIG. 7H, may lead to improvements in the electrical properties, for example, of the solder ball bridge 101 and to the repeatability of these electrical properties. Redistribution of the solder, for example, may lead to improved coverage of the solder between the two bond pads, may lead to increased contact area between the deposited solder balls, may lead to a more uniform cross-section across the solder ball bridge 101, and may lead to improved alloying with the solder-wettable surfaces of the bond pads, among other potential benefits.

It should be noted that the resulting shape of the solder in contact with the mounted device 102 and the substrate 110 may vary depending on a number of factors such as the extent of the lack of wettability of the surface of the mounted device 102 and the surface of the substrate 110, the wettability or lack of wettability of the vertical sidewalls of the bond pads, the sustainable surface tension in the solder between the bond pads, the amount of energy used in the formation of the solder ball bridge, the rate of dissipation of energy from the solder in the solder ball bridge to the bond pads and underlying substrate, the dissipation of energy from the solder in the solder ball bridge 101 to the mounted device 102 and the substrate 110, and the amount of solder used in the solder ball bridge 101, among other factors.

The resulting shape of the solder mound after redistribution of the solder from the solder balls as in FIGS. 7F and 7H may also vary depending on the factors listed above and on other factors.

The amount of solder present in a solder ball bridge 101, which is dependent on the number of deposited solder balls 104 deposited in the solder ball bridge 101, can significantly affect the ultimate shape and structure of a solder ball bridge 101. A starved solder ball bridge 101, for example, may have a thinner cross-section in one or more locations along the length of the solder ball bridge 101, particularly upon subsequent processing that would subject the solder in the solder ball bridge 101 to redistribution. Surface tension in the molten state may lead to competition between the various forces present within the solder ball bridge 101 as the solder in the solder ball bridge 101 is raised close to, or in excess of, the melting temperature of the solder. Conversely, a solder ball bridge 101 having ample solder may limit the competition between forces present within the solder ball bridge 101 and enable more preferable redistribution of solder within a solder ball bridge 101 upon exposure to a post-deposition process within which an energy source is provided to the solder ball bridge assembly 100 that enables redistribution of the solder in the solder ball bridge 101.

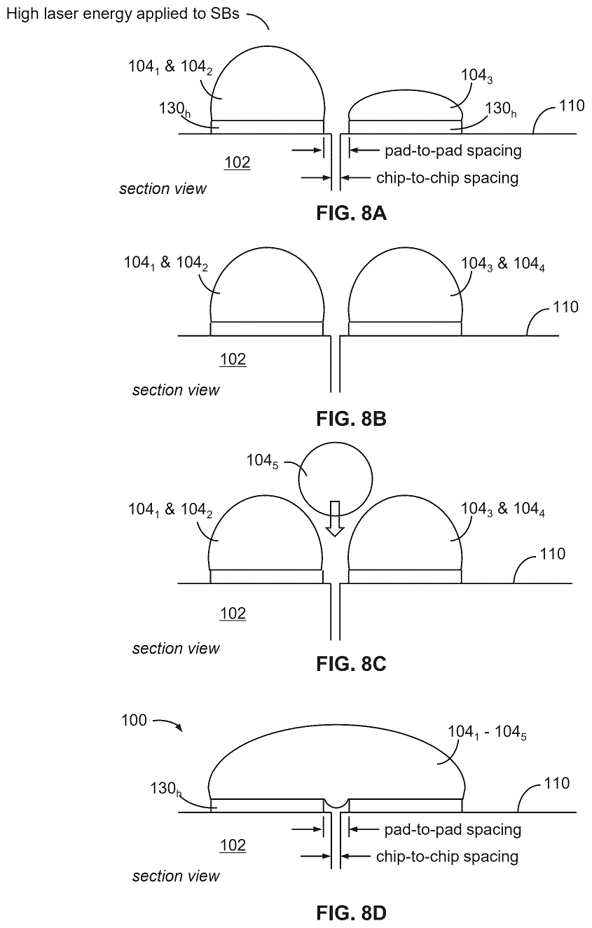

FIGS. 8A-8D show steps in the formation of embodiments of solder ball bridge assemblies 100 comprising substrate 110, mounted device 102, and solder ball bridge 101 wherein the solder balls used in the formation of solder ball bridges 101 are deposited with accompanying energy levels such that the original spheroidal shapes of the solder balls are not distinguishable after deposition (“high” energy condition as described herein).

FIG. 8A shows a cross-sectional schematic drawing of a portion of an embodiment of a solder ball bridge assembly 100 comprising substrate 110 and mounted device 102, wherein a first solder ball 104₁ and a second solder ball 104₂ are deposited onto a horizontally-oriented bond pad 130ₕ of the mounted device 102 accompanied with a “high” laser energy and a third solder ball 104₃ is deposited onto a horizontally-oriented bond pad 130ₕ of the substrate 110 also accompanied with a “high” laser energy such that the original spheroidal shapes of the solder balls are substantially indistinguishable after deposition onto the horizontally-oriented bond pads 130ₕ.

FIG. 8B shows the cross-sectional schematic drawing of the portion of the embodiment of the solder ball bridge assembly 100 shown in FIG. 8A with the addition of a fourth solder ball 104₄ wherein the fourth solder ball 104₄ is a second solder ball added to the horizontally-oriented bond pad 130ₕ formed on the substrate 110, and wherein the fourth solder ball 104₄ is deposited with accompanying “high” energy such that the original spheroidal shape of the solder ball is substantially indistinguishable after deposition.

FIG. 8C shows a cross-sectional schematic drawing of the portion of the embodiment of the solder ball bridge assembly 100 shown in FIG. 8B with a fifth solder ball 104₅ positioned over the spacing between the solder mounds formed from the first and second solder balls 104₁, 104₂ on the horizontally-oriented bond pad 130ₕ of the mounted device 102, and the third and fourth solder balls 104₃, 104₄ on the horizontally-oriented bond pad 130ₕ of the substrate 110. FIG. 8C shows the fifth solder ball 104₅ just prior to impacting the two solder mounds on the individual horizontally-oriented bond pads 130ₕ.

FIG. 8D shows a cross-sectional schematic drawing of the embodiment of the solder ball bridge assembly 100 shown in part in FIG. 8C comprising a substrate 110, a mounted device 102, and a solder ball bridge 101 formed from the five solder balls 104₁-104₅ disposed on and between the two horizontally-oriented bond pads 130ₕ as in FIGS. 8A-8C. The “high” energy accompanying the deposition of the solder balls, in the embodiment, enables a molten state to be achieved for the solder in the solder ball bridge 101 and enables increased melding of the solder balls 104₁-104₅ in comparison to deposited solder balls accompanied with “low” energy from the solder ball jetting apparatus. The embodiment of the solder ball bridge assembly 101 having solder ball bridge 101 shown in FIG. 8D illustrates a solder ball bridge having ample solder such that undesirable necking of the solder ball bridge 101 is not observed.

### Sequential Placement of Solder Balls in the Formation of Long Lateral Solder Ball Bridges

The process of formation of solder ball bridge assemblies 100 comprising the substrate 110, mounted device 102, and the solder ball bridge 101 can benefit from specific orders of placement of the solder balls that make up embodiments of the solder ball bridges 101. The sequential placement of solder balls in the formation of solder ball bridges 101 requires that initial solder balls be anchored securely in position to a bond pad 130 or other solder-wettable surface and that subsequently placed solder balls 104 be melded to one or more of these securely anchored initial solder balls, particularly over non-solder-wettable surfaces, until the formation of the solder ball bridge 101 in a solder ball bridge assembly 100 is completed.

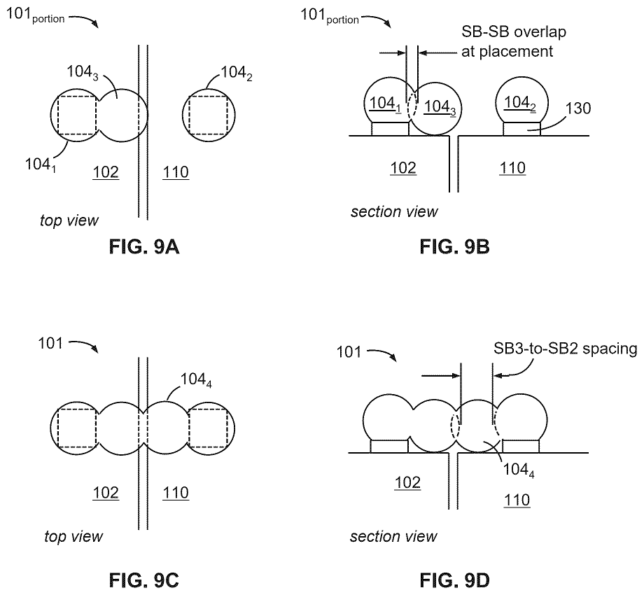

FIGS. 9A-9D show steps in the formation of an embodiment of a solder ball bridge assembly 100 comprising substrate 110, mounted device 102, and solder ball bridge 101 wherein the solder ball bridge 101 is comprised of four solder balls 104 and wherein the sequential order of placement of the solder balls in an embodiment of a solder ball bridge assembly 100 is further described.

FIGS. 9A and 9B show top view and cross-sectional schematic drawings of a portion of an embodiment of a solder ball bridge assembly 100 comprising substrate 110, mounted device 102, and partially formed solder ball bridge 101 wherein the order of placement of the first three solder balls into the solder ball bridge assembly 100, for the embodiment, corresponds to the subscript of the solder ball label. Other sequential ordering in the placement of the solder balls may also be used. For the sequence used in the formation of the embodiment shown in FIGS. 9A and 9B, first solder ball 104₁ is firstly positioned onto the bond pad 130 formed on the mounted device 102. The “low” energy accompanying the first and other solder balls in the solder ball bridge 101 in the embodiment is such that the spheroidal shapes are maintained in the formation of the solder ball bridge 101. Second solder ball 104₂ is then deposited onto the bond pad 130 formed on the substrate 110 to form the terminal ends of the solder ball bridge 101. Third solder ball 104₃ is then deposited in partial contact with the first solder ball 104₁. The solder ball-to-solder ball overlap (labeled as “SB-SB overlap at placement” in FIG. 9B) is provided in the embodiment to enable the third solder ball 104₃ to be anchored to the first solder ball 104₁ upon melding of the partially molten third solder ball 104₃ with the first solder ball 104₁ positioned on the bond pad 130 of the mounted device 102. In the embodiment, the overlapping of the solder balls 104₁, 104₃ enables the solder ball bridge 101 to be extended laterally as additional solder balls placed in contact with, and melded to, the firmly secured solder balls on the solder-wettable surfaces of the bond pads, and to enable the extension of the solder ball bridge over the non-solder-wettable surfaces of the mounted device 102, the substrate 110 outside the horizontally-oriented bond pads 130ᵥ and the “chip-to-chip spacing” between the mounted device 102 and the cavity wall of the substrate 110.

FIGS. 9C and 9D shown top view and cross-sectional schematic drawings of the portion of the embodiment of the solder ball bridge assembly 100 shown in FIGS. 9A and 9B after the addition of a fourth solder ball 104₄ to complete the formation of the solder ball bridge 101. As shown in FIG. 9D, fourth solder ball 104₄ is deposited to fill the gap labeled “SB3-to-SB2 spacing”. In the embodiment shown in FIGS. 9C and 9D, and in other embodiments configured having three or more solder balls, the diameter of a solder ball required to close a gap in the solder ball bridge is preferably greater than the solder ball-to-solder ball spacing (“SB-SB spacing”) that requires bridging. As the fourth solder ball 104₄ is deposited into the gap between the second and third solder balls 104₂, 104₃, respectively, the portions of the fourth solder ball 104₄ that contact the second solder ball 104₂ and third solder ball 104; melds into the second and third solder ball 104₂, 104₃, respectively, to anchor the fourth solder ball 104₄ in place over the non-solder-wettable surface of the underlying substrate 110 in the embodiment to form the continuous solder ball bridge 101 comprising four solder balls in the embodiment.

In the embodiment shown in FIGS. 9C and 9D, the order of placement of the first solder ball 104₁ and the second solder ball 104₂ may be reversed. In the embodiment shown in FIGS. 9C and 9D, the order of placement of the third solder ball 104₃ and the fourth solder ball 104₄ may be reversed. For embodiments having four solder balls as shown, for example, in FIGS. 9C and 9D, a first solder ball 104₁ may be placed on a bond pad 130 formed on the mounted device 102, a second solder ball 104₂ may be placed in contact with the first solder ball 104₁ (in the location occupied by solder ball 104₃ in FIG. 9D), and a third solder ball 104; may be placed onto a bond pad 130 on the substrate 110 to form a structure similar to that of FIG. 9B wherein the solder ball bridge 101 may be completed with the addition of the fourth solder ball 104₄ as in FIGS. 9C and 9D. Other permutations of the ordering of the placement of the solder balls may also be used.

In summary, in the formation of a solder ball bridge 101 in embodiments of solder ball bridge assemblies 100 having two bond pads 130 requiring a lateral interconnection, the ordering of the sequential placement of the solder balls 104 to bridge the non-solder-wettable surfaces and the “chip-to-chip spacing” between the mounted device 102 and the cavity wall of cavity 148 in substrate 110, a first solder ball is firstly anchored to a first bond pad, a second solder ball is either anchored to a second bond pad or to the first solder ball, a third solder ball is either anchored to the second bond pad (if not already covered) or to a previously deposited solder ball that is already anchored to either the first or second bond pad or another previously deposited solder ball. The addition of successively deposited solder balls continues until the completion of the lateral interconnection between the two bond pads in the embodiment of the solder ball bridge assembly 100.

In the embodiment shown in FIGS. 9C and 9D, the solder ball bridge 101 is formed between two horizontally-oriented bond pads and the sequential placement is initiated with the placement of a first solder ball onto a first bond pad. In other embodiments, the solder ball bridge may be formed between one or more vertically-oriented bond pads and the first solder ball may be anchored to this first vertically-oriented bond pad. Subsequent solder balls may then be deposited such that each solder ball in the solder ball bridge is anchored to one or more of a previously deposited solder ball or a bond pad. The embodiment of the solder ball bridge 101 of a solder ball bridge assembly 100 shown in FIGS. 9A-9D is configured having four solder balls 104. In other embodiments, solder ball bridge 101 may be formed having more than four solder balls 104 sequentially placed and anchored into position using the methods described herein.

The embodiment shown in FIGS. 9C and 9D are described for solder balls deposited in the formation of the solder ball bridge having “low” energy, such that the spheroidal shapes of the solder balls are significantly maintained after deposition into the solder ball bridge assembly 100. In other embodiments, solder balls may be deposited having “high” energy such that the spheroidal shapes of the solder balls 104 are not maintained during the formation of the solder ball bridge 101. Deformation of the solder balls may be influenced by, in such embodiments, the surface tension of the solder and the redistribution of the solder resulting from the wetting of the bond pad or other solder-wettable surface, among other factors. And in yet other embodiments, post deposition treatments may be used to one or more of reshape, densify, and redistribute one or more solder balls, among other potential benefits that may lead to improved thermal and electrical properties of all or a portion of the solder ball bridge, for example. In some embodiments, post deposition treatment may be used, for example, to redistribute the solder of the deposited solder balls, to eliminate gaps that may be present, for example, among other potential benefits, in the as-deposited solder ball bridge 101.

The solder ball diameter used in the configuration shown in FIGS. 9A and 9B, and in other embodiments and configurations of embodiments described herein, may be selected in relation to the spacing between the bond pads 130 and the size of the bond pads 130. The embodiment shown in FIG. 9B, for example, shows solder balls having a nominal diameter that is approximately equal to half of the distance between the bond pads 130ᵥ less the overlap between solder balls. In other embodiments, other relationships between the solder ball diameter and the spacing between bond pads 130ᵥ for example, may be used.

The area of the bond pads 130 to which the solder of the terminal ends of a solder ball bridge 101 are deposited, may vary over a wide range. Increased bond pad area in comparison to the diameter of the deposited solder balls, in some embodiments, enables the deposition and bonding of a plurality of solder balls onto the bond pad area that may further enable a greater quantity of solder to be deposited onto the bond pads. A greater quantity of solder may be beneficial in some embodiments, in that a greater quantity of solder on a bond pad may enable the formation of solder mounds that are higher in elevation than the solder mounds that may be present on bond pads having smaller relative areas.

Increased bond pad areas relative to the size of the solder ball used may also enable, for example, an increase in the solder material available for anchoring laterally positioned solder balls. Larger area bond pads may also provide reduced contact resistance between the solder ball bridge and the bond pad 130 and reduced resistance of the larger cross-sections of solder ball bridge 100 available with larger bond pad areas. Improved thermal coupling between the solder in the solder ball bridge 100 and mounted device 102 and substrate 110 at the terminal ends of the solder ball bridge. The increased amount of solder that may be used on larger bond pads may be a disadvantage of large area bond pads.

In some embodiments, a small area bond pad 130ᵥ may, for example, allow for the deposition of a single solder ball 104 to provide coverage over the surface area of the bond pad 130.

In some embodiments, balancing of the amount of the solder in the solder ball bridge 101 with the surface tension and other forces governing the ultimate shape of the solder ball bridge 101 may provide improved flexibility with the lateral coupling of sequentially placed solder balls in the formation of solder ball bridge 101. This balancing of the amount of solder in the solder ball bridge 101 may be improved with bond pads having larger area than the diameter of the solder ball.

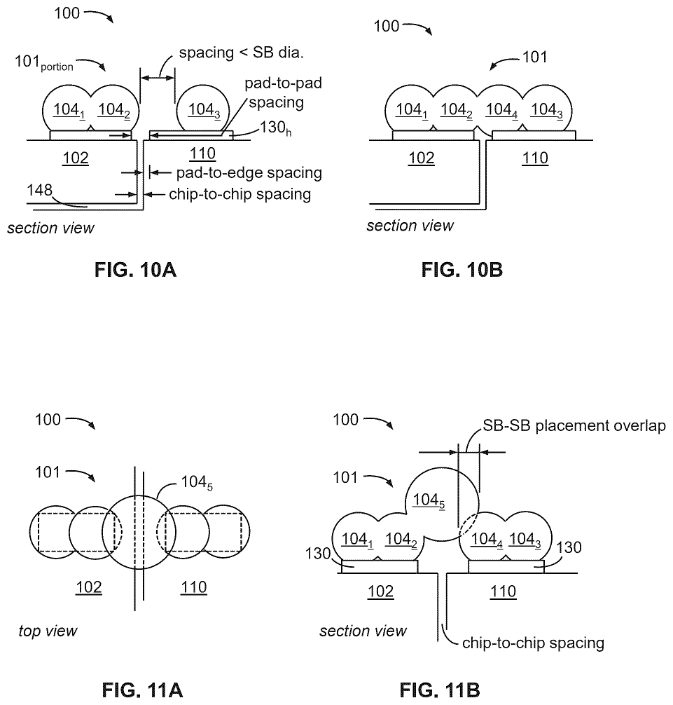

FIGS. 10A and 10B illustrate a sequential deposition of solder balls 104₁-104₄ in the formation of an embodiment of a lateral solder ball bridge 101 for a solder ball bridge 101 comprising four solder balls 104 on bond pads 130 having substantially larger area than the cross-sectional area of the solder balls deposited onto the horizontally-oriented bond pads 130ₕ in the embodiment.

FIG. 10A shows a cross-sectional schematic drawing of an embodiment of a solder ball bridge assembly 100 comprising a substrate 110, a mounted device 102, and a partially formed solder ball bridge 101 portion wherein the substrate 110 and mounted device 102 are configured having horizontally-oriented bond pads 130ₕ and wherein the horizontally-oriented bond pads 130ₕ are configured having surface area larger than the coverage area of a solder ball 104. The partially formed solder ball bridge 101 shows two solder balls 104₁ and 104₂ deposited on a first bond pad 130 on the mounted device 102 and a third solder ball 104₃ deposited on a second bond pad 130 on the substrate 110. First and second bond pads 130 are shown configured having surface area larger than the cross-sectional area of the deposited solder balls in the embodiment. Solder balls 104₁-104₃ are deposited having “low” energy such that the spheroidal shape of the solder balls is maintained after deposition on the bond pads 130ₕ. The spacing between solder balls 104₂ on first bond pad and 104₃ on the second bond pad is shown to be less than the diameter of the solder balls used in the solder ball bridge 101.

FIG. 10B shows a cross-sectional schematic drawing of an embodiment of the solder ball bridge assembly 100 comprising the substrate 110, mounted device 102, and the portion of the solder ball bridge 101 of FIG. 10A after deposition of a fourth solder ball 104₄ to complete the formation of the solder ball bridge 101. The fourth solder ball 104₄ bridges the spacing, in the embodiment, between solder balls 104₂ and 104₃ that includes the “pad-to-pad spacing” between the bond pad 130 on the mounted device 102 and the bond pad 130 on the substrate 110, and which further includes the “chip-to-chip spacing” between the mounted device 102 and the cavity wall of the cavity 148 of the substrate 110. The “pad-to-edge spacing” as noted and shown for reference, is the distance between the edge of a bond pad 130 and the wall of the cavity 148 on the substrate, or the distance between the edge of a bond pad 130 and the edge of a mounted device 102.

In the embodiments, solder balls 104₁-104₄ are of the same nominal diameter. In other embodiments, a plurality of solder ball diameters may be used in the formation of a solder ball bridge 101. In some embodiments, one or more solder balls 104 having a smaller or larger diameter than one or more other solder balls 104 in the solder ball bridge 100 may be used in the formation of the solder ball bridge assembly 100. Use of bond pads 130ₕ having larger area than the cross-sectional area of the solder balls used in the formation of solder ball bridge 101 may enable one or more of increased anchoring area between the solder balls and the bond pad upon which the solder balls are deposited, decreased contact resistance, and decreased inductance, among other potential benefits. Increased anchoring area can provide improved reliability in some embodiments.

In the embodiment in FIGS. 10A and 10B, the length of the side of the bond pad shown in the cross-section is approximately 1.8 times that of the diameter of the solder ball shown. In other embodiments, the length of one or more sides of the bond pad may be more than 1.8 times that of the diameter of the solder ball used resulting on bond pad areas having considerably larger solder-wettable surface areas than the cross-sectional area through the center of the solder ball used in the formation of a solder ball bridge 101. On bond pads 130 having larger area than the diameter of the solder balls used in the formation of the solder ball bridge 101, one or more solder balls may be sequentially placed onto the bond pad until one or more of the desired coverage and the quantity of solder is provided. Solder balls accompanied with “low” energy may be deposited until all or a portion of the larger area bond pad is covered with solder balls in some embodiments. Alternatively, solder balls accompanied with “high” energy”, as described herein, may be deposited until suitable wetting of all or a portion of the large area bond pad is achieved in other embodiments. In some embodiments, some solder balls accompanied with “low” energy and some solder balls accompanied with “high” energy may be used to deposit solder balls on the large area bond pads.

The embodiment shown in FIGS. 10A and 10B illustrates the sequential placement of four solder balls onto horizontally-oriented bond pads 130ₕ having surface area larger than the cross-sectional area of the deposited solder balls wherein the deposited solder balls are deposited with accompanying “low” energy from the solder ball jetting apparatus. The “pad-to-pad spacing” between horizontally-oriented bond pads 130ₕ, in the embodiment, is less than the diameter of the solder ball used in the formation of the solder ball bridge 101.

In the embodiment shown in FIGS. 10A and 10B, bond pads 130ₕ having a substantially larger top surface area than the cross-sectional area of the solder balls 104 deposited onto the bond pads are used. In other embodiments, bond pads 130 having a smaller top surface area comparable or approximately equal to that the of the cross-sectional area of the deposited solder balls may be used. The surface area of the bond pads that may be used in the embodiment shown in FIG. 10A and in other embodiments can vary over a wide range from that may vary, for example, from a surface area approximately equal to that of the cross-sectional area of the portion of a solder ball that forms a contact with the bond pad to a surface area many times greater than that of the cross-sectional area of the portion of the one or more solder balls that form a contact with the bond pad upon which the solder balls are deposited.

In other embodiments, a plurality of solder ball diameters may be used in the formation of the solder ball bridge 101. The use of larger diameter solder balls in all or a portion of a solder ball bridge may enable the spanning of greater distances between bond pads 130.

FIG. 11A shows a top view schematic drawing of an embodiment of a solder ball bridge assembly 100 comprising a substrate 110, a mounted device 102, and a solder ball bridge 101 wherein the solder ball bridge 101 is formed from a plurality of solder balls 104 and wherein the plurality of solder balls comprises two or more nominal diameters. FIG. 11B shows a cross-sectional schematic drawing of the embodiment of the solder ball bridge assembly 100 of FIG. 11A. The top view drawing of FIG. 10A and cross-sectional schematic drawing of FIG. 11B show a solder ball bridge 101 comprising five solder balls 104₁-104₅ wherein the fifth solder ball 104₅ has a larger diameter than the first through fourth solder balls, 104₁-104₄, respectively. The subscripts indicate the numerical order of the example sequential placement of the solder balls into the solder ball bridge structure. Other sequential placement order may also be used. Use of a larger fifth solder ball 104₅ in the embodiment enables bridging across a larger gap between the interior solder ball 104₂ and interior solder ball 104₄ in the embodiment shown in FIGS. 11A and 11B. A larger gap can accommodate larger “pad-to-pad spacings” as in for example, embodiments having one or more of greater “chip-to-chip spacings” between the mounted device and the cavity wall of the cavity 148 formed on the substrate 110 and greater “pad-to-edge spacings” between one or more of the bond pads and the edges of the chips upon which the bond pads are formed. Use of a large solder ball, as in solder ball 104₅ shown in FIGS. 11A and 11B can also lead to a reduction in the resistance of the resulting solder ball bridge, among other benefits. A larger diameter solder ball as in, for example, fifth solder ball 104₅ in solder ball bridge 101 of FIGS. 11A and 11B comprised of five solder balls, may be accompanied with a “low” energy from solder ball jetting apparatus 164 that may provide increased “SB-SB placement overlap” as noted in FIG. 11B. Use of a large solder ball as in, for example, fifth solder ball 104₅ in the embodiment shown in FIG. 11B may provide increased contact area, for example, with the solder balls 104₂, 104₄ to which the fifth solder ball 104₅ is bonded.

The use of a plurality of solder balls 104 having a plurality of solder ball diameters in the formation of solder ball bridge 101 is not restricted to embodiments of solder ball bridges 101 having five solder balls but rather solder ball bridges 101 having a plurality of solder balls 104 comprising a plurality of solder ball diameters may be used in the formation of solder ball bridge 101 having two or more solder balls 104. Additionally, one or more of the solder balls 104 may be deposited accompanied by one or more of a “low” energy from the solder ball jetting apparatus 164 and a “high” energy from the solder ball jetting apparatus 164. One or more solder ball jetting apparatuses may be used in the formation of solder ball bridges 101 having one or more of a plurality of solder balls 104 and one or more of a plurality of diameters of solder balls 104.

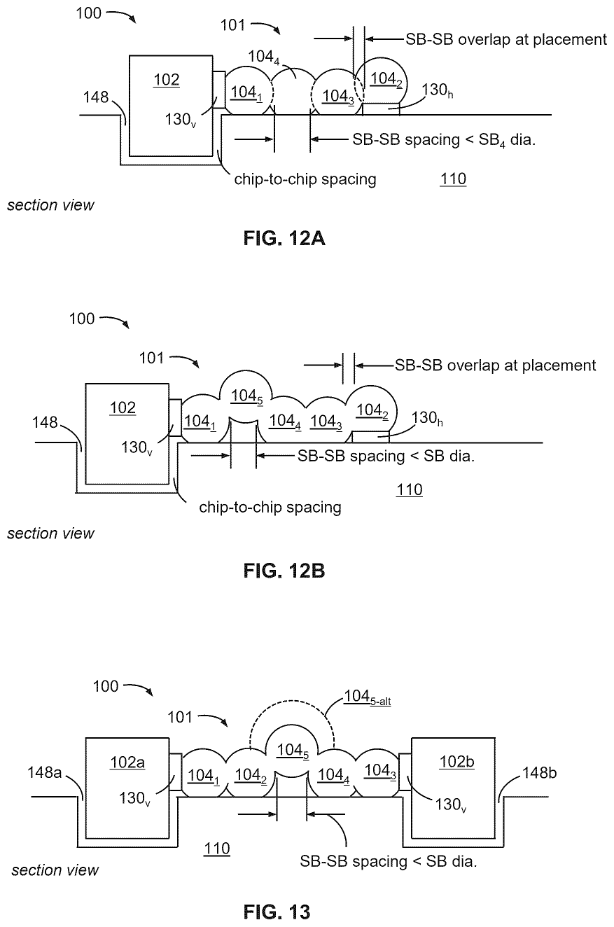

Embodiments of the solder ball bridge 101 shown in FIGS. 12A and 12B comprise four solder balls 104 and five solder balls 104, respectively, and illustrate configurations in which the distance spanned between a vertically-oriented bond pad 130ᵥ and a horizontally-oriented bond pad 130ₕ is substantially greater than the diameter of the solder balls 104 used in the formation of the solder ball bridge 101. Anchoring of the solder balls 104 to one or more of a solder-wettable bond pad 130 . . . 130ₕ and a previously placed solder ball, also solder-wettable, enables the anchoring of subsequently placed solder balls to bond pads 130ᵥ, 130ₕ and to previously placed solder balls 104 in the solder ball bridge 101 to complete the formation of a solder ball bridge 101 between the bond pads 130 . . . 130ₕ. Other configurations of bond pads may be used in other solder ball bridges 101 configured having four or more solder balls 104.

FIG. 12A shows a cross-sectional schematic drawing of an embodiment of a solder ball bridge assembly 100 comprising a substrate 110, mounted device 102 mounted in cavity 148, and a solder ball bridge 101 wherein the mounted device 102 is configured having a vertically-oriented bond pad 130ᵥ and the substrate 110 is configured having a horizontally-oriented bond pad 130ₕ. The solder ball bridge 101 comprises four laterally positioned solder balls 104₁-104₄ wherein the subscript denotes an example sequential placement of the solder balls into the solder ball bridge assembly 100. A first solder ball 104₁, in the embodiment, may be firstly deposited onto mounted device 102 in contact with the vertically-oriented bond pad 130ᵥ to anchor the solder ball 104₁ to the vertically-oriented bond pad 130ᵥ. Sufficient energy is provided from the solder ball jetting apparatus 164 to enable wetting of the bond pad 130ᵥ with the solder from solder ball 104₁. A second solder ball 104₂ is then deposited, in the embodiment, onto the horizontally-oriented bond pad 130ₕ on the substrate 110 to anchor the solder ball 104₂ to the horizontally-oriented bond pad 130ₕ. The order of the sequential placement 104₁ and 104₂ may be reversed in other embodiments. Third solder ball 104₃ is then anchored to second solder ball 104₂ shown in FIG. 12A to laterally extend the partially formed solder ball bridge from the horizontally-oriented bond pad 130ₕ towards the first solder ball 104₁. Placement of fourth solder ball 104₄ then closes the “SB-SB spacing” gap between first solder ball 104₁ and third solder ball 104₃ to complete the solder ball bridge connection between the vertically-oriented bond pad 130ᵥ on the mounted device 102 and the horizontally-oriented bond pad 130ₕ on the substrate 110. Each solder ball has an associated solder ball-to-solder ball overlap at placement, denoted “SB-SB overlap at placement” in FIG. 12A, to ensure adequate anchoring of each laterally positioned solder ball to a previously placed adjacent solder ball as the solder ball bridge spans the non-solder-wettable surfaces of the mounted device 102 and the substrate 110 between the bond pads, and spans the “chip-to-chip spacing” between the mounted device 102 and the wall of cavity 148 on the substrate 110. Appropriate laser energy accompanying the fourth solder ball 104₄ ensures that this solder ball 104₄ fits within the “SB-SB spacing” between first solder ball 104₁ and third solder ball 104₃ in the embodiment. It should be noted that other ordering of the placement of the solder balls may also be used to form the solder ball bridge 101 in the embodiment shown in FIG. 12A and in other embodiments described herein and that remain within the scope of embodiments.

Solder ball bridges 101 may comprise more than the four solder balls used to span the spacing between bond pads as in FIG. 12A.

FIG. 12B shows a cross-sectional schematic drawing of an embodiment of a solder ball bridge assembly 100 comprising a substrate 110, a mounted device 102, and a solder ball bridge 101 comprising five solder balls 104. In the embodiment, in FIG. 12B, mounted device 102 is configured having a vertically-oriented bond pad 130ᵥ and the substrate 110 is configured having a horizontally-oriented bond pad 130ₕ. Other embodiments having five solder balls may be configured having other configurations of bond pads 130. And yet other embodiments having five solder balls may be configured having other configurations of solder-wettable surface area to which the terminal ends of solder ball bridge 101 may be adhered. The solder ball bridge 101 comprises five solder balls 104₁-104₅ wherein the subscript denotes an example sequential placement of the solder balls into the solder ball bridge assembly 100. A first solder ball 104₁, in the embodiment, may be firstly deposited onto mounted device 102 in contact with the vertically-oriented bond pad 130ᵥ to anchor the solder ball 104₁ to the vertically-oriented bond pad 130 . . . . Sufficient energy is provided from the solder ball jetting apparatus 164 to enable wetting of the bond pad 130ᵥ with the solder from solder ball 104₁. Second solder ball 104₂ is then deposited onto the horizontally-oriented bond pad 130ₕ on the substrate 110, in the embodiment, to anchor solder ball 104₂ to the horizontally-oriented bond pad 130ₕ. Third solder ball 104₃ is then anchored to second solder ball 104₂ to laterally extend the solder ball bridge from the horizontally-oriented bond pad 130ₕ towards first solder ball 104₁ and fourth solder ball 104₄ is then anchored to third solder ball 104₃ to further extend the solder ball bridge towards first solder ball 104₁. Placement of fifth solder ball 104₅ then closes the “SB-SB spacing” gap between first solder ball 104₁ and fourth solder ball 104₄ to complete the solder ball bridge connection between the vertically-oriented bond pad 130ᵥ on the mounted device 102 and the horizontally-oriented bond pad 130ₕ on the substrate 110. Each solder ball has an associated solder ball-to-solder ball overlap at placement, denoted “SB-SB overlap at placement” in FIG. 12B, to ensure adequate anchoring of each laterally positioned solder ball to a priorly placed adjacent solder ball. Appropriate laser energy accompanying the fifth solder ball 104₄ ensures that this solder ball 104₅ either fits within the “SB-SB spacing” between solder ball 104₁ and fourth solder ball 104₄ or is adequately melded to the upper shoulders of these solder balls as shown in FIG. 12B. It should be noted that other sequential ordering in the placement of the solder balls 104₁-104₅ may also be used to form the solder ball bridge 101 in the embodiment shown in FIG. 12B and in other embodiments described herein that remain within the scope of embodiments. Not all “SB-SB overlap at placement” distances need be the same in the embodiment shown in FIG. 12B and other embodiments disclosed herein. The overlap between deposited solder balls may reduce undesirable splatter or redistribution of the solder, for example, upon impact with an underlying non-solder-wettable surface of the mounted device 102 and substrate 110.

FIG. 13 shows a cross-sectional schematic drawing of an embodiment of a solder ball bridge assembly 100 comprising a substrate 110, first mounted device 102a and second mounted device 102b, and a solder ball bridge 101 wherein the first and second mounted devices 102a, 102b are configured having vertically-oriented bond pads 130 . . . . In the embodiment, an example sequential placement of the solder balls 104₁-104₅ in the formation of the solder ball bridge 101 is denoted by the numerical sequence of the subscripts of the solder balls 104₁-104₅. First solder ball 104₁ is firstly positioned, for example, in close proximity to a first vertically-oriented bond pad 130ᵥ on the first mounted device 102a such that first solder ball 104₁ is anchored to the solder-wettable surface of the vertically-oriented bond pad 130ᵥ on the first mounted device 102a in the embodiment. Sufficient energy is provided from the solder ball jetting apparatus 164 to enable wetting of the bond pad 130ᵥ with the solder from solder ball 104₁. The top horizontal shoulder of vertically-oriented bond pad 130ᵥ may be used in some embodiments to improve the contact area between the incident first solder ball 104₁ and the vertically-oriented bond pad 130ᵥ which may lead to a reduction in the splatter or redistribution of solder upon impact with the non-solder-wettable surface of the substrate 110. Second solder ball 104₂ is then deposited adjacent to the first solder ball 104₁ such that the second solder ball 104₂ is securely anchored to the first solder ball 104₁. Secure anchoring of the deposited solder balls to either the vertically-oriented bond pad 130ᵥ or a previously placed solder ball may require that sufficient laser energy be provided to the solder ball to achieve a semi-molten state to enable melding of the solder ball being deposited with one or more of the surface of a bond pad and a previously deposited solder ball. Too much energy, however, can lead to substantial deformation of the solder ball as it contacts an underlying non-solder-wettable surface. Typically, the surfaces of the mounted devices 102 and the substrate 110 are non-solder-wettable surfaces that offer little to no resistance to lateral spreading of the deposited solder balls. A balance in the amount of energy may be required between a deposited solder ball having sufficient energy to form a bond with one or more of a bond pad and a previously deposited solder ball and a deposited solder ball having sufficient energy to cause excessive undesirable deformation of the deposited solder ball upon impact with one or more surfaces in the solder ball bridge assembly 100.

Following the deposition of second solder ball 104₂, third solder ball 104₃, in the embodiment, is deposited such that a bond is formed between the third solder ball 104₃ and the vertically-oriented bond pad of the second mounted device 102b. Fourth solder ball 104₄ is then placed and anchored to third solder ball 104₃. Fifth solder ball 104₅ is then deposited between the second solder ball 104₂ and the fourth solder ball 104₄ to complete the formation of the solder ball bridge 101 in the embodiment as shown in FIG. 13. Fifth solder ball 104₅ may be of the same nominal diameter as solder balls 104₁-104₄ used in the solder ball bridge 101 or the fifth solder ball may be of a different diameter. An alternative fifth solder 104₅-alt, for example, shows a fifth solder ball (with dotted line) having a larger diameter than that of solder balls 104₁-104₄. Use of solder balls having a same nominal diameter may minimize setup times if a single solder ball jetting apparatus tool is used to form the solder ball bridge 101. In embodiments having a plurality of nominal solder ball diameters used in the plurality of solder balls of which solder ball bridge 101 is comprised, additional setup time may be required. In some embodiments, multiple solder ball jetting apparatuses may be used wherein each apparatus may be used to deposit solder balls having the same nominal solder ball diameter. Larger diameter solder balls 104 may enable the spanning of larger gaps between previously deposited solder balls 104, and may enable increased overlap with previously deposited solder balls 104 that may lead to a reduction in undesirable redistribution of the solder upon incidence with the previously deposited solder balls and the underlying non-solder-wettable surfaces of the underlying substrate 110.

In some embodiments, the structure of a solder ball bridge 101 may be configured such that an arching structure is formed between bond pads 130 or other solder-wettable surfaces. In some embodiments, the formation of an arching solder ball bridge 101 may eliminate contact between the solder balls 104 in the solder ball bridge 101 and the substrate materials in the underlying substrate 110 and the mounted device(s) 102 over which the arch is formed. In other embodiments, the formation of an arching solder ball bridge may enable fabrication of solder ball bridge assemblies 100 having a large “chip-to-chip spacing” wherein the spacing is approximately equal to or greater than the diameter of the solder balls used in the formation of solder ball bridge 101. And in yet other embodiments, arching solder ball bridges may better accommodate differences in elevation between bond pads 130 at the terminal ends of a solder ball bridge 101.

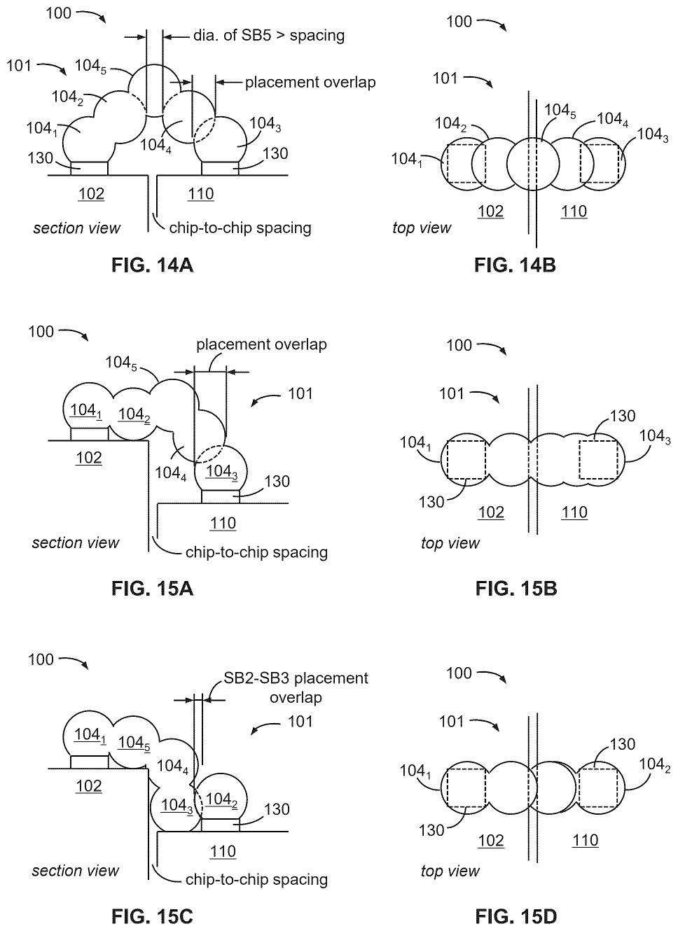

FIG. 14A shows the cross-sectional schematic drawing of an embodiment of a solder ball bridge assembly 100 comprising substrate 110, mounted device 102, and solder ball bridge 101 wherein the solder ball bridge 101 forms an arch over the spacing between the bond pads 130. In the embodiment, the arching solder ball bridge does not contact the surfaces of the mounted device 102 between the bond pads 130 and does not contact the surface of the substrate 110 between the bond pads 130. FIG. 14B shows the top view schematic drawing of the embodiment of the assembly of FIG. 14A. In the embodiment shown, an example sequential placement of the solder balls 104₁-104₅ is denoted by the numerically sequenced subscripts in the solder ball labels. First solder ball 104₁ is firstly placed on the bond pad 130 of the mounted device 102. Second solder ball 104₂ may then be positioned onto a shoulder of first solder ball 104₁ wherein the second solder ball 104₂ is positioned over the first solder ball 104₁ having a placement overlap. The “placement overlap”, as denoted in FIG. 14A and as used herein, refers to the width of a portion of a deposited solder ball 104 at placement that overlaps with an underlying solder ball upon which a solder ball 104 is deposited. A solder ball 104 deposited onto another solder ball that had been previously placed onto a bond pad 130ᵥ for example, will enable the formation of an arching solder ball bridge structure for solder balls that are placed having an “placement overlap” of less than 100%. Placement overlap of 100% will result in the simple stacking of the deposited solder balls. As the “placement overlap” however, is decreased from 100%, the lateral displacement of the resulting solder ball bridge 101 will increase provided the position of the deposited solder ball can be maintained. Overly molten solder balls may impart too much energy into the melded portion of two mating solder balls to support a growing cantilever structure which may prevent the formation of an arched structure. In the embodiment, second solder ball 104₂ may have a “placement overlap” of approximately 40%, for example, to enable lateral extension of the solder ball bridge 101. In other embodiments, the “placement overlap” may be less than 40%. And in other embodiments, the “placement overlap” may be greater than 40%. In some embodiments, the “placement overlap” may differ for one or more solder balls in the arching structure.

In the embodiment, third solder ball 104₃ may then be positioned onto the bond pad 130 of the substrate 110 followed by fourth solder ball 104₄ having a “placement overlap” as described herein of less than 100%. After sequential positioning and placement of solder balls 104₁ to 104₄, fifth solder ball 104₅ may then be positioned and placed to complete the formation of the arching solder ball bridge 101 in the embodiment shown in FIGS. 14A and 14B. Solder ball bridge 101, in the embodiment shown in FIGS. 14A and 14B, does not contact the surface of either the mounted device 102 or the surface of the substrate 110 between the bond pads 130 in the solder ball bridge assembly 100.

Embodiments of solder ball bridge assemblies 100 having solder ball bridge 101 that forms all or part of an arching structure may be used to facilitate the formation of electrical and thermal interconnections between bond pads 130 and between other solder-wettable surfaces formed at differing elevations on mounted device 102 and substrate 110. In some embodiments, an arching structure may be formed having two or more solder balls in solder ball bridge 101 and further coupled to one or more laterally coupled solder balls to form solder ball bridge 101 between bond pads 130 at differing elevations on mounted device 102 and substrate 110. In other embodiments, differences in elevation may be accommodated with laterally coupled portions of solder ball bridge 101 further coupled using a stack of two or more solder balls 104 to form solder ball bridge 101 between bond pads 130 at differing elevations on mounted devices 102 and substrate 110.

FIG. 15A shows a cross-sectional schematic drawing of an embodiment of a solder ball bridge assembly 100 comprising substrate 110, mounted device 102, and solder ball bridge 101 wherein the top surfaces of the bond pads 130 formed on the substrate 110 and the mounted device 102 are at differing clevations. FIG. 15B shows a top view schematic drawing of the embodiment of FIG. 15A. In the embodiment shown in FIGS. 15A and 15B, an arching solder ball bridge 101 is shown to accommodate the difference in elevation between bond pad 130 on mounted device 102 and bond pad 130 on substrate 110. In the embodiment shown, an example sequential placement of the solder balls 104₁-104₅ is denoted by the numerically sequenced subscripts in the solder ball labels. First solder ball 104₁ is firstly placed onto the bond pad 130 of the mounted device 102. Second solder ball 104₂, in the embodiment, is then deposited with a lateral displacement such as to be anchored to the first solder ball 104₁ in a position between the bond pad on the mounted device 102 and the bond pad on the substrate 110. Third solder ball 104₃ is then shown deposited onto the bond pad 130 of the substrate 110. Fourth solder ball 104₄ is positioned and placed onto third solder ball 104₃ having a “placement overlap” as denoted in FIG. 15A of less than 100% such that the solder ball bridge 101 is extended from the bond pad 130 on the substrate 110 toward the bond pad 130 on the mounted device 102. Fifth solder ball 104₅ is then deposited between the second solder ball 104₂ and the fourth solder ball 104₄ to complete the formation of the solder ball bridge 101 in the embodiment. In the embodiment, a first portion of solder ball bridge 101 comprises two solder balls 104₁, 104₂ forming a lateral extension from the bond pad 130 on the mounted device 102 and a second portion comprising solder balls 104₃, 104₄, 104₅ forms an arch that connects bond pad 130 on the substrate 110 to solder ball 104₂ of the first portion of solder ball bridge 101 to form solder ball bridge 101.

In other embodiments having differences in elevation between a bond pad 130 or other solder-wettable surface on a mounted device 102 and a bond pad 130 or other solder-wettable surface on substrate 110, the bond pad 130 of the mounted device 102 is lower in elevation than the bond pad 130 on the substrate 110. And in other embodiments, a bond pad 130 on one or more of the mounted device 102 and the substrate 110 is a vertically-oriented bond pad 130ᵥ. In yet other embodiments having differences in elevation between a bond pad 130 or other solder-wettable surface on mounted device 102 and a bond pad or other solder-wettable surface on substrate 110, an arching portion includes two or more solder balls that extend from a first bond pad 130 of the mounted device 102 or the substrate 110 to a second bond pad 130 of the mounted device 102 or the substrate 110.

FIGS. 15C and 15D show an embodiment of solder ball bridge 101 that is formed between a bond pad 130 on mounted device 102 and a bond pad 130 on substrate 110. In the embodiment, a first laterally coupled portion of solder ball bridge 101 comprising solder ball 104₁ and solder ball 104₅ and a second laterally coupled portion of solder ball bridge 101 comprising solder ball 104₂ and 104₃ are further coupled using the stacked solder balls 104₃, 104₄ to span the elevation between the bond pad 130 on the substrate 110 and the bond pad 130 on the mounted device 102. In the embodiment shown, an example sequential placement of the solder balls 104₁-104₅ is denoted by the numerically sequenced subscripts in the solder ball labels. First solder ball 104₁ is deposited onto bond pad 130 on mounted device 102. Second solder ball 104₂ is then deposited onto bond pad 130 on substrate 110. Third solder ball is then deposited with lateral displacement from second solder ball 104₂ and anchored to solder ball 104₁. Fourth solder ball 104₄ is deposited onto third solder ball 104₃ in the embodiment shown having little or no lateral displacement. In some embodiments, more than two solder balls may be used in stacked portion of solder ball bridge that includes solder ball 104₃ and solder ball 104₄ to accommodate the difference in elevation between the bond pads 130 on the substrate 110 and the mounted device 102. Fifth solder ball 104₅ is deposited between solder ball 104₁ and solder ball 104₄ to complete the formation of the solder ball bridge 101 shown in FIGS. 15C and 15D that spans a lateral distance between bonds pads 130 on mounted device 102 and substrate 110 and that spans a vertical distance between the top surfaces of these bond pads 130.

Formation of Assemblies that Include Heat Sinks

Embodiments of solder ball bridge assemblies 100 comprising a substrate 110, a mounted device 102, and a solder ball bridge 101 may be used in embodiments, to provide thermal coupling between mounted device 102 and substrate 110 wherein one or more of the substrate 110 and mounted device 102 includes a heat sink. In some embodiments, a heat sink may be formed from a high thermal conductivity layer coupled to substrate 110 and coupled to a bond pad 130 formed at a terminal end of solder ball bridge 101. Heat sinks, in some embodiments, may be formed, for example, from one of more layers of high thermal conductivity material such as aluminum nitride, alloys of aluminum nitride, and metal layers having high thermal conductivity. Heat sinks, in other embodiments, may be formed, for example, from one or more trenches filled with one or more of a high thermal conductivity material and a high thermal conductivity metal. And in yet other embodiments, heat sinks may be formed from a radiative solder ball array coupled to a terminal end of a solder ball bridge.

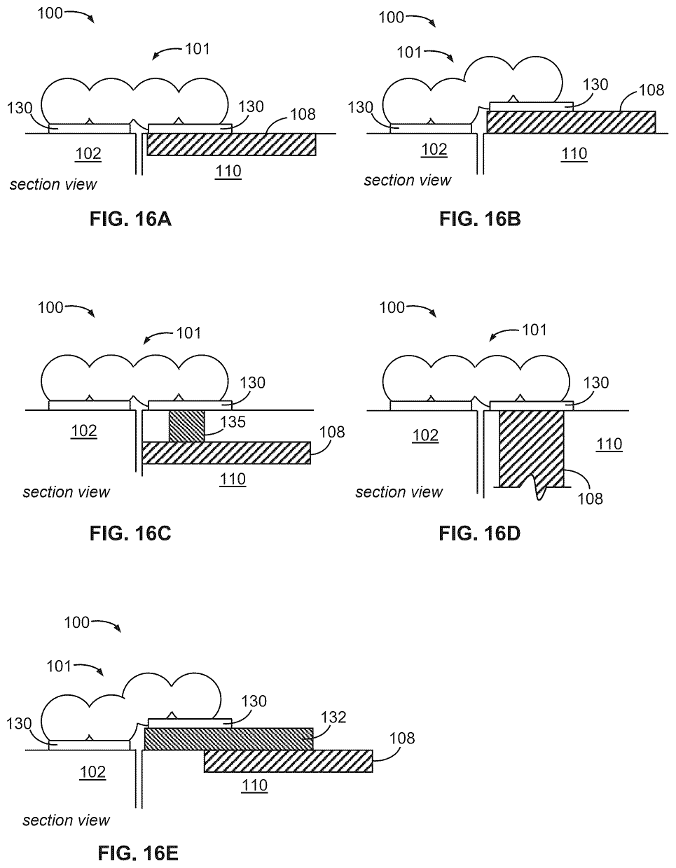

FIGS. 16A-16E show cross-sectional schematic drawings of embodiments of solder ball bridge assemblies 100 comprising substrate 110, mounted device 102, and solder ball bridge 101 wherein the solder ball bridge assemblies 100 further comprise a layer having a high thermal conductivity coupled to a bond pad 130 formed at a terminal end of the solder ball bridge 101.

FIGS. 16A and 16B show cross-sectional schematic drawings of embodiments of solder ball bridge assembly 100 comprising substrate 110, mounted device 102, and solder ball bridge 101 wherein the solder ball bridge assembly 100 further comprises high thermal conductivity layer 108 formed in the substrate 110 and on the substrate 110, respectively. The high thermal conductivity layer 108 shown in FIG. 16A may be formed, for example, in a trench or opening in the substrate 110. In some embodiments, high thermal conductivity layer 108 may be a planarized layer. The high thermal conductivity layer 108 shown in FIG. 16B may be formed, for example, by patterning of a deposited layer formed on a top surface of substrate 110. Formation of high thermal conductivity layer 108 in the substrate 110 as in the embodiment shown in FIG. 16A, and on the substrate 110 as in the embodiments shown in FIG. 16B, can affect elevation differences between bond pads formed on the mounted device 102 and the substrate 110.

FIG. 16C shows a cross-sectional schematic drawing of an embodiment of a solder ball bridge assembly 100 comprising substrate 110, mounted device 102, and solder ball bridge 101 wherein the solder ball bridge assembly 100 further comprises a high thermal conductivity layer 108 formed within the substrate 110 and interconnected via vertical interconnection 135 to bond pad 130 formed at a terminal end of the solder ball bridge 101. Formation of a buried high thermal conductivity layer 108 in the substrate 110, can facilitate improved dissipation of heating from the mounted device 102 to the substrate 110 by providing a thermally conductive path through one or more of the solder ball bridge 101, the bond pad 130ᵥ and the vertical interconnect 135 to the buried high thermal conductivity layer 108. Solder ball bridges 101 coupled to high thermal conductivity layer 108 formed in the substrate 110 enables coupling of thermal energy from mounted device 102 to substrate 110_{substrate} of substrate 110. Coupling of the solder ball bridge 101 in solder ball bridge assembly 100 to a buried high thermal conductivity layer 108, in the embodiment having a buried high thermal conductivity layer 108, enables improved dissipation of thermal energy into the substrate 110_{substrate} of substrate 110 and removal of excess thermal energy to heat sinks coupled to the substrate 110_{substrate} of substrate 110. Substrate 110_{substrate} of substrate 110 may be coupled, for example, to a pluggable package having one or more of a thermoelectric cooling module or other cooling device for removal of excess thermal energy from the one or more mounted devices 102 mounted on substrate 110.

FIG. 16D shows a cross-sectional schematic drawing of an embodiment of a solder ball bridge assembly 100 comprising substrate 110, mounted device 102, and solder ball bridge 101 wherein the solder ball bridge assembly 100 further comprises a high thermal conductivity layer 108 formed in a via within the substrate 110. Formation of a high thermal conductivity layer 108 in a deep via enables coupling of thermal energy from the mounted device 102 to a heat sink or other form of heat removal structure positioned, for example, at the back side of the substrate 110 or coupled in some way to the substrate 110. The formation of vias having high thermal conductivity fill material can provide high thermal conductivity conduits between the front side and the back side of the substrate 110. Copper may be used, for example, among other materials having high thermal conductivity properties, to fill deep vias that connect to the backside of a substrate 110_{substrate}. Other materials such as tungsten, aluminum, alloys of aluminum, aluminum nitride, for example, among other materials having high thermal conductivity may be used.

FIG. 16E shows a cross-sectional schematic drawing of an embodiment of a solder ball bridge assembly 100 comprising substrate 110, mounted device 102, and solder ball bridge 101 wherein the solder ball bridge assembly 100 further comprises a high thermal conductivity layer 108 formed in or on the substrate 110 and coupled to a bond pad 130 at a terminal end of the solder ball bridge 101 through an electrically conductive layer 132. Electrically conductive layer 132 may be, for example, a metal layer. Electrically conductive layer 132, may be used, for example, in embodiments, to propagate electrical signals in a photonic integrated circuit assembly 142 formed using all or a portion of a solder ball bridge assembly 100. Electrically conductive layers 132 formed from electrically conductive materials such as copper, alloys of copper, aluminum, and alloys of aluminum, among other conductive metal layers, may be formed more easily, and may be formed for purposes other than heat sinking. Coupling of terminal ends of solder ball bridge 101 to one or more high thermal conductivity layers 108 through electrically conductive layer 132 may facilitate improved integration schemes that may have advantages over direct coupling of a terminal end of solder ball bridge 101 to high thermal conductivity layer 108.

In addition to heat sink structures formed all or in part from high thermal conductivity layers such as high thermal conductivity layer 108, heat sinks may be formed from metal-filled vias formed in the substrate and may be formed from metal-filled trenches formed in the substrate 110.

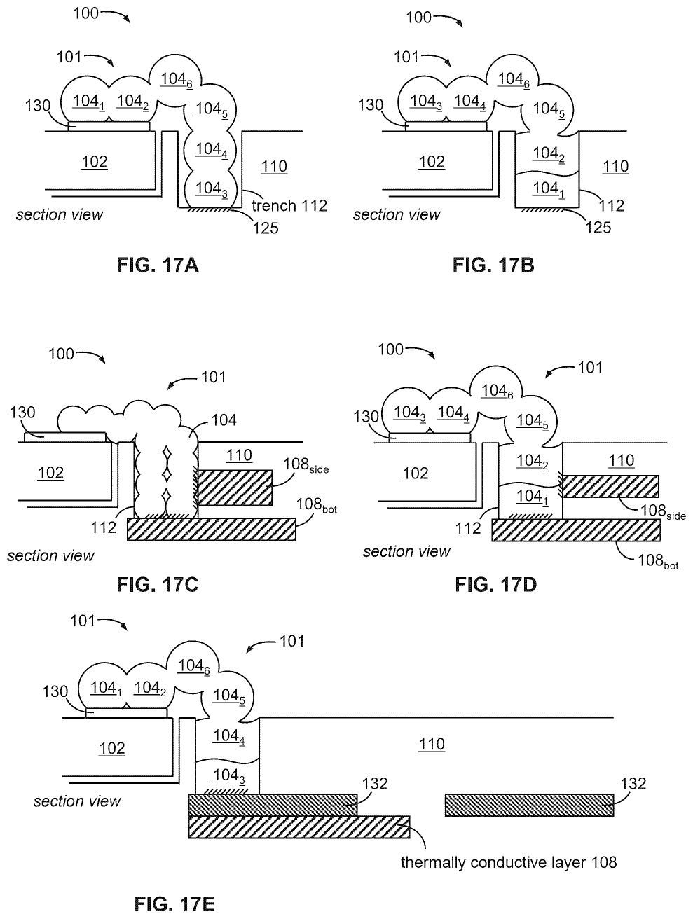

FIGS. 17A-17D show cross-sectional schematic drawings of embodiments of solder ball bridge assemblies 100 comprising substrate 110, mounted device 102, and solder ball bridge 101 wherein the solder ball bridge assemblies 100 further comprise a trench 112 formed in the substrate 110 and wherein a terminal end of the solder ball bridge 101 is coupled to the heat sink material in the trench 112. Coupling of a terminal end of a solder ball bridge 101 may be one or more of direct coupling, may be through a bond 130ᵥ may be through a metal layer, among other coupling means.

FIG. 17A shows a cross-sectional schematic drawing of an embodiment of a solder ball bridge assembly 100 comprising substrate 110, mounted device 102, and solder ball bridge 101 wherein the solder ball bridge assembly 100 further comprises trench 112 and wherein a terminal end of the solder ball bridge 101 is coupled to a bottom surface of the trench 112. In the embodiment, the bottom surface of the trench 112 is shown having solder-wettable surface 125. In other embodiments, solder-wettable surface 125, described herein in conjunction with FIG. 2C, may cover all or a portion of the trench bottom and may further cover all or a portion of the walls of trench 112. Extension of the solder ball bridge 101 into the substrate 110 as shown, in FIG. 17A, may enable, for example, additional solder mass to be coupled to the solder ball bridge 101 in the form of the added solder balls 104 in the trench 112 in some embodiments that may, for example, be used as a heat sink. Extension of the solder ball bridge 101 into the trench 112 may also, for example, lead to improved coupling of the thermal energy originating from the mounted device 102 to the substrate 110 through the walls of the trench 112 in some embodiments. A typical sequential placement of solder balls is denoted with the labeling of the solder balls 104 in the solder ball bridge 101 shown in FIG. 17A for a solder ball bridge 101 having a single row of solder balls 104 wherein the row of solder balls 104 is shown in cross-section. A typical sequential placement of the solder balls 104₁-104₆ is denoted with the sequential numbering of the solder balls wherein first solder ball 104₁ and second solder ball 104₂ are deposited onto bond pad 130 on mounted device 102, and wherein third solder ball 104₃, fourth solder ball 104₄ are sequentially deposited into the trench 112, and fifth solder ball 104₅ and sixth solder ball 104₆ are then deposited to bridge the gap between the fourth solder ball 104₄ and the second solder ball 104₂ in the embodiment.

In the embodiment shown in FIG. 17A, two solder balls 104₃, 104₄ are shown to fill the trench 112. In other embodiments, more than two solder balls may be used to fill the trench 112. The number of solder balls 104 required to fill the trench 112 can vary over a wide range and may depend, for example, on the size of the trench 112 and on the size of the solder balls used in the trench 112. In other embodiments, more than one row of solder balls 104 may be used in all or a portion of the solder ball bridge 101. Multiple rows of solder balls 104 may be positioned as solder balls 104₃, 104₄ are positioned in trench 112 that extends into (or outward) from the plane of the cross-section shown in FIG. 17A, for example. In such embodiments, more than the two solder balls 104 may be deposited in the trench 112.

FIG. 17B shows a cross-sectional schematic drawing of an embodiment of a solder ball bridge assembly 100 comprising substrate 110, mounted device 102, and solder ball bridge 101 wherein the solder ball bridge assembly 100 further comprises trench 112 and wherein a terminal end of the solder ball bridge 101 is coupled to one or more solder balls deposited in the trench 112 and wherein the one or more solder balls 104 in the trench 110 are heated to conform the solder balls 104 disposed in the trench 112 to the walls of the trench 112. In the embodiment shown in FIG. 17B, first solder ball 104₁ and second solder ball 104₂ are firstly deposited into trench 112 and optionally heated to enable the solder balls 104₁, 104₂ to reach a molten state such as to enable the solder to conform to the walls of the trench 112. After deposition of the first solder ball 104₁ and the second solder ball 104₂, the formation of the solder ball bridge 101 may continue with the deposition of the remaining solder balls. Solder ball 104₁ and solder ball 104₂ may be deposited in different steps in the formation of the embodiment of solder ball bridge assembly 100 than other solder balls in the solder ball bridge 101. Following a step that enables the solder balls 104₁, 104₂ firstly deposited into trench 112 to conform to the trench 112 such as may be achieved by heating of the solder balls 104₁, 104₂, in the embodiment shown, or the one or more solder balls deposited into a trench 112 in other embodiments, the remaining solder balls 104₃-104₆ may be sequentially placed as shown, for example, according to the subscripts of the solder ball labels shown in FIG. 17D. Heating of the solder balls 104₁, 104₂ may be achieved using laser energy delivered from the solder ball jetting apparatus, for example, or delivered from a laser positioned below the substrate from which laser energy is provided through the substrate 110 to the solder balls 104₁, 104₂. Other methods of heating may also be used.

In other embodiments, solder ball bridge 101 may be coupled to trench 112 filled with high thermal conductivity material, such as copper, for example, and the terminal end of solder ball bridge 101 may be coupled to the trench 112 having the copper fill. Other conductive fill materials may also be used.

FIG. 17C shows a cross-sectional schematic drawing of an embodiment of a solder ball bridge assembly 100 comprising substrate 110, mounted device 102, and solder ball bridge 101 wherein the solder ball bridge assembly 100 further comprises a trench 112 coupled to one or more high thermal conductivity layers 108 and wherein a terminal end of the solder ball bridge 101 is coupled to one or more solder balls 104 deposited in the trench 112, and wherein one or more solder balls 104 deposited in the trench 112 are coupled to one or more of the thermally conductive layers 108 that intersect a wall, or floor, of the trench 112. In the embodiment shown in FIG. 17C, a high thermal conductivity layer 108_{bot} is shown that intersects the bottom of trench 112. Another high thermal conductivity layer 108_{side} is shown in the embodiment that intersects a sidewall of the trench 112. A plurality of solder balls 104 are shown in the trench 112 and one or more of the solder balls 104 in the trench 112 form a contact with the high thermal conductivity layer 108_{bot} at the bottom of the trench 112 and one or more of the solder balls in the trench 112 form a contact with the high thermal conductivity layer 108_{side} that intersects a sidewall of the trench 112. In some embodiments, a high thermal conductivity layer 108_{bot} may be provided that is coupled to the bottom of trench 112 and to thermally conductive material disposed within the trench 112. In some embodiments, a high thermal conductivity layer 108_{side} may be provided that is coupled to one or more walls of trench 112 and to thermally conductive materials disposed within the trench 112. And in yet other embodiments, one or more of one or more of the high thermal conductivity layers 108_{bot} and high thermal conductivity layers 108_{side} may be provided. All or a portion of the trench bottom and the trench sidewalls may have solder-wettable surface 112 in embodiments.

FIG. 17D shows a cross-sectional schematic drawing of an embodiment of a solder ball bridge assembly 100 comprising substrate 110, mounted device 102, and solder ball bridge 101 wherein the solder ball bridge assembly 100 further comprises a trench 112 coupled to a high thermal conductivity layer 108_{bot} that intersects the bottom of the trench, and a high thermal conductivity layer 108_{side} that intersects the sidewall of the trench 112, and wherein a terminal end of the solder ball bridge is coupled to the thermally conductive layers at the bottom of the trench 112 and at the sidewall of the trench 112. In some embodiments, as shown in FIG. 17D for example, high thermal conductivity layers are provided on both the bottom of the trench 112 and at one or more sidewalls of the trench 112. In other embodiments, high thermal conductivity layers may be provided at either the bottom of the trench 112 or one or more sidewall of the trench 112. In the embodiment shown in FIG. 17D, first solder ball 104₁ and second solder ball 104₂ are shown to have been subjected to a heating step to enable the solder to achieve a molten state and that further enables the molten solder to conform to one or more of the sidewall of the trench 112 and the bottom of the trench 112 and to improve the contact between the solder in the solder balls 104₁, 104₂ with one or more of the high thermal conductivity layers 108_{bot}, 108_{side} in the embodiment. In some embodiments, heating of one or more solder balls in the trench 112, first solder ball 104₁ and second solder ball 104₂ in the configuration shown in FIG. 17E, may be performed using an annealing step prior to the deposition of one or more solder balls outside the trench 112. In other embodiments, heating of the solder balls may be performed using laser energy accompanying the deposition of the solder balls in the trench 112. And in yet other embodiments, heating of the solder balls may be performed using a laser directed through the bottom of the trench 112 from the backside of the substrate 110. Other methods of heating solder balls deposited into the trench 112 may also be used to distribute the solder from one or more solder balls in a trench 112. In the embodiment in FIG. 17D, two solder balls 104₁, 104₂ are shown to fill trench 112. In other embodiments, more than two solder balls may be used to fill trench 112 and, in such embodiments, more than two solder balls may be deposited into trench 112. In some embodiments, solder-wettable surfaces 125 may be formed on all or a portion of the trench bottom and all or a portion of the trench sidewalls.

FIG. 17E shows a cross-sectional schematic drawing of an embodiment of a solder ball bridge assembly 100 comprising substrate 110, mounted device 102, and solder ball bridge 101 wherein the solder ball bridge assembly 100 further comprises a trench 112 coupled to an electrical interconnect layer 132 and a high thermal conductivity layer 108 and wherein a terminal end of the solder ball bridge 101 is coupled to the electrical interconnect layer 132 at the bottom of the trench 112. Coupling of thermal energy from a mounted device 102 to a high thermal conductivity layer in the substrate 110 can enable improved temperature stability of the mounted device 102 as heat from the mounted device 102 can be more readily dissipated into the substrate 110. Electrical interconnect layer 132 can be formed with a solder-wettable surface layer at the bottom of the trench 112 to facilitate improved thermal coupling between the solder of the solder balls 104 in the solder ball bridge 101 and the high thermal conductivity layer 108 through the electrical interconnect layer 132. Copper and aluminum, commonly used metals used in the formation of interconnect layers in semiconductor fabrication, typically exhibit high thermal conductivity in addition to having high electrical conductivity, and can thus be used to effectively transfer thermal energy from the mounted device 102 to the high thermal conductivity layer 108 underlying the trench 112 in the embodiment shown in FIG. 17E and in other embodiments described herein that utilize an electrical interconnect layer 132 to transfer thermal energy between a terminal end of solder ball bridge 101 and a high thermal conductivity layer 108 coupled to substrate 110.

### Formation of Assemblies Coupled to an Electrical Interconnect Layer in the Substrate

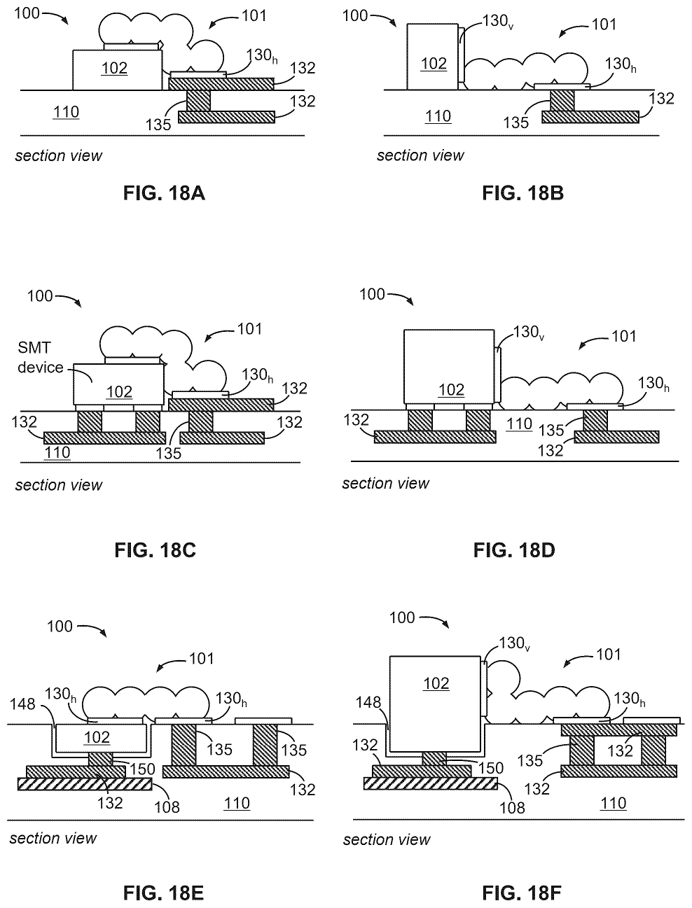

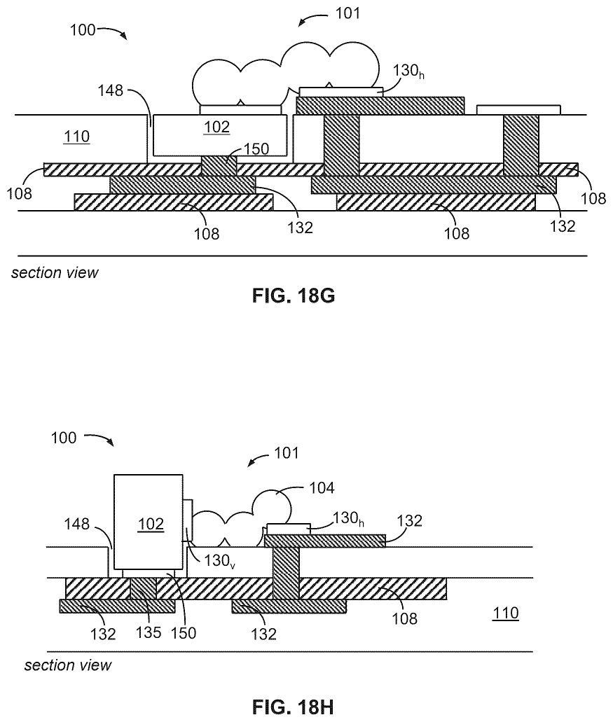

FIGS. 18A-18H show cross-sectional schematic drawings of embodiments of solder ball bridge assemblies 100 comprising substrate 110, mounted device 102, and solder ball bridge 101 wherein a bond pad 130 at a terminal end of the solder ball bridge 101 is further coupled to an electrically conductive layer 132 formed in the substrate 110. Examples of various types of mounted devices 102 used in embodiments, are also shown in FIGS. 18A-18H that include one or more of bonded devices, surface-mounted devices, and cavity-mounted devices. Other configurations of mounted devices 102 may also be used in embodiments.

FIG. 18A shows a cross-sectional schematic drawing of an embodiment of a solder ball bridge assembly 100 comprising substrate 110, mounted device 102, and solder ball bridge 101 wherein the mounted device 102 is formed on the substrate 110 and the solder ball bridge 101 is formed between a horizontally-oriented bond pad 130ₕ on the mounted device 102 and a horizontally-oriented bond pad 130ₕ on the substrate 110, and wherein the bond pad 130ₕ on the substrate 130ₕ is further coupled to an electrically conductive layer 132 formed on the substrate 110 and coupled to an electrically conductive layer 132 formed in the substrate 110 through a vertical interconnect 135. FIG. 18B shows an embodiment of a solder ball bridge assembly 100 configured having a mounted device 102 wherein the mounted device 102 is configured having a vertically-oriented bond pad 130ᵥ to which a terminal end of solder ball bridge 101 is coupled. Another terminal end of the solder ball bridge 101, in the embodiment, is coupled to an electrically conductive layer 132 through a horizontally-oriented bond pad 130ₕ formed on the substrate 110 and vertical interconnect 135. In other embodiments configured having one or more electrically conductive layers 132 coupled to a terminal end of solder ball bridge 101, the terminal end of the solder ball bridge 101 may be coupled to an electrically conductive layer 132 formed on the substrate 110 as shown, for example, in the embodiment in FIG. 18A.

Mounted device 102, in the embodiments shown in FIGS. 18A and 18B, may be a bonded device that is bonded or otherwise coupled to the substrate 110. The mounted device 102 in the embodiment shown in FIG. 18A may be, for example, one or more of an optical device and an electrical device. The mounted device 102 in the embodiment shown in FIGS. 18A and 18B may be, for example, one or more of an optical device and an electrical device fabricated, for example, from a compound semiconductor and bonded to the substrate 110. The mounted device 102 in the embodiment shown in FIGS. 18A and 18B may be, for example, a laser device fabricated from one or more of a III-V compound semiconductor material and a II-VI compound semiconductor material. Other mounted devices 102 configured as shown in the embodiments in FIGS. 18A and 18B may also be used. Mounted device 102, as shown in the embodiments in FIGS. 18A and 18B, may be bonded to substrate 110 or to an intervening layer on substrate 110 using an epoxy. Other bonding materials may also be used to combine mounted device 102 and substrate 110. In some embodiments, mounted device 102 may be formed on the substrate using one or more of chemical vapor deposition and epitaxial processing to form mounted device 102.

FIG. 18C shows a cross-sectional schematic drawing of an embodiment of a solder ball bridge assembly 100 comprising substrate 110, mounted device 102, and solder ball bridge 101 wherein the mounted device 102 is a surface-mounted device and the solder ball bridge 101 is formed between a horizontally-oriented bond pad 130ₕ on the surface mounted device and a horizontally-oriented bond pad 130ₕ on the substrate 110, and wherein the bond pad 130ₕ on the substrate 110 is further coupled to an electrical interconnect layer 132 formed on the substrate 110. The embodiment of the solder ball bridge assembly 100 coupled to the one or more optional laterally extending electrically conductive layers 132 enable additional electrical connectivity to one or more electrically conductive layers formed on and within the substrate 110. In some embodiments, a terminal end of solder ball bridge 101 may be coupled to an electrically conductive layer 132 formed on the substrate 110. In other embodiments, a terminal end of solder ball bridge may be coupled to an electrically conductive layer 132 formed within the substrate 110. In some embodiments in which a terminal end of solder ball bridge 101 is coupled to an electrically conductive layer 132 within the substrate 110, one or more vertical interconnects 135 may be used.

FIG. 18D shows an embodiment of a solder ball bridge assembly 100 configured having a vertically-oriented bond pad 130ᵥ on mounted device 102 that is coupled to a terminal end of solder ball bridge 101 in the embodiment. Another terminal end of the solder ball bridge 101 in the embodiment shown in FIG. 18D is coupled to a horizontally-oriented bond pad 130ₕ formed on the substrate 110 which is further coupled to a vertical interconnect 135 to an underlying electrically conductive layer 132 in the embodiment. Terminal ends of solder ball bridge 101 may be coupled to electrically conductive layers 132 formed on substrate 101, in some embodiments. A wide range of mountable devices may be coupled to substrate 110 using surface mounting structures and methods. Surface mounting is an established method of mounting devices onto a substrate, such as an interposer or PC board, in which metal contacts on the surface mountable device are soldered or otherwise connected to contacts on the surface of the substrate. The use of surface-mounted devices in embodiments of solder ball bridge assemblies 100 enables increased flexibility in the formation of photonic integrated circuit assemblies 142 that include embodiments of solder ball bridge assemblies 100. Mounted devices 102 such as lasers, photodiodes, lenses, arrayed waveguides, gratings, for example, among many other optical, electrical, and optoelectrical devices may be mounted to substrate 110 using surface mounting structures and techniques. Thermal and electrical coupling of surface mounted devices 102 using solder ball bridges 101 may enable improved thermal and electrical coupling of the surface-mounted devices to the substrate 110 in embodiments of photonic integrated circuit assemblies 100 having solder ball bridge assemblies 100.

Submounts having one or more of these and other optical, electrical, and optoelectrical devices may also be used, for example, in embodiments of photonic integrated circuit assemblies 142 having solder ball bridge assemblies 100 that include mounted devices 102.

FIG. 18E shows a cross-sectional schematic drawing of an embodiment of a solder ball bridge assembly 100 comprising substrate 110, mounted device 102, and solder ball bridge 101 wherein the mounted device 102 is mounted in a cavity 148 formed in substrate 110, and the solder ball bridge 101 is formed between a horizontally-oriented bond pad 130ₕ on the cavity mounted device and a horizontally-oriented bond pad 130ₕ on the substrate 110, and wherein the bond pad 130ₕ on the substrate 110 is further coupled to an electrically conductive layer 132 through vertical interconnect 135 formed in the substrate 110. In other embodiments, the horizontally-oriented bond pad 130ₕ or other solder-wettable material on the substrate may be coupled to an electrically conductive layer 132 formed on the substrate 110. The embodiment of the solder ball bridge assembly 100 coupled to the one or more optional laterally extending electrically conductive layers 132 enable additional electrical connectivity to one or more electrically conductive layers formed on and within the substrate 110. In some embodiments, a terminal end of solder ball bridge 101 may be coupled to an electrically conductive layer 132 formed on the substrate 110. In other embodiments, a terminal end of solder ball bridge may be coupled to an electrically conductive layer 132 formed within the substrate 110. In some embodiments in which a terminal end of solder ball bridge 101 is coupled to an electrically conductive layer 132 within the substrate 110, one or more vertical interconnects 135 may be used. Cavity-mounted device 102 in the embodiment shown in FIG. 18E may be placed into cavity 148 using automated pick-and-place apparatus. Cavity-mounted device 102 may use flip chip technology in some embodiments.

FIG. 18F shows an embodiment of a solder ball bridge assembly 100 configured having a vertically-oriented bond pad 130ᵥ on mounted device 102 that is coupled to a terminal end of solder ball bridge 101 in the embodiment. Another terminal end of the solder ball bridge 101 in the embodiment shown in FIG. 18F is coupled to a horizontally-oriented bond pad 130ₕ formed on the substrate 110 which is further coupled to an underlying electrically conductive layer 132. Terminal ends of solder ball bridge 101 may be coupled to electrically conductive layers 132 formed within substrate 101, that may be coupled, in some embodiments, to the electrically conductive layer 132 formed on the substrate 132 using one or more vertical interconnects 135 as shown in FIG. 18F. A wide range of cavity-mountable devices may be coupled to substrate 110 using surface mounting structures and methods. Cavity mounting of mountable devices may be performed, for example, using flip chip technology in which a mountable device having an electrical contact is mounted onto a mating contact on a substrate, such as contact 150 shown in FIG. 18F in cavity 148 of substrate 110. Cavity mounting of devices onto substrate 110 may be similar to surface mounting with regard to the formation of the electrical contact between surface-mounted devices and cavity-mounted devices. Cavity-mounted devices, however, enable the lateral coupling of optical signals, for example, to waveguides formed in substrate 110 that intersect the wall of the cavity within which a cavity-mounted device is mounted. The use of cavity-mounted devices in embodiments of solder ball bridge assemblies 100 enables increased flexibility in the formation of photonic integrated circuit assemblies 142 that include embodiments of solder ball bridge assemblies 100. Mounted devices 102 such as lasers, photodiodes, lenses, arrayed waveguides, gratings, for example, among many other optical, electrical, and optoelectrical devices may be mounted to substrate 110 using cavity mounting structures and techniques that may include electrical contacts within the cavity. Thermal and electrical coupling of cavity mounted devices 102 using solder ball bridges 101 may enable improved thermal and electrical coupling of mounted devices 102 mounted in a cavity 148 in substrate 110 in embodiments of photonic integrated circuit assemblies 100 having solder ball bridge assemblies 100.

Submounts having one or more of these and other optical, electrical, and optoelectrical devices may also be used, for example, in embodiments of photonic integrated circuit assemblies 142 having solder ball bridge assemblies 100 that include a mounted device 102 mounted in a cavity.

In some embodiments, a terminal end of a solder ball bridge 101 may be coupled to a bond pad 130ₕ formed on an electrically conductive layer 132 that is formed on the substrate 110 as shown in FIG. 18F. In some embodiments, a terminal end of a solder ball bridge 101 may be coupled to a bond pad 130ₕ formed on or in contact with a vertical interconnect 135 that is formed in the substrate 110 and further coupled to an electrically conductive layer 132 that is also formed in the substrate 110 as shown in FIG. 18E. In some embodiments having cavity-mounted devices 102, an electrically conductive layer 132 formed within the substrate 110 may be coupled to the bottom of cavity 148, through, for example, electrical connection 150. FIGS. 18E and 18F further show electrically conductive layers 132 formed below cavity 148 and coupled to the bottom side of mounted device 102. (In FIGS. 18E and 18F, the bottom of the mounted device 102 in cavity 148 is the side of the mounted device 102 facing the bottom of cavity 148.) Electrically conductive layers 132 are further coupled to high thermal conductivity layers 108 in substrate 110 in the embodiments shown in FIGS. 18E and 18F.

FIGS. 18G and 18H show cross-sectional schematic drawings of embodiments of solder ball bridge assemblies 100 comprising substrate 100, mounted device 102, and solder ball bridge 101 wherein the mounted device 102 is a cavity mounted device, wherein the mounted device 102 is coupled to one or more high thermal conductivity layers 108 formed in the substrate 108, and wherein a terminal end of the solder ball bridge 101 is coupled to an electrically conductive layer 132 formed on and in the substrate 110.

FIG. 18G shows a cross-sectional schematic drawing of the embodiment of a solder ball bridge assembly 100 comprising substrate 110, mounted device 102, and solder ball bridge 101 wherein the solder mounted device 102 is mounted in a cavity 148 formed in the substrate 110 and wherein a terminal end of solder ball bridge 101 is coupled to an electrically conductive layer 132 formed on substrate 110 and to an electrically conductive layer 132 formed in the substrate wherein the substrate further comprises a plurality of high thermal conductivity layers 108 formed in the substrate 110 and coupled to electrically conductive layer 132. A plurality of high thermal conductivity layers 108 may enable improved thermal stability of mounted devices 102. Improved thermal stability may result, for example, from increased thermal energy dissipation from the mounted device 102 through the solder ball bridge 101 and through the plurality of high thermal conductivity layers 108 to the substrate 110.

Multiple high thermal conductivity layers 132 may be formed in the substrate 110, in embodiments, to facilitate the removal and redistribution of thermal energy from mounted device 102 for dissipation in the substrate 110, for example. A plurality of high thermal conductivity layers 108 may facilitate improved thermal energy removal in comparison to embodiments configured having a single high thermal conductivity layer 108. In the embodiment shown in FIG. 18G, a terminal end (terminal end at right of solder ball bridge 101 in FIG. 18G) of solder ball bridge 101 is coupled to an electrically conductive layer 132 formed on the surface of substrate 110. In the embodiment, electrically conductive layer 132 is further coupled through vertical interconnects 135 to an underlying electrically conductive layer 132 formed within the substrate 110 which is further coupled to high thermal conductivity layers 108 positioned above and below the buried electrical interconnect layer 132. An electrical contact 150 at the base of mounted device 102 mounted in cavity 148 is also shown in the embodiment in FIG. 18G to be coupled to an electrically conductive layer 132 in the substrate 110, and further coupled to high thermal conductivity layers 108 positioned above and below the electrically conductive layer 132. In some embodiments having one or more high thermal conductivity layer 108, a single high thermal conductivity layer may be coupled to one or more electrical contact 150 of the mounted device 102. In an embodiment, a terminal end of solder ball bridge 101 may be coupled through a horizontally-oriented bond pad 130ₕ formed on an electrically conductive layer 132 on substrate 110, and further coupled to a buried electrically conductive layer 132 formed in substrate 110 through a vertical interconnect 135. In some embodiments, a buried electrically conductive layer 132 is not coupled to the terminal end of the solder ball bridge 101. And in other embodiments, an electrically conductive layer 132 on substrate 110 is not coupled to the terminal end of the solder ball bridge 101.

Solder ball bridge assembly 100 in FIG. 18G may enable increased thermal energy removal from mounted device 102 through solder ball bridge 101 to one or more of an electrically conductive layer 132 formed on or in substrate 110. Vertical interconnects 135 may be present in some embodiments to facilitate thermal energy transfer to one of more electrically conductive layers 132, and to one or more high thermal conductivity layers 108 coupled to the electrically conductive layers 132. In embodiments, such as is shown in the embodiment in FIG. 18G, coupling of mounted device 102 to an underlying electrically conductive layer 132 and further coupling of the underlying electrically conductive layer 132 to one or more high thermal conductivity layers 108 may also be used to complement thermal energy removal from mounted device 102 in solder ball bridge assemblies 100.

FIG. 18H shows a cross-sectional schematic drawing of an embodiment of a solder ball bridge assembly 100 comprising substrate 110, mounted device 102, and solder ball bridge 101 wherein the mounted device 102 is mounted in a cavity 148 formed in the substrate 110, and wherein the solder ball bridge 101 is formed between a vertically-oriented bond pad 130ᵥ on the mounted device 102 and a horizontally-oriented bond pad 130ₕ on the substrate, and wherein the bond pad 130ₕ on the substrate 110 is further coupled to an electrically conductive layer 132 formed on the substrate 110. In the embodiment, the electrically conductive layer 132 on the substrate 110 is further coupled to an underlying electrically conductive layer 132 formed in the substrate 110 through one (or more) vertical interconnects 135. The electrically conductive layer 132 formed in the substrate 110 is further coupled to high thermal conductivity layer 108 positioned, in the embodiment, above the electrically conductive layer 132. In other embodiments, high thermal conductivity layer 108 may be positioned below the electrically conductive layer 132. In some embodiments of solder ball bridge assemblies 100, a terminal end of solder ball bridge 101 may be coupled to one or more of an electrically conductive layer 132 on and in the substrate 110. And in some embodiments of solder ball bridge assemblies 100, mounted device 102 in cavity may not be configured having a bottom electrical contact 150.

Solder ball bridge assemblies 100 comprising substrate 110, mounted device 102, and solder ball bridge 101 may benefit from one or more of thermal and electrical coupling of the mounted device 102 to substrate 110 that may include one or more of a high thermal conductivity layer 108 and an electrical interconnect layer 132 formed in and on the substrate 110.

Thermal Radiators Formed from Arrays of Solder Balls

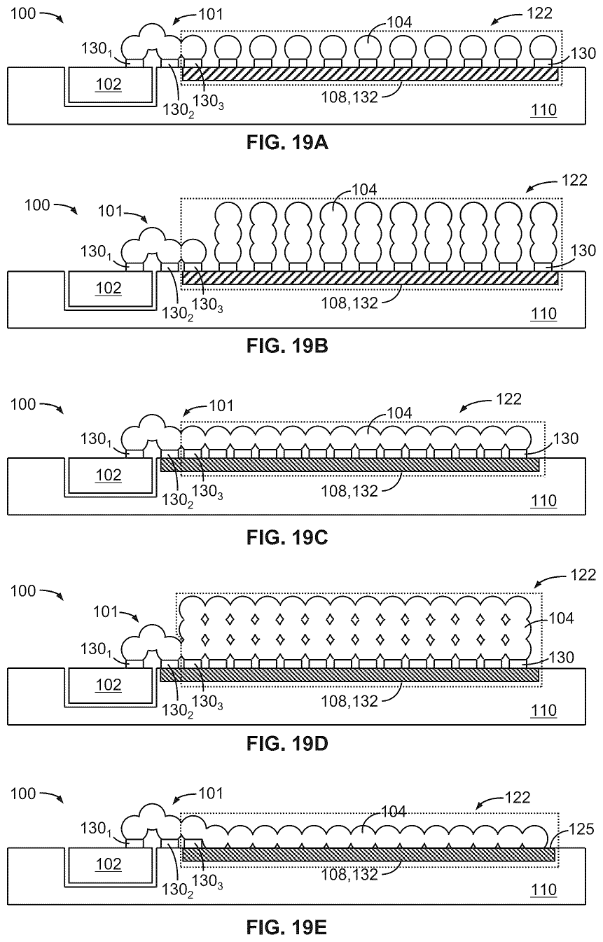

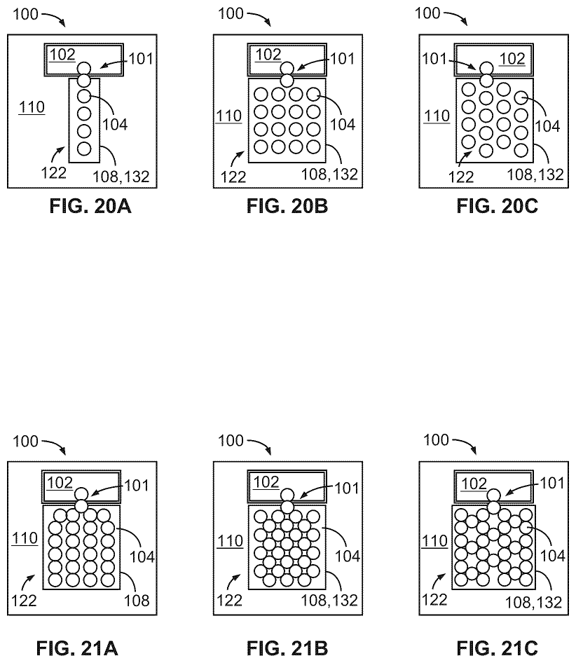

FIGS. 19A-19E, FIGS. 20A-20C, and FIGS. 21A-21C show embodiments of solder ball bridge assemblies 100 having substrate 110, mounted device 102, and solder ball bridge 101 wherein a terminal end of the solder ball bridge 101 is coupled to a radiative solder ball array 122. Radiative solder ball array 122 may be coupled to a terminal end of solder ball bridge 101 through one or more of an electrically conductive layer 132 and a high thermal conductivity layer 108. Radiative solder ball array 122, in embodiments, is a plurality of solder balls arranged on the surface of the substrate or arranged on the mounted device 122 that enables coupling of a terminal end of a solder ball bridge 101 to one or more surfaces coupled to an ambient medium for the removal of thermal energy by means of radiative heat loss and convective transfer to a surrounding medium such as, for example, air. In an example, In the embodiments of the solder ball bridge assemblies 100 shown in FIGS. 16A and 16B, terminal ends of solder ball bridge 100 in the embodiments, are coupled to a high thermal conductivity layer 108 that enables thermal energy transfer between high thermal conductivity layer 108 and the ambient in addition to the high thermal conductivity layer 108 and the substrate 110. Thermal energy transfer between the high thermal conductivity layer 108 and ambient, in some embodiments, may be improved with the addition of structures having increased surface area in comparison to the flat planar structures shown for example, in FIGS. 16A and 16B. Increased surface area may be achieved using solder balls 104 in the form of solder ball arrays 122 as further described herein in the following paragraphs and in conjunction with FIGS. 19A-19E. FIGS. 20A-20C, and in FIGS. 21A-21C.

FIGS. 19A-19E show cross-sectional schematic drawings of embodiments of solder ball bridge assemblies 100 comprising substrate 110, mounted device 102, and solder ball bridge 101 wherein a terminal end of the solder ball bridge 101 is coupled to radiative solder ball array 122. In some embodiments, a terminal end of the solder ball bridge 101 is coupled to radiative solder ball array 122 through one or more of an electrically conductive layer 132 and high thermal conductivity layer 108. In some embodiments, a terminal end of the solder ball bridge 101 is coupled to radiative solder ball array 122 through substrate 110, absent one or more of the electrically conductive layer 132 and high thermal conductivity layer 108, having bond pads 130 or other solder-wettable surface upon which the radiative solder ball array 122 is formed. Embodiments of solder ball bridge assemblies 100 having a radiative solder ball array 122 coupled to a terminal end of radiative solder ball array 122 provide further means for dissipation of thermal energy from mounted device 102.

FIG. 19A shows a cross-sectional schematic drawing of an embodiment of a solder ball bridge assembly 100 comprising substrate 110, mounted device 102, and solder ball bridge 101 wherein a terminal end of the solder ball bridge 101 is coupled to one or more of a high thermal conductivity layer 108 and an electrical interconnect layer 132, and wherein the one or more of a high thermal conductivity layer 108 and electrical interconnect layer 132 are further coupled to radiative solder ball array 122 formed on bond pads 130 further formed on the one or more of a high thermal conductivity layer 108 and electrical interconnect layer 132. The coupling of solder ball bridge 101 to the radiative solder ball array 122 through one or more of a high thermal conductivity layer 108 and electrical interconnect layer 132 coupled to a terminal end of solder ball bridge 101 enables the transfer of thermal energy between mounted device 102 and the radiative solder ball array 122. In the embodiment of the solder ball bridge assembly 100 having a terminal end of solder ball bridge 101 coupled to radiative solder ball array 122 is shown in FIG. 19A formed on a portion of substrate 110. In other embodiments, radiative solder ball array 122 may be formed on all or a portion of one or more of the substrate 110 and the mounted device 102. In the embodiment shown in FIG. 19A, the radiative solder ball array 122 is shown formed on a layer comprising one or more of a high thermal conductivity layer 108 and an electrical interconnect layer 132. In other embodiments, the radiative solder ball array may be formed on all or a portion of one or more of a high thermal conductivity layer 108 and an electrical interconnect layer 132. One or more of a high thermal conductivity layer 108 and electrical interconnect layer 132 may be one or more of a continuous lateral layer underlying the radiative solder ball array 122 and a discontinuous lateral layer underlying all or a portion of radiative solder ball array 122. In some embodiments, coupling of the solder balls 104 of the radiative solder ball array 122 may be through bond pads 130 formed on the one or more of the high thermal conductivity layer 108 and the electrical interconnect layer 132. In other embodiments, coupling of the solder balls 104 of the radiative solder ball array 122 may be through a solder-wettable surface formed on the one or more of the high thermal conductivity layer 108 and the electrical interconnect layer 132. Solder-wettable surfaces may be formed, for example, in embodiments, with suitable material selection of the one or more of the high thermal conductivity layer 108 and the electrical interconnect layer 132. Alternatively, solder-wettable surfaces may be formed, for example, in embodiments, with surface modifications of the one or more of the high thermal conductivity layer 108 and the electrical interconnect layer 132 with the addition, of a layer receptive to the solder used, with the mixing of a layer with another material as in an implantation process, among other surface modifications that improve the receptivity of the surface to materials used in the deposited solder balls 104 in the radiative solder ball array 122 and to improve the wettability of the surface to the material used in the solder ball bridge.

In the embodiment in FIG. 19A, and the embodiments shown in FIG. 19B-19E, the radiative solder ball array 122 is shown enclosed in dotted lines. The areas of these figures enclosed in dotted lines illustrate example configurations of embodiments of a solder ball bridge assembly 100 comprising a solder bridge 101 wherein a first terminal end of solder ball bridge 101 is coupled to a first solder-wettable bond pad 130₁ on the mounted device 102, wherein a second terminal end is coupled to a second bond pad 1302 or solder-wettable surface on the substrate 110, and wherein the second terminal end is extended to a third bond pad 130₃ or solder-wettable surface on the substrate 110 to which all or a portion of a radiative solder ball array 122 is further coupled. In the embodiment in FIG. 19A, the radiative solder ball array 122 comprises third bond pad 130₃ or solder-wettable surface formed on one or more of a high thermal conductivity layer 108 and electrically conductive layer 132 to which the extended solder ball bridge 101 is coupled, and further comprises one or solder balls 104 formed on the one or more of the high thermal conductivity layer 108 and electrically conductive layer 132 that facilitate an increased radiative and convective thermal energy transfer from the extended terminal end of the solder ball bridge 101 coupled to the third bond pad 130₃ to the one or more solder balls 104 in the radiative solder ball array 122. In the solder ball array 122, solder balls 104 are shown on bond pads 130 formed on the one or more of the high thermal conductivity layer 108 and electrically conductive layer 132. In other embodiments, solder balls in the radiative solder ball array 122 may be formed on a solder-wettable surface formed on the one or more of the high thermal conductivity layer 108 and electrically conductive layer 132.

Embodiments described herein that include radiative solder ball array 122 may benefit from the increased radiative surface area of a solder ball 104 in the radiative solder ball array 122 in comparison to a radiative surface absent of the radiative solder balls 104. A flat surface area equal to that of the center diameter of a sphere can be calculated from A=πr², for r=the radius of the solder ball at the center. This calculation provides the projection of the area of a sphere onto the substrate or layer upon which the area of the sphere is projected. For comparison, the area of half a sphere can be calculated form A=2πr², where r is the radius of the half-sphere. This comparison yields an increase in surface area by a factor of two for a solder ball area estimated to be that of a half sphere. Further increases in surface area may be obtained for solder balls 104 that maintain a larger percentage of the surface area of the original spherically shaped solder ball that is deposited into the surface. The contact area between the bottom of a spheroidal solder ball 104 and the surface upon which a solder ball 104 is deposited is necessary for efficient transfer of thermal energy between the substrate 110 or layer underlying a deposited solder ball 104. Tradeoffs must be made between this surface contact area and the radiative surface area of the deposited spheres. It should be noted, that the radiative surface area between the solder balls 104 is assumed to be roughly equivalent in these comparisons of embodiments with and without a radiative solder ball array 122.

The radiative solder ball array 122 in FIG. 19A is shown having solder balls 104 of a same nominal diameter. In other embodiments, one or more solder balls 104 in the radiative solder ball array 122 may be formed from one or more solder balls 104 having a first nominal diameter and one or more solder balls 104 in the radiative solder ball array formed from solder balls 104 having a second nominal diameter. In some embodiments, one or more solder balls 104 in the radiative solder ball array 122 may be formed from one or more solder balls 104 having a first nominal solder ball diameter and one or more solder balls 104 may be formed form one or more other nominal diameters in the radiative solder ball array 122. And in some embodiments having a radiative solder ball array 122 coupled to a terminal end of a solder ball bridge 101 through one or more of an electrically conductive layer 132 and a high thermal conductivity layer 108, one or more solder balls 104 may be formed from one or more first materials and one or more solder balls 104 may be formed form one or more other materials in the radiative solder ball array 122. In some embodiments, solder balls 104 in radiative solder ball array 122 may be one or more of the same material and same nominal diameter as solder balls 104 in solder ball bridge 101. In some embodiments, solder balls 104 in radiative solder ball array 122 may differ in one or more of the solder ball material and solder ball nominal diameter as the solder balls 104 used in solder ball bridge 101.

In some embodiments of solder ball bridge assemblies 100 configured having a radiative solder ball array 122, stacking of solder balls 104 in the radiative solder ball array 122 can lead to increases in radiative surface area of the solder balls 104 in the radiative solder ball array 122.

In some embodiments of solder ball array 122, solder balls 104 may be stacked to facilitate further increasing of the radiative area of the radiative surfaces of the radiative solder ball array 122. FIG. 19B shows a cross-sectional schematic drawing of an embodiment of a solder ball bridge assembly 100 comprising a substrate 110, a mounted device 102, and a solder ball bridge 101 wherein a terminal end of the solder ball bridge 101 is extended from second bond pad 1302 formed on the substrate 110 and further coupled to one or more of a high thermal conductivity layer 108 and an electrical interconnect layer 132, and wherein the one or more of a high thermal conductivity layer 108 and electrical interconnect layer 132 are further coupled to radiative solder ball array 122 formed on bond pads 130 further formed on the one or more of a high thermal conductivity layer 108 and electrical interconnect layer 132, and wherein the radiative solder ball array 122 is configured having solder balls 104 in the radiative solder ball array that are deposited in stacks. The embodiment shown in FIG. 19B is similar to that of the embodiment of FIG. 19A, with the addition of one or more stacked solder balls 104 in the radiative solder ball array 122. The increased radiative surface area of the stacked solder balls is evident in the drawing in FIG. 19B.

Solder ball array 122 is shown enclosed in dotted lines in the schematic drawing of FIG. 19B and includes the third bond pad 130₃, the one or more of the high thermal conductivity layer 108 and electrically conductive layer 132, and an array of solder balls 104 formed on the one or more of the high thermal conductivity layer 108 and electrically conductive layer 132, wherein in the embodiment shown, the solder balls 104 are deposited or otherwise formed on bond pads 130 formed on the one or more of the high thermal conductivity layer 108 and electrically conductive layer 132. In other embodiments, the array of solder balls may be formed on a solder-wettable surface formed on the one or more of the high thermal conductivity layer 108 and electrically conductive layer 132.

The embodiment shown in FIG. 19B shows stacks of solder balls 104 in the radiative solder ball array 122 having a same nominal diameter. In other embodiments, stacks of solder balls 104 may include solder balls having differing diameters. That is, a lower solder ball 104 in a stack may have a nominal diameter of 200 microns, for example, and an upper solder ball in a stack may have a nominal diameter that is less than 200 microns. In some embodiments, the radiative solder ball arrays 122 may have differing materials. That is, the solder balls 104 used in a first stack may be comprised of solder balls 104 made of a first solder alloy, for example, and the solder balls 104 used in a second stack may be comprised of solder balls 104 made of a second solder alloy.

In addition to the increased surface area provided by stacking of the solder balls 104 in the radiative solder ball array 122, bridging of the solder balls 104 with lateral interconnections between one or more layers of stacked solder balls 104 may be used in embodiments to improve the redistribution of thermal energy being dissipated in the radiative solder ball array 122.

FIG. 19C shows a cross-sectional schematic drawing of an embodiment of a solder ball bridge assembly 100 for which the terminal end of solder ball bridge 101 is coupled to a radiative solder ball array 122 that includes lateral interconnections between solder balls 104. The cross-sectional schematic drawing of FIG. 19C shows an embodiment of a solder ball bridge assembly 100 comprising substrate 110, mounted device 102, and solder ball bridge 101 wherein a terminal end of the solder ball bridge 101 is coupled to one or more of a high thermal conductivity layer 108 and an electrical interconnect layer 132, and wherein the one or more of a high thermal conductivity layer 108 and electrical interconnect layer 132 are further coupled to radiative solder ball array 122 formed on bond pads 130 further formed on the one or more of the high thermal conductivity layer 108 and the electrical interconnect layer 132, and wherein the one or more of the solder balls 104 in the radiative solder ball array 122 are laterally coupled. Lateral coupling of one or more of the solder balls in the radiative solder ball array 122 can provide improved distribution of thermal energy that may result in more efficient radiative dissipation in some embodiments. In some embodiments of solder ball bridge assemblies 100 having a terminal end of solder ball bridge 101 coupled to radiative solder ball array 122, one or more of the solder balls 104 in the solder ball array 104 may be laterally coupled to one or more other solder balls 104 in the radiative solder ball array 122. Lateral coupling between solder balls may be, for example, achieved with melding of adjacent solder balls during deposition of the solder balls. Lateral coupling may be achieved in some embodiments with melding of adjacent solder balls after deposition using, for example, a post-deposition heating step.

Solder ball array 122 is shown enclosed in dotted lines in the schematic drawing of FIG. 19C and includes the third bond pad 130₃, the one or more of the high thermal conductivity layer 108 and electrically conductive layer 132, and an array of solder balls 104 formed on the one or more of the high thermal conductivity layer 108 and electrically conductive layer 132, wherein in the embodiment shown, laterally coupled solder balls 104 are deposited or otherwise formed on bond pads 130 formed on the one or more of the high thermal conductivity layer 108 and electrically conductive layer 132.

In the embodiment shown in FIG. 19C, a terminal end of solder ball bridge 101 is coupled to a laterally coupled layer of solder balls 104. In other embodiments, a terminal end of solder ball bridge 101 may be coupled to one or more of a high thermal conductivity layer 108 and an electrically conductive layer 132 which is then coupled to the radiative solder ball array 122.

In the embodiment shown in FIG. 19C, bridging between solder balls 104 is provided in a single layer of the solder balls 104 of the radiative solder ball array 122. In other embodiments, bridging between solder balls 104 may be provided between one or more solder balls 104 in one or more layers of stacked solder balls 104 in the radiative solder ball array 122. Stacks of solder balls 104 comprising two or more nominal diameters in the radiative solder ball array 122 may be used in some embodiments, and lateral coupling may be provided on one or more layers in the stack of solder balls 104 and one or more layers in the stack of solder balls 104 may not be laterally coupled.

FIG. 19D shows a cross-sectional schematic drawing of an embodiment of a solder ball bridge assembly 100 comprising substrate 110, mounted device 102, and solder ball bridge 101 wherein a terminal end of the solder ball bridge 101 is coupled to one or more of a high thermal conductivity layer 108 and an electrical interconnect layer 132, and wherein the one or more of a high thermal conductivity layer 108 and electrical interconnect layer 132 are further coupled to radiative solder ball array 122 formed on bond pads 130 further formed on the one or more of the high thermal conductivity layer 108 and the electrical interconnect layer 132, wherein one or more of the solder balls 104 in the radiative solder ball array 122 are vertically stacked, and wherein one or more of the solder balls 104 in the radiative solder ball array 122 are laterally coupled. Lateral coupling of one or more of the solder balls in the radiative solder ball array 122 can provide improved distribution of thermal energy provided, for example, from the mounted device 102 to the radiative solder ball array 122 through solder ball bridge 101.

In some embodiments of solder ball bridge assemblies 100 having a terminal end of solder ball bridge 101 coupled to a radiative solder ball array 122, one or more layers in a stack of solder balls 104 may have one or more solder balls 104 laterally coupled to one or more other solder balls 104 in one or more layers in another stack of solder balls 104 in the radiative solder ball array 122.

Solder ball array 122 is shown enclosed in dotted lines in the schematic drawing of FIG. 19D and includes the third bond pad 130₃, the one or more of the high thermal conductivity layer 108 and electrically conductive layer 132, and an array of solder balls 104 formed on the one or more of the high thermal conductivity layer 108 and electrically conductive layer 132, wherein in the embodiment shown, stacks of laterally coupled solder balls 104 are deposited or otherwise formed on bond pads 130 formed on the one or more of the high thermal conductivity layer 108 and electrically conductive layer 132.

In some embodiments having a terminal end of solder ball bridge 101 coupled to radiative solder ball array 122, the radiative solder ball array 122 may be formed on a solder-wettable surface of one or more of an electrically conductive layer 132 and a thermally conductive layer 108. FIG. 19E shows a cross-sectional schematic drawing of an embodiment of a solder ball bridge assembly 100 comprising substrate 110, mounted device 102, and solder ball bridge 101 wherein a terminal end of the solder ball bridge 101 is coupled to one or more of a high thermal conductivity layer 108 and an electrical interconnect layer 132, and wherein the one or more of a high thermal conductivity layer 108 and electrical interconnect layer 132 are further coupled to radiative solder ball array 122 formed on solder-wettable surface 125 of the one or more of a high thermal conductivity layer 108 and electrical interconnect layer 132, and wherein the one or more of the solder balls 104 in the radiative solder ball array 122 are laterally coupled.

Solder ball array 122 is shown enclosed in dotted lines in the schematic drawing of FIG. 19E and includes the third bond pad 130₃, the one or more of the high thermal conductivity layer 108 and electrically conductive layer 132, and an array of solder balls 104 formed on the one or more of the high thermal conductivity layer 108 and electrically conductive layer 132, wherein in the embodiment shown, laterally coupled solder balls 104 are deposited or otherwise formed on solder-wettable surface 125 formed on the one or more of the high thermal conductivity layer 108 and electrically conductive layer 132.

In the embodiment shown in FIG. 19E, a single layer of bridged solder balls 104 are provided. In other embodiments, more than one layer of stacked solder balls 104 may be provided in radiative solder ball array 122 on solder-wettable surface 122 formed on one or more of electrically conductive layer 132 and high thermal conductivity layer 108. In some embodiments, solder balls 104 in solder ball array 122 are not laterally coupled. In some embodiments, solder balls 104 in solder ball array 122 are laterally coupled and deposited on a solder-wettable surface 125 formed on substrate 110, and one or more of the electrically conductive layer 132 and the high thermal conductivity layer 108 is not provided between the radiative solder ball array 122 and the substrate 110.

In some embodiments, stacks of solder balls 104 in radiative solder ball array 122 may have equal quantities of solder balls 104. In other embodiments, unequal quantities of solder balls may be provided in the stacks of solder balls 104 in the radiative solder ball array 122. The solder balls 104 in the radiative solder ball array 122 in the embodiment shown in FIG. 19E are formed on solder-wettable surface 125 of the one or more of a high thermal conductivity layer 108 and electrical interconnect layer 132, wherein the one or more of the solder balls 104 in the radiative solder ball array 122 are laterally coupled. In other embodiments, solder balls 104 in the radiative solder ball array 122 shown in FIG. 19E may be stacked, for example, to increase the radiative surface area of the stacked solder balls 104 in comparison to the single layer of deposited solder balls 104 shown in FIG. 19E.

In some embodiments, the formation of laterally connected radiative solder ball array 122 may be achieved without an underlying high thermal conductivity layer 108 or electrical interconnect layer. Interconnection of the solder balls 104 to form all or a portion of the radiative solder ball array 122 may be achieved with the initial anchoring of one or more solder balls to a bond pad 130ᵥ and the subsequent anchoring of sequentially placed solder balls 104 to the anchored solder balls 104.

In some embodiments of solder ball bridge assemblies 100, a terminal end of solder ball bridge 101 may be coupled to a solder-wettable surface area that is accompanied having sufficient energy to spread molten solder across the solder-wettable surface such that the resulting mound that is formed on the solder-wettable surface forms a radiative surface. One or more solder balls 104 deposited upon a solder-wettable surface may be deposited having sufficient energy to spread the molten solder across all or a portion of the solder-wettable surface in some embodiments. In other embodiments, one or more solder balls 104 may be deposited onto a bond pad and subsequently heated to re-distribute the solder from the deposited solder balls 104 across all or a portion of the bond pad 130 or solder-wettable surface.

A number of factors that may be considered in the formation of radiative solder ball arrays 122 are disclosed and described herein that include the use of underlying thermally and electrically conductive layers, the use of stacking of solder balls, the use of lateral coupling of solder balls, the use of a plurality of diameters, the use of multiple materials, the use of multiple stack heights, among others, that may contribute to the radiative properties of radiative solder ball array 122. Coupling of radiative solder ball array 122 to a terminal end of solder ball bridge 101 of solder ball bridge assembly 100 may facilitate improved thermal energy dissipation and may result in improved temperature control in some embodiments.

FIGS. 20A-20C show top view schematic drawing of embodiments of solder ball bridge assemblies 100 wherein a terminal end of solder ball bridge 101 is coupled to a radiative solder ball array configured having a linear array of solder balls 104 and wherein a terminal end of solder ball bridge 101 is coupled to a multidimensional radiative array of solder balls 104.

FIG. 20A shows a top view schematic drawing of a radiative solder ball array 122 coupled to a terminal end of solder ball bridge 101 comprising a row of solder balls 104. The top view schematic drawing of FIG. 20A shows an embodiment of a solder ball bridge assembly 100 comprising substrate 110, mounted device 102, and solder ball bridge 101 wherein a terminal end of the solder ball bridge 101 is coupled to a radiative solder ball array 122 comprising a row of solder balls 104, and wherein the radiative solder ball array 122 is formed on one or more of an optional high thermal conductivity layer 108 and an optional electrical interconnect layer 132. The top view drawing in FIG. 20A shows solder ball bridge 101 coupled to mounted device 102 and coupled to one or more of optional high thermal conductivity layer 108 and optional electrically conductive layer 132 through which thermal energy may be conducted or otherwise transferred. Solder ball bridge 101 is shown coupled to radiative solder ball array 122 in the embodiment shown in FIG. 20A through one or more of the optional high thermal conductivity layer 108 and the optional electrical interconnect layer 132. Electrically conductive layer 132 may be further coupled to other devices provided on, or coupled to substrate 110.

FIG. 20B shows a top view schematic drawing of an embodiment of a solder ball bridge assembly 100 comprising substrate 110, mounted device 102, and solder ball bridge 101 wherein a terminal end of the solder ball bridge 101 is coupled to a radiative solder ball array 122 comprising a plurality of solder balls 104 configured in a multidimensional array, and wherein the radiative solder ball array 122 is formed on substrate 110 that optionally includes one or more of a high thermal conductivity layer 108 and an electrically conductive layer 132. Multidimensional radiative solder ball array 122 is shown as a two-dimensional array of solder balls comprising four rows and four columns of solder balls 104 in the top view shown. In some embodiments, the two-dimensional array shown may be comprised of one or more stacks of solder balls 104.

FIG. 20C shows a top view schematic drawing of an embodiment of a solder ball bridge assembly 100 comprising substrate 110, mounted device 102, and solder ball bridge 101 wherein a terminal end of the solder ball bridge 101 is coupled to a radiative solder ball array 122 comprising a plurality of solder balls 104 in another configuration of the multidimensional array of solder balls 104, and wherein the radiative solder ball array 122 is formed on substrate 110 that optionally includes one or more of a high thermal conductivity layer 108 and an electrical interconnect layer 132.

The top view drawings in FIGS. 20A-20C show solder ball bridge 101 coupled to mounted device 102 and coupled to one or more of an optional high thermal conductivity layer 108 and an optional electrically conductive layer 132 through which thermal energy may be conducted or otherwise transferred. Solder ball bridge 101, in the embodiments, is shown coupled to radiative solder ball array 122 in FIGS. 20A-20C through one or more of a high thermal conductivity layer 108 and electrically conductive layer 132. Electrically conductive layer 132 may be further coupled to other devices provided on, or coupled to substrate 110 to provide an electrical interconnect, for example.

The structures provided in the embodiments shown in FIGS. 20A-20C may be used in conjunction with all or portions of other solder ball bridge assemblies 100 for further coupling of one or more of thermal energy and electrical energy. The embodiments configured as shown, for example, in FIGS. 20A-20C that use thermal coupling to a radiative solder ball array 122 for thermal energy dissipation may be used all or in part with the same or another solder ball bridge 101 to provide electrical energy to the mounted device 102, from the mounted device, or both to and from the mounted device 102. Descriptions provided herein in conjunction with the embodiments shown in FIGS. 20A-20C, are described in relation to the use of the disclosed structures for dissipation of thermal energy, although it should be noted that the embodiments may be configured with electrical interconnect layers 132 that enable electrical connections through the same or additional solder ball bridge 101 provided in the solder ball bridge assemblies 100. The example configurations of solder balls 104 in the radiative solder ball arrays 122 are provided as examples. Other configurations of linearly arranged and multidimensionally arranged solder balls 104 may also be used and remain within the scope of embodiments. Single rows of solder balls 104, for example, may follow a linear path as the embodiment of FIG. 20A, and may follow a curved path, a zig-zag path, and any combination of these path structures to form the radiative solder ball array 122 coupled to a terminal end of solder ball bridge 101. In embodiments having multidimensional arrays of solder balls 104, any spacing and combination of spacings of solder balls 104 may be used in the formation of the multidimensional array of solder balls 104.

FIGS. 21A-21C show top view schematic drawings of embodiments of solder ball bridge assemblies 100 comprising substrate 110, mounted device 102, and solder ball bridge 101 wherein a terminal end of the solder ball bridge 101 is coupled to radiative solder ball array 122, and wherein one or more of the solder balls 104 in the radiative solder ball array 122 are laterally coupled. Lateral coupling of the solder balls 104 in the radiative solder ball array 122 may lead to improved distribution of thermal energy and may further lead to improved thermal energy dissipation in comparison to embodiments that are not configured having laterally coupled solder balls 104.

FIG. 21A shows a top view schematic drawing of an embodiment of a solder ball bridge assembly 100 comprising substrate 110, mounted device 102, and solder ball bridge 101 wherein a terminal end of solder ball bridge 101 is coupled to a radiative solder ball array 122 comprising a plurality of solder balls 104 configured in a multidimensional array, wherein the radiative solder ball array 122 is formed on one or more of an optional high thermal conductivity layer 108 and an optional electrical interconnect layer 132, and wherein the solder balls 104 in linear rows of solder balls 104 in the radiative solder ball array 122 are laterally coupled. In the embodiment, lateral coupling of the solder balls 104 in the radiative solder ball array 122 is provided to enable lateral redistribution of the thermal energy from the mounted device 102, for example, by providing high thermal conductivity pathways from the mounted device 102 to the radiative solder ball array 122. In some embodiments having laterally coupled solder balls 104, two or more solder balls 104 in linear arrays of solder balls 104 may be laterally coupled.

FIG. 21B shows a top view schematic drawing of an embodiment of a solder ball bridge assembly 100 comprising substrate 110, mounted device 102, and solder ball bridge 101 wherein a terminal end of the solder ball bridge 101 is coupled to radiative solder ball array 122 comprising a plurality of solder balls 104 configured in an embodiment of a multidimensional radiative solder ball array 122, wherein the multidimensional radiative solder ball array 122 is formed on one or more of a high thermal conductivity layer 108 and an electrical interconnect layer 132, and wherein two or more of the solder balls 104 in the multidimensional radiative solder ball array 122 are laterally coupled. In the embodiment in FIG. 21B, some of the solder balls 104 in the radiative array of solder balls 104 are configured having lateral coupling to a plurality of other solder balls 104 in the radiative solder ball array 122 to illustrate a configuration of a multidimensional radiative solder ball array 122 having multiple laterally coupled pathways for thermal energy from the mounted device 102 to be more uniformly distributed in the radiative solder ball array 122.

FIG. 21C shows a top view schematic drawing of an embodiment of a solder ball bridge assembly 100 comprising substrate 110, mounted device 102, and solder ball bridge 101 wherein a terminal end of the solder ball bridge 101 is coupled to a radiative solder ball array 122 comprising a plurality of solder balls 104 configured in yet another embodiment of a multidimensional radiative solder ball array 122, wherein the multidimensional radiative solder ball array 122 is optionally formed on one or more of a high thermal conductivity layer 108 and an electrical interconnect layer 132, and wherein two or more of the solder balls 104 in the multidimensional radiative solder ball array 122 are laterally coupled. In the embodiment in FIG. 21C, another configuration is provided that shows some of the solder balls 104 in the radiative array of solder balls 104 having lateral coupling to a plurality of other solder balls 104 in the radiative solder ball array 122 to illustrate a configuration of a multidimensional radiative solder ball array 122 having multiple laterally coupled pathways for thermal energy from the mounted device 102 to be distributed within the radiative solder ball array 122.

In the embodiments shown in FIGS. 21A-21C, a single solder ball bridge 101 is shown connecting the mounted device 102 to the radiative solder ball array 122. In other embodiments, more than one solder ball bridge 101 may be used to connect the mounted device 102 to the radiative solder ball array 122. And in some embodiments, radiative solder ball array 122 may be coupled to one or more mounted devices 102. In embodiments of photonic integrated circuit assemblies 142 having a plurality of mounted devices 102, such as the embodiment of photonic integrated circuit assembly 142 shown in FIG. 2E having four mounted devices 102a, the photonic integrated circuit assembly 142 may be configured having a single radiative solder ball array 122 to which a solder ball bridge 101 is provided from each mounted device 102a to the radiative solder ball array 122.

### Solder Ball Bridge Assemblies on Interposer Substrate Comprising a Planar Waveguide Layer and an Electrical Interconnect Layer

In some embodiments of solder ball bridge assembly 100, comprising substrate 110, one or more mounted devices 102, and one or more solder ball bridges, substrate 110 is an interposer substrate 210 configured having a planar waveguide formed on a base structure further comprising an optional electrical interconnect layer 103 on a substrate 110_{substrate}. Planar waveguide layer 105 formed on substrate 110 enable the coupling of optical signals from mounted devices 102 to patterned planar waveguides 144 formed from the planar waveguide layer 105 to other parts of photonic integrated circuit assembly 142.

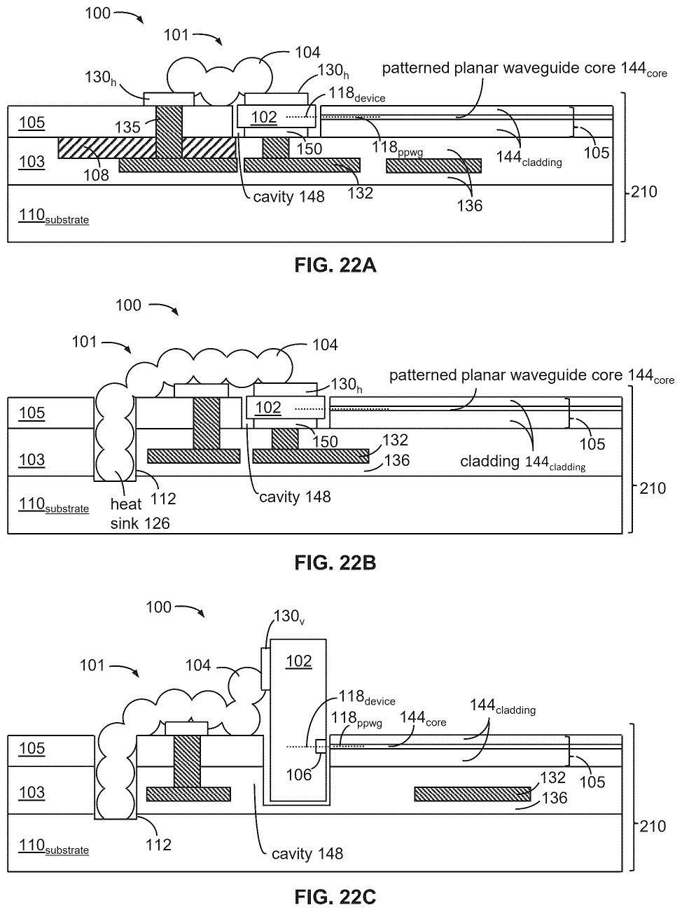

FIGS. 22A-22C show schematic cross-sectional drawings of embodiments of solder ball bridge assembly 100 comprising substrate 110, mounted device 102, and solder ball bridge 101 wherein the substrate 110 is an interposer substrate 210 configured having a planar waveguide layer 105 formed on an optional electrical interconnect layer 103, and wherein mounted device 102 is disposed in a cavity 148 formed in the planar waveguide layer 105 on the interposer substrate 210. In an embodiment of solder ball bridge assembly 100 comprising mounted device 102 and interposer substrate 210 having planar waveguide layer 105 on electrical interconnect layer 103, an optical axis 118_{device} of mounted device 102 is aligned to an optical axis 118_{pwg} of a patterned planar waveguide core 144_{core} formed from the planar waveguide layer 105 to facilitate coupling of optical signals from the mounted device 102 to the patterned planar waveguide core 144_{core} of the interposer substrate 210.

Planar waveguide layer 105, in embodiments, comprises patterned planar waveguide cores 144_{core} and one or more cladding layers 144_{cladding} surrounding the patterned planar waveguide cores 144_{core}. Patterned planar waveguide cores 144_{core} provide primary propagation pathways for optical signals substantially contained within the surrounding cladding. Optical signals, as used herein, refers to electromagnetic radiation in the optical wavelength range of approximately 200 nm to approximately 2000 nm. This wavelength range includes wavelengths in the infrared ranges commonly used in telecommunications applications such as the O-band and C-band, among other wavelengths that may be used in telecommunications applications and other applications that may benefit from photonic integrated circuits and assemblies derived all or in part from planar waveguide technology. In telecommunications applications, for example, electromagnetic radiation in infrared portions of the electromagnetic spectrum is often encoded with information and used to transfer information. In particular, electromagnetic radiation in the O-band having wavelengths in the range of 1260 to 1360 nm and in the C-band having wavelengths in the range of 1530 to 1565 nm are commonly used in optical communications technology. In embodiments, these and other optical wavelengths throughout the visible and infrared range of the electromagnetic spectrum may be used in photonic integrated circuit assemblies 142 for which patterned planar waveguide cores 144_{core}, in combination with suitable cladding layers 144_{cladding}, may be used to guide the propagation of optical electromagnetic radiation.

FIG. 22A shows a cross-sectional schematic drawing of an embodiment of an assembly comprising interposer substrate 210, a mounted device 102, and a solder ball bridge 101 wherein the interposer substrate 210 further comprises a planar waveguide layer 105 formed on an electrical interconnect layer 103, wherein the mounted device is mounted in a cavity that intersects the core layer of a patterned planar waveguide, and wherein the solder ball bridge 101 is formed between a horizontally-oriented bond pad 130ₕ formed on the mounted device 102 and a horizontally-oriented bond pad 130ₕ formed on the interposer substrate 210. In the embodiment, the horizontally-oriented bond pad 130ₕ formed on the interposer substrate 210 is further coupled through a vertical interconnect 135 to an electrically conductive layer 132 formed in electrical interconnect layer 103. In embodiments, mounted device 102 is mounted in cavity 148 in an aligned position such that the optical axis 118_{device} of the mounted device 102 is in substantial alignment with the optical axis 118_{ppwg} of a patterned planar waveguide core 144_{core} formed in the planar waveguide layer 105.

The embodiment in FIG. 22A shows a solder ball bridge assembly 100 that includes a mounted device 102 mounted in a cavity 148 wherein the cavity is formed in at least a portion of planar waveguide layer 105. Solder ball bridge 101 comprised of three laterally coupled solder balls 104 is shown, in the embodiment, between a bond pad 130ₕ formed on the top surface of mounted device 102 and a bond pad 130ₕ formed on interposer substrate 210. Planar waveguide layer 105 of interposer substrate 210 includes a patterned planar waveguide core 144_{core}. In embodiments, patterned planar waveguide core 144_{core} is a patterned waveguide core in which at least a portion of a planar waveguide core layer 105 is patterned and enveloped in one or more cladding layers 144_{cladding} to form one or more pathways for the propagation of optical signals such as is used, for example, in photonic integrated circuit assemblies.

In other embodiments, more than three solder balls 104 may be used in the formation of solder ball bridge 101 in embodiments having mounted device 102 mounted in a cavity 148 as configured, for example, in FIG. 22A. In yet other embodiments, fewer than three solder balls may be used as described herein.

Interposer substrate 210, in the embodiment shown in FIG. 22A, may be an interposer structure comprising a substrate 110_{substrate}, an electrical interconnect layer 103 formed on substrate 110_{substrate}, and a planar waveguide layer 105 formed on the electrical interconnect layer 103. In embodiments, interposer substrate 210, as used herein, is a substrate on which a mounted device 102 of solder ball bridge assembly 100 may be mounted or otherwise disposed, and wherein substrate 110_{substrate}, as used herein, is a substrate typically formed of a single material such as silicon or other semiconductor or dielectric material. Substrate 110_{substrate} may be used, for example, as a base structure upon which other layers such as one or more electrical interconnect layers, as in electrical interconnect layer 103, for example, and one or more planar waveguide layers, as in planar waveguide layer 105, for example, may be formed. (Details for a method of formation of interposer structures having patterned planar waveguides formed on an electrical interconnect layer are described in application Ser. No. 17/499,323 now U.S. Pat. No. 11,686,906 issued on Jun. 27, 2023, incorporated herein by reference in its entirety.)

Electrical interconnect layer 103 of interposer substrate 210, as shown in the embodiment in FIG. 22A, may comprise one or more electrically conductive layer 132 and one or more optional intermetal dielectric layer 136. Intermetal dielectric layer 136, in embodiments, provides dielectric insulation where required to electrically insulate the one or more electrically conductive layer 132 from other conductive layers. Vertical interconnects 135 may be used in embodiments, to form interconnections through the intermetal dielectric layers to electrical connections, devices, and other metallization layers above, within, and below the interposer substrate 210. Intermetal dielectric layers 136 may also be formed all or in part from dielectric materials having high thermal conductivity to form high thermal conductivity layers 108 described herein.

Mounted device 102, as shown in the embodiment in FIG. 22A, may be an emitting device, for example, such as a laser, a gain device, a light emitting diode, among other forms of devices that emit optical radiation upon the application of electrical power. Mounted device 102 may also be one or more of an optical device, an electrical device, and another form of optoelectrical device as further described herein. In embodiments for which mounted device 102 is an optical or optoelectrical device, and for which the optical or optoclectrical device includes an optical axis, the inclusion of the cavity 148 in all or a portion of the planar waveguide layer 105 of interposer substrate 210 can facilitate the alignment of the optical axis 118_{device} of the mounted device 102 and the optical axis 118_{ppwg} of a patterned planar waveguide core 144_{core} formed from planar waveguide layer 105. The optical axis 118_{device} of the mounted device 102 and the optical axis 118_{ppwg} of a patterned planar waveguide core 144_{core} formed on interposer substrate 210 are shown in substantial alignment in the embodiment in FIG. 22A.

FIG. 22B shows a cross-sectional schematic drawing of an embodiment of a solder ball bridge assembly 100 comprising interposer substrate 210, mounted device 102 having a horizontally-oriented bond pad, and solder ball bridge 101 wherein a terminal end of the solder ball bridge 101 extends into a trench 112 formed in the interposer substrate 210 and wherein the extension of solder ball bridge 101 into the trench 112 forms all or a portion of a heat sink 126. In the embodiment, the interposer substrate 210 includes patterned planar waveguide layer 105 formed on an electrical interconnect layer 103, wherein the mounted device 102 is mounted in a cavity 148 that intersects the patterned planar waveguide core 144_{core} of a patterned planar waveguide 144. In embodiments, mounted device 102 is mounted in cavity 148 in an aligned position such that the optical axis 118_{device} of the mounted device 102 is in substantial alignment with the optical axis 118_{ppwg} of a patterned planar waveguide core 144_{core} formed in the planar waveguide layer 105. Solder ball bridge 101 is formed in the embodiment shown in FIG. 22B between a horizontally-oriented bond pad 130ₕ formed on the mounted device 102 and a horizontally-oriented bond pad 130ₕ formed on the interposer substrate 210 and coupled to an electrically conductive layer 132 in the electrical interconnect layer 103.

Heat sink 126 in the embodiment, may be one or more solder balls 104 deposited in trench 112 to which thermal energy from mounted device 102 may be one or more of received, distributed, transferred, and stored. Solder ball bridge assembly 100 in the embodiment shown in FIG. 22B, comprises interposer substrate 210, mounted device 102, and solder ball bridge 101 wherein the mounted device 102 is mounted in a cavity 148 that intersects the patterned planar waveguide core layer 144_{core} of a patterned planar waveguide 144 formed form the planar waveguide layer 105, wherein the solder ball bridge 101 is formed between a horizontally-oriented bond pad 130ₕ formed on the mounted device 102 and a horizontally-oriented bond pad 130ₕ formed on the interposer substrate 210 and coupled to an electrically conductive layer 132 in electrical interconnect layer 103, and wherein a terminal end of the solder ball bridge 101 is further extended to the bottom of a trench 112 formed in the interposer substrate 210. Thermal energy, generated by a mounted device 102, for example, may be transferred through solder ball bridge 101 from the mounted device 102 at a first terminal end, to the one or more solder balls 104 deposited in trench 112 wherein the thermal energy may be transferred to one or more of the substrate 110_{substrate}, a high thermal conductivity layer 108 in the interposer substrate 210, and other heat sinks formed in or otherwise coupled to the interposer substrate 210. Secondary cooling may be provided to one or more of the substrate 110_{substrate}, a high thermal conductivity layer 108 formed within the interposer substrate 210, an electrically conductive layer 132 formed within the interposer substrate 210, and all or a portion of the solder balls 104 and other heat sinking materials of trench 112. Secondary cooling, such as may be provided with a Peltier device or thermoelectric cooler, liquid cooling, refrigeration, among other forms of cooling can further facilitate the extraction of thermal energy from the mounted device 102 through one or more heat sinks 126 formed in one or more trenches 112 in the interposer substrate 210. Trench 112 may include solder-wettable layer 125 formed on one or more of the bottom of the trench and a wall of the trench 112.

FIG. 22C shows a cross-sectional schematic drawing of an embodiment of a solder ball bridge assembly 100 comprising interposer substrate 210, mounted device 102 having a vertically-oriented bond pad 130ᵥ, and a solder ball bridge 101 wherein a terminal end of the solder ball bridge 101 extends into a trench 112 formed in the interposer substrate 210 and wherein the extension of solder ball bridge 101 into the trench 112 forms all or a portion of a heat sink 126. In the embodiment, the interposer substrate 210 includes patterned planar waveguide layer 105 formed on an electrical interconnect layer 103, wherein the mounted device 102 is mounted in a cavity 148 that intersects the patterned planar waveguide core 144_{core} of a patterned planar waveguide 144.

In the embodiment, a vertically-oriented bond pad 130ᵥ is formed on mounted device 102 to which a terminal end of the solder ball bridge 101 extends into trench 112 to form all or a portion of a heat sink 126 in trench 112. Solder ball bridge assembly 100 shown in the embodiment in FIG. 22C comprises interposer substrate 210, mounted device 102 having the vertically-oriented bond pad, and solder ball bridge 101 wherein the mounted device 102 is mounted in a cavity 148 that intersects the patterned planar waveguide core layer 144_{core} of a patterned planar waveguide 144 formed form the planar waveguide layer 105, wherein the solder ball bridge 101 is formed between the vertically-oriented bond pad 130ᵥ formed on the mounted device 102 and a horizontally-oriented bond pad 130ₕ formed on the interposer substrate 210 and coupled to an electrically conductive layer 132 in the electrical interconnect layer 103, and wherein a terminal end of the solder ball bridge 101 is further extended to the bottom of a trench 112 formed in the substrate 110 to form heat sink 126. Mounted devices 102 having vertically-oriented bond pads may be a photodiode, an optical sensor, an optical receiving device, among other optical devices that may be mounted in cavity 148 of interposer substrate 210. In embodiments, vertically-oriented bond pads 130ᵥ of the mounted device 102 may be coupled to a terminal end of solder ball bridge 101 that is further coupled to a heat sink 126 in the interposer substrate 210 of solder ball bridge assembly 100.

In the embodiment in FIG. 22C, as in the embodiments shown in FIGS. 22A and 22B, mounted device 102 is mounted in cavity 148 such that the optical axis 118_{device} of the mounted device 102 is in substantial alignment with the optical axis 118_{ppwg} of a patterned planar waveguide core 144_{core} formed in the planar waveguide layer 105. Mounted device 102 in FIG. 22C includes optical aperture 106 having optical axis 118_{device} that is aligned with optical axis 118_{ppwg} of the patterned planar waveguide to which the optical axis 118_{device} is aligned.

It should be noted that in some embodiments having patterned planar waveguide layer 105, an underlying electrical interconnect layer may not be present. Electrical interconnects to which a terminal end of solder ball bridge 101 may be connected, for example, and that may provide electrical power for a mounted device 102 that is one or more of an optoelectrical emitting device and an optoelectrical receiving device, such as a laser and photodiode, respectively, among others, may be provided to the photonic integrated circuit assembly from an electrical interconnect layer formed on the planar waveguide layer 105. In some embodiments comprising only optical devices without a requirement for electrical interconnections, an electrical interconnect layer may not be provided.

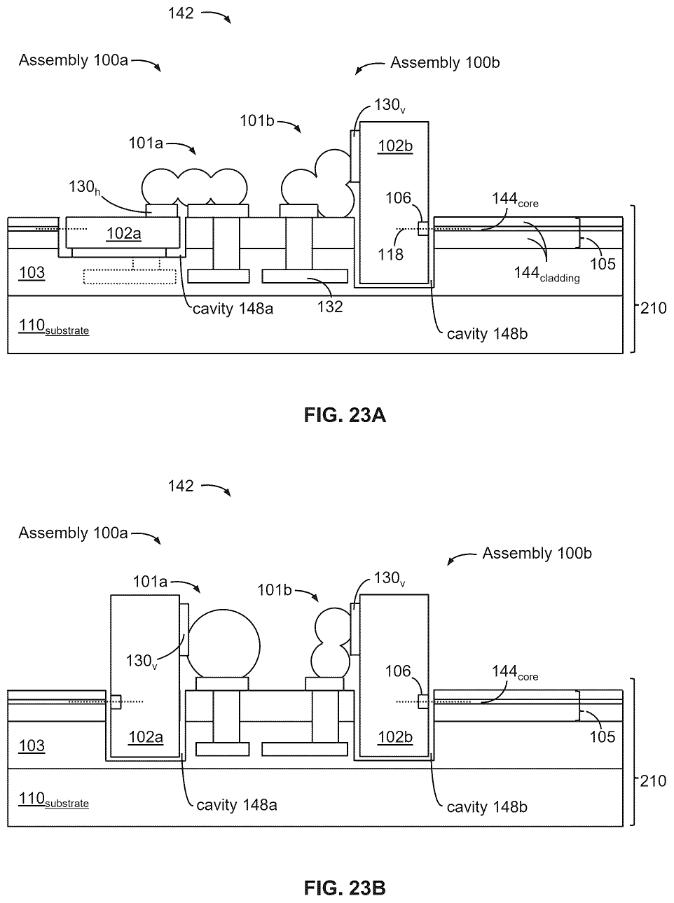

FIG. 23A shows a cross-sectional schematic drawing of an embodiment of a photonic integrated circuit assembly 142 formed on an interposer substrate 210 that includes two solder ball bridge assemblies 100a, 100b each comprising the interposer substrate 210, a mounted device 102a, 102b, respectively, having either a vertically-oriented bond pad 130ᵥ or a horizontally-oriented bond pad 130ₕ, and a solder ball bridge 101a, 101b respectively wherein the interposer substrate 210 comprises planar waveguide layer 105 formed on electrical interconnect layer 103 and wherein the solder ball bridges 101 are formed between a bond pad on a mounted device and a bond pad on the interposer substrate 210. In the embodiment of the photonic integrated circuit assembly 142 shown in FIG. 23A, two solder ball bridge assemblies 100 are provided on the interposer substrate 210. In other embodiments, more than two solder ball bridge assemblies 100 may be included in photonic integrated circuit assembly 142.

In the embodiment shown in FIG. 23A, two solder ball bridge assemblies 100a, 100b are shown in the photonic integrated circuit assembly 142 on the interposer substrate 210 each comprising the interposer substrate 210, mounted device 102a, 102b, respectively, and solder ball bridge 101a, 101b, respectively, wherein the first solder ball bridge 101a is formed between a horizontally-oriented bond pad 130ₕ on mounted device 102a and a horizontally-oriented bond pad 130ₕ on the interposer substrate 210, and wherein a second solder ball bridge 101b is formed between a horizontally-oriented bond pad 130ₕ on the interposer substrate 210 and a vertically-oriented bond pad 130ᵥ on mounted device 102b.

First solder ball bridge assembly 100a in FIG. 23A, which includes solder ball bridge 101a, forms a thermally and electrically conductive lateral connection between a horizontally-oriented bond pad 130ₕ on the interposer substrate 210 a horizontally-oriented bond pad 130ₕ on the mounted device 102a, and second solder ball bridge assembly 100b, which includes solder ball bridge 101b, forms a thermally and electrically conductive lateral connection between a horizontally-oriented bond pad on the interposer substrate 210 and a vertically-oriented bond pad 130ᵥ on the mounted device 102b. In other configurations, more than two solder ball bridge assemblies 100 may be provided. In the embodiment, mounted device 102a is mounted in a cavity 148a and mounted device 102b is mounted in a cavity 148b.

In other embodiments of photonic integrated circuit assembly 142, one or more solder ball bridge assemblies 100 may be formed on interposer substrate 210 having solder ball bridges 101 formed between two or more horizontally-oriented bond pads 130ₕ. In yet other embodiments, one or more solder ball bridge assemblies 100 may be formed between two or more vertically-oriented bond pads 130 . . . . And in yet other embodiments, one or more assemblies may be formed between one or more horizontally-oriented bond pads 130ₕ and one or more vertically oriented bond pads 130ᵥ. In yet other embodiments, one or more of these one or more solder ball bridge assemblies 100 may be formed in an embodiment of a photonic integrated circuit assembly 142 having more than one solder ball bridge assembly 100.

Embodiments of photonic integrated circuit assemblies 142 may be configured having one or more of one or more of mounted devices 102a, 102b wherein the one or more mounted devices 102a are configured as emitting devices such as lasers, and wherein the one or more mounted devices 102b are configured as receiving devices such as photodiodes. Embodiments configured having mounted devices 102a configured as lasers and having mounted devices 102b configured as photodiodes, may be further configured as transceiver devices that may be used for example in telecommunications networks. Other embodiments of photonic integrated circuit assemblies 142 having solder ball bridge assemblies 100, and having one or more of mounted device 102a configured as a laser, may be further configured as a transmitting devices, for example, and as a multiplexing device, among other devices used in telecommunications networks. Other embodiments of photonic integrated circuit assemblies 142 having solder ball bridge assemblies 100, and having one or more of mounted device 102b configured as a photodiode, may be further configured as a receiving devices, for example, and as a demultiplexing device, among other devices used in telecommunications networks.

FIG. 23B shows a cross-sectional schematic drawing of an embodiment of photonic integrated circuit assembly 142 formed on interposer substrate 210 that includes two solder ball bridge assemblies 100a, 100b each comprising the interposer substrate 210, a mounted device 102,a, 102b, respectively, having a vertically-oriented bond pad 130ᵥ, and a solder ball bridge 101a, 101b, respectively, wherein the interposer substrate 210 comprises planar waveguide layer 105 on electrical interconnect layer 103 and wherein the solder ball bridges 101a, 101b are formed between a vertically-oriented bond pad 130ᵥ on the mounted device 102a, 102b, respectively, and a horizontally-oriented bond pad 130ₕ on the interposer substrate 201. Solder ball bridge assembly 100a in the embodiment shown in FIG. 23B shows a solder ball bridge 101a formed from a single solder ball 104 connecting the horizontally-oriented bond pad 130ₕ on the interposer substrate 210 and the vertically-oriented bond pad 130ᵥ on the mounted device 102a wherein the mounted device 102a is shown mounted in cavity 148a and wherein the cavity 148a is shown formed in the planar waveguide layer 105 and partially formed in electrical interconnect layer 103. In other embodiments, cavity 148 within which a mounted device 102 is mounted may be limited to planar waveguide layer 105. In yet other embodiments, cavity 148 within which a mounted device 102 is mounted may extend fully through planar waveguide layer 105 and electrical interconnect layer 103. And in yet other embodiments of photonic integrated circuit 142 formed on an interposer substrate 210, a cavity 148 within which a mounted device 102 is mounted may extend fully through planar waveguide layer 105, fully through electrical interconnect layer 103, and partially into substrate 110_{substrate}.

Solder ball bridge assembly 100b in the embodiment of photonic integrated circuit assembly 142 in FIG. 23B shows solder ball bridge 101b forming an interconnect between cavity-mounted mounted device 102b and interposer substrate 210 wherein the solder ball bridge 101 is formed from two stacked solder balls 104 deposited between the horizontally-oriented bond pad 130ₕ on the interposer substrate 210 and the vertically-oriented bond pad 130ᵥ on the mounted device 102b in cavity 148b. Apertures 106 of the mounted devices 102a, 102b are shown in alignment with patterned planar waveguide cores 144_{core} formed from the planar waveguide layer 105.

The embodiments of the solder ball bridge assemblies 100a, 100b in FIGS. 23A and 23B show structures having cavity-mounted devices on interposer substrates 210 for which one and two solder balls 104, respectively, are used to form the interconnect between a bond pad 130ᵥ formed on the cavity-mounted device and a bond pad 130ₕ formed on the interposer substrate 210.

In some embodiments of photonic integrated circuit assemblies 142 having solder ball bridge assemblies 100, mounted devices 102 may be mounted to a submount that is mounted to a substrate configured as an interposer substrate 210. Submounts may be used, for example, in embodiments of photonic integrated circuit assemblies 142 to facilitate the formation of mountable sub-assemblies, that may include one or more mounted devices 102. Described herein are embodiments of photonic integrated circuit assemblies 142 having submounts, wherein the submounts may be one or more of cavity-mounted submounts and surface-mounted submounts mounted on substrate 110 configured as an interposer substrate 210.

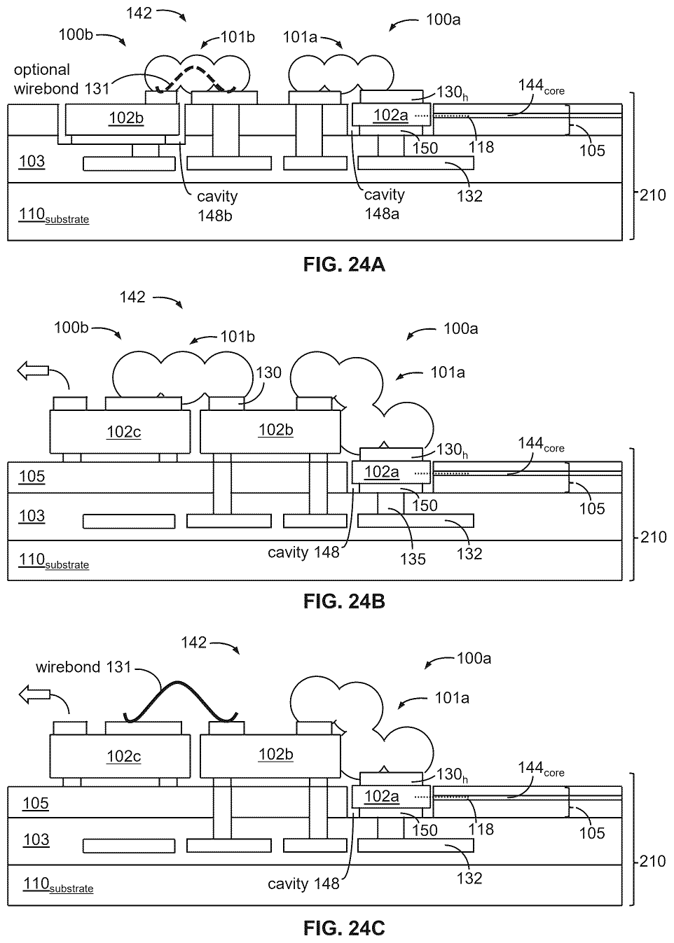

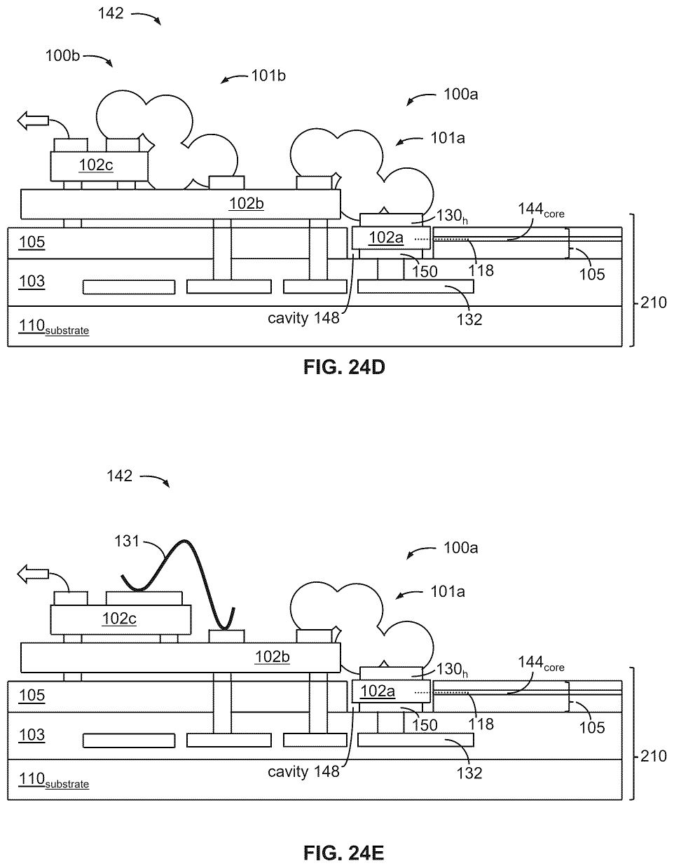

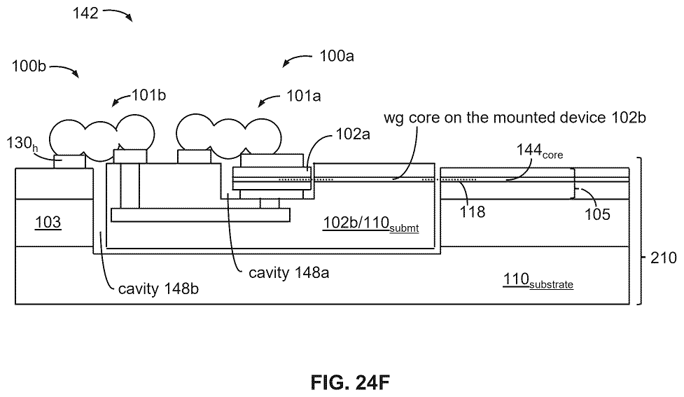

In some embodiments of photonic integrated circuit assemblies 142 having solder ball bridge assemblies 100, one or more electrical interconnections between mounted devices 102 mounted on a submount, and one or more electrical interconnections between a submount and an interposer substrate 210 may be formed using a solder ball bridge 101 and one or more electrical connection may be formed using wirebonding. Such embodiments are described in more detail in the following paragraphs in conjunction with FIGS. 24A-24F.

FIGS. 24A-24F show cross-sectional schematic drawings of embodiments of photonic integrated circuit assemblies 142 that includes a plurality of solder ball bridge assemblies 100 comprising interposer substrate 210, mounted devices 102a, 102b, and solder ball bridges 101a, 101b wherein one or more of the mounted devices 102a, 102b may be mounted in a cavity 148 that intersects the patterned planar waveguide core layer 144_{core} of a patterned planar waveguide 144 and wherein the solder ball bridges 101a, 101b are formed between mounted devices 102a, 102b and the interposer substrate 210.

The embodiments shown in FIGS. 24A-24F show example configurations of photonic integrated circuit assemblies 142 that may be used in the formation of network devices used in telecommunications networks. In these embodiments, configurations are shown in which the mounted devices 102 are cavity-mounted devices and configurations are shown in which the mounted devices 102 are surface-mounted devices. In some embodiments, cavity-mounted devices may be coupled to surface-mounted devices and some surface-mounted devices may be coupled to other surface-mounted devices as used for example in the formation of receiving devices, transmitting devices, and transceiver devices used, for example, in telecommunications networks. In some of these devices, solder ball bridges 101 may be used to form one or more electrical and thermal interconnection for one or more of the mounted devices 102 and one or more electrical and thermal interconnection may be formed using wirebonding.

FIG. 24A shows a cross-sectional schematic drawing of a photonic integrated circuit assembly 142 having two solder ball bridge assemblies 100a, 100b wherein the mounted devices 102a, 102b, respectively, are cavity-mounted devices. In the photonic integrated circuit assembly 142 shown in FIG. 24A having two solder ball bridge assemblies 100a, 100b, first solder ball bridge assembly 100a comprises interposer substrate 210, mounted device 102a mounted in cavity 148a, and solder ball bridge 101a, and second solder ball bridge assembly 100b comprises interposer substrate 210, mounted device 102b mounted in cavity 148b, and solder ball bridge 101b. Interposer substrate 210 in FIG. 24A is configured having mounted device 102a of first solder ball bridge assembly 100a mounted in a first cavity 148a that intersects the patterned planar waveguide core layer 144_{core} of a patterned planar waveguide 144, and wherein the solder ball bridge 101a of the first solder ball bridge assembly 100a is formed between a horizontally-oriented bond pad 130ₕ formed on the first mounted device 102a and a horizontally-oriented bond pad 130ₕ formed on the interposer substrate 210. A bottom contact 150 of the first mounted device 102a is shown coupled to an electrically conductive layer 132 of the electrical interconnect layer 103 of the interposer substrate 210 through a vertical interconnect 135.

In the interposer substrate 210 in FIG. 24A, mounted device 102b of second solder ball bridge assembly 100b of FIG. 24A is mounted in a second cavity 148b that intersects the patterned planar waveguide core layer 144_{core} of a patterned planar waveguide 144, and wherein the solder ball bridge 101b of the second solder ball bridge assembly 100b is formed between a horizontally-oriented bond pad formed 130ₕ on the second mounted device 102b and a horizontally-oriented bond pad 130ₕ formed on the interposer substrate 210. A bottom contact 150 of the second mounted device 102b is shown coupled to an electrically conductive layer 132 of the electrical interconnect layer 103 through a vertical interconnect 135.

Solder ball bridges 101a, 101b of FIG. 24A are configured having three solder balls 104 formed between the bond pads 130ₕ on the mounted devices 102a, 102b, respectively, and the bond pads 130ₕ on the interposer substrate 210. In other embodiments, solder ball bridges 101a, 101b may be configured with more than three solder balls 104. And in other embodiments, solder ball bridges 101a, 101b may be configured with fewer than three solder balls 104. In the embodiments of the solder ball bridge assemblies 100a, 100b shown in FIG. 24A, the solder ball bridges 101a, 101b may be formed by an initial placement of a first solder ball onto one of the bond pads 130ₕ, a placement of a second solder ball onto another bond pad 130ₕ at a lateral spacing that is less than the diameter of a third solder ball that may be used to bridge the spacing between the first and second solder ball, and placement of a third solder ball to bridge the spacing between the first and second solder balls 104.

The embodiment of the photonic integrated circuit assembly 142 shown in FIG. 24A shows two mounted devices 102a, 102b and two solder ball bridge assemblies 100a, 100b. In other embodiments, more than two mounted devices may be present in photonic integrated circuit assembly 142. In some embodiments, mounted device 102a and mounted device 102b, may be configured as emitting devices, and may each provide optical signals to a patterned planar waveguide 144 that intersects the respective cavities within which the mounted devices are mounted. In other embodiments, an optical signal from mounted device 102a may be combined with an optical signal form mounted device 102b which may be provided to a patterned planar waveguide core 144_{core} that intersects the wall of the cavity within which one of the mounted devices 102a, 102b is mounted.

In some embodiments of photonic integrated circuit assembly 142, mounted device 102b may be, for example, a driver coupled to a mounted device 102a that is configured as a laser. Alternatively, mounted device 102a may be configured as a receiving device, as shown for example in FIG. 23A, and mounted device 102b may be configured as a transimpedance amplifier. Other embodiments of photonic integrated circuit assemblies 142 may be configured having a plurality of solder ball bridge assemblies 100 that may be used to couple a plurality of mounted devices 102 to the interposer substrate 210. In some embodiments, one or more of the electrical connections to one or more of the mounted devices 102a, 102b may be formed using a solder ball bridge 101 and one or more may be formed using a wirebond 131. A wirebond 131 is shown with a dotted line in FIG. 24A for which the wirebond 131 forms an electrical interconnection between the bond pad 130 on mounted device 102b and a bond pad 130 on the interposer substrate 210. Some mounted devices 102 may benefit from the use of wirebonding techniques to form electrical connections using wirebonds 131 between one or more pairs of bond pads 130 that require electrical interconnections to be formed.

FIG. 24B shows a cross-sectional schematic drawing of an embodiment of a photonic integrated circuit assembly 142 having a plurality of solder ball bridge assemblies formed between three mounted devices mounted on interposer substrate 210 in the embodiment. A first mounted device 102a in the embodiment, is a cavity-mounted device mounted in cavity 148 in the interposer substrate 210, a second mounted device 102b is a surface-mounted device mounted on interposer substrate 210, and a third mounted device 102c is a surface-mounted device also mounted on the interposer substrate 210 in the embodiment. Configurations of photonic integrated circuit assemblies 142 such as that schematically illustrated in FIG. 24B may be used, for example, in the formation of all or a portion of devices used in the formation of telecommunications networks such as optical transmitter devices wherein the first device may be, for example, an optical emitting device such as a laser, wherein the second device may be, for example, a modulating device, and wherein the third device may be a driver. Other configurations having a plurality of surface-mounted devices wherein the surface-mounted devices are other devices used in the formation of embodiments of photonic integrated circuit assemblies 142 may also be used. Second device 102b may be, for example, a driver circuit, first device 102a may have an integrated modulator, and third device 102c, may be an ASIC or other device.

A first solder ball bridge assembly 100a for the embodiment of the photonic integrated circuit assembly 142 shown in FIG. 24B comprises first mounted device 102a, second mounted device 102b, and solder ball bridge 101a wherein a first terminal end of solder ball bridge 101a is coupled to a horizontally-oriented bond pad 130ₕ on mounted device 102a mounted in cavity 148, and a second terminal end of solder ball bridge 101a is coupled to a horizontally-oriented bond pad 130ₕ on mounted device 102b mounted on interposer substrate 210. A second solder ball bridge assembly 100b for the embodiment of the photonic integrated circuit assembly 142 shown in FIG. 24B comprises second mounted device 102b, third mounted device 102b, and solder ball bridge 101b wherein a first terminal end of solder ball bridge 101b is coupled to a horizontally-oriented bond pad 130ₕ on mounted device 102b surface-mounted on interposer substrate 210 and a second terminal end of solder ball bridge 101b is coupled to a horizontally-oriented bond pad 130ₕ on mounted device 102c also surface-mounted on interposer substrate 210.

In the embodiment shown in FIG. 24B, cavity-mounted device 102a in cavity 148 intersects the wall of cavity 148 to enable coupling of an optical feature of the mounted device 102a with a patterned planar waveguide core 144_{core} formed from all or a portion of the planar waveguide layer 105. Use of solder ball jetting to form embodiments of solder ball bridge assemblies 100 enables the use of solder ball jetting apparatus to form other interconnections that may be present in photonic integrated circuit assemblies 142 that include solder ball bridges 101. In the embodiment of the solder ball bridge assembly 100 that includes interposer substrate 210, additional solder ball bridges 101 may be formed, for example, between solder-wettable bond pads formed on one or more of the interposer substrate 210, on one or more mounted devices 102 mounted on the interposer, and to other devices coupled to the interposer (as indicated by the hollow arrow pointing to the left of the drawing in FIG. 24B). In the embodiment shown in FIG. 24B, mounted device 102a mounted in cavity 148 intersects the patterned planar waveguide core 144_{core} of a patterned planar waveguide 144 formed from planar waveguide layer 105. Mounted device 102b in FIG. 24B is a surface-mounted device mounted on the interposer substrate 210. Electrical connections of the surface-mounted device 102b are shown coupled to electrically conductive layer 132 of electrical interconnect layer 103 through a vertical interconnect 135. The embodiment further shows a mounted device 102c that is also a surface-mounted device. Mounted device 102c in some embodiments, may be optionally coupled to an electrically conductive layer 132 of the electrical interconnect layer 103. In other embodiments, mounted device 102c may not be coupled to an underlying electrically conductive layer 132. Mounted device 102b and mounted device 102c are shown in the embodiment of photonic integrated circuit assembly 142 configured having a laterally coupled solder ball bridge 101c that forms a lateral interconnection between solder-wettable horizontally-oriented bond pads 130ₕ on the mounted device 102b and mounted device 102c. Mounted device 102b and mounted device 102c may be, for example, one or more of a modulator, a driver, an encoder, a decoder, among other electrical and optical devices. The use of wafer level solder ball jetting processes can facilitate improvements in productivity that may not be available using wirebonding or other methods of formation of electrical interconnects.

In some embodiments, the formation of electrical interconnections on embodiments of photonic integrated circuit assemblies 142 having solder ball bridges 101 may also have one or more electrical interconnections using wirebonding. A combination of wirebonds 131 and solder ball bridges 101 may be used for example in the formation of the electrical connections formed between bond pads formed on a substrate and bond pads formed on mounted devices and between bond pads formed on mounted devices and bond pads formed on other mounted devices. FIG. 24C shows a cross-sectional schematic drawing of an embodiment of a photonic integrated circuit assembly 142 of FIG. 24B wherein the electrical interconnections between first mounted device 102a and interposer substrate 210 are formed using solder ball bridge assemblies 100a and electrical interconnections between second mounted device 102b and third mounted device 102c are formed using wirebonds 131.

Wirebonds may be used in semiconductor processing to form electrical connections between horizontally-oriented bond pads 130ₕ on mounted devices, substrates, and other components used in the formation of integrated circuit assemblies. Unlike solder ball jetting that is suitable for wafer level processing, wirebond formation is typically limited to singulated die. In some embodiments, the improved electrical characteristics of embodiments of solder ball bridges 101 may be combined with wirebonding to form hybrid structures having both solder ball bridges 101 and wirebonds to form one or more of electrical and thermal interconnections in embodiments of photonic integrated circuit assemblies 142. The formation of integrated circuit assemblies using solder ball bridges 101 and wirebonds, as illustrated in the configuration shown in FIG. 24C, may be beneficial for some applications such as, for example, integrated circuit assemblies having large gaps that cannot be easily bridged with solder ball jetting, and, for example, integrated circuit assemblies having large step heights between mounted devices and between mounted devices and substrate 110.

FIGS. 24D and 24E further show embodiments of photonic integrated circuit assemblies 142 configured having first mounted device 102a, second mounted device 102b, and third mounted device 102c wherein first mounted device is a cavity-mounted device as described, for example, in conjunction with the first mounted device 102a of FIGS. 24B and 24C, wherein second mounted device 102b is a submount device that is surface-mounted to interposer substrate 210 configured as an interposer structure 210 having planar waveguide layer 105 and electrical interconnect layer 103, and wherein third mounted device 102c is mounted to the submount mounted device 102b. In the embodiment shown in FIG. 24D, electrical interconnections are formed between bond pads on the first mounted device 102a and bond pads on the interposer substrate 210 and between bond pads on the second mounted device 102b and bond pads on the third mounted device 102c using solder ball bridges 101. In the embodiment shown in FIG. 24E, electrical interconnections are formed between bond pads on the first mounted device 102a and bond pads on the interposer substrate 210 using solder ball bridges 101 and electrical connections are formed between bond pads on the second mounted device 102b and bond pads on the third mounted device 102c using wirebonds.

In the embodiment of the photonic integrated circuit 142 shown in FIG. 24D, the third mounted device 102c is configured as a surface-mounted device on the second mounted device 102b wherein the second mounted device 102b is configured as a surface-mounted submount on interposer substrate 210. Third mounted device 102c is electrically coupled to second mounted device through solder ball bridge 101b. First mounted device 102a is mounted in cavity 148 on interposer substrate 210 and coupled to second mounted device 102b through solder ball bridge 101a. Configurations having submounts such as second mounted device 102b enables the formation of subassemblies having one or more of optical and electrical devices that may be fabricated, and optionally tested, for example, independently of the interposer substrate 210 and then mounted onto the interposer substrate 210. Photonic integrated circuit assemblies 142 having one or more submounts having one or more mounted devices may enable improved productivity in the formation of these photonic integrated circuit assemblies 142.

In some embodiments having submounts, electrical interconnections between bond pads on the submount and mounted devices on the interposer substrate 210 and between mounted devices mounted on the submount may be formed using embodiments of solder ball bridges 100.

And in some embodiments having submounts, some of the electrical interconnections between bond pads on the submount and mounted devices on the interposer substrate 210 and between mounted devices mounted on the submount may be formed using embodiments of solder ball bridges 100 and some of the electrical interconnections between bond pads on the submount and mounted devices on the interposer substrate 210 and between mounted devices mounted on the submount may be formed using wirebonds 131.

Configurations of photonic integrated circuit assemblies 142, such as in the configuration shown in FIG. 24D, may be used, for example, in the formation of receiving and transmitting devices configured for telecommunications applications.

The cross-sectional schematic drawing in FIG. 24D shows an embodiment of a photonic integrated circuit assembly 142 having first solder ball bridge assembly 100a comprising the interposer substrate 210, mounted device 102a, and solder ball bridge 101a wherein mounted device 102a is mounted in cavity 148, and wherein a first terminal end of solder ball bridge 101a is coupled to a bond pad 130ₕ of mounted device 102a and a second terminal end of solder ball bridge 101a is coupled to a bond pad 130ₕ of the mounted device 102b configured as a submount.

The embodiment of the photonic integrated circuit assembly 142 in FIG. 24D further shows second solder ball bridge assembly 100b comprising mounted device 102b configured as a submount, mounted device 102c, and solder ball bridge 101b wherein mounted device 102c is a surface-mounted device mounted on the mounted device 102b configured as a submount. A submount may be one or more of a mounted device 102 and a substrate 110. For the solder ball bridge assembly 100a, the mounted device 102b configured as a submount, is a mounted device 102 in relation to the interposer substrate 210. For the solder ball bridge assembly 100b, the mounted device 102b configured as a submount, is a substrate 110 in relation to the mounted device 102c mounted on the submount.

In solder ball bridge assembly 100b of FIG. 24D, a first terminal end of solder ball bridge 101b is coupled to a bond pad 130ₕ of mounted device 102c and a second terminal end of solder ball bridge 101b is coupled to a bond pad 130ₕ of the mounted device 102b configured as a submount. In this embodiment, mounted device 102b is both a mounted device 102 mounted on interposer substrate 210, and a substrate 110 to which mounted device 102c is mounted. Solder ball bridge 101a is formed between the interposer substrate 210 and the submount mounted device 102b, and solder ball bridge 101b is formed between the mounted device 102c and the mounted device 102b configured, in the embodiment, as a substrate 110 for the mounted device 102c.

In FIG. 24D, solder ball bridge 101b forms one or more of an electrical and a thermal interconnection between the bond pad 130ₕ on the surface-mounted device 102c and bond pad 130ₕ on mounted device 102b configured as a submount in the configuration shown. FIG. 24E shows a cross-sectional schematic drawing of the embodiment of the photonic integrated circuit assembly 142 as in the assembly of FIG. 24D wherein wirebonds 131 are used to form the interconnection between the bond pad 130ₕ on the mounted device 102c and the bond pad 130ₕ on the mounted device 102b configured as a submount, and wherein a solder ball bridge 101a is used to form an interconnection between the bond pad 130ₕ on mounted device 102b configured as a submount, and the bond pad 130 on the mounted device 102a mounted in cavity 148 of interposer substrate 210. FIG. 24E shows the interposer substrate 210, the mounted device 102b configured as a submount, and mounted device 102c mounted on the mounted device 102b configured as a submount of FIG. 24D, wherein electrical interconnections are formed using wirebonds 131 between the bond pad 130ₕ on the mounted device 102c and the bond pad 130ₕ on the mounted device 102b configured as a submount.

In some embodiments, one or more of an electrical and a thermal interconnection may be formed between one or more bond pads 130 on a mounted device 102c and one or more bond pads 130 on a mounted device 102b configured as a submount. One or more of the electrical and thermal interconnections may be formed using a solder ball bridge 101 and one or more of the electrical and thermal interconnections may be formed using wirebonds. Thermal coupling using wirebonds may be inferior to thermal coupling using solder ball bridges due to the significantly larger cross-section provided by solder ball bridges 101 although the use of the wirebonds 131 to form one of more electrical connection may be advantageous in some configurations.

FIG. 24F shows a cross-sectional schematic drawing of an embodiment of a photonic integrated circuit assembly 142 configured having a first mounted device 102a on a second mounted 102b configured as a submount 102b wherein solder ball bridges 101 are used to form interconnections between the first mounted device 102a and the second mounted device 102b configured as a cavity-mounted submount and between the second mounted device 102b configured as a cavity-mounted submount and the interposer substrate 210.

FIG. 24F shows a cross-sectional schematic drawing of an embodiment of a photonic integrated circuit assembly 142 configured having a plurality of solder ball bridge assemblies 100 comprising a substrate 110, a mounted device 102, and a solder ball bridge 101.

In a first solder ball bridge assembly 100a of the photonic integrated circuit assembly 142 shown in FIG. 24F, the substrate 110 is a mounted device 102b configured as a submount 110_{subent} mounted in a cavity 148b, the mounted device 102 is mounted device 102a mounted in cavity 148a formed in the mounted device 102b configured as a submount 110_{subent}, and the solder ball bridge 101 is solder ball bridge 101a formed between a bond pad 130ₕ on the mounted device 102a and a bond pad 130ₕ formed on the mounted device 102b configured as a submount 110_{subent}. Solder ball bridge 101a is configured having three solder balls 104 in the embodiment. In the solder ball bridge assembly 100a of FIG. 24F, the substrate 110 is configured having mounted device 102b configured as a submount 110_{subent}, which further includes an optional patterned planar waveguide layer and an optional underlying electrical interconnect layer.

In the solder ball bridge assembly 100b of FIG. 24F, the substrate 110 is configured as interposer substrate 210 having planar waveguide layer 105 on electrical interconnect 103; the mounted device 102 in solder ball bridge assembly 100b is configured as mounted device 102b further configured as a submount 110_{subent}; and solder ball bridge 101 is configured as solder ball bridge 101b having a first terminal end coupled to a bond pad 130ₕ on the mounted device 102b configured as a submount 110_{subent} and a second terminal end coupled to a bond pad 130ₕ on the interposer substrate 210. The solder ball bridge assembly 100b of FIG. 24F comprises the interposer substrate 210, mounted device 102b configured as a submount 110_{subent} mounted in cavity 148b, and solder ball bridge 101b formed between a bond pad 130ₕ on the interposer substrate 210 and a bond pad 130ₕ on the mounted device 102b configured as submount 110_{subent}.

In solder ball bridge assembly 100b of FIG. 24F, a first terminal end of solder ball bridge 101b is coupled to a bond pad 130ₕ of mounted device 102b configured as submount 110_{subent} and a second terminal end of solder ball bridge 101b is coupled to a bond pad 130ₕ of the interposer substrate 210. In this embodiment, mounted device 102b is both a mounted device 102 mounted on interposer substrate 210, and a substrate 110 to which mounted device 102a is mounted. Solder ball bridge 101a is formed between mounted device 102a and the mounted device 102b configured as a submount 110_{subent}. Solder ball bridge 101b is formed between the mounted device 102b configured as a submount 110_{subent} and the substrate 110 configured as interposer substrate 210.

Summarizing, for the solder ball bridge assembly 100a of FIG. 24F, the mounted device 102a is a mounted device 102 in relation to the mounted device 102b configured as a substrate as submount 110_{subent}. Submount 110_{subent} in the solder ball bridge assembly 100a is configured as a substrate 110. And for the solder ball bridge assembly 100b, the mounted device 102b configured as a submount 110_{subent}, is a mounted device 102 in relation to the substrate 110 configured as interposer substrate 210 in the embodiment.

Configurations of photonic integrated circuit assemblies 142, as shown in FIG. 24F, may be used, for example, in the formation of all or a portion of receiving and transmitting devices configured for telecommunications applications.

In FIG. 24F, solder ball bridge 101a forms one or more of an electrical and thermal interconnection between a bond pad 130ₕ on the mounted device 102a and the mounted device 102b configured as a submount 110_{subent}, and solder ball bridge 101b forms one or more of an electrical and a thermal interconnection between a bond pad 130ₕ on the mounted device 102b and a bond pad 130ₕ on interposer substrate 210. In some embodiments of photonic integrated circuit assembly 142 as in FIG. 24F, wirebonds 131 may be used to form one or more interconnections between bond pads 130ₕ on the mounted device 102a and bond pads 130ₕ on the mounted device 102b configured as a submount 110_{subent}. And in some embodiments, wirebonds 131 may be used to form one or more interconnections between bond pads 130ₕ on mounted device 102b configured as a submount 110_{subent}, and bond pads 130ₕ on the interposer substrate 210. In some embodiments, one or more of an electrical and a thermal interconnection may be formed between one or more bond pads 130 on a mounted device 102c and one or more bond pads 130 on a mounted device 102b configured as a submount. One or more of the electrical and thermal interconnections may be formed using a solder ball bridge 101 and one or more of the electrical and thermal interconnections may be formed using wirebonds.

The example configurations in FIGS. 24A-24F show embodiments of photonic integrated circuit assemblies 142 having one or more solder ball bridge assemblies 100 wherein the solder ball bridge assemblies 100 may enable improved productivity resulting from wafer level processing, may enable improved electrical performance as a result of the improved electrical characteristics of solder ball bridges 101 in comparison to fine-wire solutions such as wirebonding, and may enable the fabrication of advanced circuit assemblies that may be limited by current production techniques. Small mounted devices, for example, may be susceptible to breakage from wirebonding that is of very limited concern with the solder ball jetting apparatus used to form lateral bridge structures at the wafer level that induce little or no stress on mounted devices.

Solder Ball Bridge Assemblies Having Substrates with Self-Aligned Alignment Aids

The alignment of optical devices in embodiments of photonic integrated circuit assemblies 142 described herein may be performed using active alignment methods and passive alignment methods. “Active alignment” methods are alignment techniques that typically require human intervention to align the optical axis of an optical device, for example, in an assembly with the optical axis of another component or optical device in an assembly. “Active alignment” is typically much simpler to implement but may require significantly more manpower than “passive alignment” methods. “Passive alignment” methods are methods that require little or no human intervention in achieving alignment of the optical axes of two or more devices in an assembly. High volume manufacturing methodologies would benefit from structures and methods that enable “passive alignment” techniques to be utilized. The adoption of “passive alignment” methodologies to enable high volume manufacturing strategies can benefit from structures and methods that facilitate the alignment of two or more devices utilized, for example, in photonic integrated circuit assemblies.

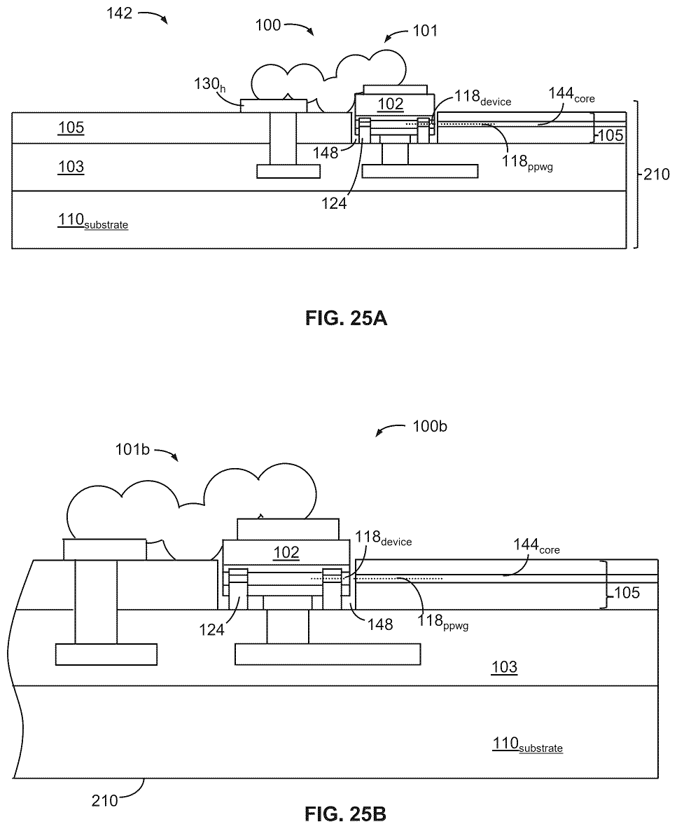

In FIGS. 25A-25B through FIGS. 33A-33B, alignment structures and the formation and use of these alignment structures in interposer substrates 210 that may be utilized in the formation of embodiments of photonic integrated circuit assemblies 142 are disclosed. These alignment structures, and the methods of formation of interposer substrates 210 having these alignment structures to facilitate “passive alignment” techniques, may be used further to facilitate high volume manufacturing methodologies. In some embodiments, self-aligned patterning techniques, as described herein, are used in the formation of alignment structures that facilitate the alignment of mounted devices 102 with patterned planar waveguide cores 144_{core} formed from the planar waveguide layer 105 of interposer substrate 210.

In embodiments of solder ball bridge assemblies 100, substrate 110 in some embodiments may include alignment aids to facilitate the alignment of optical features of mounted devices 102 with patterned planar waveguide cores, for example, and the alignment of optical features of mounted devices with other devices mounted on the substrate 110. On interposer substrates 210 used in the formation of solder ball bridge assemblies 100, self-aligned alignment aids may be formed using all or a portion of the planar waveguide layer 105 as described herein. Solder ball bridge assemblies 100 comprising interposer substrates 210 that include self-aligned alignment aids are described in the following paragraphs.

The formation of embodiments of solder ball bridge assemblies 100 comprising interposer substrate 210, mounted device 102, and solder ball bridge 101 may benefit from the inclusion of interposer substrates 210 having self-aligned features that include patterned planar waveguide cores 144_{core}, lateral alignment aids 124 formed in cavities 148, and lateral alignment aids 178 that facilitate alignment of optical fiber cables 154, and fiducials in that the inclusion of these self-aligned alignment features on the interposer substrate 210 can facilitate improved optical coupling between one or more devices mounted on the solder ball bridge assembly 100 and patterned planar waveguide cores 144_{core} in photonic integrated circuit assemblies 142 formed using all or a portion of interposer substrate 210.

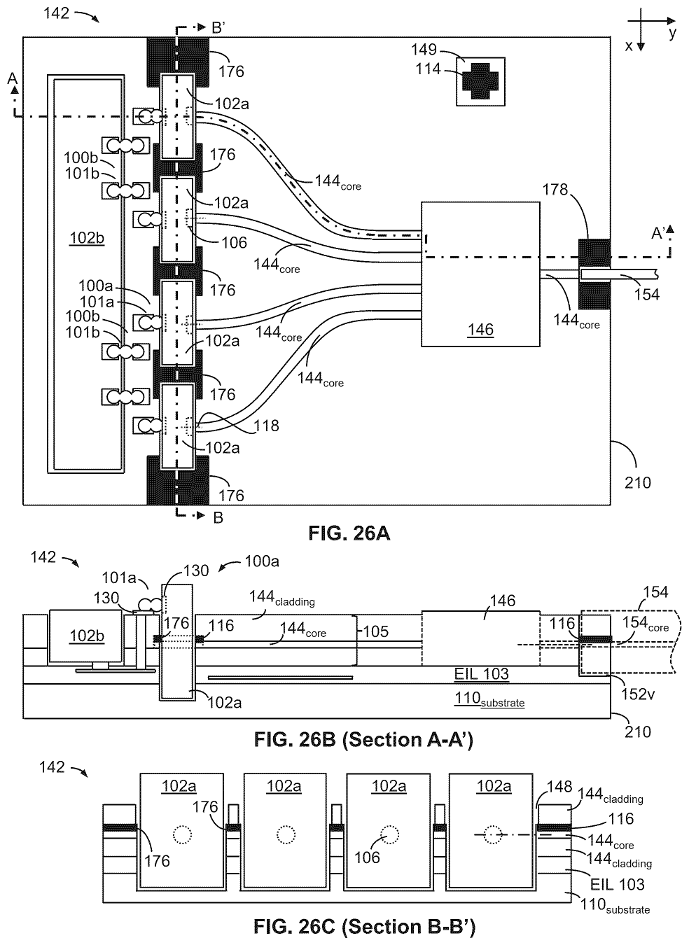

FIG. 25A shows a cross-sectional schematic drawing of an embodiment of a solder ball bridge assembly 100 comprising an interposer substrate 210, mounted device 102, and solder ball bridge 101 wherein the interposer substrate 210 comprises planar waveguide layer 105 formed on an electrical interconnect layer 103, wherein the mounted device 102 is mounted in a cavity 148 on alignment aids 124 formed from planar waveguide layer 105, and wherein the alignment aids may be used to facilitate alignment of an optical feature of the mounted device 102 with a patterned planar waveguide core 144_{core} of a patterned planar waveguide 144 that intersects a wall of the cavity 148. Alignment aids enable alignment of the optical axis 118_{device} of the mounted device 102 with the optical axis 118_{ppwg} of a patterned planar waveguide 144 that intersects the wall of the cavity 148. Solder ball bridge 101, in the embodiment, is formed between a bond pad 130ₕ on the mounted device 102 and a bond pad 130ₕ formed on the interposer substrate 210. Mounted device 102, in the embodiment, is mounted on and between the alignment pillars 124 formed in the cavity 148, Mechanical contact formed between a top surface of the alignment pillar 124 and a bottom-facing contact on mounted device 102 enables alignment of the vertical component of the optical axes 118_{device}, 118_{ppwg}. Mechanical contact formed between an inward-facing surface of the alignment pillars with an outward facing surface on the mounted device 102 enables the optical axes of the mounted device 102 to be aligned within the placement tolerance of mounted device 102 within the alignment pillars 124. Additional detail is provided herein in conjunction with the following figures, namely FIGS. 26A-26C to FIGS. 29A-29C.

A portion of the embodiment of the solder ball bridge assembly 100 of FIG. 25A is shown enlarged in FIG. 25B to better illustrate the substantial alignment of the optical axis 118_{device} of mounted device 102 with the optical axis 118_{ppwg} of a patterned planar waveguide core 144_{core} that intersects the wall of the cavity 148. Substantial alignment of the optical axes of the mounted device 102 and the patterned planar waveguide core 144_{core} that intersects the wall of the cavity 148 may facilitate improved optical coupling of optical signals transmitted between the mounted devices 102 and the patterned planar waveguide cores 144_{core}. Alignment of the optical axes 118_{device}, 118_{ppwg} is achieved with the use of alignment pillars 124 and other alignment aids formed on the interposer substrate 210 that are formed self-aligned with the patterned planar waveguide cores 144_{core} that intersect the wall of cavity 148. Alignment aids may be formed from all or a portion of planar waveguide layer 105 as further described herein.

The embodiment of the solder ball bridge assembly 100 shown in FIGS. 25A and 25B that includes self-aligned alignment aids and patterned planar waveguide cores 144_{core} may be included in photonic integrated circuit assemblies 142 and assemblies having one or more additional mounted devices 102 for which solder ball bridges 101 may be formed to provide one or more of thermal and electrical interconnectivity between a terminal end of the solder ball bridge formed on the mounted device 102 and a terminal end of the solder ball bridge formed on the interposer substrate 210.

Embodiments configured as shown in FIGS. 25A and 25B that include self-aligned alignment aids 124 formed in cavity 148 may be included in photonic integrated circuit assemblies 142 as further described herein.

### Demultiplexing Circuit Assembly

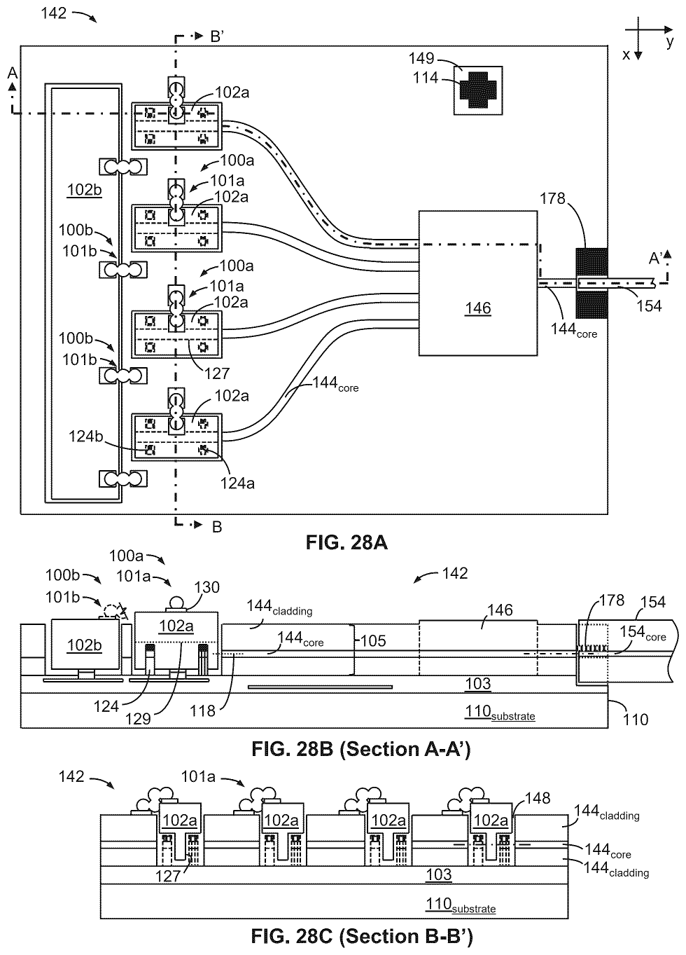

Embodiments of photonic integrated circuit assemblies 142 may be formed having specific design purposes. The types of alignment aids for a specific design of a photonic integrated circuit assembly 142 may therefore depend on the types of mounted devices 102 that require integration within the interposer substrate 210, or other substrate 110. Two specific photonic integrated circuit assemblies 142 that utilize differing types of mounted devices 102 are shown in FIGS. 26A-26C and in FIGS. 28A-28C. In a first embodiment, a photonic integrated circuit assembly 142 shown in FIGS. 26A-26C that may be all or a portion of a receiving device as might be used, for example, in a demultiplexing device in a telecommunications network. In a second embodiment, a photonic integrated circuit assembly 142 shown in FIGS. 28A-28C may be all or a portion of a transmitting device as might be used, for example in a multiplexing device in a telecommunications network. In other embodiments, all or a portion of the photonic integrated circuit assembly 142 of the demultiplexing device shown in FIGS. 26A-26C may be combined with all or a portion of the photonic integrated circuit assembly 142 of the multiplexing device shown in FIGS. 28A-28C to form all or a portion of a transceiver device comprising a demultiplexing portion and a multiplexing portion of a photonic integrated circuit assembly 142 that may be used, for example, in a telecommunications network.

The embodiment of the photonic integrated circuit assembly 142 shown in FIGS. 26A-26C and configured as one or more of a receiving circuit assembly, demultiplexing devices, receiving device, among other receiving circuits and assemblies, utilizes mounted devices 102 configured as photodiodes having vertically-oriented bond pads 130 . . . . Photonic integrated circuit assembly 142 in FIGS. 26A-26C further includes an optical fiber cable 154. In other embodiments of photonic integrated circuit assemblies 142, other devices may be used in addition to, or as alternatives to, the devices shown in FIGS. 26A-26C. The embodiment shown in FIGS. 26A-26C is shown to illustrate an example configuration of a photonic integrated circuit assembly 142 for which self-aligned alignment aids may be used to facilitate alignment of the one or more mounted devices 102 and optical fiber cables 154 in the formation of a photonic integrated circuit assembly 142 configured as a receiving device that may be used in a telecommunications network. Mounted devices 102 mounted on interposer substrate 210 having one or more alignment aids are used in the formation of solder ball bridge assemblies 100 comprising the interposer substrate 210 having the alignment aids, mounted devices 102 that may have complementary features to facilitate mounting in conjunction with the alignment aids on interposer substrate 210, and solder ball bridge 101 wherein a terminal end of the solder ball bridge 101 is formed between a bond pad formed on the interposer substrate 210 having alignment features and a mounted device 102 mounted using one or more alignment features.

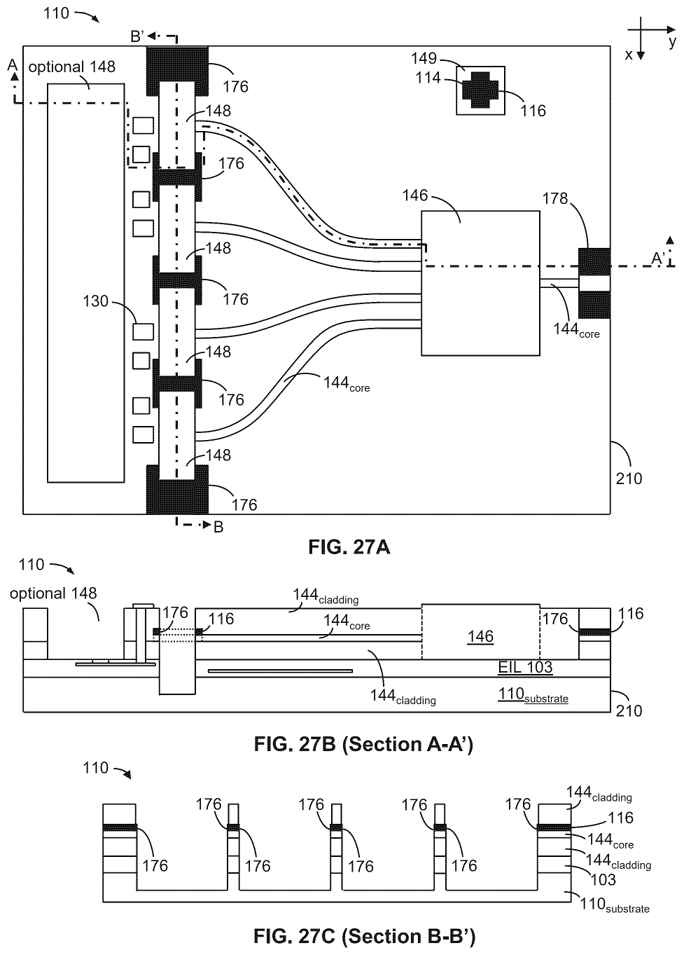

The following description for the demultiplexing circuit assembly begins at incoming optical fiber cable 154 and continues with a path through the photonic integrated circuit assembly that an incoming multiplexed signal may travel as it progresses through the circuit assembly. Photonic integrated circuit assembly 142 is shown configured as a demultiplexing circuit assembly in FIGS. 26A-26C wherein an optical fiber cable 154 is coupled to the interposer substrate 210 through a v-groove 152v formed all or in part in the substrate 110_{substrate} of the interposer substrate 210, and wherein an incoming signal to the photonic integrated circuit assembly 142 is received from the optical fiber cable 154 to a patterned planar waveguide 144 that includes a patterned planar waveguide core 144_{core} and suitable cladding layers 144_{cladding} surrounding the patterned planar waveguide cores 144_{core}. For further clarity, corresponding drawings of the interposer substrate 210 of photonic integrated circuit assembly 142 without the solder ball bridges 101a, 101b, without the mounted devices 102a, 102b, and without optical fiber cable 154 are shown in FIGS. 27A-27C. Optical signals, in the embodiment, received from an optical fiber 154 may be transferred through patterned planar waveguide 144 to optical circuit 146 that may include, for example, a demultiplexing device such as an arrayed waveguide or an echelle grating that partitions the optical signal into constituent wavelengths. In an example configuration having an arrayed waveguide, all or a portion of the arrayed waveguide may be formed using the waveguide structure that includes patterned planar waveguide cores 144_{core} and the cladding layers 144_{cladding}. Alternatively, all or a portion of an arrayed waveguide device may be fabricated elsewhere and mounted to the interposer substrate 210 to form all or a portion of optical circuit 146. Other mounted devices may also be formed from all or a portion of planar waveguide 105 and all or a portion of one or more devices may also be mounted on, or coupled to, interposer substrate 210 to form optical circuit 146.

In the embodiment of photonic integrated circuit assembly 142 configured as a demultiplexing circuit assembly, demultiplexed optical signals are transferred from, for example, the arrayed waveguide in photonic integrated circuit assembly 142, to the four patterned planar waveguides 144, and to the apertures 106 of the mounted devices 102a mounted in cavities 148. Mounted devices 102a, configured in the embodiment as photodiodes, receive optical signals from the patterned planar waveguides 144 that intersect the wall of a cavity 148 within which a device 102a is mounted, and convert the optical signals to electrical signals having, for example, a modulated current and voltage. One or more mounted devices 102b, may then, for example, be used to one or more of process, modify, transform, relay, transfer, communicate, among other forms of transferring and transforming of the optical signals. A transimpedance amplifier may be used, for example, to convert current signals to voltage signals for further processing. Other devices may also be included in, or coupled to, photonic circuit assembly 142.

The top view schematic drawing of the photonic integrated circuit assembly 142 in FIG. 26A shows an embodiment of a photonic integrated circuit assembly 142 formed on an interposer substrate 210 wherein the photonic integrated circuit assembly 142 includes multiple instances of solder ball bridge assemblies 100a comprising the interposer substrate 210, a mounted device 102a, and a solder ball bridge 101a and wherein the mounted devices 102a of the multiplicity of solder ball bridge assemblies 100a are mounted in cavities 148 having optional self-aligned alignment features 176. Optional alignment features 176 are formed self-aligned with patterned planar waveguide cores 144_{core} wherein the patterned planar waveguide cores 144_{core} intersect a wall of a cavity 148 in the embodiment.

Alignment aids 176 and other alignment aids described herein are optional alignment aids used in the formation of embodiments of photonic integrated circuit assemblies 142 having one or more solder ball bridge assemblies 100 comprising substrate 110, mounted device 102, and solder ball bridge 101, wherein the substrate 110 is configured having the optional alignment aids.

The top view schematic drawing of the interposer substrate 210, of the photonic integrated circuit assembly 142 of FIG. 26A, is shown FIG. 27A. That is, FIG. 27A shows the photonic integrated circuit assembly 142 of FIG. 26A without the plurality of solder ball bridges 101a, 101b, without the mounted devices 102a, 102b, and without the optical fiber cable 154.

FIG. 26B and FIG. 26C show Section A-A′ and Section B-B′, respectively, from the top view drawing of the photonic integrated circuit assembly 142 of FIG. 26A. Similarly, FIGS. 27B and 27C show Section A-A′ and Section B-B′, respectively, from the top view drawing of interposer substrate 210 of FIG. 26A without the mounted devices 102a, 102b.

In the top view schematic drawing of the photonic integrated circuit assembly 142 in FIG. 26A, optical fiber cable 154 is shown in an optional lateral alignment feature 178 wherein the alignment feature 178 enables lateral alignment of the optical fiber cable 154 with a patterned planar waveguide core 144_{core} of the patterned planar waveguide 144 formed from the planar waveguide layer 105. Patterned planar waveguide core 144_{core} and lateral alignment feature 178 may be formed using a same patterned mask layer 116 to ensure self-alignment between these and other self-aligned features as further described herein. In FIGS. 26A-26C and in FIGS. 27A and 27B, the self-aligned features formed using a same patterned mask layer are shown in blacked-filled features in the drawings. FIG. 27A shows substrate 210 of FIG. 26A without the mounted fiber 154 to more clearly show the lateral alignment aid 178 without the optical fiber cable 154.

Patterned planar waveguide core 144_{core} is enveloped in cladding layer 144_{cladding}. Cladding layer 144_{cladding} may be one or more layers of cladding material having a lower index of refraction than that of the core layer 144_{core}. Patterned planar waveguide core 144_{core} may be used in the formation of all or a portion of an optional photonic integrated sub-circuit 146, wherein photonic integrated sub-circuit 146 comprises all or a portion of one or more optical devices that together form all or a portion of a photonic circuit that may be formed on the interposer substrate 210. Photonic integrated sub-circuit 146 is not drawn to scale but rather is provided in FIG. 26A to illustrate that the features of embodiments, described herein, may be a portion of a more expansive photonic or electrical circuit comprising one or more circuit elements in addition to those coupled to solder ball bridge assemblies 100. Photonic integrated sub-circuit 146 may provide, for example, optical devices and circuit elements pertaining to the formation of one or more of an optical receiving device, a demultiplexing device, a demultiplexing circuit assembly, among other devices and circuit assemblies that utilize solder ball bridge assemblies 100 as used, for example, in telecommunications networks and photonic integrated circuits used for other applications. In some embodiments, photonic integrated sub-circuit 146 may provide all or a portion of one or more optical devices, circuit elements, electrical devices, photonic structures, among others that may be used in conjunction with solder ball bridge assemblies 100 formed on substrate 110.

In the configuration of the photonic integrated circuit assembly 142 shown in FIG. 26A, four patterned planar waveguide cores 144_{core} of patterned planar waveguides 144 are shown coupled to photonic integrated sub-circuit 146 at a first terminal end and that are each coupled at a second terminal end to a mounted device 102a mounted in a cavity 148. Mounted devices 102a in the embodiment, may be, for example, a receiving device such as a photodiode having a receiving orifice 106 that, in an embodiment, receives optical signals from a patterned planar waveguide core 144_{core} of a patterned planar waveguide 144. In an embodiment, a mounted device 102a that is a receiving device such as a photodiode, receives the optical signals from a patterned planar waveguide core 144_{core} and converts the optical signals to electrical signals. Solder ball bridge assemblies 100a include solder ball bridges 101a that form thermal and electrical interconnections between the bond pads 130 on the receiving devices 102a and bond pads 130 on the interposer substrate 210 and that enable coupling of the electrical signals output from the bond pads 130 on the receiving devices 102a to underlying electrically conductive layers 132 in electrical interconnect layer 103, in the embodiment, as illustrated in FIG. 26B. Electrically conductive layers 132, may be, for example, coupled to one or more devices of interposer substrate 210 and may further be coupled to one or more devices in a telecommunications network or other photonic circuits to which all or a portion of the interposer substrate 210 is coupled.

In the photonic integrated circuit assembly 142 shown, solder ball bridge assemblies 100b include solder ball bridges 101b that form thermal and electrical interconnections between bond pads 130 on mounted device 102b and bond pads 130 formed on the interposer substrate 210. Mounted device 102b may be, for example, one or more of one or more of an application specific integrated circuit (ASIC), a digital signal processor (DSP), a transimpedance amplifier (TIA), an electrical device, an electrical circuit, an optoelectrical device, and an optical device, among other devices that may be included in or otherwise coupled to photonic integrated circuit assembly 142. In the photonic integrated circuit assembly 142 shown in FIG. 26A, a single mounted device 102b is provided. In other photonic integrated circuit assemblies 142 configured having one or more solder ball bridge assemblies 100 comprising the interpose substrate 210 and a mounted device 102, a plurality of solder ball bridge assemblies 100 may be included each having a mounted device 102 and a solder ball bridge 101 coupled to an interposer substrate 210 or another mounted device 102.

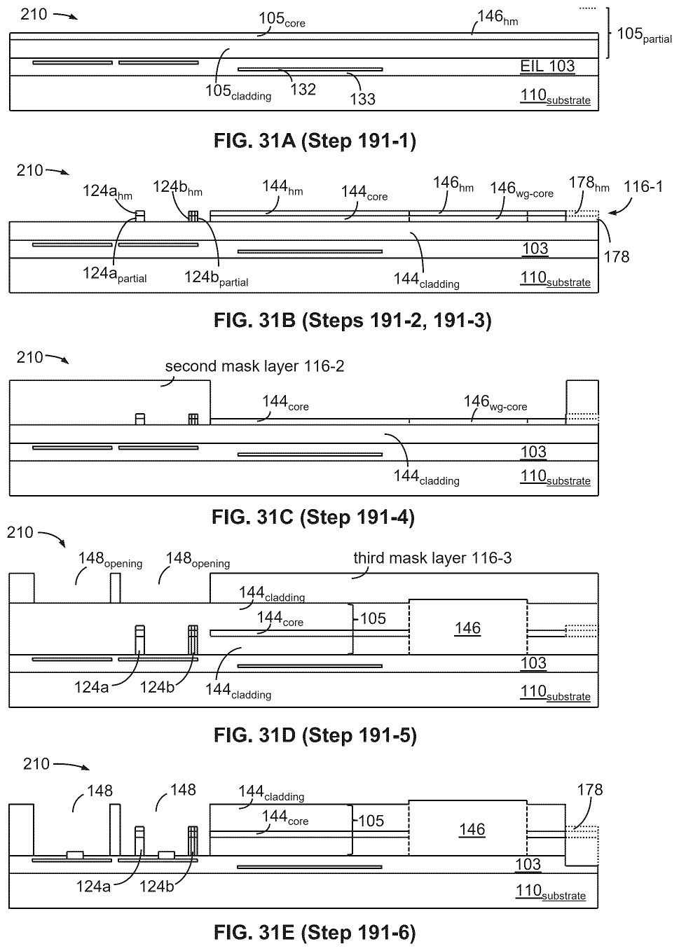

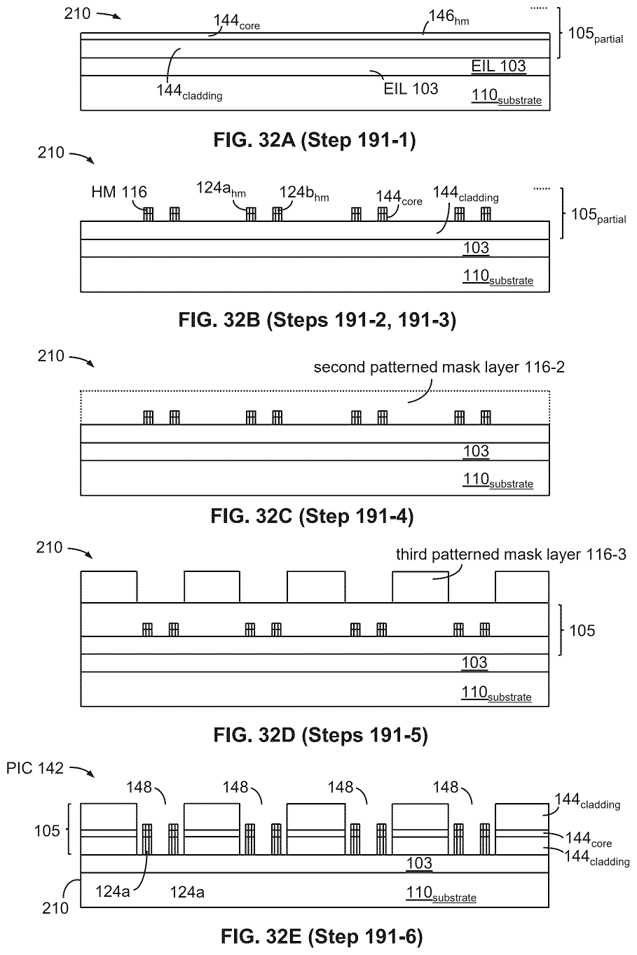

Mounted devices 102a of interposer substrate 210, of the photonic integrated circuit assembly 142 of FIGS. 26A-26C, are mounted in cavities 148 and each aligned with a planar waveguide core 144_{core} of a patterned planar waveguide 144 that intersects the wall of a cavity 148. Alignment of the optical axis 118_{device} of the mounted device 102a with the optical axis of an end facet of the patterned planar waveguide core 144_{core} that intersects the wall of the cavity 148 within which the mounted device 102a is mounted, may be enhanced with the use of lateral alignment aids 176 that may be formed in conjunction with the formation of a cavity 148. Alignment aids 176 in the photonic integrated circuit assembly 142 are lateral alignment aids that enable lateral positioning of mounted devices 102a within cavity 148 such that the optical axis of the mounted device 102a can be positioned in substantial alignment with the optical axis of a patterned planar waveguide core 144_{core} that intersects the cavity 148 upon placement of the mounted device 102a into the cavity 148. Lateral alignment of the optical axis 118_{ppwg} of the patterned planar waveguide core 144_{core} and the optical axis 118_{device} of the receiving aperture of the mounted device 102a, may be achieved with the use of a same patterned hard mask 116 to form the patterned planar waveguide cores 144_{core} and the lateral alignment aids 176 that provide lithographic resolution in the lateral positioning of these features as described further herein. (See, for example. FIGS. 31A-31E and FIGS. 32A-32E.) In addition to the lateral alignment aids 176, for alignment of mounted devices 102a, and the lateral alignment aids 178, for alignment of optical fiber cables 154, one or more fiducials 114 may also be formed having the same lithographic patterning resolution of the relative positioning of self-aligned features formed from a same patterned mask layer 116. The resolution of the lithographic patterning technology, coupled with the resolution of the etching technique, for example, or other patterning method may be used to determine the ultimate spatial resolution between the positioning of the patterned planar waveguide cores 144_{core}, the lateral alignment features 174, 178, and the fiducials 114 on interposer substrate 210. The lateral alignment features 174, 178 and the fiducials are shown with black fill to more clearly identify the features that are co-patterned using a same patterned mask layer 116 in FIGS. 26A-26C and FIGS. 27A-27C. For the embodiment shown, the four patterned waveguide cores 144_{core} are not filled in black, but are labeled “144_{core}” as is the patterned planar waveguide core 144_{core} that couples the optical fiber cable 154 and the photonic integrated sub-circuit 146 in the photonic integrated circuit assembly 142.

The cross-sectional schematic drawings in FIGS. 26B and 26C and in FIGS. 27B and 27C show additional detail of the photonic integrated sub-circuit assembly 146 of the top view schematic drawing shown in FIG. 26A and the top view schematic drawing of the interposer substrate 210 shown in FIG. 27A, respectively. FIG. 26B shows the mounted devices 102a, 102b mounted in cavities 148 wherein the cavities 148 are formed in planar waveguide layer 105. In some embodiments, cavities 148 may include all or a portion of the planar waveguide layer 105, may include all or a portion of electrical interconnect layer 103, and may include all or a portion of substrate 110_{substrate}. Lateral alignment aids 176 are formed using a patterned mask layer 116 and shown in FIGS. 26B and 27B in dotted lines to indicate out of plane projections onto the A-A′ section plane of the cross-sectional drawings. Solder ball bridge 101a is shown to form one or more of a thermal and electrical interconnection between bond pad 130 on mounted device 102a and bond pad 130 on the interposer substrate 210. In the embodiment, bond pad 130 on the interposer substrate 210 is coupled to one or more of an electrically conductive layer 132 and high thermal conductivity layer 108 in an underlying electrical interconnect layer 103 or elsewhere within, or coupled to, interposer substrate 210. In the embodiment, no alignment aids are shown in conjunction with the mounted device 102b, although in other embodiments, alignment aids may be used in conjunction with mounted devices 102b. And in yet other embodiments, alignment aids may be used with other mounted devices. The cross-section in FIG. 26B further shows a projection in dotted lines of fiber optic cable 154 mounted in, for example, a v-groove 152v. In other embodiments, optical fiber cable 154 may be mounted in a fiber attachment unit which may use lateral alignment aids 178 to facilitate alignment of the optical fiber core 154_{core} with a patterned planar waveguide core 144_{core} on the interposer substrate 210. In other embodiments, optical fiber cable 154 may be coupled to interposer substrate 210 using a grating. And in other embodiments, more than one optical fiber cable 154 may be coupled to interposer substrate 210. And in yet other embodiments, an optical fiber cable 154 may not be coupled to interposer substrate 210. FIG. 27B shows interposer substrate 210 without the solder ball bridges 101a, 101b, without the mounted devices 102a, 102b, and without the optical fiber cable 154.

FIGS. 26C and 27C show Section B-B′ from the top view drawings of FIGS. 26A and 27A, respectively. FIG. 26C shows devices 102a positioned in cavities 148 and aligned using the optional alignment aids 176. Portions of the alignment aids 176 within the cavities 148 provide a vertical surface that was formed self-aligned with other self-aligned features, such as patterned planar waveguide cores 144_{core} and alignment aid 178, for example. Co-fabricated fiducials 114 formed in a fiducial cavity 149, are also formed using the same patterned mask layer 116 and method of patterning to facilitate precise placement within the boundaries formed by the alignment aids 176. The use of self-aligned fiducials 114 in conjunction with automated pick-and-place apparatus, may provide precise placement within the corresponding cavity 148, the walls of which may be patterned using the same patterned mask layer 116 as that used in the formation of the fiducials 114, the patterned planar waveguide cores 144_{core}, and the alignment aids 176. Precise placement within the self-aligned alignment aid 176 may facilitate alignment of the aperture 106 of mounted device 102a with patterned planar waveguide cores 144_{core} formed on the interposer substrate 210. FIG. 27C shows the interposer substrate 210 of the photonic integrated sub-circuit assembly 146 of FIG. 26C without the mounted devices 102a.

### Multiplexing Circuit Assembly

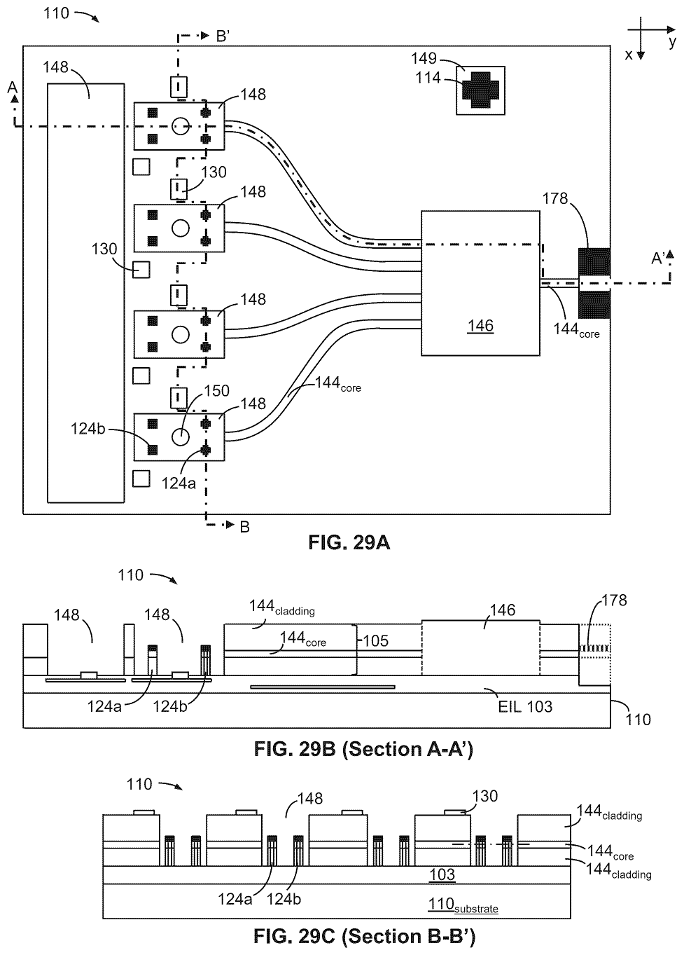

FIGS. 28A-28C and FIGS. 29A-29C further show embodiments of photonic integrated circuit assemblies 142 having alignment aids that are alignment pillars 124 formed in cavities 148 that may facilitate vertical alignment of mounted devices 102 in addition to the lateral alignment of mounted devices 102 mounted in cavities 148 as in FIGS. 26A-26C. The embodiments of the photonic integrated circuit assemblies 142 described in FIGS. 28A-28C also include lateral alignment aids, shown for example, in conjunction with lateral alignment aids 178 used in the alignment of optical fiber cable 154.

The embodiment of the photonic integrated circuit assembly 142 shown in FIGS. 28A-28C and configured as one or more of a transmitting circuit assembly, multiplexing device, emitting device, among other transmitting circuits and assemblies, utilizes mounted devices 102 configured as lasers. Assembly 142 in FIGS. 28A-28C further includes an optical fiber cable 154. In other embodiments of photonic integrated circuit assemblies 142, other devices may be used in addition to, or as alternatives to, the devices shown in FIGS. 28A-28C. The embodiment of the photonic integrated circuit 142 in FIGS. 28A-28C shows an example configuration of photonic integrated circuit assembly 142 for which self-aligned alignment aids formed within cavities 148 on an interposer substrate 210 may be used to facilitate alignment of the one or more mounted devices 102 and optical fiber cables 154 to patterned planar waveguides in the photonic integrated circuit assembly 142 configured as a transmitting device that may be used, for example, in a telecommunications network.

Mounted devices 102, mounted on interposer substrate 210 having one or more alignment aids, are used in the formation of solder ball bridge assemblies 100 comprising the interposer substrate 210 having the alignment aids, mounted devices 102 that may have complementary features to facilitate mounting in conjunction with the alignment aids on interposer substrate 210, and solder ball bridge 101 wherein a terminal end of the solder ball bridge 101 is formed between a bond pad formed on the interposer substrate 210 having alignment features and a mounted device 102 mounted using one or more alignment features.

The following description for the multiplexing circuit assembly begins at electrical signal input to the mounted device 102b and continues through the mounted devices 102 and to the patterned planar waveguides 144 and devices of the photonic integrated circuit sub-assembly 146 to the outgoing optical fiber 154. Electrical signals, input to a driver or other circuit element mounted on substrate 210, for example, provide electrical input to lasers, which either through direct modulation or through modulation of a secondary device such as electro-absorption modulation of optical signals from a continuous wave emitting laser, continue through the circuit assembly as a plurality of optical signals in the patterned planar waveguides 144 that intersect a wall of a cavity 148 within which the lasers are mounted, are combined in the optical multiplexing device of photonic integrated sub-circuit 146, and output through a common waveguide to the optical fiber cable in this example configuration.

The photonic integrated circuit assembly 142 of FIGS. 28A-28C, and corresponding drawings of the interposer substrate 210 of photonic integrated circuit assembly 142 shown in FIGS. 29A-29C, is shown configured as a transmitting circuit wherein four mounted devices 102a mounted in cavities 148 in interposer substrate 210 are configured as transmitting devices, such as lasers. The lasers in cavity 148 receive an electrical signal from all or a portion of a mounted device 102b, which may be configured as one or more drivers, for example, and may further include, for example, a DSP. Electrical signals, received by the mounted devices 102a through one or more of electrical contacts formed at the base of the cavity and electrical contacts on the top surfaces of the lasers, in the configuration shown, result in the emission of optical signals from the lasers to an end facet formed in the wall of cavities 148. The modulated optical signals from the lasers travel through the patterned planar waveguide cores 144_{core} to the photonic integrated sub-circuit 146 within which the discrete signals from the four patterned planar waveguides may be multiplexed or otherwise combined into a single patterned planar waveguide core 144_{core} for coupling to an optical fiber cable 154 mounted, for example, in a v-groove formed in the substrate or a fiber attachment unit mounted to the interposer substrate 210. In other embodiments, photonic integrated circuit assembly 142 configured as a multiplexing device, may have more than four lasers coupled to the photonic integrated sub-circuit 146 configured as a multiplexing device. And in yet other embodiments, photonic integrated circuit assembly 142 configured as a multiplexing device, may have fewer than four lasers coupled to the photonic integrated sub-circuit 146 configured as a multiplexing device.

In the embodiment, the outgoing signal is provided to the optical fiber cable 154 through waveguides that include a patterned planar waveguide core 144_{core} and suitable cladding layers 144_{cladding} surrounding the patterned planar waveguide cores 144_{core}. Optical signals, in the embodiment, transferred from optical circuit 146 that may include, for example, a multiplexing device such as an arrayed waveguide. In an example configuration having an arrayed waveguide, all or a portion of the arrayed waveguide may be formed using the waveguide structure that includes patterned planar waveguide cores 144_{core} and the cladding layers 144_{cladding}. Alternatively, all or a portion of an arrayed waveguide device may be fabricated elsewhere and mounted to the interposer substrate 210.

In the embodiment of photonic integrated circuit assembly 142 configured as a transmitting circuit, multiplexed optical signals are transferred from, for example, the arrayed waveguide in photonic integrated sub-circuit 146, to a patterned planar waveguide core 144_{core} to the mounted optical fiber cable 154.

The top view schematic drawing of the photonic integrated circuit assembly 142 in FIG. 28A shows an embodiment of a photonic integrated circuit assembly 142 formed on an interposer substrate 210 wherein the photonic integrated circuit assembly 142 includes multiple instances of solder ball bridge assemblies 100a comprising the interposer substrate 210, a mounted device 102a, and a solder ball bridge 101a and wherein the mounted devices 102a of the multiplicity of solder ball bridge assemblies 100a are mounted in cavities 148 having self-aligned alignment features that are alignment pillars 124. Alignment pillars 124 are formed self-aligned with patterned planar waveguide cores 144_{core} that intersect a wall of a cavity 148 in the embodiment. Devices 102a in the embodiment, are mounted on alignment pillars 124 in cavities 148 wherein the mounting of the mounted devices 102a on the alignment pillars 124 facilitates alignment of the devices with the patterned planar waveguide cores 144_{core} in the photonic integrated circuit assembly 142 as further described in the following paragraphs.

The top view schematic drawing of the interposer substrate 210, of the photonic integrated circuit assembly 142 of FIG. 28A, is shown FIG. 29A. That is, FIG. 29A shows the photonic integrated circuit assembly 142 of FIG. 28A without the solder ball bridges 101a, 101b, without the mounted devices 102a, 102b, and without the optical fiber cable 154.

FIG. 28B and FIG. 28C show Section A-A′ and Section B-B′, respectively, from the top view drawing of the photonic integrated circuit assembly 142 of FIG. 28A. Similarly, FIGS. 29B and 29C show Section A-A′ and Section B-B′, respectively, from the top view drawing of interposer substrate 210 of FIG. 28A without the mounted devices 102a, 102b.

In the top view schematic drawing of the photonic integrated circuit assembly 142 in FIG. 28A, optical fiber cable 154 is shown in an optional lateral alignment feature 178 wherein the alignment feature 178 enables lateral alignment of the optical fiber cable 154 with a patterned planar waveguide core 144_{core} formed from the planar waveguide layer 105. Patterned planar waveguide core 144_{core} and lateral alignment feature 178 may be formed using a same patterned mask layer 116 as further described herein (See, for example, FIGS. 29A-29C.) In another embodiments, a fiber attachment unit may be used in conjunction with the lateral alignment feature 178 to mount optical fiber cable 154 to interposer substrate 210 and in such an embodiment, lateral alignment features 178 may be used to laterally align the fiber attachment unit containing one or more optical fibers. FIG. 29A shows interposer substrate 210 of FIG. 28A without the mounted fiber 154. Patterned planar waveguide core 144_{core} is enveloped in cladding layer 144_{cladding}. Cladding layer 144_{cladding} may be one or more layers of cladding material having a lower index of refraction than that of the core layer 144_{core}. Patterned planar waveguide core 144_{core} may be used in the formation of all or a portion of an optional photonic integrated sub-circuit 146, wherein photonic integrated sub-circuit 146 comprises all or a portion of one or more optical devices that together form all or a portion of a photonic circuit that may be formed on the interposer substrate 210. Photonic integrated sub-circuit 146 is not drawn to scale but rather is provided in FIG. 28A to illustrate that the features of embodiments, described herein, may be a portion of a more expansive photonic or electrical circuit comprising one or more circuit elements in addition to those coupled to solder ball bridge assemblies 100. Photonic integrated sub-circuit 146 may provide, for example, optical devices and circuit elements pertaining to the formation of an optical transmitting device and device assembly as used in telecommunications networks. In some embodiments, photonic integrated sub-circuit 146 may provide all or a portion of one or more optical devices, circuit elements, electrical devices, photonic structures, among others that may be used in conjunction with solder ball bridge assemblies 100 formed on interposer substrate 210.

In the configuration of the photonic integrated circuit assembly 142 shown in FIG. 28A, four patterned planar waveguide cores 144_{core} are shown coupled to photonic integrated sub-circuit 146 at a first terminal end and that are each coupled to a mounted device 102a mounted in a cavity 148. In other embodiments, more than four patterned planar waveguide cores 144_{core} may be present. And in yet other embodiments, interposer substrate 210 may be configured having less than four patterned planar waveguide cores 144_{core}. Mounted devices 102a in the embodiment, may be configured, for example, as transmitting devices, such as, for example, lasers. Mounted devices 102a, configured as lasers, may be, for example, one or more of direct modulated lasers (DMLs) and electro-absorption modulated lasers (EMLs). In an embodiment, a mounted device 102a, mounted in a cavity 148 in all or a portion of the planar waveguide layer on interposer substrate 210, receives an electrical signal through one or more electrical contacts at the one or more of the top and bottom contacts of the mounted devices, in the configuration shown, and emits an optical signal that is coupled to a patterned planar waveguide core 144_{core} that intersects the wall of the cavity 148 within which a mounted device 102a is positioned.

In the embodiment of the photonic integrated circuit assembly 142 shown in FIGS. 28A-28C, solder ball bridge assemblies 100a include solder ball bridges 101a that form thermal and electrical interconnections between the bond pads 130 on the transmitting devices 102a and bond pads 130 on the interposer substrate 210 that enable coupling of the electrical signals output from underlying electrically conductive layers 132, for example, in electrical interconnect layer 103 to the bond pads 130 on the transmitting devices 102a as illustrated in FIG. 28B. Conductive layers 132, may be, for example, coupled to one or more devices of interposer substrate 210 and may further be coupled to one or more devices in a telecommunications network or other photonic circuits to which all or a portion of the interposer substrate 210 is coupled.

In the photonic integrated circuit assembly 142 shown, solder ball bridge assemblies 100b include solder ball bridges 101b that form thermal and electrical interconnections between bond pads 130 on mounted device 102b and bond pads 130 formed on the interposer substrate 210. Mounted device 102b may be, for example, one or more of an application specific integrated circuit (ASIC), a digital signal processor (DSP), a modulator, a drive, an electrical device, an electrical circuit, an optoelectrical device, and an optical device, among other devices that may be included in or otherwise coupled to photonic integrated circuit assembly 142. In the photonic integrated circuit assembly 142 shown in FIG. 28A, a single mounted device 102b is provided. In other photonic integrated circuit assemblies 142 configured having one or more solder ball bridge assemblies 100 comprising the interposer substrate 210 and mounted device 102, a plurality of solder ball bridge assemblies 100 may be included each having a mounted device 102 and a solder ball bridge 101 coupled to interposer substrate 210 or another mounted device 102.

Mounted devices 102a in the photonic integrated circuit assembly 142 are coupled to the interposer substrate 210 using alignment pillars 124a, 124b that facilitate lateral alignment and vertical alignment in the embodiment. Alignment pillars 124a, 124b, formed in cavities 148 in the photonic integrated circuit assembly 142, facilitate lateral alignment by enabling lateral positioning of mounted devices 102a within cavity 148 such that the optical axis of the mounted device 102a can be positioned in substantial alignment with the optical axis of a patterned planar waveguide core 144_{core} that intersects the cavity 148 upon placement of the mounted device 102a into the cavity 148. Vertical alignment surface 127 of mounted device 102a, in the embodiment shown, forms a contact with the surfaces of the alignment pillars 124a, 124b that face proximal surfaces on the mounted devices to limit the range of positions of mounted device 102a to within a range of lateral positions between the two like alignment pillars such as the alignment pillars 124b, for example. Lateral alignment of the optical axes of a mounted device 102a with the optical axis of a patterned planar waveguide core 144_{core} is achieved with the use of a common patterned mask layer 116 to form the patterned planar waveguide cores 144_{core} and the alignment pillars 124a, 124b that provide lithographic resolution in the lateral positioning of these features as described further herein, for example, in FIGS. 31A-31E and FIGS. 32A-32E. In addition to the facilitation of the lateral alignment of the optical axis 118_{device} of the mounted devices 102a with the optical axis 118_{ppwg} of the patterned planar waveguide cores 144_{core} at the intersection of the patterned planar waveguide cores 144_{core} with the wall of a cavity 148, alignment pillars 124a, 124b further facilitate the vertical alignment of the optical axis of a mounted device 102a with the optical axis 118_{ppwg} of the intersecting facet of the patterned planar waveguide cores 144_{core}. Vertical alignment is achieved with the mounting of a mounted device 102a onto a top surface of one or more of the alignment pillars 124a, 124b such that a bottom surface 129 of the mounted device 102a contacts a top surface of the one or more alignment pillars 124a, 124b.

Furthermore, in addition to the lateral alignment pillars 124a, 124b and the lateral alignment aids 178 that provide physical boundaries for alignment of an optical fiber cable 154, one or more fiducials 114 may also be formed having the same self-aligned spatial positioning resolution. In some embodiments, fiducials may be separate from other alignment pillars. In yet other embodiments, fiducials may be formed from one or more alignment pillars 124. In the embodiment shown in FIGS. 28A and 29A, a fiducial 114 is shown that is formed separately from the alignment pillars 124a, 124b and other alignment features that facilitate lateral alignment of a mounted device or optical fiber cable, for example, on interposer substrate 210. Fiducials are also provided, in the embodiment of FIGS. 28A and 29A with the alignment pillars 124b in cavities 148.

The resolution of the lithographic patterning technology, coupled with the resolution of the etching technique, for example, or other patterning method may be used to determine the ultimate spatial resolution between the positioning of the patterned planar waveguide cores 144_{core}, the alignment pillars 124a, 124b, lateral alignment features 178, and the fiducials 114 on the interposer substrate 210. The lateral alignment features 178 and the fiducials 114 are shown with black fill to more clearly identify the features that are co-patterned using a same patterned mask layer 116 in FIGS. 28A-28C and FIGS. 29A-29C. In FIG. 28A, the alignment pillars 124a, 124b are shown hatched to indicate that they are projections from below the mounted devices 102a. The underlying alignment pillars 124a, 124b in cavities 148 are shown with black fill in FIG. 29A with the co-patterned alignment features 178 and fiducials 114. For the embodiment shown, the four patterned waveguide cores 144_{core} are identified as is the patterned planar waveguide core 144_{core} connecting the optical fiber cable 154 and the photonic integrated sub-circuit 146.

The cross-sectional schematic drawings in FIGS. 28B and 28C and in FIGS. 29B and 29C show additional detail of the photonic integrated sub-circuit assembly 146 of the top view schematic drawing shown in FIG. 28A and the top view schematic drawing of the interposer substrate 210 shown in FIG. 29A, respectively. FIG. 28B shows the mounted devices 102a, 102b mounted in cavities 148 wherein the cavities 148 are formed in planar waveguide layer 105. Alignment pillars 124a, 124b formed in some cavities 148, facilitate lateral and vertical alignment of mounted devices 102a. Lateral alignment is facilitated, for example, using vertical surfaces 127 of the mounted devices 102a to limit the position of the mounted device 102a after placement to the spacing provided between like alignment pillars 124a and like alignment pillars 124b in the embodiment shown. In other embodiments, other vertical surfaces on the alignment pillars and on the mounted devices 102a may be used to limit the range of positions that may be occupied by the mounted devices 102a in a cavity 148. Furthermore, vertical alignment is facilitated, for example, using horizontal surface 129 of mounted device 102a that is placed, in the embodiment, such that horizontal surface 129 contacts a top surface of one or more of the alignment pillars 124a, 124b to enable alignment of the optical axis of the mounted device 102a with the optical axis of a patterned planar waveguide core 144_{core} that intersects the wall of the cavity 148 within which mounted device 102a is positioned.

Alignment pillars 124a, 124 and lateral alignment aids 178 are formed using patterned mask layer 116 and suitable patterning processing, such as a dry etch patterning process, for example, and are shown in FIGS. 28B and 29B in dotted lines to indicate out of plane projections onto the A-A′ section plane of the cross-sectional drawings.

Solder ball bridge 101a in FIGS. 28B and 28C is shown to form one or more of a thermal and electrical interconnection between bond pad 130 on mounted device 102a and bond pad 130 on interposer substrate 210. In some embodiments, bond pad 130 on the interposer substrate 210 may be coupled to one or more of an electrically and thermally conductive layer 132 in an underlying electrical interconnect layer 103. In some embodiments, bond pad 130 may be coupled to one or more of a thermal heat sink and an electrically conductive layer formed on the interposer substrate 210. In some embodiments, one or more bond pad 130 coupled to a solder ball bridge 101 may be coupled to a heat sink configured as described herein. In some embodiments, one or more bond pads coupled to a solder ball bridge 101 may be coupled to an electrically conductive layer formed in the electrical interconnect layer 103 or above or within the planar waveguide layer 105.

In the embodiment, no lateral or vertical alignment aids are shown in conjunction with the mounted device 102b, although in other embodiments, alignment aids may be used in conjunction with mounted devices 102b. And in yet other embodiments, alignment aids may be used with other mounted devices. The cross-section in FIG. 28B further shows a projection in dotted lines of fiber optic cable 154 mounted in, for example, a v-groove 150v. In other embodiments, optical fiber cable 154 may be mounted in a fiber attachment unit which may use lateral alignment aids 178 to facilitate alignment of the optical fiber core 154_{core} with a patterned planar waveguide core 144_{core} on the interposer substrate 210. In other embodiments, optical fiber cable 154 may be coupled to interposer substrate 210 using a grating. And in other embodiments, more than one optical fiber cable 154 may be coupled to interposer substrate 210. And in yet other embodiments, an optical fiber cable 154 may not be coupled to the interposer substrate 210. FIG. 29B shows the interposer substrate 210 without the solder ball bridges 101a, 101b, without the mounted devices 102a, 102b, and without the optical fiber cable 154.

FIGS. 28C and 29C show Section B-B′ from the top view drawings of FIGS. 28A and 29A, respectively. FIG. 28C shows devices 102a in aligned positions on alignment pillars 124a, 124b in cavities 148 such that the optical axes of the mounted devices 102a are aligned with a terminal facet of a patterned planar waveguide core 144_{core} that intersects the wall of a cavity 148. Portions of the alignment pillars 124a, 124b within the cavities 148 provide a vertical surface that was formed having lateral positioning resolution equivalent to that of the lithography technology used, and that when coupled to the co-fabricated fiducials 114 formed using the same hard mask patterning method facilitate precise placement within the alignment pillars 124a, 124b. Placement of a mounted device within the alignment pillars 124a, 124b using fiducials in conjunction with automated or non-automated pick-and-place apparatus, may facilitate precise positioning within a corresponding cavity 148. Vertical positioning of a mounted device is facilitated by the top surface of one or more alignment pillars 124a, 124b in contact with a bottom surface 129 of the mounted device 102a.

Precise placement within the alignment pillars 124a, 124b enables the alignment of the optical axis 118_{device} of mounted devices 102a with the facets of the patterned planar waveguide cores 144_{core} formed on the interposer substrate 210 that intersect the walls of cavities 148. FIG. 29C shows the interposer substrate 210 of the photonic integrated sub-circuit assembly 146 of FIG. 28C without the mounted devices 102a.

The photonic integrated circuit assemblies 142 shown in FIGS. 26A-26C and FIGS. 28A-28C, the unpopulated interposer substrates 210 of which are shown in FIGS. 27A-27C and FIGS. 29A-29C, respectively, illustrate embodiments of a photonic integrated sub-circuit assemblies 146 having one or more solder ball bridge assemblies 100 coupled to an interposer substrate 210 having alignment aids that facilitate placement and positioning of mounted devices 102a onto the interposer substrate 210 wherein the solder ball bridge assemblies 100 comprise the interposer substrate 210 having alignment aids, the mounted device 102a, and solder ball bridge 101a and wherein the interposer substrate 210 further includes mounted device 102b.

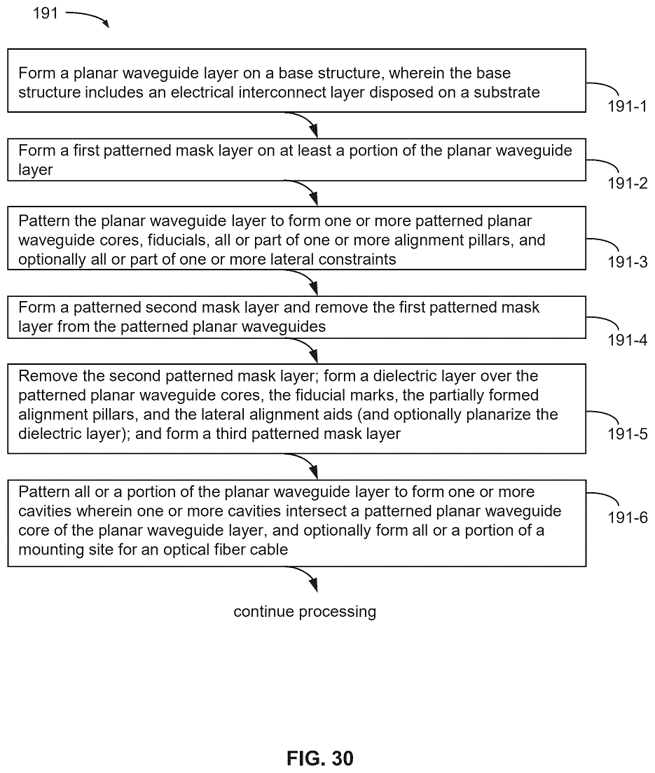

The mounted devices 102a in the photonic integrated circuit assemblies 142 are positioned fully or in part to the interposer substrate 210 using one or more of alignment aids 176, 124a, 124b respectively. Alignment aids 176 in the photonic integrated circuit assembly 142 are lateral alignment aids that enable lateral positioning of mounted devices 102a within cavity 148 such that the optical axis of the mounted device 102a can be positioned in substantial alignment with the optical axis of a patterned planar waveguide core 144_{core} that intersects the cavity 148 upon placement of the mounted device 102a into the cavity 148. Lateral alignment of the optical axes of the patterned planar waveguide core 144_{core} and the optical axis of the receiving aperture, for example, of the receiving device, is achieved with the use of a common patterned mask layer to form the patterned planar waveguide cores 144_{core} and the lateral alignment aids 176 that provide lithographic resolution in the lateral positioning of these features as described further herein, for example, in FIGS. 31A-31E and FIGS. 32A-32E, in conjunction with method 191 shown in FIG. 30. In addition to the mechanical lateral alignment aids 176 provided with the patterning of the waveguide core layer 144_{core}, one or more fiducials 114 may be formed that are also formed having relative positioning within the resolution of the lithographic technology used to form the alignment aids that include the fiducials 114, the patterned planar waveguide cores 144_{core}, the lateral alignment aids 176, 178, and the alignment aids 124. These features are more clearly shown in blackened and hatched features in FIGS. 27A-27C and FIGS. 29A-29C.

Alignment aids 124a, 124b, to which the mounted device 102a is coupled in the configuration of the photonic integrated circuit assembly 142 shown in FIGS. 28A-28C are alignment pillars that enable both lateral alignment and vertical alignment of mounted devices 102. In some embodiments, alignment aids that provide lateral alignment and other alignment aids that provide vertical alignment of the mounted devices 102 mounted in cavities 148 may be formed and utilized in embodiments that provide lateral and vertical alignment. That is, a plurality of alignment pillars may be provided in cavity 148 that provide one or more of lateral and vertical alignment of mounted devices 102 within which the mounted devices 102 are mounted. In some embodiments, cavities 148 having alignment pillars that provide vertical alignment may be included. In other embodiments, cavities 148 having alignment pillars that provide lateral alignment may be included. And in some embodiments, lateral alignment in the x-direction shown in the reference coordinates in FIGS. 28A and 29A may be provided using the alignment aids formed in cavity 148 and alignment in y-direction shown in the reference coordinates in FIGS. 28A and 29A may be provided using all or a portion of a wall of cavity 148 within which a mounted device is mounted.

FIG. 30 shows a flowchart for a method of forming an interposer substrate 210 having self-aligned lateral alignment features formed from the planar waveguide layer 105 of interposer substrate 210. In FIG. 30, the flowchart shows a method 191 of forming a portion of an interposer substrate 210 wherein one or more of one or more of self-aligned patterned planar waveguides 144, alignment pillars 124, lateral alignment aids 176, fiber alignment features 178, and fiducials 114 are formed all or in part from a planar waveguide layer 105 of the interposer structure 210 using a same patterned mask layer 116, and wherein one or more of these alignment features are formed in the interposer substrate 210 to which a terminal end of a solder ball bridge 101 is formed, and one or more of these alignment features are used to facilitate the alignment of a mounted device 102 onto the interposer substrate 210.

The steps in the flowchart of FIG. 30 are shown in conjunction with the cross-sectional schematic drawings in FIGS. 31A-31E and the cross-sectional schematic drawings in FIGS. 32A-32E.

FIGS. 31A-31E show cross-sectional schematic drawings of some steps in the formation of an interposer structure having self-aligned alignment features. Cross sections are taken through the location of Section A-A′ of FIG. 29A. FIGS. 31A-31E show the progression in the formation of the interposer substrate 210 along Section A-A′ of FIG. 29A. FIG. 29A shows the interposer substrate 210 for the embodiment of photonic integrated circuit assembly 142 of FIG. 28A for which a same patterned mask layer 116 is used to form self-aligned features in the interposer substrate 210.

FIGS. 32A-32E show cross-sectional schematic drawings of some steps in the formation of an interposer structure having self-aligned alignment features. Cross sections are taken through the location of Section B-B′ of FIG. 29A. FIGS. 32A-32E show the progression in the formation of the interposer substrate 210 along Section B-B′ of FIG. 29A.

Step 191-1 of method 191 is a forming step in which all or a portion of a planar waveguide layer 105, up to and including the planar waveguide core layer 144_{core} is formed on a base structure, wherein the base structure comprises electrical interconnect layer 103 on a substrate 110_{substrate}. The partially formed interposer substrate 210 in the embodiment formed in Step 191-1 is shown in FIGS. 31A and 32A. The electrical interconnect layer 103 is formed in some embodiments on a substrate 110_{substrate} such as silicon. Other semiconducting substrates such as indium phosphide, gallium arsenide, or other semiconductors can also be used. In other embodiments, a ceramic or insulating substrate can be used. In yet other embodiments, a metal substrate can be used. And in yet other embodiments, a combination of one or more semiconductor layers, insulating layers, and metal layers are used to form a substrate 110_{substrate} upon which the optional electrical interconnect layer 103 and a first portion of the planar waveguide layer 105ₚₐᵣₜᵢₐₗ are formed. In some embodiments, the electrical interconnect layer 103 is not in direct contact with the substrate but rather an intervening layer is present. Similarly, the planar waveguide layer 105, in some embodiments, is not in direct contact with the underlying electrical interconnect layer 103 but rather an intervening layer or layers may be present. Substrate 110_{substrate} forms a portion of interposer substrate 210 in some embodiments of solder ball bridge assemblies 100. In some embodiments, all or a portion of a top cladding layer may be formed on the core layer 105_{core} in Step 191-1 and processed in combination with the core layer 105_{core} in Steps 191-2 to 191-6 described herein.

Step 191-2 of the method 191 is a forming step in which a first patterned mask layer 116-1 is formed on the planar waveguide core layer 105_{core} of planar waveguide layer 105 and Step 191-3 of the method 191 is a patterning step in which all or a portion of the planar waveguide core layer 105_{core} of the planar waveguide layer 105 is patterned to form one or more of one or more patterned planar waveguide cores 144_{core}, one or more fiducials 114, all or a portion of one or more alignment pillars 124a, 124b, and all or a portion of one or more lateral alignment features 176, 178. FIGS. 31B and 32B show the embodiment of interposer substrate 210 from FIGS. 31A and 32A after Steps 191-2 and 191-3 of method 191.

The planar waveguide core layer 105_{core} of the planar waveguide layer 105 is the core layer through which optical signals primarily propagate upon formation of patterned planar waveguide cores 144_{core} from the waveguide layer 105. First patterned mask layer 116-1 includes patterns for the formation of patterned planar waveguide cores 144_{core} and all or a portion of alignment aids formed from one or more of the first patterned mask layer 116-1 and the planar waveguide layer 105. In the cross-sectional drawing shown in FIG. 31B, patterned portions of the first patterned mask layer 116-1 include patterned planar waveguide mask layer portion 144ₕₘ for the formation of patterned planar waveguide cores 144_{core}, patterned mask layer portion 124ₐₕₘ, 124_{bhm} for the formation of alignment pillars 124a, 124b, and patterned mask layer portion 178ₕₘ for the formation of optical fiber lateral alignment aids 178. Other portions of first patterned mask layer 116-1 for other alignment aids may also be provided such as, for example, a patterned mask layer portion 176ₕₘ (not shown) for the formation of lateral alignment aids 176. A portion of first patterned mask layer 116-1, for example, may also be provided for the fiducial 114 as shown in the top view of FIG. 29A but not shown in the Section A-A′ cross-sectional drawing of FIG. 31B and not shown in the Section B-B′ cross-sectional drawing of FIG. 32B. And although not an alignment aid, a patterned mask layer portion 146ₕₘ of first patterned mask layer 116-1 is provided and shown for a device 146 formed from all or a portion of planar waveguide layer 105. Lateral alignment aids 176 are shown, for example in the embodiment of FIG. 27A.

In some embodiments, first patterned mask layer 116-1 is formed directly on the planar waveguide core layer 105_{core} of the planar waveguide layer 105. In other embodiments, first patterned mask layer 116-1 may be formed on a thin layer of cladding on the planar waveguide core layer 105_{core}. And in yet other embodiments, the first patterned mask layer 116-1 may be formed on a thin sacrificial layer that is removed in a subsequent processing step prior to the patterning of the planar waveguide core layer 105_{core}.

Portions of the first patterned mask layer 116-1 may be used in some embodiments of interposer substrate 210 to form all or a portion of optical devices for embodiments in which the optical devices are formed wholly or in part from the planar waveguide layer 105, such as arrayed waveguides, for example. For such embodiments, patterned portions 146ₕₘ of first patterned mask layer 116-1 may be included. Optical devices may be waveguides, gratings, lens, or any device that can be formed from at least a portion of the planar waveguide layer and may also be self-aligned with other features formed from first patterned mask layer 116-1. Alternatively, in other embodiments of interposer substrate 210, optical devices may be mounted devices, and not fabricated directly from the planar waveguide layer 105 but added at a later step in the process of forming a photonic integrated circuit assembly 142 on the interposer substrate 210. Optical devices may be formed from one or more of a portion of a device formed from the planar waveguide layer and one or more of a portion of a mounted device.

In some embodiments of the interposer substrate 210, the planar waveguide layer 105 is formed of one or more layers of silicon dioxide, silicon nitride, silicon oxynitride, silicon, or other dielectric material suitable for propagating optical signals. In some embodiments, planar waveguide layer 105 is formed from one or more polymer layers. In yet other embodiments, one or more dielectric layers is combined with one or more polymer layers to form a waveguide structure. Suitable waveguides generally include a high refractive index signal-carrying core layer encapsulated in a low refractive index cladding layer. Top and bottom cladding layers need not have the same index of refraction and need not be the same material. Air or other gas may be used in some embodiments, for all or a portion of a top cladding layer in some embodiments.

In embodiments described herein, the core layer 144_{core} of patterned planar waveguides 144 formed from planar waveguide layer 105 is formed from a layer of silicon. In other embodiments described herein, the core layer 144_{core} of patterned planar waveguides 144 formed from planar waveguide layer 105 is formed from a layer of silicon oxynitride. In yet other embodiments described herein, the core layer 144_{core} of patterned planar waveguides 144 formed from planar waveguide layer 105 is formed from a layer of silicon nitride. And in yet other embodiments described herein, the core layer 144_{core} of patterned planar waveguides 144 formed from planar waveguide layer 105 is formed from a polymer layer. In some embodiments, core layer 144_{core} of patterned planar waveguides 144 formed from planar waveguide layer 105, the core layer may be formed from one or more of layers.

In embodiments, cladding layer 144_{cladding} may be formed from one or more of silicon oxide, silicon dioxide, silicon oxynitride, and silicon nitride, for example, among other materials having a lower index of refraction than the core layer 144_{core}.

In embodiments, aluminum or an alloy of aluminum may be used, for example, to form the first patterned mask layer 116-1. First patterned mask layer 116-1, in an embodiment, is a patterned aluminum hard mask layer. Aluminum and alloys of aluminum are known to exhibit a high resistance to dry etching in fluorinated etching chemistries used, for example, in plasma etching apparatus in semiconductor fabrication, and thus the dimensions of the hard mask can be substantially maintained during the dry etch patterning of the planar waveguide layers 105 formed from one or more of dielectric and polymer layers reactive to fluorinated etch chemistries. A hard mask, as used herein, refers to a non-polymer-based masking layer with a material that has a high resistance to the plasma etch, dry etch, or wet etch, used in the patterning of surrounding materials. Aluminum, for example, is an example of a hard mask material in embodiments. Aluminum is a metal layer that has a high resistance to fluorine containing etch chemistries. In other embodiments, other hard masks are used that also exhibit high resistance to the etch chemistry such as Au, Ag, Ni, and Pt. In other embodiments, hard masks layers such as Ti, TiOₓ, Ta, TaOₓ, aluminum oxide, silicon nitride, silicon carbide, or a combination of one or more of these materials may be used. In some embodiments, oxygen or other oxygen-containing gas is added to the etching chemistry to increase the resistance of a hard mask to the etch chemistry. In yet other embodiments, diluents are added to the fluorinated gas chemistry such as one or more of argon, helium, nitrogen, and oxygen, among others to increase the resistance of the hard mask to the fluorinated etch chemistry. In embodiments, the masking layer typically has a slow rate of removal in comparison to the rate of removal of the planar waveguide layer. Methods for selective etching of silicon dioxide, silicon nitride, silicon oxynitride, silicon, and other waveguide materials are well understood by those skilled in the art of semiconductor processing, as are methods of increasing the etch resistance of aluminum hard mask layers and other hard mask layers using fluorinated etch chemistries. In some embodiments, polymer-based masks may be used in place of, or in addition, to hard mask layers, although the etch resistance of polymer-based masks may be significantly less than that of a hard mask for the patterning of thick waveguide layers.

To pattern the planar waveguides from dielectric layers using dry etch processes, fluorinated etch chemistries in which one or more commonly utilized gases such as CF₄, CHF₃, C₂F₈, SF₆, among others, are used. Etching of polymers may be performed using etching chemistries that include these and other fluorinated chemistries and may include oxygen and oxygen-containing gases, for example.

Step 191-3 of method 191 is a patterning step in which all or a portion of the planar waveguide layer 105 that includes the planar waveguide core layer 105_{core} is etched or otherwise patterned to form the patterned planar waveguide cores 144_{core} of the patterned planar waveguides 144, alignment pillars 124a, 124b, lateral alignment aids 176, optical fiber cable alignment features 178, fiducials 114, and devices 146 formed from all or a portion of the waveguide layer 105.

The cross-sectional schematic drawing of the interposer substrate 210 along Section A-A′ after Step 191-3 of method 191 shown in FIG. 31B illustrates the formation of the patterned features from a same patterned mask layer to ensure that the features are self-aligned, in that within the resolution of the patterning of the lithographic patterning technique employed, the positioning of the features formed from all or a portion of the waveguide core layer relative to other features formed from all or a portion of the waveguide core layer using a the same first patterned mask layer 116-1 can be formed within sub-micron positional resolution (for typical lithographic patterning techniques).

Step 191-4 of method 191 is a forming and removing step in which a second patterned mask layer 116-2 is formed on the structure to facilitate selective removal of the remaining first patterned mask layer 116-1 on portions of the patterned planar waveguide cores 144_{core} as shown in FIG. 31C along Section A-A″. Removal of the first patterned mask layer 116-1 from the patterned planar waveguide cores 144_{core} and patterned device cores 146wg core formed from at least a portion of the core layer 105_{core} of the planar waveguide layer 105 facilitates improved propagation of optical signals through patterned planar waveguides 144 formed from the planar waveguide layer 105 in comparison to waveguides in which a metal layer such as may be used in the formation of first patterned mask layer 116-1 is present. Removal of the first patterned mask layer 116-1 may be facilitated, for example, with the use of a photoresist mask layer in the formation of the second patterned mask layer 116-2, for example, in which a layer of photoresist is patterned to enable removal of the photoresist layer covering the portions 144ₕₘ of the first patterned mask layer 116-1 that remains on the patterned planar waveguide cores 144_{core} as shown in FIG. 31C. Openings in the second patterned mask layer 116-2 shown in FIG. 31C enables removal of the exposed first patterned mask layer 116-1 while providing protective covering on the portions of the first patterned mask layer 116-1 for which the layer is to remain. The first patterned mask layer 116 may not be removed, for example, on some alignment aids. In other embodiments, a hard mask layer may be used for second patterned mask layer 116-2. In embodiments in which a photoresist layer is used in Step 191-4, the mask layer 116-2 is patterned to expose the underlying patterned hard mask layer portion 144ₕₘ on the patterned waveguide cores 144_{core} and to protect the patterned first mask layer portions over, for example, the fiducial marks 114, over the alignment pillars 124, over lateral alignment aids 176, optical fiber cable alignment features 178, and over any other features for which the first patterned mask layer 116-1 is left in place after the removing portion of the forming and removing Step 191-4 of method 191. Exposure of the portions of the first patterned mask layer 116-1 over the waveguide cores enables selective removal of this first patterned mask layer 116-1 in Step 191-4 of method 191 from the patterned planar waveguide cores 144_{core} using an etching or other patterning or removal step without the removal of the first patterned mask layer 116-1 from the fiducial marks 114, the alignment pillars 124, lateral alignment features 176, fiber alignment features 178, and other alignment features for which the first patterned mask layer may remain in place.

FIG. 31C shows the embodiment of interposer substrate 210 of FIG. 31B after formation of the second patterned mask layer 116-2 and removal of the first patterned mask layer 116-1 from at least the patterned planar waveguide cores 144_{core} and after subsequent removal of the mask layer 116-2 used in embodiments to protect the remaining hard mask portions. Removal of the hard mask portions 144ₕₘ from the patterned planar waveguide cores 144_{core} is achieved in some embodiments using a wet etch process that selectively removes metal or other hard mask material, for embodiments formed used a metal hard mask, with little or no removal of the underlaying planar waveguide layer 105. Metal etchants, such as those used for the removal of an aluminum hard mask, for example, and that have little or no effect on silicon-based dielectrics, for example, are well known in the art of semiconductor processing. In other embodiments, a dry etch process may be used. A benefit of a wet etch process to remove the hard mask portions 144ₕₘ from the patterned planar waveguide cores 144_{core} includes a high preferential selectivity for etching of metals that may be used in the formation of a hard mask with minimal removal of the underlying planar waveguide cores 144_{core} for embodiments in which dielectric materials are used in the formation the waveguide layer 105. FIG. 32C shows the cross section from Section B-B′, which shows the added second patterned mask layer 116-2 in comparison to FIG. 32B.

Step 191-5 of method 191 is a removing and forming step in which the second patterned mask layer 116-2 is removed, a cladding layer 144_{cladding} is formed on the patterned planar waveguide cores 144, and a third patterned mask layer 116-3 is formed on the cladding layer 144_{cladding}. FIGS. 31D and 32D show the embodiment of interposer substrate 210 of FIGS. 31D and 32D, respectively, after Step 191-5 of method 191.

Removal of the second patterned mask layer 116-2 may be performed, for example, in an oxygen plasma for methods 191 in which a patterned photoresist layer is used in the formation of second patterned mask layer 116-2. Other suitable removal processes may be used for the removal of second patterned mask layers 116-2 formed from other materials. For the formation of the cladding layer 144_{cladding}, a dielectric layer is formed, for example, over the patterned planar waveguide cores 144_{core}, over the partially formed alignment pillars 124, the lateral alignment aids 176, and the optical fiber alignment features 178, as shown in the embodiment in FIGS. 31D and 32D for the interposer substrate 210 along Section A-A′ and Section B-B′, respectively. Cladding layer 144_{cladding} may also be optionally formed on fiducials 114 in Step 191-5.

Cladding layer 144_{cladding} may be one or more layers of silicon dioxide, silicon nitride, or silicon oxynitride, for example, and may include one or more of a planar waveguide cladding layer, a buffer layer, a spacer layer, and a passivation layer, among others. In some embodiments, cladding layer 144_{cladding} includes a planarization layer and a planarization step is used to planarize the cladding layer 144_{cladding}. Other dielectrics or combinations of dielectrics and other materials may be used in the formation of cladding layer 144_{cladding}.

Subsequent to the formation of the cladding layer 144_{cladding}, third patterned mask layer 116-3 is formed on the cladding layer 144_{cladding}. The third patterned mask layer 116-3, in embodiments, provides openings for the formation of one or more cavities 148 in the planar waveguide layer 105 wherein the planar waveguide layer 105 comprises the cladding layers 105_{cladding}, 144_{cladding} and the core layers 105_{core}, 144_{core}. As used herein, the labels “144”, “144_{core}”, and “144_{cladding}” refer to the patterned planar waveguides, the patterned planar waveguide cores, and the cladding of the patterned planar waveguides, respectively, formed from all or a portion of the planar waveguide layer 105. As used herein, the labels “105”, “105_{core}”, and “105_{cladding}” refer to the more general planar waveguide layer, the core layer of the planar waveguide layer, and the cladding layer of the planar waveguide layer, respectively, without specific reference to a patterned planar waveguide 144 formed from the planar waveguide layer 105. The patterned planar waveguides 144 comprising the patterned planar waveguide cores 144_{core} and the patterned planar waveguide cladding 144_{cladding}, for example, are formed from the planar waveguide layer 105 wherein the planar waveguide layer 105 further includes alignment features formed from the planar waveguide layer 105 that are not a portion of a patterned planar waveguide 144.

Step 191-6 of method 191 is a patterning and optional forming step in which all or a portion of the planar waveguide layer 105 is patterned to form one or more cavities in the planar waveguide layer 105 that intersect a patterned planar waveguide core 144_{core}. Optionally, all or a portion of one or more mounting site for one or more optical fiber cables may also be formed in Step 191-6 of method 191.

FIGS. 31E and 32E show the embodiment of interposer substrate 210 of FIGS. 31D and 32D, respectively, after Step 191-6 that includes the patterning of the planar waveguide layer 105 to form cavities 148. Cavities 148 include alignment pillars 124a, 124b that have remaining first patterned mask layer 116-1 wherein the first patterned mask layer 116-1 exhibits a high resistance to the patterning process used in the removal of the planar waveguide material to form the cavities 148. Some cavities may be formed having alignment pillars such as alignment pillars 124a, 124b shown in FIGS. 31E and 32E and other cavities may be formed that do not have alignment pillars.

Additional processing may be used for the formation of additional features on interposer substrate 210 following Step 191-6. Upon full or partial completion of the interposer substrate 210, cavities 148 in the interposer substrate 210 may be populated with devices 102a, 102b to further complete solder ball bridge assemblies 100 comprising the interposer substrate 210, mounted device 102, and solder ball bridge 101 connecting, for example, the interposer substrate 210 and each mounted device 102.

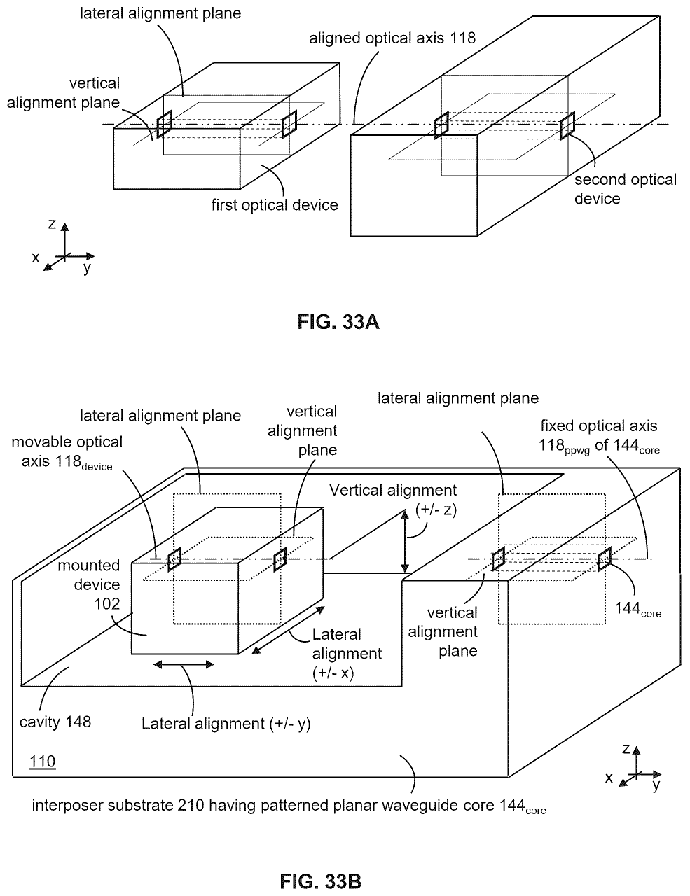

FIG. 33A show a schematic perspective drawing that illustrate aspects of the alignment of the optical axes of two optical devices. To bring the two devices into optical alignment, the optical axis of a first optical device may be positioned in substantial alignment with the optical axis of a second optical device. Optical axes of the two devices may be, for example, features of the devices that enable coupling of optical signals between the two devices. To form an aligned structure comprising a first optical device and a second optical device, both the lateral alignment plane and the vertical alignment plane of the first optical device and the lateral alignment plane and the vertical alignment plane of the second optical device are brought into substantial alignment to enable coupling of optical signals between the two optical devices as illustrated in FIG. 33A. The aligned optical axis 118 for the aligned structure is noted in FIG. 33A.

FIG. 33B shows a schematic perspective drawing that illustrate aspects of the alignment of the optical axis 118_{device} of a movable mounted device 102 in a cavity 148 of interposer substrate 210 with the optical axis 118_{ppwg} of fixed patterned planar waveguide core 144_{core} that intersects the wall of the cavity 148 within which the mounted device 102 is mounted. In the perspective drawing in FIG. 33B, the optical axis 118_{device} of a mounted device 102 is shown in cavity 148 positioned in substantial alignment with the optical axis 118_{ppwg} of a fixed patterned planar waveguide core 144_{core} formed on interposer substrate 210. Positioning processes may be used to bring the lateral and vertical alignment planes into alignment of the mounted device 102 with the lateral and vertical alignment planes of the fixed patterned planar waveguide core 144_{core} formed, for example, from the planar waveguide layer 105 of the interposer substrate 210. The aligned optical axis 118 of FIG. 33A is shown in FIG. 33B to be comprised of the optical axis 118_{device} of the mounted device 102 and the optical axis 118_{ppwg} of the patterned planar waveguide core 144_{core} formed from the planar waveguide layer 105 of the interposer substrate 210. To form an aligned structure comprising a mounted device 102 and a patterned planar waveguide core 144_{core}, both the lateral alignment plane and the vertical alignment plane of the mounted device 102 are brought into substantial alignment with the lateral and the vertical alignment planes of the fixed patterned planar waveguide core 144_{core} of the interposer substrate 210 as illustrated in FIG. 33B. Substantial alignment may be such that an acceptable percentage of an optical signal originating in one or more of the mounted device 102 and the patterned planar waveguide core 144_{core} is transferred between the mounted device 102 and the patterned planar waveguide core 144_{core}. An acceptable signal transfer between a mounted device 102 and a patterned planar waveguide core, in embodiments, may be greater than 90%. In other embodiments, an acceptable signal transfer may be greater than 50%. And in yet other embodiments, an acceptable signal transfer may be any signal greater than 1%. The acceptability of the level of signal transfer between a mounted device 102 and a patterned planar waveguide core 144_{core} may depend, for example, on the use of the optical signal after transfer. In some embodiments, high levels of signal transfer between mounted devices 102 and patterned planar waveguide cores 144_{core} are necessary for efficient operation of the photonic integrated circuit assembly 142 and in other embodiment, a very small detectable signal may be satisfactory as in on-off power detection, for example.

FIG. 33B shows “vertical alignment (+/−z)” to illustrate vertical alignment in a vertical or “z” direction. Alignment in the vertical direction in embodiments may be determined by the height of an alignment pillar 124, for example, and the contact surface (e.g. 129) on a bottom surface of a mountable device. FIG. 33B also shows “lateral alignment (+/−x)” to illustrate a lateral alignment in a lateral or “x” direction. Alignment in the “x” direction in embodiments may be determined to be limited by the spacing between two or more alignment pillars 124 or lateral alignment aids 176, 178, for example, and a vertical (or near vertical) surface (e.g. 127) of a mountable device. FIG. 33B also shows “lateral alignment (+/−y)” to illustrate a lateral alignment in a lateral or “y” direction. Alignment in the “y” direction in embodiments may be determined to be limited by the spacing between two or more alignment pillars 124 or lateral alignment aids 176, 178, for example, and a vertical (or near vertical) surface (e.g. 127) of a mountable device. Alternatively, alignment in the lateral “+y” direction may be determined by a surface of a mounted device coming into contact with the wall of a cavity 148.

In other embodiments, the optical axes of two mounted devices 102 may be brought into alignment in a solder ball bridge assembly 100. In such embodiments, both mounted devices 102 may be movable in the effort to bring the optical axes of each mounted device into alignment to form aligned optical axis 118.

### Post Deposition Treatment of Solder Ball Bridge Assemblies

Solder balls 104 in embodiments of solder ball bridges 101 and solder ball bridge assemblies 100 that include solder ball bridges 101 may be subjected to heating before, during, and after deposition from, for example, a laser configured with or in accordance with the solder ball jetting apparatus 164. Heating during the deposition can facilitate improved bonding of solder material in the solder balls with solder-wettable surfaces on the substrate 110 and mounted devices 102 by providing solder in a molten or semi-molten state. Heating during deposition can also facilitate improved lateral solder ball bridge formation by enabling improved anchoring of deposited solder balls 104 to previously deposited solder balls 104 in a solder ball bridge 101. Heating sources other than a laser provided with the solder ball jetting apparatus 164 may also be used, such as under substrate laser sources, and radiant heating and convective heating sources. In some embodiments, for example, solder ball bridges 101 may be heated after deposition to enhance the bonding to one or more bond pads 130ᵥ to redistribute the solder on the bond pad, to fill spacing between bond pads, to provide more favorably shaped solder interconnections, among other potential benefits.

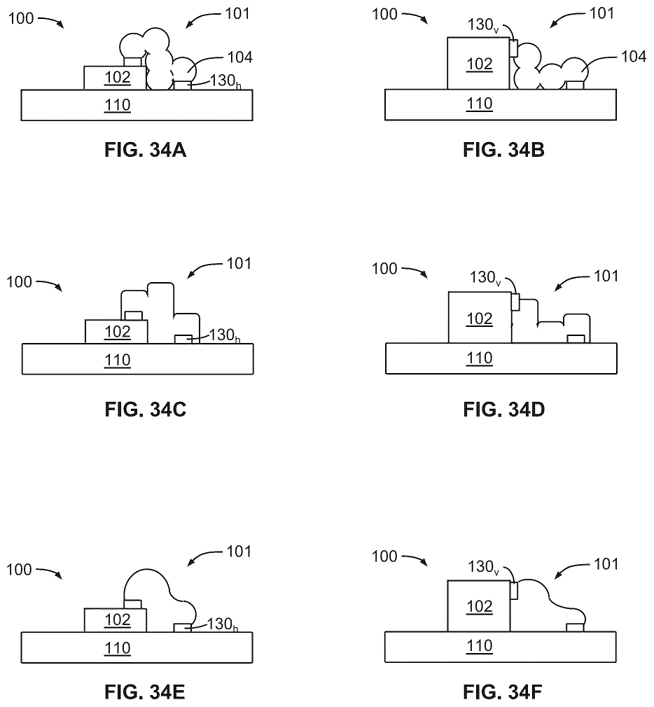

FIGS. 34A-34F show schematic cross-sectional drawings of embodiments of solder ball bridge assemblies 100 having a substrate 110, a mounted device 102, and a solder ball bridge 101 that illustrate the potential benefits of post deposition heating on a number of configurations of solder ball bridge 101.

FIGS. 34A and 34B show schematic cross-sectional drawings of embodiments of solder ball bridge assemblies 100 having solder balls 104 deposited with little or no deformation of the solder balls 104. FIG. 34A shows an embodiment of a solder ball bridge assembly 100 that includes a solder ball bridge 101 having a first terminal end coupled to a horizontally-oriented bond pad 130ₕ on substrate 110 and a second terminal end coupled to a horizontally-oriented bond pad 130ₕ formed on mounted device 102. FIG. 34B shows an embodiment of a solder ball bridge assembly 100 that includes a solder ball bridge 101 having a first terminal end coupled to a horizontally-oriented bond pad 130ₕ on substrate 110 and a second terminal end coupled to a vertically-oriented bond pad 130ᵥ formed on mounted device 102. The spheroidal shapes of the deposited solder balls 104 are shown to be substantially maintained in the embodiments shown in FIGS. 34A and 34B as may be the case with minimal heating of the solder balls during the jetting process in solder ball jetting apparatus 164.

In general, the ultimate shape that a grouping of deposited solder balls 104 may take after heating results from a number of factors that include, for example, surface tension in the molten state, the viscosity of molten solder, the bonding of the molten solder to solder-wettable surfaces, and the lack of bonding of the molten solder to non-solder-wettable surfaces, among other factors. Deformation of the solder balls may result, for example, from excess heating during the deposition process.

FIGS. 34C and 34D show schematic cross-sectional drawings of embodiments of solder ball bridge assemblies 100 having solder balls 104 subjected to heating, for example, during the deposition of the solder balls. Heating of the solder balls 104 during the deposition can lead to deformation of the solder balls 104 resulting in a more columnar pillar of solder material as shown in the embodiments of FIGS. 34C and 34D for embodiments having the horizontally-oriented bond pads 130ₕ on the mounted device 102 of FIG. 34A and the vertically-oriented bond pads 130ᵥ on the mounted device 102 of FIG. 34B, respectively.

The formation of columnar solder structures may require an initial close spacing of stacks of one or more solder balls 104 that may further require additional heating to form or improve the lateral melding between the stacks of solder balls 104. Solder balls stacks formed too closely, may result in periodic overlap between the stacks that can lead to non-uniform stacking of the solder balls 104. Conversely, solder ball stacks formed too far apart may result in increased difficulty in the anchoring of the solder balls in a growing stack to previously deposited adjacent stacks. Anchoring of solder balls 104 with previously deposited solder balls is necessary for forming lateral solder ball bridges 101 across non-solder-wettable surfaces between bond pads 130 that may be present, for example, on the substrate 110 and on the mounted devices 102 in embodiments of solder ball bridge assemblies 100.

Moderate post deposition heating of the solder ball bridge structures shown in FIGS. 34A and 34B may also result in the formation of the columnar solder structures 104 as shown in FIGS. 34C and 34D in some embodiments.

FIG. 34E and FIG. 34F show schematic cross-sectional drawings of the embodiments of solder ball bridge assemblies 100 from FIGS. 34A and 34B after exposure of the solder balls 104 in solder ball bridges 110 to heating, for example, after the deposition of the solder balls. Exposure of the solder ball structures shown in FIGS. 34A and 34B to temperatures at near the melting point of the solder used in the solder ball bridge assemblies 100 can soften or melt the solder in the solder ball bridge 101 and can lead to deformation of the solder balls 104, redistribution of the solder from the solder balls, gap filling, among other potential benefits. In FIG. 34E, the solder from the as-deposited solder balls 104 from FIG. 34A are shown to be redistributed between the bond pads leading to a more uniformly distributed cross-section of solder between the bond pads 130ₕ. The redistributed solder is also shown to provide improved coverage of the solder-wettable surfaces of the bond pads. Although some moderation in heating of the as-deposited solder balls in the solder ball bridge 101 shown in FIG. 34E, excessive heating may be problematic in that the solder in contact with the non-solder-wettable surfaces between the bond pads may be prone to thinning at increased temperatures as the viscosity of the solder is reduced, the surface tension of the solder that acts to bind the solder is reduced, and the resistance to movement of the solder on the non-solder-wettable surface is reduced. In FIG. 34F, the solder from the as-deposited solder balls 104 from FIG. 34B are shown to be redistributed between the bond pads leading to a more uniformly distributed cross-section of solder between the bond pads. The redistributed solder is also shown to provide improved coverage of the solder-wettable surfaces of the bond pads.

In the embodiments of FIGS. 34E and 34F, schematic cross-sectional drawings of embodiments of solder ball bridge assemblies 100 having solder balls 104 subjected, for example, to heating after deposition is shown for which the heating leads to redistribution of the material in the solder balls. Prior to the post-deposition treatment of FIGS. 34E and 34F, the solder ball bridges 101 may resemble, for example, the solder ball bridge 101 shown in FIGS. 34A-34D. Post-deposition heating of the solder balls 104 can lead to significant deformation and re-shaping of the solder material as shown in the reshaped solder ball bridges schematically illustrated in the embodiments of FIGS. 34E and 34F for which the solder ball spheres of the embodiments of FIGS. 34A and 34B, or the columnar pillars of the embodiments of FIGS. 34C and 34D may no longer be distinguishable. Post-deposition heating may provide such benefits as, for example, one or more of a densification of the solder in the solder ball bridge 101, removal of voids in the solder ball bridge 101, providing a more consistent cross-section throughout the solder ball bridge 101, removal of impurities from the interior of the solder ball bridge 101, and improved step coverage of the solder ball bridge 101 on the surfaces in contact with the solder ball bridge 101 between the mounted device 102 and the substrate 110, among other benefits. Post-deposition heating may also provide such benefits as, for example, as improved adhesion with a surface of one or more of the substrate 110 and the mounted device 102, improved alloying between the solder ball bridge and one or more of the substrate 110 and the mounted device 102, improved alloying between the solder ball bridge and one or more bond pads, contact pads, electrical interconnects, heat sinks, or other contact surface formed on one of more of the substrate 110 and the mounted device 102, among other benefits.

FIGS. 34A-34F show examples of the effects of various amounts of heating applied in the solder ball deposition process in the formation of embodiments of solder ball bridge 101. These examples are not intended to limit the scope of the use of heating before, during, or after deposition, but rather to illustrate the benefits of heating on the resulting solder ball bridges 101 subjected to heating. The application of heating either through the use of an integrated laser during the deposition of the solder balls 104, for example, or other means remains within the scope of the formation of solder ball bridge 101 in embodiments of solder ball bridge assemblies 100 described herein. Heating may be applied to one or more of a solder ball 104, a solder ball bridge 101, mounted device 102, and the substrate 110 and the ambient within which the solder ball 104, solder ball bridge 101, mounted device 102, and the substrate 110 reside. Heating may be provided in the form of providing energy from a laser positioned one or more of above and below the substrate 110. Heating may be provided by a heating source to the substrate 110 as in, for example, the form of a heated susceptor upon which the wafer 110_{wafer} is disposed during the deposition of the solder balls 104 to form the solder ball bridges 101. Heating may be provided to the ambient within which the solder balls are formed. Heating may also be provided to the ambient within which the solder balls reside after formation as in a post-deposition annealing process in a heated chamber. Other sources of heating may also be used.

Thin dielectric layers may be formed over as-deposited solder ball bridges 101 in some embodiments to contain the as-deposited solder within the deposited layer and restrict the movement of solder during post deposition processing in which the solder in one or more of the deposited solder balls 104 within, or coupled to, the solder ball bridge 101 is subjected to conditions that enable re-distribution. Redistribution of the solder contained within a dielectric layer may facilitate, for example, one or more of improved bridging between bond pads formed on the mounted device 102 and the substrate and the removal of gaps in the solder ball bridge, among other potential benefits from redistribution of the solder in the solder ball bridge 101. A deposited layer may be one or more of a silicon oxide layer, a silicon nitride layer, a silicon oxynitride layer, and a polymer layer, among other material layers. The deposited layer is preferably a dielectric layer. In some embodiments, the deposited layer may be a passivation layer. In some embodiments, the deposited layer may be a planarization layer. In some embodiments, the deposited layer formed over the as-deposited solder ball bridges 101 may remain in place after redistribution of the solder in the solder ball bridge 101 and in some embodiments, the deposited layer may be removed after redistribution of the solder in the solder ball bridge 101. In some embodiments, the deposited layer may be formed after a first thermal treatment having one or more processing steps to facilitate partial redistribution of all or a portion of a solder ball bridge 101.

### Small Diameter Solder Balls in Solder Ball Bridge Formation

The diameters of solder balls 104 available in commercially available solder ball jetting systems can range from approximately 20 micrometers to approximately 2 millimeters. Such a range of diameters can enable a wide range of sizes and configurations of solder ball bridges 101 formed in embodiments of solder ball bridge assemblies 100. Some example configurations of solder ball bridges 101 in embodiments of solder ball bridge assemblies 100 have been shown throughout herein including in FIGS. 5A-18H and elsewhere.

In some embodiments of solder ball bridge assembly 100 comprising substrate 110, mounted device 102, and solder ball bridge 101, the solder ball bridge 101 is comprised of solder balls 104 having small diameters in relation to the length of the solder ball bridges 101 formed by the solder balls 104. Stated in another way, a large number of solder balls are required to form one or more of the length and width of the solder ball bridge 101. In some embodiments configured having a small diameter solder ball 104 relative to the length of the solder ball bridge 101, more than ten solder balls are required to provide the required length of the solder ball bridge 101. In yet other embodiments, more than five solder balls 104 are required to provide the required length of the solder ball bridge 101.

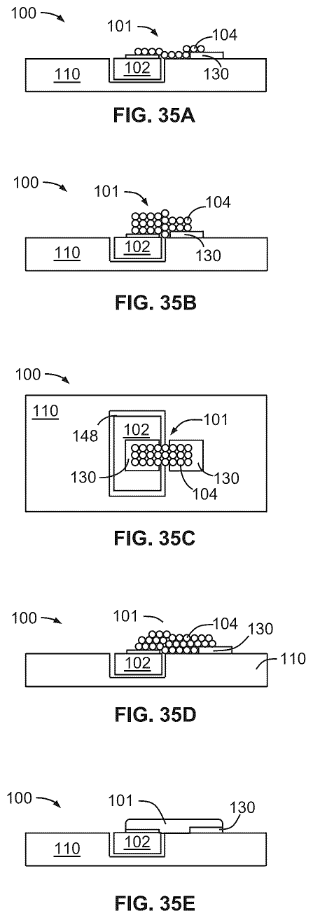

FIGS. 35A-35B and 35D-35F show cross-sectional schematic drawings, and FIG. 35C shows a top view drawing, of embodiments of solder ball bridge assemblies 100 comprising substrate 110, mounted device 102, and solder ball bridge 101 wherein the solder ball bridges 101 are formed from a large quantity of small diameter solder balls 104.

In the embodiments shown in FIGS. 35A-35E, mounted device 102 is shown mounted in cavity 148 and a bond pad 130 is provided on substrate 110 in proximity to cavity 148. A bond pad 130 is also shown on mounted device 102 that may facilitate adhesion of the solder ball bridge 101 to the mounted device in the embodiments illustrated in FIGS. 35A-35E.

FIG. 35A shows a cross-sectional drawing of an embodiment of a solder ball bridge assembly 100 comprising substrate 110, mounted device 102, and solder ball bridge 101 wherein the solder ball bridge 101 is formed from numerous small diameter solder balls 104 for which the solder ball diameter is significantly less than the length of the solder ball bridge 101. Eleven solder balls 104 are shown in the embodiment in FIG. 35A. Particular attention is given to embodiments having small solder ball diameters as configurations of embodiments having small diameter solder balls 104 may enable improved distribution of solder on and between the bond pad 130 on the mounted device 102 and the bond pad 130ᵥ for example, or other solder-wettable contact location on the substrate 110.

The solder ball bridge 101 in FIG. 35A is configured having a single layer of solder balls 104. In embodiments, the single layer may comprise one or more lateral rows of solder balls in the single layer of solder balls 104.

FIG. 35B shows a cross-sectional drawing of another embodiment of a solder ball bridge assembly 100 comprising substrate 110, mounted device 102, and solder ball bridge 101 wherein the solder ball bridge 101 is formed from small diameter solder balls for which the solder ball diameter is comparable to the distance separating a bond pad 130 on the mounted device 102 and a bond pad 130 on the substrate 110 to which the terminal ends of the solder ball bridge 101 are coupled. In the embodiment, the length of the solder ball bridge 101 is significantly greater than the diameter of the solder ball 104 on account of the large area of the bond pads 130.

The solder ball bridge 104 in FIG. 35B is configured having a plurality of layers wherein the plurality of layers of solder balls 104 are stacked without lateral displacement of the solder balls in the individual stacks. The solder balls stacks are shown having minimal merging of the solder balls for clarity although vertical and lateral melding of the stacked solder balls is within the scope of embodiments configured having solder balls of relatively small diameter in comparison to the length of the solder ball bridge 101.

FIG. 35C shows a schematic top view drawing of the embodiment of the solder ball bridge assembly 100 shown in FIG. 35B. In the top view drawing, top views of the solder ball bridge 101 comprised of a plurality of laterally positioned rows of solder balls 104 of FIG. 35B are shown in relation to mounted device 102 and the bond pad 130 thereon, and the bond pad 130 on the substrate 110 in this embodiment. In other embodiments, other quantities and configurations of solder balls 104 may be used. In the embodiment shown in FIG. 35C, for example, the solder balls 104 are arranged in a linear configuration between the bond pad on the mounted device 102 and the bond pad 130 on the substrate 110. In other embodiments, the solder balls 104 may not be aligned having a straight linear path between the bond pad on the mounted device 102 and the bond pad 130 on the substrate 110. Top view profiles may, for example, be L-shaped, may be curved, and may have one or more of linear, curved, and L-shaped sections to form the solder ball connection between the bond pad 130 on the mounted device 102 and the bond pad 130 on the substrate 110. In the embodiment shown in FIG. 35B, each row of solder balls is shown having the same number of solder balls 104. In other embodiments, the number of solder balls in one or more rows may be different. The number of stacked solder balls used in each layer of solder balls may also differ in some embodiments. Lateral rows and vertical layers of solder balls need not have the same number of solder balls 104 in embodiments.

FIG. 35D shows a cross-sectional drawing of another embodiment of a solder ball bridge assembly 100 comprising substrate 110, mounted device 102, and solder ball bridge 101 wherein the solder ball bridge is formed from small diameter solder balls in relation to the length of the solder ball bridge 101 and for which the solder balls 104 are stacked to enable higher density stacking of the solder balls 104. In the embodiment shown in FIG. 35D, the solder balls 104 are not stacked directly upon the underlying solder balls but rather the solder balls 104 in a particular row are offset in relation to the underlying solder balls 104 to enable a greater packing density and overlapping of the solder material. An example offset may be, for example, the placement of a solder ball in an overlying row within a central location of four solder balls in an underlying row such that the overlying solder ball forms a simultaneous contact with four solder balls in the underlying row. Other configurations of improving the density of solder balls in a multilayer solder ball bridge 101 by offsetting the placement of solder balls 104 may also be used. Offsetting of the solder balls in a second row can facilitate the filling of gaps between solder balls 104 and between bond pads 130 and can significantly improve the anchoring of solder balls 104 to adjacent solder balls 104 in the underlying rows as described, for example, in conjunction with the embodiment shown in FIG. 13 wherein a solder ball 104 is positioned in an overlapping position between two previously deposited solder balls at a lower elevation in the solder ball bridge assembly 100. The spacing between solder ball 104₂ and 104₄ in FIG. 13 may be further reduced than as illustrated for overlapping solder balls 104 shown, for example, in FIG. 35D.

FIG. 35E shows the embodiment of the solder ball bridge assembly 100, as shown in FIG. 35D, comprising a substrate 110, a mounted device 102, and a solder ball bridge 101 for which heating has been applied to one or more of the solder balls 104, all or a portion of the bond pad 130ᵥ and all or a portion of another surface to which the solder ball bridge 101 is bonded. The heating may be provided one or more of before, during, and after deposition of the solder balls 104 such that the temperature of the solder in the solder ball bridge 101 during heating is at or in proximity to the melting temperature of the solder used in the solder ball bridge 101. FIG. 35E shows an illustration of the deformation of the solder balls 104 and the resulting solder ball bridge 101 as a result of the application of the heating for embodiments such as those shown in FIG. 35D.

### U-Shaped Bond Pads in Solder Ball Bridge Assemblies

In some embodiments of solder ball bridge assembly 101, U-shaped bond pads 130ᵤ may be used to facilitate distribution of the solder at the terminal ends of the solder ball bridges 101. In this section, example configurations of U-shaped bond pads 130ᵤ, and more generally the solder-wettable surfaces, used at the terminal ends of solder ball bridges are described.

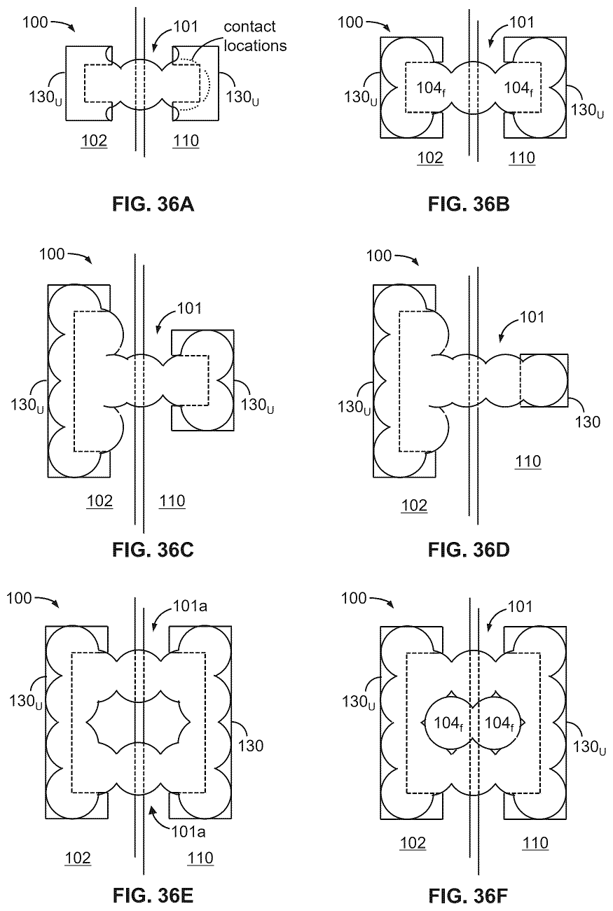

FIG. 36A shows a top view schematic drawing of an embodiment of a solder ball bridge assembly 100 wherein the bond pads 130 at the terminal end of solder ball bridge 101 are U-shaped bond pads 130. U-shaped bond pads 130ᵤ, as shown may facilitate improved distribution of the solder and enable improved coupling and anchoring of the bridging solder balls to the solder on the bond pads. The example configuration for the U-shaped bond pad 130ᵤ in FIG. 36A shows dotted lines labeled “contact locations” to identify locations of solder on the U-shaped bond pad 130ᵤ that may intersect with the solder ball subsequently placed onto solder mounded onto the U-shaped bond pads 130ᵤ using, for example, accompanying “high” energy sufficient to wet the U-shaped bond pad 130ᵤ. Additional contact locations may enable improved anchoring of solder balls 104 that are coupled to solder from previously deposited solder balls 104 on the bond pads 130ᵤ.

FIG. 36B shows a top view schematic drawing of another embodiment of a solder ball bridge assembly 100 wherein the bond pads are U-shaped bond pads 130ᵤ and a plurality of solder balls 104 are deposited onto the “U” portion of the U-shaped bond pad. Filler Solder balls 104f are shown substantially filling the volume between the legs of the U-shaped bond pad 130ᵤ. In some embodiments, the wetting action of the U-shaped bond pad 130ᵤ may act to prevent filling of the space between the legs of the “U” of the U-shaped bond pad until the volume of solder on the bond pad is sufficient to enable filling of the volume between the legs of the “U”. Some tradeoffs in the energy accompanying the deposited solder balls 104 may also be required to facilitate filling of the volume between the legs of the “U” of the U-shaped bond pads 130ᵤ.

FIG. 36C shows a top view schematic drawing of yet another embodiment of a solder ball bridge assembly 100 wherein one of the bond pads is a U-shaped bond pad 130ᵤ having a width that is approximately four times the diameter of the solder ball 104 used in the solder ball bridge 101 and one of the bond pads is U-shaped having a width that is approximately two times the diameter of the solder ball 104 used in the solder ball bridge 101. The embodiment shown in FIG. 36C shows the flexibility in the widths of the U-shaped bond pads 130ᵤ that may be used to facilitate improved anchoring of solder balls 104 with various configurations of bond pad sizes.

FIG. 36D shows a top view schematic drawing of yet another embodiment of a solder ball bridge assembly 100 wherein one of the bond pads at a terminal end of solder ball bridge 101 is a U-shaped bond pad 130_{c}. FIG. 36D shows the U-shaped bond pad 130ᵤ configured as in FIG. 36C on the mounted device 102 used in combination in the solder ball bridge assembly 100 with a rectangular shaped bond pad 130 on the substrate 110.

FIG. 36E shows a top view schematic drawing of yet another embodiment of a solder ball bridge assembly wherein the bond pads in the solder ball bridge assembly 100 are U-shaped bond pads 130_{c}. In the embodiment shown in FIG. 36E, a plurality of bridges are formed between the solder balls 104 on the U-shaped bond pads 130ᵤ on the mounted device 102 and the solder balls 104 on the U-shaped bond pads 130 on the substrate 110. The embodiment in FIG. 36E shows two solder ball bridges 101a, 101b in the solder ball bridge assembly 100. In other embodiments, more than two solder ball bridges 101 may be used in the solder ball bridge assembly 100.

FIG. 36F shows a top view schematic drawing of yet another embodiment of a solder ball bridge assembly 100 wherein the bond pads are U-shaped bond pads 130ᵤ. The configuration of solder balls 104 in the solder ball bridge assembly 100 are as shown in FIG. 36E with additional solder balls 104f used to fill all or a portion of the volume between the solder ball bridges 101a, 101b of the embodiment shown in FIG. 36E to enable formation of the single larger solder ball bridge 101 of FIG. 36F.

FIGS. 36A-36F show U-shaped bond pads 130ᵤ to facilitate improved anchoring of solder balls to embodiments of the solder ball bridge assembly 100. In other embodiments, other shaped bond pads may be used. Other bond pads that may provide advantages in some configurations of solder ball bridge assemblies may include H-shaped bond pads, C-shaped bond pads, L-shaped bond pads, I-shaped bond pads, B-shaped bond pads, D-shaped bond pads, E-shaped bond pads, O-shaped bond pads, T-shaped bond pads, V-shaped bond pads, W-shaped bond pads, among other shaped bond pads. Additionally, bond pads shapes may be formed from all or a portion of these bond pad shapes and combinations of these shapes. Other shapes may also be used to facilitate improved anchoring and coupling of solder balls in the formation of solder ball bridge assemblies 100 in embodiments. In some embodiments, solder-wettable materials may be used in place of all or a portion of the U-shaped and other shaped bond pads described herein.

Descriptions of improved coupling and anchoring of solder balls in deposited solder ball bridges 101, facilitated with U-shaped bond pads 130ᵤ, may be observed in other shaped bond pads that when coupled with suitable accompanying “low” or “high” energy levels of the deposited solder balls 104, facilitate improved anchoring of the solder balls in the formation of the solder ball bridge assemblies 100.

The U-shaped bond pads 130ᵤ and other shaped bond pads, may be used in embodiments of the solder ball bridge assembly 100 that are formed having vertically-oriented bond pads 130ᵥ and angled bond pads 130_{angle} at one or more terminal ends of a solder ball bridge 101. An example configuration of a solder ball bridge assembly 100 having an angled bond pad 130_{angle}, for example, is shown in the INSET in FIG. 1J.

### Methods of Formation of Solder Ball Assemblies

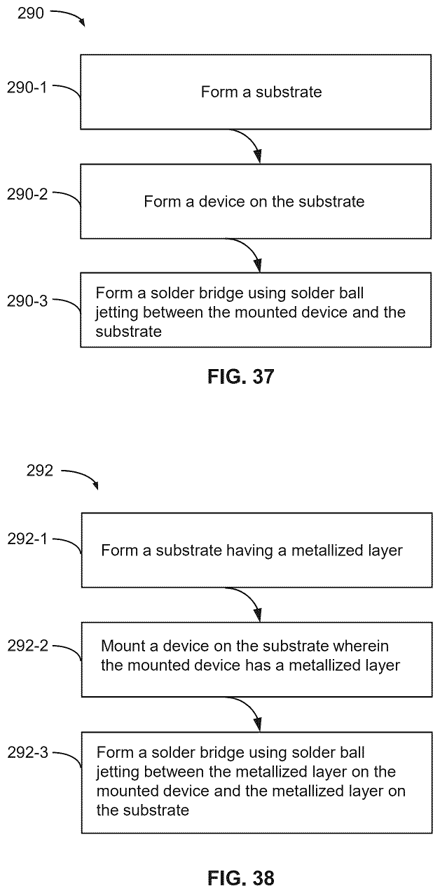

Some methods of formation of embodiments of solder ball bridge assembly 100 are described in FIGS. 37-40.

FIG. 37 shows a flowchart for a method of forming some embodiments of solder ball bridge assemblies 100 comprising substrate 110, mounted device 102 mounted or otherwise formed on the substrate, and a solder ball bridge 101 formed between the mounted device 102 and the substrate 110.

FIG. 37 shows a flowchart for a method 290 for the formation of some embodiments of solder ball bridge assembly 100. Step 290-1 of method 290 is a forming step in which a substrate 110 is formed.

A “substrate” as used herein refers to, but is not limited to, a mechanical support such as a semiconductor support structure such as a semiconductor wafer as is commonly used in semiconductor device fabrication. A “substrate” as used herein may also refer to, but is not limited to, a mechanical support formed from an insulator material such as an insulating wafer formed from an oxide, nitride, or carbide material. A “substrate” as used herein may also refer to, but is not limited to, a mechanical support formed from a metal material such as a metal wafer formed from a metal. A “substrate” as used herein may also refer to, but is not limited to, a mechanical support formed from one or more of a semiconductor layer, an insulating layer, and a metal layer. Insulating and semiconductor layers, in embodiments, may be formed in a combination in the form of, for example, a planar waveguide layer. Metal layers, in combination with insulating layers, may be formed, for example, to provide an electrical interconnect layer 103. Electrical devices such as a substrate upon which complementary metal oxide semiconductor devices may be used to form substrate 110 in some embodiments. Other circuitry may also be included in a substrate that forms a mechanical support in embodiments. In embodiments, a combination of layers of one or more of a semiconductor, insulator, and metal upon which devices and structures such as planar waveguide structures, semiconductor devices, optical devices, photonic devices, optoelectronic devices, electronic devices, and the like can be deposited, grown, mounted, placed, or otherwise formed and for which assemblies such as photonic integrated circuit assemblies 142 described herein may be formed may be used to form a substrate 110. In some embodiments, a substrate 110 may further include a substrate 110_{substrate} such as a semiconductor or other substrate as described herein, that forms a mechanical support for the formation of a substrate 110 having additional layers. In some embodiments, substrate 110 and substrate 110_{substrate} may be a same substrate. In some embodiments, substrate 110 may be an interposer substrate 210 comprising a planar waveguide layer 105 and an optional electrical interconnect layer 103.

Step 290-2 of method 290 is a forming step in which a mounted device 102 is formed or otherwise disposed on the substrate 110. In some embodiments, a mounted device 102 may be formed on a substrate 110, for example, by mounting a mounted device 102 on a substrate 110. Mounting of a mounted device 102 may be performed, for example, via a flip chip process in which a mounted device 102 having one or more metal contacts are aligned and coupled to one or more metal contacts on the substrate 110. In some embodiments, mounted devices 102 may not have underlying electrical contacts. In these and other embodiments, a mounted device 102 may be formed on the substrate 110 by one or more of bonding, adhering, gluing, epoxying, alloying, fusing, mounting, a mounted device 102 onto substrate 110, among other methods of adjoining, affixing, and providing a permanent or temporary coupling of mounted device 102 and substrate 110. In yet other embodiments, a mounted device 102 may be formed on a substrate 110 by a sequence of patterning and deposition steps to fabricate all or a portion of mounted device 102 on the substrate 110. In yet other embodiments, all or a portion of a mounted device 102 may be one or more of epitaxially grown, deposited, layered, or otherwise formed on the substrate 110. A first portion of a mounted device 102 may be bonded to a substrate 110 and a remaining portion may be fabricated using a sequence of patterning and deposition steps to form mounted device 102 in some embodiments.

Step 290-3 of method 290 is a forming step in which a solder ball bridge 101 is formed using a solder ball jetting apparatus 164, wherein a first terminal end of a solder ball bridge is formed between a mounted device 102 and the substrate 110 upon which the mounted device 102 is disposed. A solder ball bridge 101 may be formed, for example, by a sequential deposition of solder balls 104 between the terminal locations on a substrate 110 and a mounted device 102. In some embodiments, heating may be applied to the solder ball 104 to facilitate one or more of bonding, filling, shaping, among other attributes of the solder ball bridge 101. In some embodiments, the terminal end of a solder ball bridge 101 may be further extended to form additional solder ball bridges 101 to other devices 102 and other locations on the substrate 110 as described herein.

FIG. 38 shows a flowchart for a method of forming some embodiments of solder ball bridge assemblies 100 wherein the solder ball bridge assemblies 100 comprise substrate 110 having a metallized layer, a mounted device 102 having a metallized layer mounted or otherwise formed on the substrate 110, and a solder ball bridge 101 formed between the metallized layers of the mounted device 102 and the substrate 110.

FIG. 38 shows a flowchart for a method 292 for the formation of other embodiments of solder ball bridge assembly 100. In some embodiments, metallization layers may be provided on one or more of a mounted device 102 and substrate 110 to facilitate the disposition of the mounted device 102 onto the substrate 110 and to facilitate the providing of terminal locations on one or more of the substrate 110 and mounted device 102. Metal layers on the mounted device 102 may be formed on the downward-facing surface, for example, to facilitate the mounting of the mounted device 102 onto complementary metal layers on the substrate 110 and on the upward-facing surfaces to facilitate the formation of a solder ball bridge 101 on all or a portion of the mounted device 102. A downward-facing surface, as used herein, refers to the surface of the mounted device 102 disposed on the substrate 110 that faces the upward facing surface of the substrate 110 to which the mounted device 102 is mounted or otherwise disposed.

Step 292-1 of method 292 is a forming step in which a substrate 110 is formed, wherein the substrate 110 has a metallized layer. In embodiments, the metallized layer may be patterned to form one or more bond pads 130 in a first portion of the substrate 110 to couple one or more of one or more bond pads, contact pads, electrical interconnects, solder bump, solder layer, or other form of metal contact of a mounted device 102, and in a second portion of the substrate 110 to form one or more bond pads, contact pads, electrical interconnects, solder bump, or solder layer, or other form of metal contact on which a portion of a solder ball bridge 101 may be formed. The first portion of the substrate 110 may be formed in an optional cavity 148 formed in the substrate 110.

Step 292-2 of method 292 is a mounting step in which a mounted device 102 having one or more of one or more bond pads, contact pads, electrical interconnects, solder bump, solder layer, or other form of metal contact is mounted on the substrate. Mounting of a mounted device 102 onto the substrate 110 is performed using the first portion of the substrate 110 as described in Step 292-1 of method 292 wherein all or a portion of a metal feature of the downward-facing surface of the mounted device 102 is brought into contact with an upward-facing feature of the substrate 110. Mounting of a mounted device 102 onto the substrate 110 forms an assembly comprising a substrate 110 and a mounted device 102 on the substrate 110.

Step 292-3 of method 292 is a forming step in which a solder ball bridge 101 is formed using a solder ball jetting apparatus such as solder ball jetting apparatus 164, wherein the solder ball bridge 101 is formed between all or a portion of upward-facing portion of a mounted device 102 and all or a portion of a metal layer on the substrate 110 upon which the mounted device 102 is disposed. A solder ball bridge 101 may be formed, for example, by a sequential deposition of solder balls 104 between a terminal location on a substrate 110 and at least a portion of an upward-facing surface of mounted device 102. In some embodiments, heating may be applied to the solder ball 104 prior to or after deposition to facilitate one or more of bonding, filling, shaping, among other attributes of the solder ball bridge 101.

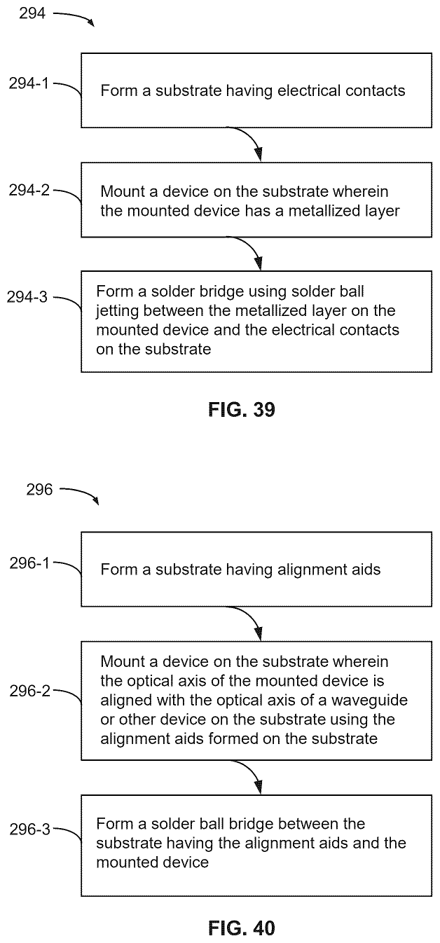

FIG. 39 shows a flowchart for a method of forming some embodiments of solder ball bridge assemblies 100 wherein the solder ball bridge assemblies 100 comprise a substrate 110 having electrical contacts, a mounted device 102 mounted or otherwise formed on the substrate wherein the mounted device 102 includes a metallized layer, and a solder ball bridge 101 formed between the metallized layers of the mounted device 102 and the electrical contacts of the substrate 110.

FIG. 39 shows a flowchart for a method 294 for the formation of yet other embodiments of solder ball bridge assembly 100.

Step 294-1 of method 294 is a forming step in which a substrate 110 is formed, wherein the substrate 110 has electrical contacts. Electrical contacts may be formed on a surface of the substrate 110 to facilitate interconnection of devices 102 and other devices on, and coupled to, the substrate 110 using solder ball bridges 101.

Step 294-2 of method 294 is a mounting step in which a mounted device 102 having a metallized layer on a downward-facing surface is mounted on the substrate 110 having upward-facing electrical contacts. A metallized layer in embodiments, may be, for example, a bond pad 130. In other embodiments, a metallized layer on the mounted device 102 may be one or more of a solder layer, a solder bump, and other metal layer.

Step 294-3 of method 294 is a forming step in which a solder ball bridge 101 is formed using a solder ball jetting apparatus, wherein the solder ball bridge 101 is formed between a metallized layer formed on a mounted device 102 and electrical contacts formed on the substrate 110.

FIG. 40 shows a flowchart for a method 296 for the formation of yet other embodiments of solder ball bridge assembly 100.

FIG. 40 shows a flowchart for a method of forming some embodiments of solder ball bridge assemblies 100 wherein the solder ball bridge assemblies 100 comprise a substrate 110 having alignment aids formed in a cavity 148, a mounted device 102 receptive to the alignment aids mounted in the cavity 148 of substrate 110, and a solder ball bridge 101 formed between the substrate 101 having the alignment aids and the mounted device 102 mounted in the cavity 148. In some embodiments, substrate 110 may be an interposer substrate 210.

Step 296-1 of method 296 is a forming step in which a substrate 110 is formed, wherein the substrate 110 has alignment features. Alignment features may include, for example, one or more of vertical alignment pillars, lateral alignment aids to aid in the positioning of one or more devices onto substrate 110, alignment aids for the alignment of fiber optic cables, fiducials, among other alignment aids. Alignment aids formed on substrate may be used to align one or more of a vertical component of an optical axis and a lateral component of an optical axis. Coupled with a self-aligned fiducial, as described herein, lateral alignment aids may facilitate precise positioning of mounted devices 102 onto substrate 110. In some embodiments, devices 102, mounted on, or within, alignment features formed on substrate 110, may firstly be brought into alignment using alignment features, and then having been brought into alignment, may secondly have solder ball bridge 101 formed between the mounted device 102 and the substrate 110.

Alignment aids may be formed on a substrate 110 to facilitate alignment of devices 102 mounted or otherwise formed on the alignment aids, and to facilitate the subsequent interconnection of the devices 102 to the substrate 110 using solder ball bridges 101.

Step 296-2 of method 296 is a mounting step in which a mounted device 102 is mounted on, or within, alignment aids formed on the substrate 110, to facilitate alignment of the optical axis of the mounted device with an optical axis of a waveguide or other device or feature of the substrate 110. Alignment of the optical axis of the mounted device may include one or more of a vertical and a lateral component of an optical axis.

Step 296-3 of method 296 is a forming step in which a solder ball bridge 101 is formed using a solder ball jetting apparatus, wherein the solder ball bridge 101 is formed between the substrate 110 and a mounted device 102 having alignment aids.

Embodiments of solder ball bridge assemblies 100 comprising substrate 110, mounted device 102 disposed on substrate 110, and a solder ball bridge 101 formed between the mounted device 102 and the substrate 110 have been described herein. Solder ball bridge 101 in some embodiments, facilitates the transfer of thermal energy from mounted device 102 to the substrate 110. In some embodiments, solder ball bridge 101 is coupled to a heat sink that further facilitates the dissipation of thermal energy from mounted device 102 to the substrate 110. In yet other embodiments, solder ball bridge 101 forms an electrical interconnect between the mounted device 102 and an electrical contact formed or otherwise disposed on the substrate 110. Electrical connections formed from solder balls 104 enable the formation of low resistance connections that are also low in inductance in comparison to interconnects formed by wire bonding techniques for which lengthier connections are often formed using narrower wire diameters. Embodiments of solder ball bridge assemblies 100 can be formed using full wafer processing, in that unsingulated wafers may be utilized with solder ball jetting apparatus which is typically not available in commercial wire bonders. The formation of solder ball bridge assemblies 100 using solder ball jetting apparatus, may also eliminate mechanical stress that may be introduced from the attachment of wire bonds onto a mounted device. In embodiments having a device such as a mounted device 102 disposed on a substrate such as substrate 110, the application of a wire bond may lead to the introduction of mechanical stress upon contact of the wire bonding apparatus with the mounted device 102 and the resulting applied forces associated with the wire bonding process when wire bonds are formed with a mounted device 102 disposed on a substrate. The ultrasonic energy that is typically used to secure the wire and to form the wire bond with a contact pad on a mounted device in the formation of wire bonds, may also be avoided in the formation of embodiments of solder ball bridge assemblies 100. Wire bonds must often be made exceedingly long in relation to the diameter of the wire resulting in interconnections having unnecessarily high inductance values. The short bulky connections provided in embodiments of solder ball bridge assemblies 100 using solder ball bridges 101 enables low resistance connections having lower inductance in comparison to wire bonded interconnects.

The lateral connections formed from solder ball bridges 101 between the various configurations of bond pads on substrates 110 and mounted devices 102 described herein use a placement and anchoring approach as described herein, for example, in conjunction with the descriptions of, for example, FIGS. 1A-1J, FIGS. 5A-5F. FIGS. 6A-6F. FIGS. 7A-7H, FIGS. 8A-8D, FIGS. 9A-9D, FIGS. 10A-10B, FIGS. 11A-11B, FIGS. 12A-12B, FIG. 13, FIGS. 14A-14B, FIGS. 15A-15D. The formation of the solder ball bridges 101, using the structures and methods described herein, enables the coupling and interconnection of bond pads 130 on mounted devices 102 with bond pads 130 on substrate 110 that provide low electrical resistance, low inductance, and high thermal conductivity.

Effective electrical and thermal interconnectivity is an essential component used in the formation of photonic integrated circuit assemblies and for the formation of electrical circuits in general, and the lateral anchoring of one or more solder balls together using wafer level solder ball jetting enables the formation of these high electrical and thermal conductivity interconnections over non-solder-wettable surfaces.

Solder ball bridge assemblies 100 that include substrate 110, mounted device 102, and solder ball bridge 101 are described herein for substrates that include interposer structures having a planar waveguide layer and an optional electrical interconnect layer, interposer structures having a planar waveguide layer that further includes alignment aids formed in cavities in the planar waveguide layer and elsewhere in photonic integrated circuit assemblies, among other substrates.

The foregoing descriptions of embodiments have been presented for purposes of illustration and description and are not intended to be exhaustive or to limit embodiments to the forms disclosed. Modifications to, and variations of, the disclosed embodiments will be readily apparent to those skilled in the art, and the general principles defined herein may be applied to other embodiments without departing from the spirit and scope of the embodiments disclosed herein. Thus, embodiments should not be limited to those specifically described herein but rather are to be accorded the widest scope consistent with the principles and features disclosed herein.

What is claimed is:

1. A method comprising
forming a first solder-wettable surface area on a planar surface of a substrate;
assembling a device on the substrate,
wherein the device comprises a second solder-wettable surface area,
wherein the second solder-wettable surface area is disposed substantially parallel to the planar surface of the substrate;
forming a solder bridge connecting the first and second solder-wettable surface areas,
wherein the solder bridge is bonded with the first and second solder-wettable surface areas,
wherein forming the solder bridge comprises disposing a solder ball to be solidified or more than one solder balls to be solidified and fused together.

2. A method as in claim 1,
wherein forming the solder bridge comprises configuring the solder bridge to function as at least a portion of a heat sink for the device.

3. A method as in claim 1,
wherein one of
forming the solder bridge comprises disposing two first solder balls each on the first and second solder-wettable surface areas and one or more second solder balls connecting the two first solder balls, or
forming the solder bridge comprises disposing at least two third solder balls fused to each other along a direction between the first and second solder-wettable surface areas on the planar surface, with forming the solder bridge further comprising disposing at least a fourth solder ball stacked on a third solder ball of the at least two third solder balls.

4. A method as in claim 1, further comprising
forming a dielectric layer on the solder bridge, with the dielectric layer configured to constrain the solder bridge during an anneal process of the solder bridge.

5. An assembly as in claim 1,
wherein forming the solder bridge comprises only disposing the solder ball with the solder ball, after being solidified, connecting the first and second solder-wettable surface areas.

6. A method comprising
forming a first solder-wettable surface area on a first portion of a planar surface of the substrate;
forming a cavity on a second portion of the planar surface;
forming a device in the cavity,
wherein the device comprises a second solder-wettable surface area;
forming a solder bridge connecting the first and second solder-wettable surface areas,
wherein the solder bridge is disposed across a gap formed by the cavity between the device and the substrate,
wherein forming the solder bridge comprises disposing multiple solder balls to be solidified and fused together.

7. A method as in claim 6, further comprising
forming an electrical interconnect layer on the substrate under the device,
wherein the electrical interconnect layer comprises an electrical interconnection line connected to the first solder-wettable surface area or to a terminal pad of the device.

8. A method as in claim 6, further comprising
forming an electrical interconnect layer on the substrate under the device,
wherein the electrical interconnect layer comprises an electrical interconnection line comprising a thermal conductive material to function as a heat sink.

9. A method as in claim 6,
wherein forming the solder bridge comprises configuring the solder bridge to function as a heat sink or at least as a portion of a heat sink for the device.

10. A method as in claim 6, further comprising
forming a trench on the substrate before forming the first solder-wettable surface area at a bottom of a trench on the substrate,
wherein the two or more at least partially molten solder balls fill the trench for the solder bridge to function as a heat sink.

11. A method as in claim 6,
wherein forming the solder bridge comprises disposing at least one of multiple rows or multiple stacks of solder balls configured to increase at least one of a thermal conductivity or an electrical conductivity of the solder bridge.

12. An assembly as in claim 6,
wherein the solder bridge comprises at least two solder balls of different sizes.

13. A method as in claim 6, further comprising
forming one or more alignment aids in the cavity,
wherein the one or more alignment aids are configured to passively align the device to an optical or optoelectronic element on the substrate.

14. A method as in claim 6,
wherein the first solder wettable surface area is substantially parallel to the planar surface of the substrate,
wherein the second solder wettable surface area is substantially parallel or substantially perpendicular to the planar surface of the substrate.

15. A method as in claim 6,
wherein the device comprises one of a laser or a photodiode.

16. A method as in claim 6,
wherein the device comprises a photodiode,
wherein the photodiode is assembled in the cavity such that the second solder wettable surface area is substantially perpendicular to the planar surface of the substrate.

17. A method as in claim 6, further comprising
forming a wire bond connecting a terminal pad on the device with a terminal pad on the planar surface of the substrate.

18. A method as in claim 6, further comprising
forming one or more sets of elements on the substrate, with a set of the one or more sets of elements comprising a first solder-wettable surface area, a cavity, a device comprising a second solder-wettable surface area, and a solder bridge connecting the first and second solder-wettable surface areas.

19. A method as in claim 6, further comprising
forming a third solder-wettable surface on one or more of a high thermal conductivity layer, an electrically conductive layer, a metal filled trench, or a solder ball array,
extending the solder bridge to the third solder-wettable surface.

20. A method of providing solder bridges for integrated circuit assemblies in wafer level processing, the method comprising
forming multiple first solder-wettable surface areas on a substrate;
assembling multiple integrated circuits on the substrate,
wherein each integrated circuit of the multiple integrated circuits comprises a second solder-wettable surface area corresponded to a first solder-wettable surface area of the multiple first solder-wettable surface areas;
forming multiple solder bridges, with each solder bridge connecting the first solder-wettable surface area and the second solder-wettable surface area,
wherein the solder bridge is bonded with the first and second solder-wettable surface areas,
wherein forming the each solder bridge comprises disposing multiple solder balls to be solidified and fused together.
